(19) United States
(12) Patent Application Publication
(10) Pub. No.: US 2026/0247717 A1
(43) Pub. Date: Aug. 20, 2026

(54) SEMICONDUCTOR DEVICE AND METHOD FOR MANUFACTURING SEMICONDUCTOR DEVICE

(71) Applicant: SEMICONDUCTOR ENERGY LABORATORY CO., LTD., Atsugi-shi, Kanagawa-ken (JP)

(72) Inventors: Masataka NAKADA, Tochigi, Tochigi (JP); Yukinori SHIMA, Tatebayashi, Gunma (JP); Masayoshi DOBASHI, Shimotsuga, Tochigi (JP); Junichi KOEZUKA, Tochigi, Tochigi (JP); Masami JINTYOU, Shimotsuga, Tochigi (JP)

(21) Appl. No.: 19/162,551

(22) PCT Filed: Mar. 4, 2024
(86) PCT No.: PCT/IB2024/052049

§ 371 Date: Sep. 5, 2025

(30) Foreign Application Priority Data
Mar. 10, 2023 (JP) 2023-038008

(51) Int. Cl. H10D 86/40; H10D 30/01; H10D 30/67; H10D 86/01; H10D 86/60; H10H 29/32; H10K 59/121

(52) U.S. Cl. CPC H10D 86/471; H10D 30/0312; H10D 30/0318; H10D 30/6728; H10D 30/6731; H10D 30/6734; H10D 30/6736; H10D 86/0221; H10D 86/431; H10D 86/481; H10D 86/60; H10H 29/32; H10K 59/1213

(57) ABSTRACT

A semiconductor device that occupies a small area is provided. The semiconductor device includes a first transistor, a second transistor, and a first insulating layer. The first transistor includes a first conductive layer, a second conductive layer, and a first semiconductor layer. The second transistor includes a third conductive layer over the first insulating layer, a second insulating layer in contact with a top surface and a side surface of the third conductive layer and a top surface of the first insulating layer, a third insulating layer over the second insulating layer, and a second semiconductor layer over the third insulating layer. The first insulating layer is provided over the first conductive layer. The first insulating layer and the second insulating layer include a first opening reaching the first conductive layer. The second conductive layer is provided over the second insulating layer. The second conductive layer includes a second opening in a region overlapping with the first opening. In the first opening and the second opening, the first semiconductor layer is in contact with a top surface of the first conductive layer, a side surface of the first insulating layer, a side surface of the second insulating layer, and a side surface of the second conductive layer.

### TECHNICAL FIELD

One embodiment of the present invention relates to a semiconductor device and a manufacturing method thereof. One embodiment of the present invention relates to a transistor and a manufacturing method thereof. One embodiment of the present invention relates to a display apparatus including a semiconductor device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

In this specification and the like, a semiconductor device refers to a device that utilizes semiconductor characteristics, and means a circuit including a semiconductor element (a transistor, a diode, a photodiode, or the like), a device including the circuit, and the like. The semiconductor device also means all devices that can function by utilizing semiconductor characteristics. For example, an integrated circuit, a chip including an integrated circuit, and an electronic component including a chip in a package are examples of the semiconductor device. Moreover, a memory device, a display apparatus, a light-emitting apparatus, a lighting device, and an electronic device themselves are semiconductor devices and each of them includes a semiconductor device in some cases.

### BACKGROUND ART

Semiconductor devices including transistors are applied to a wide range of electronic devices. In addition, uses for a display apparatus are diversified in recent years, and for example, the display apparatus is used for a portable information terminal, a television device (also referred to as a television receiver), digital signage, a PID (Public Information Display), and the like. Examples of the display apparatus include a display apparatus including an organic EL (Electro Luminescence) element or a light-emitting diode (LED), a display apparatus including a liquid crystal element, and electronic paper performing display by an electrophoretic method.

In a display apparatus, when the area occupied by transistors is reduced, the pixel size can be reduced and resolution can be increased. Furthermore, when the area occupied by transistors is reduced, the aperture ratio can be increased. Thus, minute transistors have been required.

As devices requiring high-resolution display apparatuses, for example, devices for virtual reality (VR), augmented reality (AR), substitutional reality (SR), or mixed reality (MR) have been actively developed.

Patent Document 1 discloses a high-resolution display apparatus using an organic EL element.

### REFERENCE

### Patent Document

[Patent Document 1] PCT International Publication No. 2016/038508

### SUMMARY OF THE INVENTION

### Problems to be Solved by the Invention

An object of one embodiment of the present invention is to provide a semiconductor device including a transistor having a minute size. Another object is to provide a semiconductor device including a transistor having a short channel length. Another object is to provide a semiconductor device including a transistor having a high on-state current. Another object is to provide a semiconductor device including a transistor having a short channel length and a transistor having a long channel length. Another object is to provide a semiconductor device including a transistor having favorable electrical characteristics. Another object is to provide a semiconductor device that occupies a small area. Another object is to provide a semiconductor device having low wiring resistance. Another object is to provide a semiconductor device or a display apparatus having low power consumption. Another object is to provide a semiconductor device or a display apparatus including a transistor having high reliability. Another object is to provide a high-resolution display apparatus. Another object is to provide a method for manufacturing a semiconductor device or a display apparatus having high productivity. Another object is to provide a semiconductor device or a display apparatus including a novel transistor, and manufacturing methods thereof.

Note that the description of these objects does not preclude the existence of other objects. One embodiment of the present invention does not necessarily achieve all of these objects. Other objects can be derived from the description of the specification, the drawings, and the claims.

### Means for Solving the Problems

One embodiment of the present invention is a semiconductor device including a first transistor, a second transistor, and a first insulating layer. The first transistor includes a first conductive layer, a second conductive layer, and a first semiconductor layer. The second transistor includes a third conductive layer over the first insulating layer, a second insulating layer in contact with a top surface and a side surface of the third conductive layer and a top surface of the first insulating layer, a third insulating layer over the second insulating layer, and a second semiconductor layer over the third insulating layer. The first insulating layer is provided over the first conductive layer. The first insulating layer and the second insulating layer include a first opening reaching the first conductive layer. The second conductive layer is provided over the second insulating layer. The second conductive layer includes a second opening in a region overlapping with the first opening. In the first opening and the second opening, the first semiconductor layer is in contact with a top surface of the first conductive layer, a side surface of the first insulating layer, a side surface of the second insulating layer, and a side surface of the second conductive layer.

In the semiconductor device, the first semiconductor layer preferably includes a region in contact with a top surface of the second conductive layer.

In the semiconductor device, the first semiconductor layer is preferably not in contact with the third insulating layer.

In the semiconductor device, the first semiconductor layer and the second semiconductor layer each preferably include a metal oxide.

In the semiconductor device, the first insulating layer preferably includes a fourth insulating layer and a fifth insulating layer over the fourth insulating layer. The fourth insulating layer preferably includes an oxide or an oxynitride. The second insulating layer and the fifth insulating layer each preferably include a nitride or a nitride oxide.

In the semiconductor device, the second insulating layer preferably includes a region having a larger amount of hydrogen than the fifth insulating layer.

In the semiconductor device, a fourth insulating layer is preferably included. A top surface of the fourth insulating layer is preferably in contact with a bottom surface of the first conductive layer. The first insulating layer preferably includes a fifth insulating layer and a sixth insulating layer over the fifth insulating layer. The sixth insulating layer preferably includes an oxide or an oxynitride. The fourth insulating layer and the fifth insulating layer each preferably include a nitride or a nitride oxide.

In the semiconductor device, the fourth insulating layer preferably includes a region having a larger amount of hydrogen than the fifth insulating layer.

In the semiconductor device, a capacitor is preferably included. The capacitor preferably includes the second conductive layer, the third conductive layer, and the second insulating layer interposed between the second conductive layer and the third conductive layer.

One embodiment of the present invention is a method for manufacturing a semiconductor device. The method includes forming a first conductive layer; forming a first insulating film over the first conductive layer; forming a second conductive layer over the first insulating film; forming a second insulating film over the first insulating film and the second conductive layer; forming, over the second insulating film, a third conductive layer including a region overlapping with the first conductive layer; forming, over the second insulating film, a first insulating layer including a region overlapping with the second conductive layer; processing the third conductive layer to form a fourth conductive layer including a first opening; processing the first insulating film and the second insulating film to form a second insulating layer and a third insulating layer that include a second opening reaching the first conductive layer; forming a first semiconductor layer in contact with a top surface of the first conductive layer, a side surface of the second insulating layer, a side surface of the third insulating layer, and a side surface of the fourth conductive layer in the first opening and the second opening and forming, over the first insulating layer, a second semiconductor layer including a region overlapping with the second conductive layer; forming a fourth insulating layer over the first semiconductor layer and the second semiconductor layer; and forming a fifth conductive layer including a region overlapping with the first semiconductor layer and forming a sixth conductive layer including a region overlapping with the second semiconductor layer over the fourth insulating layer.

### Effect of the Invention

One embodiment of the present invention can provide a semiconductor device including a transistor having a minute size. Alternatively, a semiconductor device including a transistor having a short channel length can be provided. Alternatively, a semiconductor device including a transistor having a high on-state current can be provided. Alternatively, a semiconductor device including a transistor having a short channel length and a transistor having a long channel length can be provided. Alternatively, a semiconductor device including a transistor having favorable electrical characteristics can be provided. Alternatively, a semiconductor device that occupies a small area can be provided. Alternatively, a semiconductor device having low wiring resistance can be provided. Alternatively, a semiconductor device or a display apparatus having low power consumption can be provided. Alternatively, a semiconductor device or a display apparatus including a transistor having high reliability can be provided. Alternatively, a high-resolution display apparatus can be provided. Alternatively, a method for manufacturing a semiconductor device or a display apparatus having high productivity can be provided. Alternatively, a semiconductor device or a display apparatus including a novel transistor, and manufacturing methods thereof can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIG. 1A is a top view illustrating an example of a semiconductor device. FIG. 1B and FIG. 1C are cross-sectional views illustrating the example of the semiconductor device.

FIG. 2A and FIG. 2B are perspective views illustrating an example of a semiconductor device.

FIG. 3 is a cross-sectional view illustrating an example of a semiconductor device.

FIG. 4A is a top view illustrating an example of a semiconductor device. FIG. 4B is a cross-sectional view illustrating the example of the semiconductor device.

FIG. 5 is a cross-sectional view illustrating an example of a semiconductor device.

FIG. 6A is a top view illustrating an example of a semiconductor device. FIG. 6B and FIG. 6C are cross-sectional views illustrating the example of the semiconductor device.

FIG. 7A is a top view illustrating an example of a semiconductor device. FIG. 7B is a cross-sectional view illustrating the example of the semiconductor device.

FIG. 8A is a top view illustrating an example of a semiconductor device. FIG. 8B is a cross-sectional view illustrating the example of the semiconductor device.

FIG. 9A and FIG. 9B are cross-sectional views illustrating an example of a semiconductor device.

FIG. 10A and FIG. 10B are cross-sectional views illustrating an example of a semiconductor device.

FIG. 11A to FIG. 11C are cross-sectional views illustrating examples of a semiconductor device.

FIG. 12A is a top view illustrating an example of a semiconductor device. FIG. 12B and FIG. 12C are cross-sectional views illustrating the example of the semiconductor device.

FIG. 13A to FIG. 13C are cross-sectional views illustrating an example of a semiconductor device.

FIG. 14A and FIG. 14B are cross-sectional views illustrating an example of a semiconductor device.

FIG. 15A to FIG. 15C are cross-sectional views illustrating an example of a semiconductor device.

FIG. 16A to FIG. 16C are cross-sectional views illustrating an example of a semiconductor device.

FIG. 17A to FIG. 17C are cross-sectional views illustrating an example of a semiconductor device.

FIG. 18 is a cross-sectional view illustrating an example of a semiconductor device.

FIG. 19A and FIG. 19B are cross-sectional views illustrating an example of a semiconductor device.

FIG. 20A is a top view illustrating an example of a semiconductor device. FIG. 20B is a cross-sectional view illustrating the example of the semiconductor device.

FIG. 21A and FIG. 21B are cross-sectional views illustrating examples of a semiconductor device.

FIG. 22A is a top view illustrating an example of a semiconductor device. FIG. 22B and FIG. 22C are cross-sectional views illustrating the example of the semiconductor device.

FIG. 23A and FIG. 23B are equivalent circuit diagrams of a semiconductor device. FIG. 23C is a top view illustrating an example of the semiconductor device.

FIG. 24 is a cross-sectional view illustrating an example of a semiconductor device.

FIG. 25 is a perspective view illustrating an example of a semiconductor device.

FIG. 26A to FIG. 26D are perspective views illustrating an example of a semiconductor device.

FIG. 27A and FIG. 27B are equivalent circuit diagrams of a semiconductor device. FIG. 27C is a top view illustrating an example of the semiconductor device.

FIG. 28 is a cross-sectional view illustrating an example of a semiconductor device.

FIG. 29 is a perspective view illustrating an example of a semiconductor device.

FIG. 30A to FIG. 30D are perspective views illustrating an example of a semiconductor device.

FIG. 31A to FIG. 31D are cross-sectional views illustrating an example of a method for manufacturing a semiconductor device.

FIG. 32A to FIG. 32C are cross-sectional views illustrating an example of a method for manufacturing a semiconductor device.

FIG. 33A to FIG. 33C are cross-sectional views illustrating an example of a method for manufacturing a semiconductor device.

FIG. 34A to FIG. 34C are cross-sectional views illustrating an example of a method for manufacturing a semiconductor device.

FIG. 35A and FIG. 35B are cross-sectional views illustrating an example of a method for manufacturing a semiconductor device.

FIG. 36A and FIG. 36B are cross-sectional views illustrating an example of a method for manufacturing a semiconductor device.

FIG. 37A to FIG. 37C are cross-sectional views illustrating an example of a method for manufacturing a semiconductor device.

FIG. 38A is a perspective view illustrating an example of a display apparatus. FIG. 38B is a block diagram illustrating the example of the display apparatus.

FIG. 39A is a circuit diagram of a latch circuit. FIG. 39B is a circuit diagram of an inverter circuit.

FIG. 40A and FIG. 40B are circuit diagrams of pixel circuits. FIG. 40C is a cross-sectional view illustrating an example of the pixel circuit.

FIG. 41 is a circuit diagram of a pixel circuit.

FIG. 42A and FIG. 42B are cross-sectional views illustrating examples of display apparatuses.

FIG. 43 is a cross-sectional view illustrating an example of a display apparatus.

FIG. 44A to FIG. 44C are cross-sectional views illustrating an example of a display apparatus.

FIG. 45A and FIG. 45B are cross-sectional views illustrating examples of display apparatuses.

FIG. 46 is a cross-sectional view illustrating an example of a display apparatus.

FIG. 47A to FIG. 47D are diagrams illustrating examples of electronic devices.

FIG. 48A to FIG. 48F are diagrams illustrating examples of electronic devices.

FIG. 49A to FIG. 49G are diagrams illustrating examples of electronic devices.

FIG. 50A and FIG. 50B are STEM images of a transistor of Example.

FIG. 51A and FIG. 51B are STEM images of a transistor of Example.

FIG. 52 is a diagram showing Id-Vg characteristics of transistors of Example.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and description thereof is not repeated. The same hatching pattern is used for portions having similar functions, and the portions are not especially denoted by reference numerals in some cases.

In this specification and the like, when a plurality of components are denoted by the same reference numerals, and in particular need to be distinguished from each other, an identification sign such as “_1”, “[n]”, or “[m, n]” is sometimes added to the reference numerals. Components denoted with identification signs such as “_1”, “[n]”, and “[m, n]” in the drawings and the like are sometimes described without such identification signs in this specification and the like when the components do not need to be distinguished from each other.

The position, size, range, or the like of each component illustrated in the drawings does not represent the actual position, size, range, or the like in some cases for easy understanding. Therefore, the disclosed invention is not necessarily limited to the position, size, range, or the like disclosed in the drawings.

In this specification and the like, ordinal numbers such as “first” and “second” are used for convenience and do not limit the number of components or the order of components (e.g., the order of steps or the stacking order of layers). An ordinal number used for a component in a certain part in this specification is not the same as an ordinal number used for the component in another part in this specification or the scope of claims in some cases.

Note that the term “film” and the term “layer” can be interchanged with each other depending on the case or circumstances. For example, the term “conductive layer” can be changed into the term “conductive film”. As another example, the term “insulating film” can be changed into the term “insulating layer”.

A transistor is a kind of semiconductor element and can achieve a function of amplifying current or voltage, a switching operation for controlling electrical continuity or discontinuity, and the like. An IGFET (Insulated Gate Field Effect Transistor) and a thin film transistor (TFT) are in the category of a transistor in this specification and the like.

Functions of a “source” and a “drain” are sometimes replaced with each other when a transistor of opposite polarity is used or when the direction of current is changed in circuit operation, for example. Thus, the terms “source” and “drain” can be used interchangeably in this specification and the like. Note that a source and a drain of a transistor can also be referred to as a source terminal and a drain terminal or a source electrode and a drain electrode, for example, as appropriate depending on circumstances.

A “gate” and a “back gate” can be interchanged with each other. Thus, the terms “gate” and “back gate” can be used interchangeably in this specification and the like. Note that a gate and a back gate of a transistor can also be referred to as a gate electrode and a back gate electrode, for example, as appropriate depending on circumstances.

In this specification and the like, “electrically connected” includes the case where connection is made through an “object having any electric function”. Here, there is no particular limitation on the “object having any electric function” as long as electric signals can be transmitted and received between components that are connected through the object. Examples of the “object having any electric function” include a switching element such as a transistor, a resistor, a coil, and other elements with a variety of functions as well as an electrode and a wiring.

Unless otherwise specified, off-state current in this specification and the like refers to leakage current between a source and a drain of a transistor in an off state (also referred to as a non-conduction state or a cutoff state). Unless otherwise specified, off state in an n-channel transistor refers to a state where a voltage V_{gs} between its gate and source is lower than a threshold voltage Vₜₕ (in a p-channel transistor, higher than Vₜₕ).

In this specification and the like, the expression “having substantially the same top surface shapes” means that the outlines of stacked layers at least partly overlap with each other. For example, the case of processing the upper layer and the lower layer with use of the same mask pattern or mask patterns that are partly the same is included. Note that, in some cases, the outlines do not completely overlap with each other and the upper layer is positioned inward from the lower layer or the upper layer is positioned outward from the lower layer; such a case is also described by the expression “having substantially the same top surface shapes”. The state of “having the same top surface shape” or “having substantially the same top surface shapes” can be rephrased as the state where “end portions are aligned with each other” or “end portions are substantially aligned with each other”.

In this specification and the like, a tapered shape refers to such a shape that at least part of the side surface of a component is inclined with respect to a substrate surface or a formation surface. For example, the tapered shape preferably includes a region where the angle formed by the inclined side surface and the substrate surface or the formation surface (such an angle is also referred to as a taper angle) is less than 90°. Note that the side surface, the substrate surface, and the formation surface of the component are not necessarily completely flat and may have a substantially planar shape with a small curvature or a substantially planar shape with slight unevenness.

In this specification and the like, a device manufactured using a metal mask or an FMM (fine metal mask, high-resolution metal mask) may be referred to as a device having an MM (metal mask) structure. In this specification and the like, a device manufactured without using a metal mask or an FMM is sometimes referred to as a device having an MML (metal maskless) structure. Note that a device having the MML (metal maskless) structure can be manufactured without using a metal mask, and thus can break through the resolution limit due to alignment accuracy of the metal mask. Furthermore, the device having the MML structure can eliminate the need for the manufacturing facilities for metal masks and the washing process for metal masks. In addition, the device having the MML structure can be manufactured at low cost, and thus is suitable for mass production.

In this specification and the like, a structure where light-emitting layers of light-emitting elements (also referred to as light-emitting devices) having different emission wavelengths are separately formed is sometimes referred to as an SBS (Side By Side) structure. The SBS structure can optimize materials and structures of light-emitting elements and thus can increase the degree of freedom in selecting materials and structures, so that the luminance and the reliability can be easily improved.

In this specification and the like, a hole or an electron is sometimes referred to as a “carrier”. Specifically, a hole-injection layer or an electron-injection layer may be referred to as a “carrier-injection layer”, a hole-transport layer or an electron-transport layer may be referred to as a “carrier-transport layer”, and a hole-blocking layer or an electron-blocking layer may be referred to as a “carrier-blocking layer”. Note that the above-described carrier-injection layer, carrier-transport layer, and carrier-blocking layer cannot be clearly distinguished from each other in some cases. One layer may have two or three functions of the carrier-injection layer, the carrier-transport layer, and the carrier-blocking layer in some cases.

In this specification and the like, a light-emitting element includes an EL layer between a pair of electrodes. The EL layer includes at least a light-emitting layer. Here, examples of layers (also referred to as functional layers) included in the EL layer include a light-emitting layer, carrier-injection layers (a hole-injection layer and an electron-injection layer), carrier-transport layers (a hole-transport layer and an electron-transport layer), and carrier-blocking layers (a hole-blocking layer and an electron-blocking layer). In this specification and the like, a light-receiving element (also referred to as a light-receiving device) includes at least an active layer functioning as a photoelectric conversion layer between a pair of electrodes. In this specification and the like, one of the pair of electrodes may be referred to as a pixel electrode and the other may be referred to as a common electrode.

In this specification and the like, a sacrificial layer (which may also be referred to as a mask layer) is positioned above at least a light-emitting layer (specifically, a layer processed into an island shape among layers included in an EL layer) and has a function of protecting the light-emitting layer in the manufacturing process.

In this specification and the like, step disconnection refers to a phenomenon in which a layer, a film, or an electrode is split because of the shape of the formation surface (e.g., a step).

### Embodiment 1

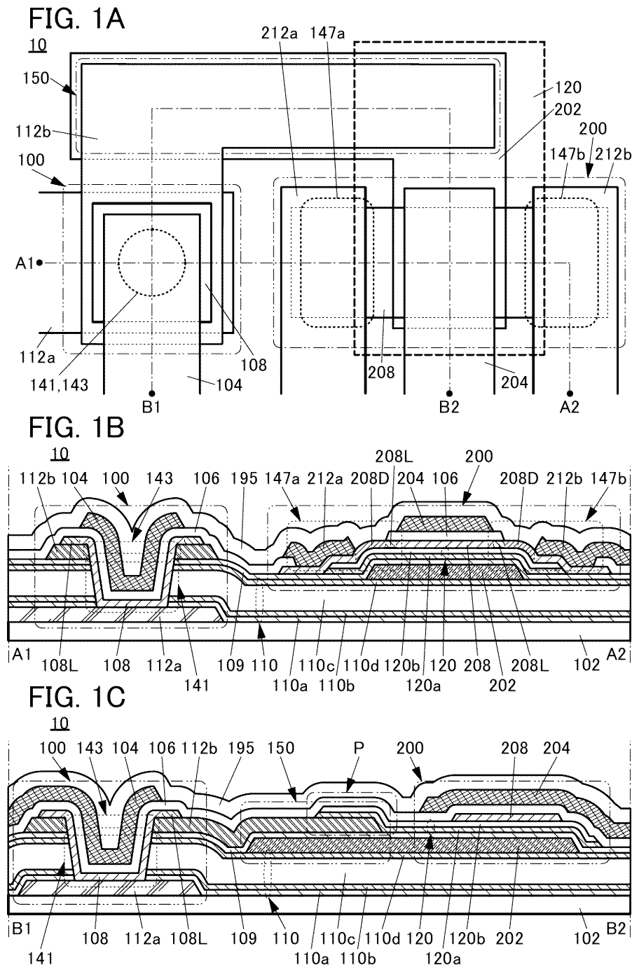

In this embodiment, a semiconductor device of one embodiment of the present invention is described with reference to FIG. 1 to FIG. 30.

One embodiment of the present invention is a semiconductor device including a first transistor, a second transistor, and a first insulating layer.

The first transistor includes a first conductive layer, a second conductive layer, a first semiconductor layer, a gate insulating layer over the first semiconductor layer, and a first gate electrode over the gate insulating layer. The first conductive layer functions as one of a source electrode and a drain electrode of the first transistor, and the second conductive layer functions as the other of the source electrode and the drain electrode.

The second transistor includes a third conductive layer over the first insulating layer, a second insulating layer in contact with the top surface and the side surface of the third conductive layer and the top surface of the first insulating layer, a third insulating layer over the second insulating layer, a second semiconductor layer over the third insulating layer, a gate insulating layer over the second semiconductor layer, and a second gate electrode over the gate insulating layer. The third conductive layer functions as a back gate electrode of the second transistor.

The first insulating layer is provided over the first conductive layer. The first insulating layer and the second insulating layer have a first opening reaching the first conductive layer. The second conductive layer is provided over the second insulating layer. The second conductive layer has a second opening in a region overlapping with the first opening. In the first opening and the second opening, the first semiconductor layer is in contact with the top surface of the first conductive layer, the side surface of the first insulating layer, the side surface of the second insulating layer, and the side surface of the second conductive layer.

The channel length of the first transistor can be controlled by the thickness of the insulating layer interposed between the first conductive layer and the second conductive layer. That is, the channel length is not affected by the light-exposure performance of a light-exposure apparatus used for manufacture. Thus, the channel length can have a value smaller than the minimum dimension of light exposure by the light-exposure apparatus (hereinafter also referred to as the minimum dimension). The transistor having a short channel length can have a high on-state current.

The second transistor has a structure different from that of the first transistor. Being affected by the performance of a light-exposure apparatus used for manufacture, the channel length of the second transistor has a value greater than or equal to the minimum dimension of the light-exposure apparatus. Thus, the second transistor can have a longer channel length than the first transistor. The transistor having a long channel length can have favorable saturation characteristics.

The first transistor having a short channel length and the second transistor having a long channel length can be formed over the same substrate by the steps some of which are shared. For example, when the first transistor is used as the transistor required to have a high on-state current and the second transistor is used as the transistor required to have favorable saturation characteristics, the semiconductor device can achieve high performance.

In this specification and the like, the state where the change in current is small in the saturation region of the Id-Vd characteristics of a transistor is sometimes described using the expression “favorable saturation characteristics”.

### Structure Example 1

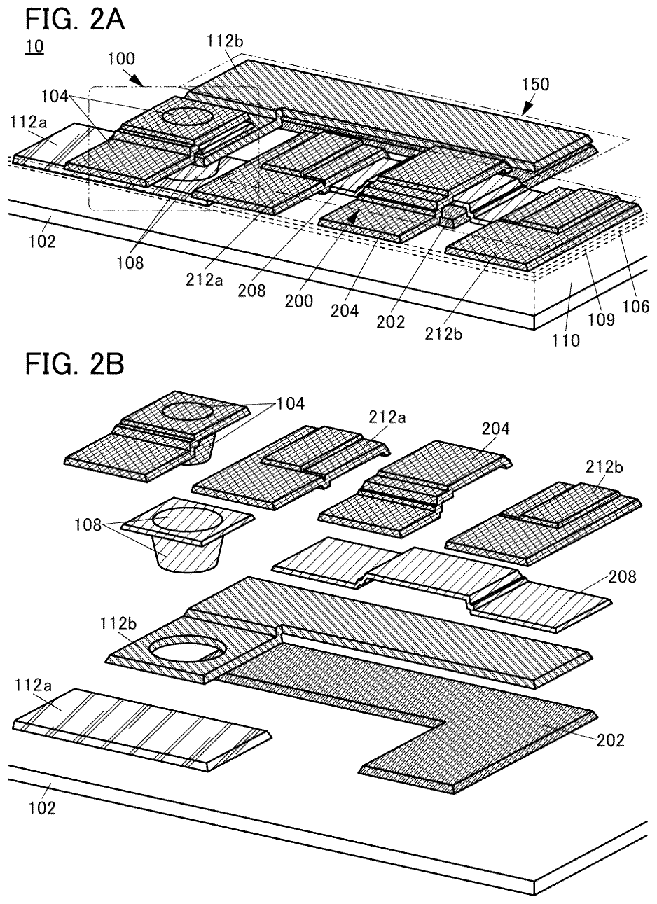

The semiconductor device of one embodiment of the present invention will be described. FIG. 1A is a top view (also referred to as a plan view) of a semiconductor device 10. FIG. 1B is a cross-sectional view of a cut plane along the dashed-dotted line A1-A2 illustrated in FIG. 1A, and FIG. 1C is a cross-sectional view of a cut plane along the dashed-dotted line B1-B2 illustrated in FIG. 1A. FIG. 2A is a perspective view of the semiconductor device 10. Note that in FIG. 1A, some components (e.g., an insulating layer) of the semiconductor device 10 are not illustrated. Some components are not illustrated in top views of semiconductor devices in the following diagrams, as in FIG. 1A.

The semiconductor device 10 includes a transistor 100, a transistor 200, a capacitor 150, and an insulating layer 110. The transistor 100, the transistor 200, and the capacitor 150 are provided over a substrate 102. The transistor 100 and the transistor 200 have structures different from each other. Some formation steps can be common between the transistor 100, the transistor 200, and the capacitor 150.

The transistor 100 includes a conductive layer 104, an insulating layer 106, a semiconductor layer 108, a conductive layer 112a, and a conductive layer 112b. In the transistor 100, the conductive layer 104 functions as a gate electrode (also referred to as a first gate electrode), and part of the insulating layer 106 functions as a gate insulating layer (also referred to as a first gate insulating layer). The conductive layer 112a functions as one of a source electrode and a drain electrode, and the conductive layer 112b functions as the other. The layers included in the transistor 100 may each have a single-layer structure or a stacked-layer structure.

The transistor 200 includes a conductive layer 204, a conductive layer 212a, a conductive layer 212b, the insulating layer 106, a semiconductor layer 208, an insulating layer 120, an insulating layer 109, and a conductive layer 202. In the transistor 200, the conductive layer 204 functions as a gate electrode (also referred to as a first gate electrode), and part of the insulating layer 106 functions as a gate insulating layer (also referred to as a first gate insulating layer). The conductive layer 202 functions as a back gate electrode (also referred to as a second gate electrode), and part of the insulating layer 120 and part of the insulating layer 109 function as a back gate insulating layer (also referred to as a second gate insulating layer). The conductive layer 212a functions as one of a source electrode and a drain electrode, and the conductive layer 212b functions as the other. The layers included in the transistor 200 may each have a single-layer structure or a stacked-layer structure. Note that a structure can also be employed where the transistor 200 does not include the conductive layer 202.

An insulating layer 195 is provided to cover the transistor 100, the transistor 200, and the capacitor 150. The insulating layer 195 functions as a protective layer for the transistor 100, the transistor 200, and the capacitor 150.

In FIG. 2A, the insulating layer 110 and the insulating layer 106 are transparent and their outlines are indicated by dashed lines, and the insulating layer 195 is not illustrated. In FIG. 2B, some components illustrated in FIG. 2A are illustrated to be shifted in the normal direction of a surface of the substrate 102.

First, the structure of the transistor 100 is described.

The conductive layer 112a is provided over the substrate 102. The insulating layer 110 is provided over the conductive layer 112a. The insulating layer 110 is provided to cover the top surface and the side surface of the conductive layer 112a. The insulating layer 109 is provided over the insulating layer 110. The insulating layer 109 and the insulating layer 110 have an opening 141 reaching the conductive layer 112a. It can be said that the conductive layer 112a is exposed by forming the opening 141.

The conductive layer 112b is provided over the insulating layer 109. The conductive layer 112b includes a region overlapping with the conductive layer 112a with the insulating layer 109 and the insulating layer 110 therebetween. It can also be said that the insulating layer 109 and the insulating layer 110 each include a region interposed between the conductive layer 112a and the conductive layer 112b. The conductive layer 112b includes an opening 143 in the region overlapping with the conductive layer 112a. The opening 143 is provided in a region overlapping with the opening 141.

The semiconductor layer 108 is provided to cover the opening 141 and the opening 143. The semiconductor layer 108 is in contact with the top surface of the conductive layer 112a, the side surface of the insulating layer 110, and the side surface of the insulating layer 109 in the opening 141, and is in contact with the side surface of the conductive layer 112b in the opening 143. In addition, the semiconductor layer 108 includes a region in contact with the top surface of the conductive layer 112b. The semiconductor layer 108 has a shape along the shapes of the top surface and the side surface of the conductive layer 112b, the side surface of the insulating layer 109, the side surface of the insulating layer 110, and the top surface of the conductive layer 112a. The semiconductor layer 108 includes a region overlapping with the conductive layer 112a with the conductive layer 112b, the insulating layer 109, and the insulating layer 110 therebetween.

The semiconductor layer 108 is in contact with and electrically connected to the conductive layer 112a and the conductive layer 112b. In the semiconductor layer 108, the region in contact with the conductive layer 112a functions as one of a source region and a drain region, and the region in contact with the conductive layer 112b functions as the other. In the semiconductor layer 108, a channel formation region is provided between the source region and the drain region.

The semiconductor layer 108 preferably includes a region in contact with the top surface and the side surface of the conductive layer 112b. By employing the structure where the semiconductor layer 108 is in contact with not only the side surface but also the top surface of the conductive layer 112b, the contact area between the semiconductor layer 108 and the conductive layer 112b is increased, so that the contact resistance between the semiconductor layer 108 and the conductive layer 112b can be reduced. This can increase the on-state current of the transistor 100. Although FIG. 1B and the like illustrate a structure where an end portion of the semiconductor layer 108 is in contact with the top surface of the conductive layer 112b, one embodiment of the present invention is not limited thereto. The semiconductor layer 108 can cover also an end portion of the conductive layer 112b on the side not facing the opening 143. The end portion of the semiconductor layer 108 can be in contact with the top surface of the insulating layer 109. Alternatively, a structure can be employed where the semiconductor layer 108 is not in contact with the top surface of the conductive layer 112b but is in contact with only the side surface of the conductive layer 112b on the opening 143 side.

The insulating layer 106 is provided to cover the opening 141 and the opening 143. The insulating layer 106 is provided over the semiconductor layer 108, the conductive layer 112b, and the insulating layer 109. The insulating layer 106 includes a region in contact with the top surface and the side surface of the semiconductor layer 108, the top surface and the side surface of the conductive layer 112b, and the top surface of the insulating layer 109. The insulating layer 106 has a shape along the shapes of the top surface and the side surface of the semiconductor layer 108, the top surface and the side surface of the conductive layer 112b, and the top surface of the insulating layer 109.

The conductive layer 104 is provided over the insulating layer 106 and includes a region in contact with the top surface of the insulating layer 106. The conductive layer 104 includes a region overlapping with the semiconductor layer 108 with the insulating layer 106 therebetween. The conductive layer 104 has a shape along the shape of the top surface of the insulating layer 106.

The transistor 100 is what is called a top-gate transistor including the gate electrode above the semiconductor layer 108. Furthermore, since the bottom surface of the semiconductor layer 108 is in contact with the conductive layer 112a and the conductive layer 112b that function as the source electrode and the drain electrode, the transistor 100 can be referred to as a TGBC (Top Gate Bottom Contact) transistor. In the transistor 100, the source electrode and the drain electrode are positioned at different levels with respect to the surface of the substrate 102 which is the formation surface, and a drain current flows in a direction perpendicular or substantially perpendicular to the surface of the substrate 102. In the transistor 100, the drain current can also be regarded as flowing in the vertical direction or the substantially vertical direction. Accordingly, the transistor of one embodiment of the present invention can be referred to as a vertical-channel transistor, a vertical transistor, or a VFET (Vertical Field Effect Transistor).

The channel length of the transistor 100 can be controlled by the thickness of the insulating layer 110 provided between the conductive layer 112a and the conductive layer 112b. Thus, a transistor with a channel length shorter than the minimum dimension of a light-exposure apparatus used for manufacturing the transistor can be manufactured with high accuracy. Furthermore, variation in characteristics among a plurality of the transistors 100 are also reduced. Accordingly, the operation of the semiconductor device including the transistor 100 can be stabilized and the reliability thereof can be improved. When the variation in characteristics is reduced, the circuit design flexibility is increased and the operation voltage of the semiconductor device can be reduced. Thus, power consumption of the semiconductor device can be reduced.

In the transistor 100, since the source electrode, the layer including the channel formation region, and the drain electrode can be provided to overlap with each other, the area occupied by the transistor can be significantly reduced as compared with what is called a planar transistor in which a layer including a channel formation region is provided in a planar shape.

The conductive layer 112a, the conductive layer 112b, and the conductive layer 104 can function as wirings, and the transistor 100 can be provided in a region where these wirings overlap with each other. That is, the areas occupied by the transistor 100 and the wirings can be reduced in the circuit including the transistor 100 and the wirings. Accordingly, the area occupied by the circuit can be reduced, which makes it possible to provide a small semiconductor device.

Next, the structure of the transistor 200 is described.

The conductive layer 202 is provided over the insulating layer 110.

The insulating layer 109 is provided over the conductive layer 202. The insulating layer 109 is provided to cover the top surface and the side surface of the conductive layer 202. The insulating layer 109 is in contact with the top surface and the side surface of the conductive layer 202 and the top surface of the insulating layer 110. That is, the conductive layer 202 is surrounded by the insulating layer 110 and the insulating layer 109.

The insulating layer 109 is preferably provided also between the insulating layer 110 and the conductive layer 112b. That is, the insulating layer 109 preferably includes a region in contact with the bottom surface of the conductive layer 112b. Furthermore, the insulating layer 109 preferably includes a region in contact with the side surface of the semiconductor layer 108 in the opening 141.

The insulating layer 120 is provided over the insulating layer 109. The insulating layer 120 is provided at least in a region overlapping with the conductive layer 202.

The semiconductor layer 208 is provided over the insulating layer 120. The semiconductor layer 208 includes a region overlapping with the conductive layer 202 with the insulating layer 120 and the insulating layer 109 therebetween. For the semiconductor layer 208, the same material as the semiconductor layer 108 can be used. The semiconductor layer 208 can be formed in the same step as the semiconductor layer 108. For example, a film to be the semiconductor layer 108 and the semiconductor layer 208 is formed and then the film is processed, whereby the semiconductor layer 108 and the semiconductor layer 208 can be formed.

The insulating layer 106 is provided over the semiconductor layer 208. One part of the insulating layer 106 functions as the gate insulating layer of the transistor 100 and another part of the insulating layer 106 functions as the gate insulating layer of the transistor 200. The insulating layer 106 includes an opening 147a and an opening 147b in regions overlapping with the semiconductor layer 208.

The conductive layer 204, the conductive layer 212a, and the conductive layer 212b are provided over the insulating layer 106. The conductive layer 204 includes a region overlapping with the semiconductor layer 208 with the insulating layer 106 therebetween. The conductive layer 204 includes a region overlapping with the conductive layer 202 with the semiconductor layer 208 therebetween. The conductive layer 212a and the conductive layer 212b are provided to cover part of the opening 147a and part of the opening 147b, respectively. The conductive layer 212a is in contact with the semiconductor layer 208 in the opening 147a, and the conductive layer 212b is in contact with the semiconductor layer 208 in the opening 147b. The semiconductor layer 208 is electrically connected to the conductive layer 212a and the conductive layer 212b. For the conductive layer 204, the conductive layer 212a, and the conductive layer 212b, the same material as the conductive layer 104 can be used. The conductive layer 204, the conductive layer 212a, and the conductive layer 212b can be formed in the same step as the conductive layer 104. For example, a film to be the conductive layer 104, the conductive layer 204, the conductive layer 212a, and the conductive layer 212b is formed and then the film is processed, whereby the conductive layer 104, the conductive layer 204, the conductive layer 212a, and the conductive layer 212b can be formed.

In the channel length direction, the conductive layer 202 functioning as the back gate electrode of the transistor 200 preferably extends beyond an end portion of a region where the conductive layer 204 and the semiconductor layer 208 overlap with each other. That is, in the channel length direction, the size of the conductive layer 202 is preferably larger than the size of the region where the conductive layer 204 and the semiconductor layer 208 overlap with each other. Specifically, the conductive layer 202 preferably has a portion that protrudes beyond an end portion of the conductive layer 204 in the channel length direction.

A portion of the semiconductor layer 208 that overlaps with at least one of the conductive layer 204 and the conductive layer 202 functions as a channel formation region. The semiconductor layer 208 includes a pair of regions 208L between which the channel formation region is interposed and a pair of regions 208D outside the pair of regions 208L. Here, for easy explanation, a portion of the semiconductor layer 208 that overlaps with the conductive layer 204 is sometimes referred to as the channel formation region; however, a portion not overlapping with the conductive layer 204 and overlapping with the conductive layer 202 (a portion including the regions 208L and the regions 208D) can also function as the channel formation region.

The regions 208L and the regions 208D each include an impurity element. As the impurity element, one or more of hydrogen, boron, carbon, nitrogen, fluorine, phosphorus, sulfur, arsenic, aluminum, magnesium, silicon, and a noble gas can be used. Note that typical examples of the noble gas include helium, neon, argon, krypton, and xenon. It is particularly preferable to use one or more of boron, phosphorus, aluminum, magnesium, and silicon as the impurity element.

An impurity element is supplied (or added or implanted) to the semiconductor layer 208 using the conductive layer 204, the conductive layer 212a, and the conductive layer 212b as masks. Thus, the region 208D is formed in the region of the semiconductor layer 208 that overlaps with none of the conductive layer 204, the conductive layer 212a, the conductive layer 212b, and the insulating layer 106, and the region 208L is formed in the region of the semiconductor layer 208 that overlaps with none of the conductive layer 204, the conductive layer 212a, and the conductive layer 212b and overlaps with the insulating layer 106.

In the semiconductor layer 208, a region in contact with the conductive layer 212a and the region 208D adjacent to the region function as one of a source region and a drain region. In the semiconductor layer 208, a region in contact with the conductive layer 212b and the region 208D adjacent to the region function as the other of the source region and the drain region.

The insulating layer 120 is preferably provided at least in a region in contact with the channel formation region of the transistor 200. FIG. 1C and the like illustrate a structure where an end portion of part of the insulating layer 120 is in contact with the top surface of the insulating layer 109, and another end portion is in contact with the top surface of the conductive layer 112b. As illustrated in FIG. 1B, the semiconductor layer 208 covers the side surface of part of the insulating layer 120. That is, the semiconductor layer 208 includes a portion protruding beyond the end portion of the insulating layer 120. Part of an end portion of the semiconductor layer 208 is in contact with the top surface of the insulating layer 120, and another part is in contact with the top surface of the insulating layer 109. It can also be said that part of the bottom surface of the semiconductor layer 208 is in contact with the top surface of the insulating layer 120, and another part is in contact with the top surface of the insulating layer 109. Note that a structure can also be employed where the insulating layer 120 is provided in a region where the semiconductor layer 208 is provided such that the bottom surface of the semiconductor layer 208 is entirely in contact with the top surface of the insulating layer 120.

It is preferable that between the formation of the insulating layer 120 and the formation of the semiconductor layer 208, another layer (in particular, a conductive layer) not be formed. Specifically, it is preferable that after the formation of a conductive film to be the conductive layer 112b, the insulating layer 120 be formed and the semiconductor layer 208 be formed over the insulating layer 120. In that case, a component included in the conductive layer (e.g., a metal included in the conductive layer 112b) can be inhibited from being attached to the interface between the insulating layer 120 and the semiconductor layer 208, whereby the transistor 200 can have favorable electrical characteristics and high reliability.

By forming the insulating layer 120 after the formation of the conductive film to be the conductive layer 112b, the insulating layer 120 can include a region that is in contact with the conductive layer 112b like a region P indicated by the dashed-dotted line in FIG. 1C. In this structure, the insulating layer 120 is in contact with at least the side surface of the conductive layer 112b and may also be in contact with the top surface of the conductive layer 112b. The end portion of the insulating layer 120 may be in contact with one or both of the top surface and the side surface of the conductive layer 112b. Note that a structure can also be employed where the insulating layer 120 does not include a region in contact with the conductive layer 112b.

Note that as illustrated in FIG. 1C and the like, it is preferable that the semiconductor layer 108 not be in contact with the insulating layer 120. That is, it is preferable that the insulating layer 120 not be provided between the semiconductor layer 108 and the conductive layer 112b. Provision of the insulating layer 120 between the semiconductor layer 108 and the conductive layer 112b might reduce the contact area between the semiconductor layer 108 and the conductive layer 112b to increase the contact resistance between the semiconductor layer 108 and the conductive layer 112b. Thus, it is preferable that the insulating layer 120 not be in contact with the semiconductor layer 108.

The transistor 200 is a planar transistor in which the semiconductor layer 208 is provided in a planar shape. In addition, the transistor 200 is what is called a top-gate transistor including the gate electrode above the semiconductor layer 208. For example, when an impurity element is supplied to the semiconductor layer 208 with the conductive layer 204, which functions as the gate electrode, used as a mask, the regions 208D functioning as the source region and the drain region can be formed in a self-aligned manner. The transistor 200 can be referred to as a TGSA (Top Gate Self-Aligned) transistor.

The channel length of the transistor 200 can be controlled by the length of the conductive layer 204. Accordingly, the channel length of the transistor 200 has a value larger than or equal to that of the minimum dimension of a light-exposure apparatus used for manufacture of the transistor. That is, the channel length of the transistor 200 can be longer than the channel length of the transistor 100. The transistor having a long channel length can have favorable saturation characteristics.

The transistor 100 having a short channel length and the transistor 200 having a long channel length can be formed over the same substrate by the steps some of which are shared. For example, when the transistor 100 is used as the transistor required to have a high on-state current and the transistor 200 is used as the transistor required to have favorable saturation characteristics, the semiconductor device can achieve high performance.

When the semiconductor device of one embodiment of the present invention is used for a pixel circuit of a display apparatus, for example, the area occupied by the pixel circuit can be reduced and the display apparatus can have high resolution. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel, for example.

The capacitor 150 has a structure where the conductive layer 202, the insulating layer 109, and the conductive layer 112b are stacked in this order. The conductive layer 112b and the conductive layer 202 function as a pair of electrodes of the capacitor 150. The conductive layer 112b functions as the other of the source electrode and the drain electrode of the transistor 100 and also functions as one of the pair of electrodes of the capacitor 150. The conductive layer 202 functions as the back gate electrode of the transistor 200 and also functions as the other of the pair of electrodes of the capacitor 150. In the insulating layer 109, a region interposed between the conductive layer 112b and the conductive layer 202 functions as a dielectric of the capacitor 150. When the conductive layer 112b and the conductive layer 202 are formed in different steps, the capacitor 150 including these conductive layers as the pair of electrodes can be formed. Forming the conductive layer 112b and the conductive layer 202 in different steps allows the conductive layer 112b and the conductive layer 202 to be formed using different materials, offering a wider range of material choices.

Although the capacitor 150 is formed of the conductive layer 112b, the conductive layer 202, and the insulating layer 109 in the examples described with FIG. 1A and the like, there is no particular limitation on the structure of the capacitor 150. Furthermore, the semiconductor device 10 can have a structure not including the capacitor 150.

Although the other of the source electrode and the drain electrode of the transistor 100 is electrically connected to one of the pair of electrodes of the capacitor 150 and one of the source electrode and the drain electrode of the transistor 200 is electrically connected to the other of the pair of electrodes of the capacitor 150 in the structures illustrated in FIG. 1A and the like, there is no particular limitation on the electrical connection relationship between the transistor 100, the transistor 200, and the capacitor 150.

Next, the detailed structures of the transistor 100 and the transistor 200 are described.

A semiconductor material used for each of the semiconductor layer 108 and the semiconductor layer 208 is not particularly limited. For example, a single-element semiconductor or a compound semiconductor can be used. Examples of the single-element semiconductor include silicon and germanium. Examples of the compound semiconductor include gallium arsenide and silicon germanium. Other examples of the compound semiconductor include an organic semiconductor, a nitride semiconductor, and an oxide semiconductor (OS). These semiconductor materials may contain an impurity as a dopant.

There is no particular limitation on the crystallinity of a semiconductor material used for each of the semiconductor layer 108 and the semiconductor layer 208, and any of an amorphous semiconductor, a single crystal semiconductor, and a semiconductor having crystallinity other than single crystal (a microcrystalline semiconductor, a polycrystalline semiconductor, or a semiconductor partly including crystal regions) can be used. A single crystal semiconductor or a semiconductor having crystallinity is preferably used because degradation of the transistor characteristics can be inhibited.

For each of the semiconductor layer 108 and the semiconductor layer 208, silicon can be used. Examples of silicon include single crystal silicon, polycrystalline silicon, microcrystalline silicon, and amorphous silicon. An example of polycrystalline silicon is low-temperature polysilicon (LTPS). A transistor including amorphous silicon in a channel formation region can be formed over a large glass substrate, and can be manufactured at low cost. A transistor including polycrystalline silicon in a channel formation region has high field-effect mobility and enables high-speed operation. A transistor including microcrystalline silicon in a channel formation region has higher field-effect mobility and enables higher-speed operation than the transistor including amorphous silicon.

Each of the semiconductor layer 108 and the semiconductor layer 208 preferably includes a metal oxide exhibiting semiconductor characteristics (also referred to as an oxide semiconductor).

The band gaps of the metal oxides used for the semiconductor layer 108 and the semiconductor layer 208 are each preferably greater than or equal to 2.0 eV, further preferably greater than or equal to 2.5 eV.

A transistor including an oxide semiconductor (hereinafter referred to as an OS transistor) has much higher field-effect mobility than a transistor including amorphous silicon. In addition, the OS transistor has an extremely low off-state current, and charge accumulated in a capacitor that is connected in series to the transistor can be retained for a long period. Furthermore, a semiconductor device can have lower power consumption by including the OS transistor.

The insulating layer 110 preferably includes one or more inorganic insulating films. Examples of a material that can be used for the inorganic insulating film include an oxide, a nitride, an oxynitride, and a nitride oxide. Examples of the oxide include silicon oxide, aluminum oxide, magnesium oxide, gallium oxide, germanium oxide, yttrium oxide, zirconium oxide, lanthanum oxide, neodymium oxide, hafnium oxide, tantalum oxide, cerium oxide, gallium zinc oxide, and hafnium aluminate. Examples of the nitride include silicon nitride and aluminum nitride. Examples of the oxynitride include silicon oxynitride, aluminum oxynitride, gallium oxynitride, yttrium oxynitride, and hafnium oxynitride. Examples of the nitride oxide include silicon nitride oxide and aluminum nitride oxide.

In this specification and the like, an oxynitride refers to a material that contains more oxygen than nitrogen in its composition. A nitride oxide refers to a material that contains more nitrogen than oxygen in its composition.

The insulating layer 110 includes a region in contact with the semiconductor layer 108. In the case of using a metal oxide for the semiconductor layer 108, at least part of the region of the insulating layer 110 that is in contact with the semiconductor layer 108 preferably contains oxygen to improve the characteristics of the interface between the semiconductor layer 108 and the insulating layer 110. Specifically, the portion of the insulating layer 110 that is in contact with the channel formation region in the semiconductor layer 108 preferably contains oxygen. One or more of an oxide and an oxynitride is suitably used for the portion of the insulating layer 110 that is in contact with the channel formation region in the semiconductor layer 108.

The insulating layer 110 preferably has a stacked-layer structure. FIG. 1B and the like illustrate an example where the insulating layer 110 includes an insulating layer 110a, an insulating layer 110b over the insulating layer 110a, an insulating layer 110c over the insulating layer 110b, and an insulating layer 110d over the insulating layer 110c.

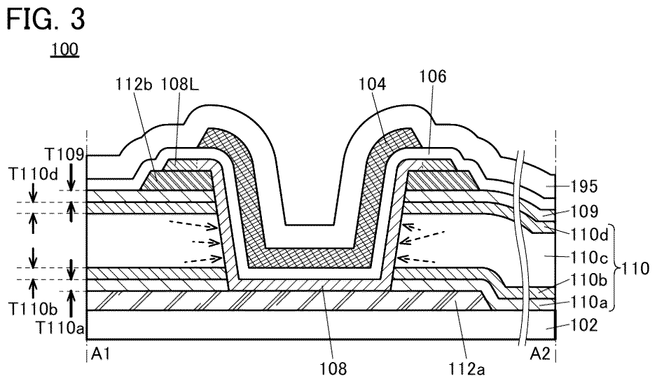

FIG. 3 is an enlarged view of the transistor 100 illustrated in FIG. 1B. A region of the semiconductor layer 108 that is in contact with the insulating layer 110c functions as the channel formation region. The insulating layer 110c preferably contains oxygen, and is preferably formed using any one or more of the oxides and oxynitrides described above. Specifically, one or both of silicon oxide and silicon oxynitride can be suitably used for the insulating layer 110c.

It is further preferable that a film from which oxygen is released by heat application be used as the insulating layer 110c. When the insulating layer 110c releases oxygen by heat applied in the manufacturing process of the transistor 100, the oxygen can be supplied to the semiconductor layer 108. Supply of oxygen from the insulating layer 110c to the semiconductor layer 108, particularly to the channel formation region, can repair oxygen vacancies (V_{O}) and reduce oxygen vacancies (V_{O}). In addition, defects generated by entry of hydrogen into an oxygen vacancy (V_{O}) (hereinafter also referred to as V_{O}H) can be reduced. Consequently, the transistor 100 with favorable electrical characteristics and high reliability can be obtained.

For example, the insulating layer 110c can be supplied with oxygen when heat treatment in an atmosphere containing oxygen or plasma treatment in an atmosphere containing oxygen is performed. Alternatively, an oxide film may be formed over the top surface of the insulating layer 110c by a sputtering method in an atmosphere containing oxygen to supply oxygen. After that, the oxide film may be removed. Note that a method for supplying oxygen to the insulating layer 110c will be described in Embodiment 2.

The insulating layer 110c is preferably formed by a film formation method such as a sputtering method or a plasma-enhanced chemical vapor deposition (PECVD, also referred to as plasma CVD) method. In particular, when the insulating layer 110c is formed by a sputtering method, which is a method that does not use a gas containing hydrogen, the insulating layer 110c can be a film having an extremely low hydrogen content. Thus, supply of hydrogen to the channel formation region is inhibited and the electrical characteristics of the transistor 100 can be stabilized.

In the insulating layer 110c, a substance is preferably easily diffused. In other words, the diffusion coefficient of a substance in the insulating layer 110c is preferably high. Preferably, oxygen in particular is easily diffused in the insulating layer 110c. That is, the diffusion coefficient of oxygen in the insulating layer 110c is preferably high. Oxygen contained in the insulating layer 110c is diffused in the insulating layer 110c and supplied to the semiconductor layer 108 through the interface between the insulating layer 110c and the semiconductor layer 108. In FIG. 3, dashed arrows schematically show diffusion of oxygen contained in the insulating layer 110c to the interface between the insulating layer 110c and the semiconductor layer 108. The insulating layer 110c that easily allows diffusion of oxygen enables efficient supply of oxygen contained in the insulating layer 110c to the semiconductor layer 108 (in particular, the channel formation region).

The diffusion coefficient of oxygen in the insulating layer 110c at 350° C. is preferably higher than or equal to 5×10⁻¹² cm²/sec, further preferably higher than or equal to 1×10⁻¹¹ cm²/sec, still further preferably higher than or equal to 5×10⁻¹¹ cm²/sec, yet still further preferably higher than or equal to 1×10⁻¹⁰ cm²/sec. Accordingly, oxygen contained in the insulating layer 110c can be supplied to the semiconductor layer 108 efficiently. Since the diffusion coefficient is preferably as high as possible, the upper limit thereof is not set. Note that the diffusion coefficient of oxygen in the insulating layer 110c is not necessarily within the above range.

The diffusion coefficient can be calculated by thermal desorption spectroscopy (TDS), for example. Alternatively, secondary ion mass spectrometry (SIMS) can be used.

The formation of the insulating layer 110c will be specifically described. Here, an example where silicon oxynitride is formed by a PECVD method is described.

A deposition gas containing silicon and an oxidizing gas can be used as the source gas of the insulating layer 110c. As the deposition gas containing silicon, one or more of silane (SiH₄), disilane (Si₂H₆), trisilane (Si₃H₈), silane fluoride (SiF₄), and TEOS (Tetraethoxysilane, Si(OC₂H₅)₄) can be used, for example. As the oxidizing gas, a gas containing oxygen can be suitably used. As the oxidizing gas, for example, one or more of oxygen (O₂), ozone (O₃), dinitrogen monoxide (N₂O), nitrogen monoxide (NO), and nitrogen dioxide (NO₂) can be used. In the case where silane (SiH₄) is used as the deposition gas containing silicon, dinitrogen monoxide (N₂O) is preferably used as the oxidizing gas, in which case the number of particles can be smaller than that of the case where oxygen (O₂) is used. Alternatively, in the case where silicon oxide is formed as the insulating layer 110c and TEOS is used as the deposition gas containing silicon, oxygen (O₂) can be suitably used as the oxidizing gas.

When the plasma density with respect to the flow rate of the deposition gas is reduced, that is, when the ratio of the plasma density to the flow rate of the deposition gas is reduced, in the formation of the insulating layer 110c by a PECVD method, the insulating layer can have a high diffusion coefficient. Here, in the case where an RF power source is used to bring the source gas into a plasma state, the plasma density can be reduced by reducing the power of the RF power source (hereinafter also referred to as RF power). By reducing the RF power with respect to the flow rate of the deposition gas (reducing the ratio of the RF power to the flow rate of the deposition gas), the insulating layer can have a high diffusion coefficient. By reducing the ratio of the RF power to the flow rate of the deposition gas (hereinafter also referred to as an F ratio), the diffusion coefficient of oxygen in the insulating layer 110c is increased, so that oxygen contained in the insulating layer 110c can be efficiently supplied to the semiconductor layer 108 (in particular, the channel formation region). However, in the case where a gas containing hydrogen (e.g., SiH₄) is used as the source gas, too low an F ratio might increase the amount of hydrogen contained in the insulating layer 110c. A large amount of hydrogen contained in the insulating layer 110c might cause the insulating layer 110c to release a large amount of impurities containing a hydrogen atom (e.g., water, hydrogen, and ammonia).

When the unit of the gas flow rate is represented by sccm (Standard Cubic Centimeters Per Minute) and that of the RF power is represented by W (Watt), the F ratio in the formation of the insulating layer 110c is preferably less than or equal to 12, less than or equal to 10, less than or equal to 9, less than or equal to 8, less than or equal to 7, less than or equal to 6, or less than or equal to 5 and greater than or equal to 2 or greater than or equal to 3. For example, in the case where the flow rate of silane (SiH₄) is 290 sccm and the RF power is 1160 W, the F ratio is 4. When the F ratio is within the above range, oxygen contained in the insulating layer 110c can be efficiently supplied to the semiconductor layer 108 (in particular, the channel formation region) and the amount of impurities released from the insulating layer 110c can be reduced. Note that the F ratio in the formation of the insulating layer 110c is not necessarily within the above range.

In this specification and the like, sccm represents a flow rate at 1 atmospheric pressure and 0° C. (273.15 K). Although the F ratio of the case where the unit of a gas flow rate is represented by sccm and that of the RF power is represented by W is shown, when a different unit is used, the unit can be converted into the above unit to calculate the F ratio. For example, in the case where the flow rate is 0.3 SLM (Standard Liter Per Minute), the F ratio can be calculated by converting 0.3 SLM into 300 sccm.

The electrical characteristics of the transistor 100 having a shorter channel length are more affected by oxygen vacancies (V_{O}) and V_{O}H in the channel formation region than those of a transistor having a longer channel length. Therefore, it is extremely important to efficiently supply oxygen from the insulating layer 110c to the semiconductor layer 108 (in particular, the channel formation region) and to reduce the amount of impurities released from the insulating layer 110c. When the F ratio in the formation of the insulating layer 110c is within the above range, the transistor 100 can have favorable electrical characteristics and high reliability.

When a gas is released from a film by heat application to the film, diffusion in the film and reaction at the film surface can be the bottleneck processes for the gas release, for example. Diffusion is less likely to be the bottleneck in a film that easily allows diffusion of a substance, and thus the temperature at which a gas starts to be released when heat is applied (hereinafter, also referred to as a release temperature) is low. By contrast, diffusion is the bottleneck in a film that does not easily allow diffusion of a substance, and thus the release temperature of a gas is high. As described above, a film that easily allows diffusion of a substance is preferably used for the insulating layer 110c. Thus, the release temperature of a gas when heat is applied to the insulating layer 110c is preferably low. For example, the release temperature of a gas in TDS of the insulating layer 110c is preferably low. In particular, the release temperature of oxygen (¹⁶O₂, m/z=32) in TDS of the insulating layer 110c is preferably low.

Note that oxygen may be supplied from the insulating layer 110c to the semiconductor layer 108 in the manufacturing process of the semiconductor device 10 to reduce the amount of oxygen that can be released from the insulating layer 110c in the semiconductor device 10 after the manufacturing process. Thus, in the case where TDS is performed on the semiconductor device 10, the amount of released oxygen is sometimes small. Note that in a film that easily allows diffusion of oxygen, a substance other than oxygen is also easily diffused; thus, when the release temperature of a released gas other than oxygen is low, the film is probably a film that easily allows diffusion of oxygen. For example, when the release temperature of nitrogen (¹⁴N₂, m/z=28) is low in TDS of the semiconductor device 10, it is presumed that the release temperature of oxygen is also low and oxygen is easily diffused in the film. In TDS of the semiconductor device 10, the release temperature of nitrogen (¹⁴N₂, m/z=28) is preferably lower than or equal to 250° C., lower than or equal to 200° C., lower than or equal to 180° C., lower than or equal to 170° C., or lower than or equal to 160° C. and higher than or equal to 140° C. In that case, oxygen contained in the insulating layer 110c can be efficiently supplied to the semiconductor layer 108 (in particular, the channel formation region) and the amount of impurities released from the insulating layer 110c can be reduced. Note that in the case where TDS is performed on the semiconductor device 10, the layers above the insulating layer 110c are preferably removed to expose the insulating layer 110c. Note that in this embodiment, the temperature rising rate of the sample surface temperature in TDS is approximately 14° C./min. The temperature rising rate of the stage where the sample is placed can be approximately 32° C./min, for example. Note that the release temperature of nitrogen (¹⁴N₂, m/z=28) in TDS of the semiconductor device 10 is not necessarily within the above range.

An example of a method for calculating the release temperature in TDS is described. In a graph where the X axis represents the sample surface temperature and the Y axis represents the detection intensity (e.g., current value) of the mass analyzer, a tangent is drawn at a point where the slope on a low temperature side of a peak becomes the maximum, and the intersection of the tangent and the X axis (Y=0) can be the release temperature. The detection intensity of the mass analyzer is preferably subjected to background processing. An example of the background processing is a method in which the minimum value of the detection intensity in the entire temperature range of the measurement is subtracted as a background value from a measured value.

Note that in film formation, the etching rate with respect to an etchant is low when the F ratio is high, whereas the etching rate with respect to an etchant is high when the F ratio is low; thus, the etching rate can be used as an indicator of ease of diffusion. As the etchant, an etchant containing hydrofluoric acid can be used, for example. Specific examples include hydrofluoric acid and BHF (Buffered Hydrofluoric acid). Note that BHF is an etchant containing hydrofluoric acid and a buffer agent (e.g., ammonium fluoride (NH₄F)). Alternatively, any of these etchants to which a surface-active agent is added may be used. For example, in the case where silicon oxide or silicon oxynitride is used for the insulating layer 110c, the etching rate of the insulating layer 110c with respect to 0.5 wt % hydrofluoric acid at 25° C. is preferably higher than or equal to 8 nm/min, higher than or equal to 9 nm/min, higher than or equal to 10 nm/min, higher than or equal to 11 nm/min, or higher than or equal to 12 nm/min and lower than or equal to 15 nm/min. Note that the etching rate can be calculated by dividing a difference between the thickness of a target film before the etching and the thickness of the target film after the etching by the etching time. Note that the etching rate of the insulating layer 110c is not necessarily within the above range.

Here, the use of a material having high electrical conductivity for the semiconductor layer 108 enables the transistor to have a high on-state current. However, the use of a material having high electrical conductivity facilitates the formation of oxygen vacancies (V_{O}); the increased oxygen vacancies (V_{O}) in the channel formation region shift the threshold voltage of the transistor, which might increase the drain current flowing at a gate voltage of 0 V (hereinafter, also referred to as cut-off current). For example, a negative shift of the threshold voltage might increase the cut-off current in the case of an n-channel transistor. The insulating layer 110c enables oxygen supply to at least the region of the semiconductor layer 108 that is in contact with the insulating layer 110c, i.e., the channel formation region, reducing the oxygen vacancies (V_{O}) and V_{O}H in the channel formation region. This inhibits the threshold voltage shift and allows the transistor to have both a low cut-off current and a high on-state current. Consequently, the semiconductor device can have both low power consumption and high performance.

In the semiconductor layer 108, the region in contact with the conductive layer 112a functions as one of the source region and the drain region of the transistor 100, and the region in contact with the conductive layer 112b functions as the other. The source region and the drain region are each a region having lower electric resistance than the channel formation region. In other words, the source region and the drain region are each a region having a higher carrier concentration or a higher oxygen vacancy density than the channel formation region.

The insulating layer 110b is provided between the insulating layer 110c and the conductive layer 112a. The insulating layer 110d is provided between the insulating layer 110c and the conductive layer 112b. It is preferable that the insulating layer 110b and the insulating layer 110d themselves release a small amount of impurities (e.g., hydrogen and water) and not easily transmit impurities. Thus, the impurities contained in the insulating layer 110b and the insulating layer 110d can be inhibited from being diffused into the channel formation region. Consequently, the transistor 100 with favorable electrical characteristics and high reliability can be obtained.

For each of the insulating layer 110b and the insulating layer 110d, a film that does not easily transmit oxygen is preferably used. Accordingly, oxygen contained in the insulating layer 110c can be inhibited from being diffused into the conductive layer 112a through the insulating layer 110a and the insulating layer 110b. Similarly, oxygen contained in the insulating layer 110c can be inhibited from being diffused into the conductive layer 112b through the insulating layer 110d and the insulating layer 109. This can inhibit the conductive layer 112a and the conductive layer 112b from being oxidized and having increased electric resistance. At the same time, oxygen contained in the insulating layer 110c can be inhibited from being diffused to the insulating layer 110b side and the insulating layer 110d side, which increases the amount of oxygen supplied to the channel formation region from the insulating layer 110c and can reduce oxygen vacancies (V_{O}) and V_{O}H in the channel formation region.

When a film that does not easily allow diffusion of oxygen is used for each of the insulating layer 110b and the insulating layer 110d, oxygen can be effectively supplied from the insulating layer 110c to the channel formation region. Note that a structure can also be employed where one or both of the insulating layer 110b and the insulating layer 110d are not provided.

It is preferable that the insulating layer 110b and the insulating layer 110d each contain nitrogen and be each formed using any one or more of the nitrides and nitride oxides described above. For example, one or both of silicon nitride and silicon nitride oxide can be suitably used for each of the insulating layer 110b and the insulating layer 110d. Alternatively, any one or more of oxide and oxynitride can be used for one or both of the insulating layer 110b and the insulating layer 110d. For example, aluminum oxide can be suitably used for each of the insulating layer 110b and the insulating layer 110d. Note that for the insulating layer 110b and the insulating layer 110d, the same material or different materials may be used.

Note that in this specification and the like, different materials mean materials in which some or all of constituent elements are different or materials having the same constituent elements and different compositions.

For example, a thickness T110b of the insulating layer 110b can be greater than or equal to 3 nm, greater than or equal to 5 nm, greater than or equal to 10 nm, greater than or equal to 20 nm, greater than or equal to 50 nm, or greater than or equal to 70 nm and less than 1 μm, less than or equal to 500 nm, less than or equal to 400 nm, less than or equal to 300 nm, less than or equal to 200 nm, less than or equal to 150 nm, or less than or equal to 120 nm. The thickness T110b can be the shortest distance between the formation surface of the insulating layer 110b (the top surface of the conductive layer 110a here) and the top surface of the insulating layer 110b in a cross-sectional view, as illustrated in FIG. 3. Note that the thickness T110b is not necessarily within the above range.

If the thickness T110b of the insulating layer 110b is large, a larger amount of impurities might be released from the insulating layer 110b, resulting in an increase in the amount of impurities diffused into the channel formation region. Meanwhile, if the thickness T110b is small, oxygen contained in the insulating layer 110c might be diffused to the conductive layer 112a side through the insulating layer 110b, resulting in a reduction in the amount of oxygen supplied to the channel formation region. When the thickness T110b is set within the above-described range, the oxygen vacancies (V_{O}) and V_{O}H in the channel formation region can be reduced. Furthermore, the conductive layer 112a can be inhibited from being oxidized by oxygen contained in the insulating layer 110c and from having increased electric resistance.

For example, a thickness T110d of the insulating layer 110d can be greater than or equal to 3 nm, greater than or equal to 5 nm, greater than or equal to 10 nm, greater than or equal to 15 nm, or greater than or equal to 20 nm and less than or equal to 1 μm, less than or equal to 500 nm, less than or equal to 300 nm, less than or equal to 200 nm, less than or equal to 150 nm, less than or equal to 120 nm, or less than or equal to 100 nm. The thickness T110d can be the shortest distance between the formation surface of the insulating layer 110d (the top surface of the conductive layer 110c here) and the top surface of the insulating layer 110d in a cross-sectional view, as illustrated in FIG. 3. Note that the thickness T110d is not necessarily within the above range.

If the thickness T110d of the insulating layer 110d is large, a larger amount of impurities might be released from the insulating layer 110d, resulting in an increase in the amount of impurities diffused into the channel formation region. Meanwhile, if the thickness T110d is small, oxygen contained in the insulating layer 110c might be diffused to the conductive layer 112b side through the insulating layer 110d, resulting in a reduction in the amount of oxygen supplied to the channel formation region. When the thickness T110d is set within the above-described range, the oxygen vacancies (V_{O}) and V_{O}H in the channel formation region can be reduced. Furthermore, the conductive layer 112b can be inhibited from being oxidized by oxygen contained in the insulating layer 110c and from having increased electric resistance.

The insulating layer 110a is provided between the insulating layer 110b and the conductive layer 112a. The insulating layer 109 is provided between the insulating layer 110d and the conductive layer 112b. For each of the insulating layer 110a and the insulating layer 109, a material that releases impurities (e.g., water and hydrogen) that reduce the electric resistance of the semiconductor layer 108 is preferably used. For each of the insulating layer 110a and the insulating layer 109, a material that can be used for each of the insulating layer 110b and the insulating layer 110d can be used. For example, silicon nitride or silicon nitride oxide can be suitably used for each of the insulating layer 110a and the insulating layer 109. Note that for the insulating layer 110a and the insulating layer 109, the same material or different materials may be used. In addition, the same material may be used for the insulating layer 110a, the insulating layer 110b, the insulating layer 110d, and the insulating layer 109, or different materials may be used for some or all of them.

When a material that releases impurities (e.g., water and hydrogen) is used for the insulating layer 110a, a region of the semiconductor layer 108 that is in contact with the insulating layer 110a can be a low-resistance region. In the semiconductor layer 108, the low-resistance region can be provided between the channel formation region and the region in contact with the conductive layer 112a (one of the source region and the drain region). Similarly, when a material that releases impurities is used for the insulating layer 109, a region of the semiconductor layer 108 that is in contact with the insulating layer 109 can be a low-resistance region. In the semiconductor layer 108, the low-resistance region can be provided between the channel formation region and the region in contact with the conductive layer 112b (the other of the source region and the drain region). The low-resistance region can function as a buffer region for relieving a drain electric field. These low-resistance regions may function as the source region and the drain region.

The low-resistance region provided between the drain region and the channel formation region inhibits generation of a high electric field in the vicinity of the drain region, so that generation of hot carriers is inhibited to inhibit the deterioration of the transistor. For example, in the case where the conductive layer 112a functions as the drain electrode, the conductive layer 112b functions as the source electrode, and the region of the semiconductor layer 108 that is in contact with the insulating layer 110a functions as the low-resistance region, a high electric field is not easily generated in the vicinity of the drain region, so that generation of hot carriers is inhibited to inhibit deterioration of the transistor. In the case where the conductive layer 112a functions as the source electrode, the conductive layer 112b functions as the drain electrode, and the region of the semiconductor layer 108 that is in contact with the insulating layer 109 functions as the low-resistance region, a high electric field is not easily generated in the vicinity of the drain region, so that generation of hot carriers is inhibited to inhibit the deterioration of the transistor.

In the case where the region of the semiconductor layer 108 that is in contact with the insulating layer 110a functions as the source region or the drain region, the distance from the source region in the semiconductor layer 108 to the gate electrode and the distance from the drain region to the gate electrode can be made more equal. Thus, the electric field of the gate electrode applied to the channel formation region can be more uniform.

A thickness T110a of the insulating layer 110a and a thickness T109 of the insulating layer 109 can each be greater than or equal to 30 nm, greater than or equal to 50 nm, greater than or equal to 60 nm, or greater than or equal to 70 nm and less than or equal to 300 nm, less than or equal to 200 nm, less than or equal to 150 nm, or less than or equal to 120 nm, for example. The thickness T110a can be the shortest distance between the formation surface of the insulating layer 110a (the top surface of the conductive layer 112a here) and the top surface of the insulating layer 110a in a cross-sectional view, as illustrated in FIG. 3. The thickness T109 can be the shortest distance between the formation surface of the insulating layer 109 (the top surface of the insulating layer 110d here) and the top surface of the insulating layer 109 in a cross-sectional view. Note that each of the thickness T110a and the thickness T109 is not necessarily within the above range. The thickness T110a and the thickness T109 may be the same or different from each other.

If the thickness T110a of the insulating layer 110a is large, a larger amount of impurities might be released from the insulating layer 110a, resulting in an increase in the amount of impurities diffused into the channel formation region. By contrast, if the thickness T110a is small, a smaller amount of impurities might be diffused into a region of a semiconductor layer 108a that is in contact with the insulating layer 110a, resulting in an increase in the electric resistance of the region. The same applies to the thickness T109 of the insulating layer 109. The thickness T110a and the thickness T109 that are each within the above range can inhibit an increase in oxygen vacancies (V_{O}) and V_{O}H in the channel formation region and form a low-resistance region between the source region and the drain region and the channel formation region.

It is further preferable that for the insulating layer 110a in contact with the conductive layer 112a, a material that releases impurities that reduce the electric resistance of the conductive layer 112a be used. In this case, the electric resistance of the conductive layer 112a can be reduced. For example, in the case of using a metal oxide for the conductive layer 112a, it is further preferable that the impurities contain hydrogen. In this case, the conductive layer 112a can have a high carrier concentration and low electric resistance. Moreover, the conductive layer 112a can function as a wiring, and the semiconductor device can have low wiring resistance. Note that an impurity that reduces the electric resistance of the conductive layer 112a may be the same as or different from an impurity that reduces the electric resistance of the semiconductor layer 108.

It is further preferable that for the insulating layer 109 including regions in contact with the conductive layer 112b and the conductive layer 202, a material that releases impurities that reduce the electric resistance of the conductive layer 112b and the conductive layer 202 be used. In this case, the electric resistance of the conductive layer 112b and the conductive layer 202 can be reduced. For example, in the case of using a metal oxide for the conductive layer 112b, it is further preferable that the impurities contain hydrogen. In this case, the conductive layer 112b can have a high carrier concentration and low electric resistance. Moreover, the conductive layer 112b can function as a wiring, and the semiconductor device can have low wiring resistance. Similarly, in the case of using a metal oxide for the conductive layer 202, it is further preferable that the impurities contain hydrogen. Note that the electric resistance of the semiconductor layer 108, the electric resistance of the conductive layer 112a, the electric resistance of the conductive layer 112b, and the electric resistance of the conductive layer 202 may be reduced by the same impurity, or some or all of them may be reduced by different impurities.

Providing the insulating layer 110b between the insulating layer 110a and the insulating layer 110c can inhibit impurities released from the insulating layer 110a from being diffused into the channel formation region in the semiconductor layer 108 through the insulating layer 110b and the insulating layer 110c. Consequently, the transistor 100 with favorable electrical characteristics and high reliability can be provided.

The insulating layer 110a preferably includes a region having a higher impurity content than the insulating layer 110b. Specifically, the insulating layer 110a preferably includes a region having a higher hydrogen content than the insulating layer 110b. The impurity content of each of the insulating layer 110a and the insulating layer 110b can be analyzed by secondary ion mass spectrometry (SIMS), for example.

In the case where the same material is used for the insulating layer 110a and the insulating layer 110b, using different film formation conditions enables adjustment of the amount of impurities to be released. Specifically, the film formation conditions for the insulating layer 110a may be different from those for the insulating layer 110b in any one or more of the film formation power (film formation power density), the film formation pressure, the kind of film formation gas, the flow rate ratio of a film formation gas, the film formation temperature, and the distance between the substrate and the electrode during formation. For example, the film formation power density for the insulating layer 110a may be lower than the film formation power density for the insulating layer 110b, in which case the insulating layer 110a can have an impurity content higher than the hydrogen content of the insulating layer 110b. Accordingly, the amount of impurities released from the insulating layer 110a due to heat applied thereto can be increased.

The film formation gas used for the formation of the insulating layer 110a preferably contains more hydrogen than the film formation gas used for the formation of the insulating layer 110b. Specifically, when a silicon nitride film or a silicon nitride oxide film is formed as each of the insulating layer 110a and the insulating layer 110b by using a PECVD method, the proportion of a flow rate of an ammonia gas to the whole film formation gas used for the formation of the insulating layer 110a (hereinafter also referred to as ammonia flow rate ratio) is preferably higher than the proportion of a flow rate of an ammonia gas to the whole film formation gas used for the formation of the insulating layer 110b. The formation of the insulating layer 110a under the condition where the ammonia flow rate ratio is high can increase the hydrogen content of the insulating layer 110a. Furthermore, the amount of hydrogen released from the insulating layer 110a due to heat applied thereto can be increased. It is possible to use an ammonia gas for the formation of the insulating layer 110a and not to use an ammonia gas for the formation of the insulating layer 110b. In particular, in the case where a channel length L100 is short (e.g., less than or equal to 100 nm) or a material having high conductivity is used for the semiconductor layer 108, an ammonia gas is not necessarily used for the formation of the insulating layer 110b. In these cases, an increased amount of hydrogen released from the insulating layer 110b might further increase the influence on the electrical characteristics. When an ammonia gas is not used for the formation of the insulating layer 110b, the amount of hydrogen in the insulating layer 110b can be reduced, so that the transistor can have favorable electrical characteristics.

The film density of the insulating layer 110b is preferably higher than the film density of the insulating layer 110a. In that case, impurities contained in the insulating layer 110a can be inhibited from being diffused into the channel formation region in the semiconductor layer 108 through the insulating layer 110b and the insulating layer 110c. The film density can be evaluated by Rutherford backscattering spectrometry (RBS) or X-ray reflection (XRR), for example. A difference in film density can be evaluated using a transmission electron microscopy (TEM) image of a cross section in some cases. In TEM observation, a transmission electron (TE) image is dark-colored (dark) when the film density is high, and a transmission electron (TE) image is pale (bright) when the film density is low. Thus, the transmission electron (TE) image of the insulating layer 110b is a dark-colored (dark) image compared to the insulating layer 110a in some cases. Note that since the insulating layer 110a and the insulating layer 110b have different film densities even when including the same materials, it is sometimes possible to identify the boundary between these insulating layers by a difference in contrast in a TEM image of a cross section. Note that the film density of the insulating layer 110b may be lower than or equal to the film density of the insulating layer 110a.

Providing the insulating layer 110d between the insulating layer 109 and the insulating layer 110c can inhibit impurities released from the insulating layer 109 from being diffused into the channel formation region in the semiconductor layer 108 through the insulating layer 110d and the insulating layer 110c. Consequently, the transistor 100 with favorable electrical characteristics and high reliability can be provided.

The insulating layer 109 preferably includes a region having a higher impurity content than the insulating layer 110d. Specifically, the insulating layer 109 preferably includes a region having a higher hydrogen content than the insulating layer 110d.

The film density of the insulating layer 110d is preferably higher than the film density of the insulating layer 109. The description of the insulating layer 110b can be referred to for the insulating layer 110d and the description of the insulating layer 110a can be referred to for the insulating layer 109; thus, the detailed description thereof is omitted. Note that the film density of the insulating layer 110d may be lower than or equal to the film density of the insulating layer 109

Note that in the semiconductor layer 108, at least one of the region in contact with the insulating layer 110b and the region in contact with the insulating layer 110d may be a region having lower electric resistance than the channel formation region. In other words, the region is a region having a higher carrier concentration or a higher oxygen vacancy density than the channel formation region. As described above, when an excessive amount of impurities is released from the insulating layer 110b and the insulating layer 110d, impurities might be diffused into the channel formation region. Even when a material that releases impurities is used for the insulating layer 110b and the insulating layer 110d, the amount of released impurities is preferably small.

Although the structure where the insulating layer 110 has a stacked-layer structure of four layers is described here, one embodiment of the present invention is not limited thereto. The insulating layer 110 preferably includes at least the insulating layer 110c. A structure can also be employed where one or more of the insulating layer 110a, the insulating layer 110b, and the insulating layer 110d are not provided. The insulating layer 110 can also have a single-layer structure or a stacked-layer structure of two layers, three layers, or five or more layers.

There is no limitation on the top surface shapes of the opening 141 and the opening 143, and the shapes can each be a circle, an ellipse, a polygon such as a triangle, a tetragon (including a rectangle, a rhombus, and a square), or a pentagon, or any of these polygons with rounded corners, for example. Note that the polygon may be a concave polygon (a polygon at least one of the interior angles of which is greater than 180°) or a convex polygon (a polygon all the interior angles of which are less than or equal to 180°). The top surface shapes of the opening 141 and the opening 143 are preferably circles as illustrated in FIG. 1A and the like. When the top surface shapes of the openings are circles, processing accuracy in forming the openings can be high, whereby the openings can be formed to have minute sizes. In this specification and the like, a circle is not limited to a perfect circle.

In this specification and the like, the top surface shape of the opening 141 refers to the shape of an end portion of the top surface of the insulating layer 109 on the opening 141 side. The top surface shape of the opening 143 refers to the shape of an end portion of the bottom surface of the conductive layer 112b on the opening 143 side.

As illustrated in FIG. 1A and the like, the top surface shape of the opening 141 and the top surface shape of the opening 143 can be the same or substantially the same. In that case, it is preferable that the end portion of the bottom surface of the conductive layer 112b on the opening 143 side be aligned with or substantially aligned with the end portion of the top surface of the insulating layer 109 on the opening 141 side as illustrated in FIG. 1B, FIG. 1C, and the like. The bottom surface of the conductive layer 112b refers to the surface thereof on the insulating layer 109 side. The top surface of the insulating layer 109 refers to the surface thereof on the conductive layer 112b side.

Note that it is also possible to employ a structure where the top surface shape of the opening 141 and the top surface shape of the opening 143 are not the same. In the case where the top surface shapes of the opening 141 and the opening 143 are circles, the opening 141 and the opening 143 may be, but not necessarily, arranged concentrically.

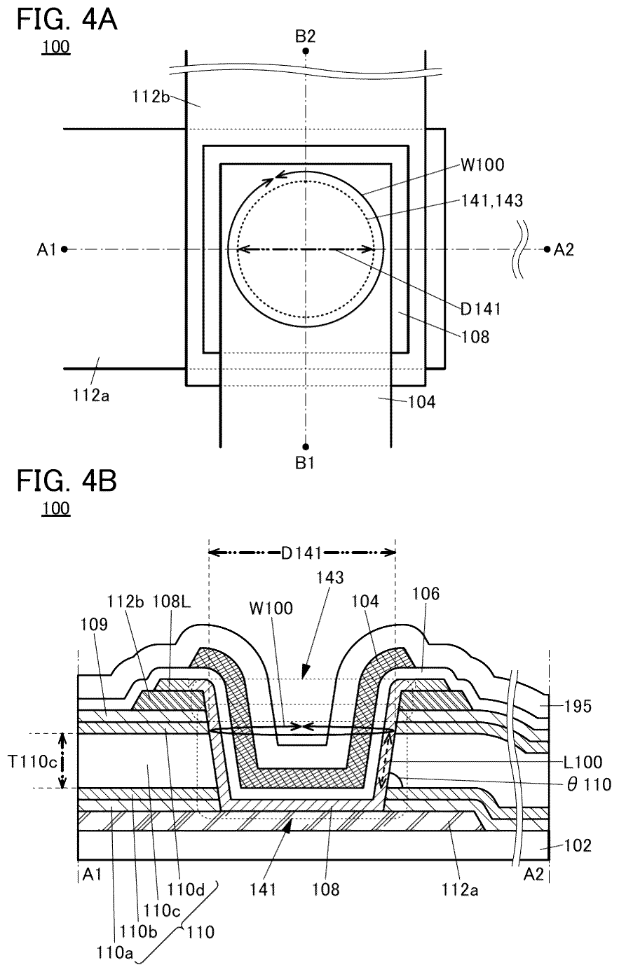

The channel length and the channel width of the transistor 100 are described with reference to FIG. 4A and FIG. 4B. FIG. 4A and FIG. 4B are enlarged views of the transistor 100 illustrated in FIG. 1A and FIG. 1B. Here, the case where the region of the semiconductor layer 108 that is in contact with the insulating layer 110c functions as the channel formation region is described as an example.

In FIG. 4B, the channel length L100 of the transistor 100 is indicated by a dashed double-headed arrow. The channel length L100 of the transistor 100 corresponds to the length of the side surface of the insulating layer 110c on the opening 141 side in a cross-sectional view. In other words, the channel length L100 depends on a thickness T110c of the insulating layer 110c and an angle θ110 formed by the side surface of the insulating layer 110c on the opening 141 side and the formation surface of the insulating layer 110c (which is the top surface of the insulating layer 110b here). Thus, the channel length L100 can be a value smaller than that of the minimum dimension of a light-exposure apparatus, which enables a transistor having a minute size. Specifically, a transistor with an extremely short channel length that could not be achieved with a conventional light-exposure apparatus for mass production of flat panel displays (the minimum line width: approximately 2 μm or approximately 1.5 μm, for example) can be achieved. Moreover, it is also possible to obtain a transistor with a channel length shorter than 10 nm without using an extremely expensive light-exposure apparatus used in the latest LSI technology.

The channel length L100 can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm. For example, the channel length L100 can be greater than or equal to 100 nm and less than or equal to 1 μm.

The reduction in the channel length L100 can increase the on-state current of the transistor 100. With the use of the transistor 100, a circuit capable of high-speed operation can be manufactured. Furthermore, the area occupied by the circuit can be reduced. Therefore, a semiconductor device with a small size can be obtained. The application of the semiconductor device of one embodiment of the present invention to a large display apparatus or a high-resolution display apparatus can reduce signal delay in wirings and reduce display unevenness even if the number of wirings is increased, for example. In addition, since the area occupied by the circuit can be reduced, the bezel of the display apparatus can be narrowed.

By adjusting the thickness T110c of the insulating layer 110c and the angle θ110, the channel length L100 can be controlled. Note that in FIG. 4B, the thickness T110c of the insulating layer 110c is indicated by the dashed-dotted double-headed arrow.

The thickness T110c of the insulating layer 110c can be, for example, greater than or equal to 5 nm, greater than or equal to 7 nm, or greater than or equal to 10 nm and less than 3 μm, less than or equal to 2.5 μm, less than or equal to 2 μm, less than or equal to 1.5 μm, less than or equal to 1.2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm.

The side surfaces of the insulating layer 109 and the insulating layer 110 on the opening 141 side each preferably have a tapered shape. The angle θ110 is preferably less than 90°. By reducing the angle θ110, the coverage with a layer (e.g., the semiconductor layer 108) formed over the insulating layer 109 and the insulating layer 110 can be improved. The smaller the angle θ110 is, the longer the channel length L100 can be. The larger the angle θ110 is, the shorter the channel length L100 can be.

The angle θ110 can be, for example, greater than or equal to 30°, greater than or equal to 35°, greater than or equal to 40°, greater than or equal to 45°, greater than or equal to 50°, greater than or equal to 55°, greater than or equal to 60°, greater than or equal to 65°, or greater than or equal to 70°and less than 90°, less than or equal to 85°, or less than or equal to 80°. The angle θ110 can be less than or equal to 75°, less than or equal to 70°, less than or equal to 65°, or less than or equal to 60°.

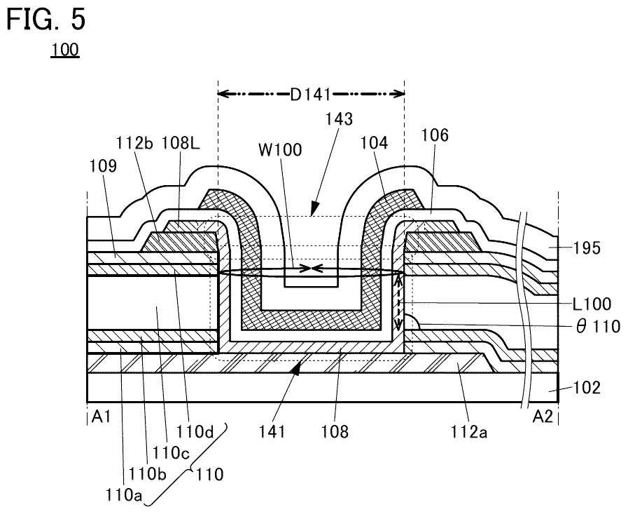

Although the angle θ110 is less than 90° in FIG. 4B and the like, one embodiment of the present invention is not limited thereto. As illustrated in FIG. 5, the angle θ110 can be 90° or approximately 90°. Accordingly, the channel length L100 of the transistor 100 can be made shorter.

Although FIG. 4B and the like illustrate a structure where the side surfaces of the insulating layer 109 and the insulating layer 110 on the opening 141 side are linear in a cross-sectional view, one embodiment of the present invention is not limited thereto. In the cross-sectional view, the side surfaces of the insulating layer 109 and the insulating layer 110 on the opening 141 side may be curved, or the side surfaces may include both a linear region and a curved region.

It is preferable that the conductive layer 112b not be provided inside the opening 141. Specifically, it is preferable that the conductive layer 112b not be in contact with the side surfaces of the insulating layer 109 and the insulating layer 110 on the opening 141 side. In particular, it is preferable that the conductive layer 112b not be in contact with the side surface of the insulating layer 110c on the opening 141 side. If the conductive layer 112b is also provided inside the opening 141 and the conductive layer 112b is in contact with the side surface of the insulating layer 110c, the channel length L100 of the transistor 100 is shorter than the length of the side surface of the insulating layer 110c and the channel length L100 is difficult to control in some cases. Accordingly, it is preferable that the top surface shape of the opening 143 be the same as the top surface shape of the opening 141, or the opening 143 encompass the opening 141 in the top view (also referred to as a plan view).

In FIG. 4A and FIG. 4B, a channel width W100 of the transistor 100 is indicated by a solid double-headed arrow. The channel width W100 is the length of the side surface of the insulating layer 110c on the opening 141 side. A width D141 of the opening 141 is indicated by a dashed double-dotted double-headed arrow. In the case where the top surface shape of the opening 141 is a circle, the width D141 corresponds to the diameter of the circle and the channel width W100 of the transistor 100 is the length of the circumference of the circle. That is, the channel width W100 is π×D141. As described above, in the case where the top surface shape of the opening 141 is a circle, the channel width W100 of the transistor can be small as compared with the case where the top surface shape is any other shape.

The width D141 of the opening 141 sometimes varies in the depth direction. As the width D141 of the opening 141, for example, the average value of the following three diameters can be used: the diameter at the highest level of the insulating layer 110c (or the insulating layer 109 and the insulating layer 110) in a cross-sectional view, the diameter at the lowest level thereof, and the diameter at the midpoint between these levels. For another example, any of the diameter at the highest level of the insulating layer 110c (or the insulating layer 109 and the insulating layer 110) in the cross-sectional view, the diameter at the lowest level thereof, and the diameter at the midpoint between these levels can be used as the diameter of the opening 141.

In the case where the opening 141 is formed by a photolithography method, the width D141 of the opening 141 is larger than or equal to the minimum dimension of a light-exposure apparatus. The width D141 can be, for example, greater than or equal to 200 nm, greater than or equal to 300 nm, greater than or equal to 400 nm, or greater than or equal to 500 nm and less than 5 μm, less than or equal to 4.5 μm, less than or equal to 4 μm, less than or equal to 3.5 μm, less than or equal to 3 μm, less than or equal to 2.5 μm, less than or equal to 2 μm, less than or equal to 1.5 μm, or less than or equal to 1 μm.

In the case where the channel length L100 of the transistor 100 is short, a material that releases a smaller amount of hydrogen is preferably used for each of the insulating layer 110b and the insulating layer 110d. In the case of using a material that releases a smaller amount of hydrogen for each of the insulating layer 110b and the insulating layer 110d, the insulating layers preferably have small thicknesses. For example, when the channel length L100 is less than or equal to 100 nm, the thickness T110b of the insulating layer 110b and the thickness T110d of the insulating layer 110d are each preferably greater than or equal to 1 nm, greater than or equal to 3 nm, or greater than or equal to 5 nm and less than or equal to 50 nm, less than or equal to 40 nm, less than or equal to 30 nm, less than or equal to 20 nm, less than or equal to 15 nm, or less than or equal to 10 nm. Accordingly, the amount of impurities being diffused into the channel formation region can be reduced, and the transistor 100 can have favorable electrical characteristics and high reliability even with the short channel length L100.

Although the structure where the region of the semiconductor layer 108 that is in contact with the insulating layer 110c functions as the channel formation region is described as an example, one embodiment of the present invention is not limited thereto. The region of the semiconductor layer 108 that is in contact with the insulating layer 110b may also function as the channel formation region. Similarly, the region that is in contact with the insulating layer 110d may also function as the channel formation region.

Although FIG. 1B and the like illustrate an example where the semiconductor layer 108, the insulating layer 106, and the conductive layer 104 cover the opening 141 and the opening 143 in the transistor 100, one embodiment of the present invention is not limited thereto. A structure can be employed where a step is formed between the insulating layer 110 and the conductive layer 112a, and the semiconductor layer 108, the insulating layer 106, and the conductive layer 104 are provided along the step.

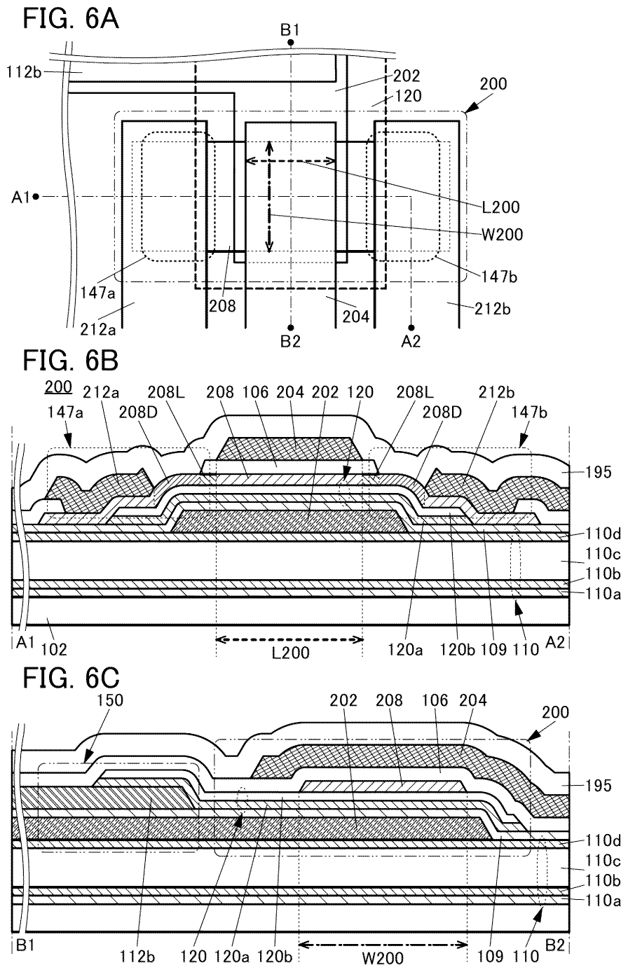

Next, the channel length and the channel width of the transistor 200 are described with reference to FIG. 6A to FIG. 6C. FIG. 6A to FIG. 6C are enlarged views of the transistor 200 illustrated in FIG. 1A to FIG. 1C.

Here, for easy explanation, the portion of the semiconductor layer 208 that overlaps with the conductive layer 204 is described as the channel formation region.

The channel length of the transistor 200 is the length of the region between the pair of regions 208D where the semiconductor layer 208 and the conductive layer 204 overlap with each other. In FIG. 6A and FIG. 6B, a channel length L200 of the transistor 200 is indicated by a dashed double-headed arrow. The channel length L200 of the transistor 200 depends on the length of the conductive layer 204 and has a value larger than or equal to that of the minimum dimension of a light-exposure apparatus used for manufacture of the transistor. For example, the channel length L200 can be greater than or equal to 1.5 μm. The transistor having a long channel length can have favorable saturation characteristics.

The channel width of the transistor 200 is the width of the region where the semiconductor layer 208 and the conductive layer 204 overlap with each other in the direction orthogonal to the channel length direction. In FIG. 6A and FIG. 6C, a channel width W200 of the transistor 200 is indicated by a dashed-dotted double-headed arrow.

As described above, the channel length L100 of the transistor 100 can have a value smaller than that of the minimum dimension of the light-exposure apparatus, and the channel length L200 of the transistor 200 can have a value larger than or equal to that of the minimum dimension of the light-exposure apparatus. For example, when the transistor 100 is used as the transistor required to have a high on-state current and the transistor 200 is used as the transistor required to have favorable saturation characteristics, the semiconductor device 10 can achieve high performance by utilizing the advantages of the transistors. Furthermore, some formation steps can be common between the transistor 100 and the transistor 200. Specifically, the semiconductor layer 108 and the semiconductor layer 208 can be formed in the same step. One part of the insulating layer 106 functions as the gate insulating layer of the transistor 100 and another part of the insulating layer 106 functions as the gate insulating layer of the transistor 200. The conductive layer 104, the conductive layer 204, the conductive layer 212a, and the conductive layer 212b can be formed in the same step. This allows higher productivity and lower manufacturing cost of the semiconductor device 10.

As illustrated in FIG. 6A and FIG. 6C, the conductive layer 204 and the conductive layer 202 preferably protrude outward from the end portion of the semiconductor layer 208 in the channel width direction of the transistor 200. In that case, as illustrated in FIG. 6C, the whole of the semiconductor layer 208 in the channel width direction is covered with the conductive layer 204 with the insulating layer 106 therebetween and also covered with the conductive layer 202 with the insulating layer 120 therebetween. In such a structure, the semiconductor layer 208 can be electrically surrounded by electric fields generated by a pair of gate electrodes.

FIG. 6A and FIG. 6C illustrate a structure where the conductive layer 204 and the conductive layer 202 are not electrically connected to each other. A constant potential can be supplied to one of the pair of gate electrodes, and a signal for driving the transistor 200 can be supplied to the other of the pair of gate electrodes. In this structure, the potential supplied to one of the gate electrodes can control the threshold voltage at the time of driving the transistor 200 with the other gate electrode.

The conductive layer 204 and the conductive layer 202 can be electrically connected to each other. When the same potential is supplied to the conductive layer 204 and the conductive layer 202, electric fields for inducing a channel can be effectively applied to the semiconductor layer 208, whereby the on-state current of the transistor 200 can be increased. Thus, the transistor 200 can also be miniaturized. For example, an opening reaching the conductive layer 202 is provided in the insulating layer 106 and the insulating layer 120 and the conductive layer 204 can be formed to cover the opening.

The conductive layer 202 can be electrically connected to the conductive layer 212a or the conductive layer 212b. For example, an opening reaching the conductive layer 202 is provided in the insulating layer 106, the insulating layer 120, and the insulating layer 109 and the conductive layer 212a or the conductive layer 212b can be formed to cover the opening.

A material that can be used for the insulating layer 110 can be used for the insulating layer 120.

The insulating layer 120 preferably has a stacked-layer structure. FIG. 6B and the like illustrate a structure where the insulating layer 120 has a stacked-layer structure of an insulating layer 120a and an insulating layer 120b over the insulating layer 120a. For each of the insulating layer 120a and the insulating layer 120b, a material that can be used for the insulating layer 110 can be used.

It is further preferable that a film from which oxygen is released by heat application be used as the insulating layer 120b in contact with the channel formation region in the semiconductor layer 208. When the insulating layer 120b releases oxygen by heat applied in the manufacturing process of the transistor 200, the oxygen can be supplied to the semiconductor layer 208, particularly to the channel formation region. Oxygen contained in the insulating layer 120b is diffused into the insulating layer 120b and supplied to the semiconductor layer 208 through the interface between the insulating layer 120b and the semiconductor layer 208. Supply of oxygen from the insulating layer 120b to the semiconductor layer 208, particularly to the channel formation region, can repair oxygen vacancies (V_{O}) and reduce oxygen vacancies (V_{O}). In addition, V_{O}H can be reduced. Consequently, the transistor 200 with favorable electrical characteristics and high reliability can be obtained.

The diffusion coefficient of oxygen in the insulating layer 120b at 350° C. is preferably higher than or equal to 1×10⁻¹² cm²/sec, further preferably higher than or equal to 5×10⁻¹² cm²/sec. Note that the diffusion coefficient of oxygen in the insulating layer 120b is not necessarily within the above range.

For the insulating layer 120b, a material that can be used for the insulating layer 110c can be used. The insulating layer 120b preferably contains oxygen and is suitably formed using any one or more of an oxide and an oxynitride. Specifically, for example, one or both of silicon oxide and silicon oxynitride can be suitably used for the insulating layer 120b.

The formation of the insulating layer 120b will be specifically described. Here, an example where silicon oxynitride is formed by a PECVD method is described.

A gas including a deposition gas containing silicon and an oxidizing gas can be used as the source gas of the insulating layer 120b. For the deposition gas containing silicon and the oxidizing gas, the above description can be referred to.

In the formation of the insulating layer 120b by a PECVD method, the F ratio is preferably less than or equal to 20, less than or equal to 18, less than or equal to 16, less than or equal to 14, less than or equal to 13, less than or equal to 12, or less than or equal to 11 and greater than or equal to 4, greater than or equal to 6, greater than or equal to 7, greater than or equal to 8, or greater than or equal to 9. The diffusion coefficient of oxygen in the insulating layer 120b may be lower than the diffusion coefficient of oxygen in the insulating layer 110c. Thus, the F ratio in the formation of the insulating layer 120b can be higher than the F ratio in the formation of the insulating layer 110c. With a high F ratio, the film formation rate of the insulating layer 120b can be increased and the productivity can be increased. For example, in the case where silicon oxide or silicon oxynitride is used for the insulating layer 120b, the etching rate of the insulating layer 120b with respect to 0.5 wt % hydrofluoric acid at 25° C. is preferably higher than or equal to 5 nm/min, higher than or equal to 6 nm/min, or higher than or equal to 7 nm/min and lower than or equal to 15 nm/min. Note that the F ratio in the formation of the insulating layer 120b is not necessarily within the above range. The diffusion coefficient of oxygen in the insulating layer 120b may be higher than or equal to the diffusion coefficient of oxygen in the insulating layer 110c. The etching rate of the insulating layer 120b is not necessarily within the above range.

Here, the electrical characteristics of the transistor 200 having a longer channel length are less affected by the oxygen vacancies (V_{O}) and V_{O}H in the channel formation region than those of the transistor 100 with a shorter channel length. Accordingly, the amount of oxygen supplied from the insulating layer 120b to the semiconductor layer 208 may be smaller than the amount of oxygen supplied from the insulating layer 110c to the semiconductor layer 108. The amount of oxygen released from the insulating layer 120b may be smaller than the amount of oxygen released from the insulating layer 110c.

The diffusion coefficient of a substance in the insulating layer 110c is preferably higher than the diffusion coefficient of the substance in the insulating layer 120b. In particular, the diffusion coefficient of oxygen in the insulating layer 110c is preferably higher than the diffusion coefficient of oxygen in the insulating layer 120b. This allows the transistor 100 having a short channel length to have favorable electrical characteristics and high reliability. The F ratio in the formation of the insulating layer 110c is preferably lower than the F ratio in the formation of the insulating layer 120b. The etching rate of the insulating layer 110c with respect to an etchant is preferably higher than the etching rate of the insulating layer 120b. Note that the diffusion coefficient of the substance in the insulating layer 120b may be lower than or equal to the diffusion coefficient of the substance in the insulating layer 110c. The F ratio in the formation of the insulating layer 120b may be lower than or equal to the F ratio in the formation of the insulating layer 110c. The etching rate of the insulating layer 120b with respect to an etchant may be higher than or equal to the etching rate of the insulating layer 110c.

It is preferable that the insulating layer 120a itself release a small amount of impurities (e.g., hydrogen and water) and not easily transmit impurities. Thus, the impurities contained in the insulating layer 120a can be inhibited from being diffused into the channel formation region in the semiconductor layer 208. Consequently, the transistor 200 with favorable electrical characteristics and high reliability can be obtained.

For the insulating layer 120a, a film that does not easily transmit oxygen is preferably used. Accordingly, oxygen contained in the insulating layer 120b can be inhibited from being diffused into the conductive layer 202 through the insulating layer 120a. This can inhibit the conductive layer 202 from being oxidized and having increased electric resistance. At the same time, oxygen contained in the insulating layer 120b can be inhibited from being diffused to the insulating layer 120a side, which increases the amount of oxygen supplied to the channel formation region from the insulating layer 120b and can reduce oxygen vacancies (V_{O}) and V_{O}H in the channel formation region.

For the insulating layer 120a positioned on the conductive layer 202 side, a material that does not easily allow diffusion of a metal element contained in the conductive layer 202 is preferably used. This inhibits the metal element contained in the conductive layer 202 from being diffused into the channel formation region in the semiconductor layer 208 through the insulating layer 120.

For the insulating layer 120a, a material that can be used for each of the insulating layer 110b and the insulating layer 110d is preferably used. The insulating layer 120a preferably contains nitrogen and is suitably formed using any one or more of a nitride and a nitride oxide. Specifically, for example, one or both of silicon nitride and silicon nitride can be suitably used for the insulating layer 120a. Alternatively, any one or more of an oxide and an oxynitride can be used for the insulating layer 120a. For the insulating layer 120a, aluminum oxide can be suitably used, for example. For the insulating layer 120a, the insulating layer 110b, and the insulating layer 110d, the same material or different materials may be used.

The insulating layer 120a is provided over the insulating layer 109. The insulating layer 109 preferably includes a region having a higher impurity content than the insulating layer 120a. Specifically, the insulating layer 109 preferably includes a region having a higher hydrogen content than the insulating layer 120a.

The film density of the insulating layer 120a is preferably higher than the film density of the insulating layer 109. The description of the insulating layer 110b and the insulating layer 110d can be referred to for the insulating layer 120a; thus, the detailed description thereof is omitted. Note that the film density of the insulating layer 120a may be lower than or equal to the film density of the insulating layer 109.

Although the insulating layer 120 has a two-layer structure here, one embodiment of the present invention is not limited thereto. The insulating layer 120 may have a stacked-layer structure of three or more layers or a single-layer structure.

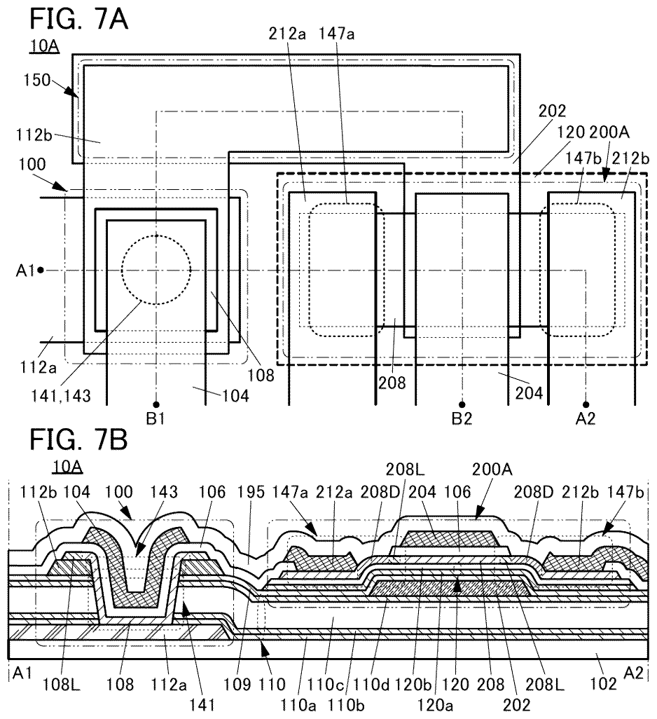

Although FIG. 1B and the like illustrate a structure where the semiconductor layer 208 includes a region in contact with the side surface of the insulating layer 120, one embodiment of the present invention is not limited thereto. FIG. 7A is a top view of a semiconductor device 10A of one embodiment of the present invention. FIG. 7B is a cross-sectional view of a cut plane along the dashed-dotted line A1-A2 illustrated in FIG. 7A. FIG. 1C can be referred to for a cross-sectional view of a cut plane along the dashed-dotted line B1-B2 illustrated in FIG. 7A. The semiconductor device 10A includes the transistor 100, a transistor 200A, the capacitor 150, and the insulating layer 110. As in the transistor 200A, a structure can be employed where the semiconductor layer 208 does not include a region in contact with the side surface of the insulating layer 120. The end portion of the semiconductor layer 208 is in contact with the top surface of the insulating layer 120. The insulating layer 120 is provided in the entire region where the semiconductor layer 208 is provided, and the entire bottom surface of the semiconductor layer 208 is in contact with the top surface of the insulating layer 120. In the top view, the insulating layer 120 covers the semiconductor layer 208. This reduces a step in the formation surface of the semiconductor layer 208 and can improve the coverage with the semiconductor layer 208.

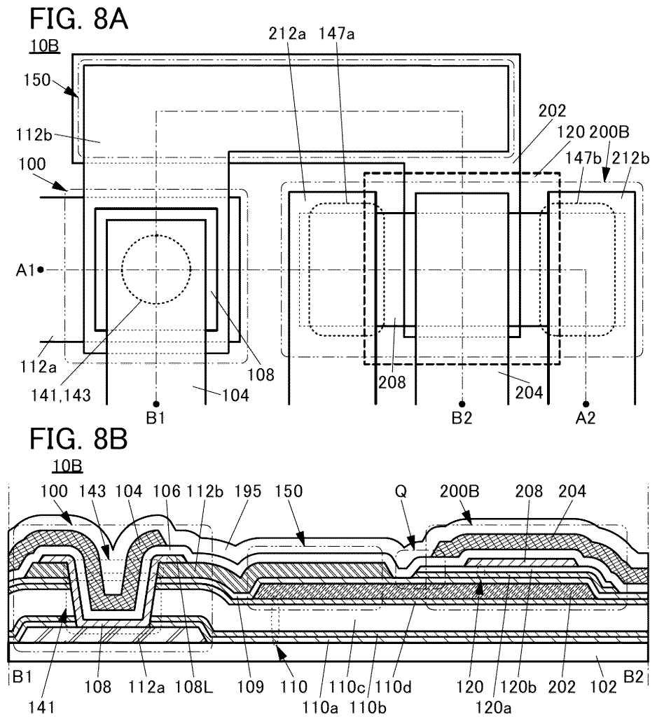

Although FIG. 1C and the like illustrate a structure where the insulating layer 120 includes a region in contact with the conductive layer 112b, one embodiment of the present invention is not limited thereto. FIG. 8A is a top view of a semiconductor device 10B of one embodiment of the present invention. FIG. 1B can be referred to for a cross-sectional view of a cut plane along the dashed-dotted line A1-A2 illustrated in FIG. 8A. FIG. 8B is a cross-sectional view of a cut plane along the dashed-dotted line B1-B2 illustrated in FIG. 8A. The semiconductor device 10B includes the transistor 100, a transistor 200B, the capacitor 150, and the insulating layer 110. As in the transistor 200B, a structure can be employed where the insulating layer 120 does not include a region in contact with the conductive layer 112b. As in a region Q indicated by a dashed-dotted line in FIG. 8B, the end portion of the insulating layer 120 is in contact with the top surface of the insulating layer 109.

In the semiconductor layer 208, the region 208D is a region having lower electric resistance than the channel formation region. In other words, the region 208D is a region having a higher carrier concentration, a region having a higher oxygen vacancy density, or a region having a higher impurity concentration than the channel formation region.

The region 208L is a region whose electric resistance is substantially equal to or higher than that of the channel formation region. The region 208L can be referred to as a region whose carrier concentration is substantially equal to or higher than that of the channel formation region, a region whose oxygen vacancy density is substantially equal to or higher than that of the channel formation region, or a region whose impurity concentration is substantially equal to or higher than that of the channel formation region. Furthermore, the region 208L is a region whose electric resistance is substantially equal to or higher than that of the region 208D. The region 208L can be referred to as a region whose carrier concentration is substantially equal to or lower than that of the region 208D, a region whose oxygen vacancy density is substantially equal to or lower than that of the region 208D, or a region whose impurity concentration is substantially equal to or lower than that of the region 208D.

The region 208L functions as a buffer region that relieves a drain electric field. The region 208L is a region not overlapping with the conductive layer 204 and thus is a region where a channel is hardly formed by application of gate voltage to the conductive layer 204. The region 208L preferably has a higher carrier concentration than the channel formation region. Thus, the region 208L can function as an LDD (Lightly Doped Drain) region. The region 208L functioning as the LDD region is provided between the channel formation region and the region 208D, whereby the transistor 200 can have a high drain breakdown voltage.

The carrier concentration in the semiconductor layer 208 preferably has a distribution such that the concentration is lowest in the channel formation region and increases in the order of the region 208L and the region 208D. Providing the region 208L between the channel formation region and the region 208D can keep the carrier concentration of the channel formation region extremely low even when an impurity such as hydrogen is diffused from the region 208D in the manufacturing process, for example.

Note that the carrier concentration in the region 208L is not necessarily uniform and sometimes has a gradient such that the carrier concentration decreases from the region 208D side toward the channel formation region. For example, one or both of the hydrogen concentration and the oxygen vacancy (V_{O}) concentration in the region 208L may have a gradient such that the concentration decreases from the region 208D side to the channel formation region side.

As illustrated in FIG. 1B and the like, end portions of parts of the conductive layer 212a and the conductive layer 212b are preferably positioned in the opening 147a and the opening 147b, respectively. In other words, the end portions of parts of the conductive layer 212a and the conductive layer 212b preferably have a region in contact with the semiconductor layer 208 in the opening 147a and the opening 147b, respectively. Accordingly, the region in contact with the conductive layer 212a can be adjacent to one of the pair of regions 208D and the region in contact with the conductive layer 212b can be adjacent to the other of the pair of regions 208D. The region in contact with the conductive layer 212a and the one of the pair of regions 208D function as one of the source region and the drain region of the transistor 200. The region in contact with the conductive layer 212b and the other of the pair of regions 208D function as the other of the source region and the drain region of the transistor 200.

There is no particular limitation on the top surface shapes of the opening 147a and the opening 147b. The top surface shapes of the opening 147a and the opening 147b can be any of the shapes that can be used for the opening 141 and the opening 143. Although the top surface shapes of the opening 147a and the opening 147b are quadrangles with rounded corners unlike the top surface shapes of the opening 141 and the opening 143 in the structure illustrated in FIG. 1A and the like, one embodiment of the present invention is not limited thereto. The top surface shapes of the opening 147a and the opening 147b may be the same as the top surface shapes of the opening 141 and the opening 143.

When the region 208L and the region 208D are formed by supplying an impurity element to the semiconductor layer 208, the impurity element may be supplied to the semiconductor layer 108 through the insulating layer 106 using the conductive layer 104 as a mask. In that case, a region 108L is formed in the region of the semiconductor layer 108 that does not overlap with the conductive layer 104. Note that in the transistor 100, the region of the semiconductor layer 108 that is in contact with the conductive layer 112b functions as the source region or the drain region. The region 108L is formed in part of the source region or the drain region. Note that the impurity element concentration in the region 108L may be different from the impurity element concentration in the region 208L. The region 108L is not necessarily formed. For example, in the case where the conductive layer 104 extends to cover the end portion of the semiconductor layer 108, the conductive layer 104 masks the whole semiconductor layer 108; thus, the impurity element is not supplied to the semiconductor layer 108 and the region 108L is not formed.

Although the conductive layer 212a and the conductive layer 212b are formed in the same step as the conductive layer 204 here, one embodiment of the present invention is not limited thereto. The conductive layer 212a and the conductive layer 212b may be formed in a step different from that in which the conductive layer 204 is formed. For example, the conductive layer 104 and the conductive layer 204 are formed over the insulating layer 106 and an impurity element is supplied to the semiconductor layer 208 using the conductive layer 204 as a mask, whereby the source region and the drain region are formed. The insulating layer 195 is formed over the conductive layer 104 and the conductive layer 204, an opening reaching the source region and an opening reaching the drain region are formed in the insulating layer 106 and the insulating layer 195, and the conductive layer 212a and the conductive layer 212b can be formed to cover the openings.

Although the thickness of the semiconductor layer 208 is uniform without varying from place to place in the example illustrated in FIG. 1B and the like, one embodiment of the present invention is not limited thereto. A structure can be employed where the thickness of the semiconductor layer 208 is different between the region overlapping with the insulating layer 106 and the region not overlapping with the insulating layer 106. For example, when the opening 147a and the opening 147b are formed, the semiconductor layer 208 is sometimes partly removed, so that the semiconductor layer 208 has a thickness smaller in the region not overlapping with the insulating layer 106 than in the region overlapping with the insulating layer 106. Alternatively, the thickness of the semiconductor layer 208 may be different between the region overlapping with any of the insulating layer 106, the conductive layer 212a, and the conductive layer 212b and the region overlapping with none of them. For example, when the conductive layer 212a and the conductive layer 212b are formed, the semiconductor layer 208 is sometimes partly removed, so that the semiconductor layer 208 has a thickness smaller in the region overlapping with none of the insulating layer 106, the conductive layer 212a, and the conductive layer 212b than in the region overlapping with any of them. Alternatively, the thickness of the semiconductor layer 208 may be different among the region overlapping with the insulating layer 106, the region overlapping with any of the insulating layer 106, the conductive layer 212a, and the conductive layer 212b, and the region overlapping with none of them.

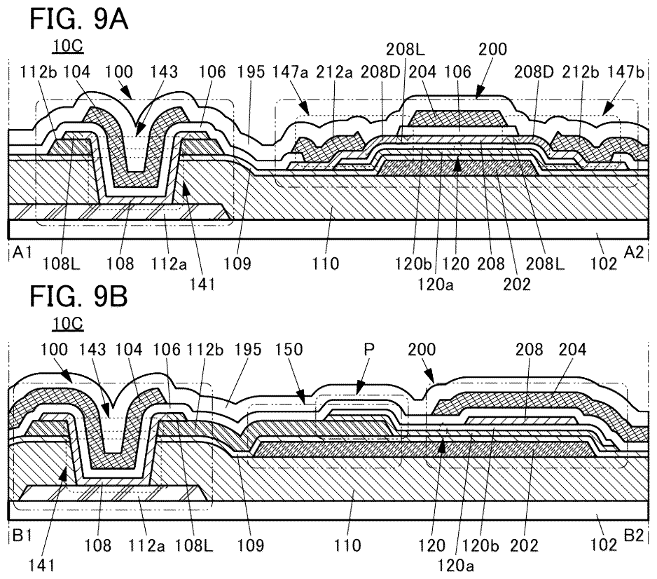

Although FIG. 1B and the like illustrate a structure where the insulating layer 110 has a stacked-layer structure, one embodiment of the present invention is not limited thereto. The insulating layer 110 can have a single-layer structure. FIG. 9A and FIG. 9B are cross-sectional views of a semiconductor device 10C of one embodiment of the present invention. FIG. 1A can be referred to for a top view of the semiconductor device 10C. FIG. 9A is a cross-sectional view of a cut plane along the dashed-dotted line A1-A2 illustrated in FIG. 1A, and FIG. 9B is a cross-sectional view of a cut plane along the dashed-dotted line B1-B2 illustrated in FIG. 1A. The semiconductor device 10C includes the transistor 100, the transistor 200, the capacitor 150, and the insulating layer 110. The insulating layer 110 has a single-layer structure.

The region of the semiconductor layer 108 that is in contact with the insulating layer 110 functions as the channel formation region of the transistor 100. The amount of impurities released from the insulating layer 110 is preferably as small as possible. In the case where a metal oxide is used for the semiconductor layer 108, the amount of impurities containing a hydrogen element released from the insulating layer 110 is preferably as small as possible. The hydrogen content of the insulating layer 110 is preferably as low as possible. This inhibits supply of hydrogen to the semiconductor layer 108, whereby the transistor 100 can have favorable electrical characteristics. Silicon nitride can be suitably used for the insulating layer 110, for example. The insulating layer 110 is preferably formed by a method not using a gas containing hydrogen. In this case, the insulating layer 110 having a low hydrogen content can be formed. For the formation of the insulating layer 110, a sputtering method can be particularly suitably used.

Note that in the case where the insulating layer 110 has a single-layer structure, the amount of impurities containing a hydrogen element released from the insulating layer 109 is also preferably as small as possible. The hydrogen content of the insulating layer 109 is preferably as low as possible. In this case, the region of the semiconductor layer 108 that is in contact with the insulating layer 109 may also function as the channel formation region. Silicon nitride can be suitably used for the insulating layer 109, for example. For the formation of the insulating layer 109, a sputtering method can be particularly suitably used.

### [Semiconductor Layer 108 and Semiconductor Layer 208]

Metal oxides that can be used for the semiconductor layer 108 and the semiconductor layer 208 are specifically described. Examples of the metal oxide include indium oxide, gallium oxide, and zinc oxide. The metal oxide preferably contains at least indium or zinc. The metal oxide preferably contains one or two or more selected from indium, an element M, and zinc. The element M is a metal element or metalloid element that has a high bonding energy with oxygen, such as a metal element or metalloid element whose bonding energy with oxygen is higher than that of indium, for example. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from gallium, aluminum, tin, and yttrium, and still further preferably one or more of gallium, aluminum, and tin. These elements are further preferable because they have high bonding energy with oxygen and have substantially the same ion radius as indium or zinc. In addition, tin is tetravalent and is preferable because the carrier mobility can be increased. In this specification and the like, a metal element and a metalloid element may be collectively referred to as a “metal element”, and a “metal element” described in this specification and the like may refer to a metalloid element.

For each of the semiconductor layer 108 and the semiconductor layer 208, indium zinc oxide (also referred to as In—Zn oxide or IZO (registered trademark)), indium tin oxide (also referred to as In—Sn oxide or ITO), indium titanium oxide (In—Ti oxide), indium gallium oxide (In—Ga oxide), indium tungsten oxide (also referred to as In—W oxide or IWO), indium gallium aluminum oxide (In—Ga—Al oxide), indium gallium tin oxide (also referred to as In—Ga—Sn oxide or IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO) can be used, for example. Alternatively, indium tin oxide containing silicon (also referred to as ITSO), gallium tin oxide (Ga—Sn oxide), aluminum tin oxide (Al—Sn oxide), or the like can be used.

Note that the metal oxide may contain, instead of or in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a larger period number can have high field-effect mobility in some cases. Examples of the metal element with a larger period number include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

When the proportion of the number of indium atoms in the total number of atoms of all the metal elements contained in the metal oxide is increased, the field-effect mobility of the transistor can be increased. In addition, the transistor can have a high on-state current.

In this specification and the like, the proportion of the number of indium atoms in the total number of atoms of all the metal elements contained is sometimes referred to as indium content percentage. The same applies to other metal elements. In the case where a plurality of elements are contained as the element M, the sum of the proportion of the number of element M atoms in the total number of atoms of all the metal elements contained can be referred to as the content percentage of the element M.

By increasing the content percentage of zinc in the metal oxide, the metal oxide has high crystallinity, so that diffusion of impurities in the metal oxide can be inhibited. Consequently, a change in electrical characteristics of the transistor can be inhibited, and the reliability of the transistor can be improved.

By increasing the content percentage of the element M in the metal oxide, the metal oxide can have a wide band gap. In addition, formation of oxygen vacancies (V_{O}) in the metal oxide is inhibited; accordingly, generation of carriers due to oxygen vacancies (V_{O}) is inhibited and a shift in the threshold voltage of the transistor can be inhibited. This can reduce a cutoff current, so that the transistor can have normally-off characteristics. Moreover, a transistor with a low off-state current can be provided. Furthermore, a change in electrical characteristics of the transistor can be inhibited, and the reliability of the transistor can be improved.

The electrical characteristics and reliability of the transistors depend on the compositions of the metal oxides used for the semiconductor layer 108 and the semiconductor layer 208. Therefore, by determining the composition of the metal oxide in accordance with the electrical characteristics and reliability required for the transistor, the semiconductor device can have both favorable electrical characteristics and high reliability.

When a metal oxide is In-M-Zn oxide, the atomic proportion of In is preferably higher than or equal to the atomic proportion of the element M in the In-M-Zn oxide. Examples of the atomic ratio of the metal elements in such In-M-Zn oxide include In:M:Zn=1:1:1, In:M:Zn=1:1:1.2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=5:1:9, In:M:Zn=6:1:6, In:M:Zn=10:1:1, In:M:Zn=10:1:3, In:M:Zn=10:1:4, In:M:Zn=10:1:6, In:M:Zn=10:1:7, In:M:Zn=10:1:8, In:M:Zn=5:2:5, In:M:Zn=10:1:10, In:M:Zn=20:1:10, In:M:Zn=40:1:10, and a composition in the neighborhood of any of these atomic ratios. Note that a composition in the neighborhood includes the range of ±30% of an intended atomic ratio. By increasing the atomic proportion of indium in the metal oxide, the on-state current or field-effect mobility of the transistor can be improved.

The atomic proportion of In can also be lower than the atomic proportion of the element M in the In-M-Zn oxide. Examples of the atomic ratio of the metal elements in such In-M-Zn oxide include In:M:Zn=1:3:2, In:M:Zn=1:3:3, In:M:Zn=1:3:4, and In:M:Zn=1:3:6 and a composition in the neighborhood of any of these atomic ratios. By increasing the proportion of the number of element M atoms in the metal oxide, generation of oxygen vacancies (V_{O}) can be inhibited.

In the case where a plurality of elements are contained as the element M, the sum of the atomic proportions of the elements can be the atomic proportion of the element M.

The use of a material with a high indium content percentage for each of the semiconductor layer 108 and the semiconductor layer 208 can increase the on-state current or field-effect mobility of the transistors. Furthermore, with the element M, generation of oxygen vacancies (V_{O}) can be inhibited. The content percentage of the element M (the proportion of the number of element M atoms in the total number of atoms of all the metal elements contained) is preferably higher than or equal to 0.1% and lower than or equal to 25%, further preferably higher than or equal to 0.1% and lower than or equal to 20%, still further preferably higher than or equal to 0.1% and lower than or equal to 10%, yet still further preferably higher than or equal to 0.1% and lower than or equal to 8%, yet still further preferably higher than or equal to 0.1% and lower than or equal to 6%, yet still further preferably higher than or equal to 0.1% and lower than or equal to 4%. Accordingly, a transistor with favorable electrical characteristics can be provided. For example, a metal oxide with In:M:Zn of 40:1:10 or the neighborhood thereof is preferably used. The element M is preferably one or more kinds of the above elements, further preferably one or more kinds selected from aluminum, gallium, tin, and yttrium. Specifically, a metal oxide with In:Sn:Zn of 40:1:10 or the neighborhood thereof can be suitably used. Alternatively, a metal oxide with In:Al:Zn of 40:1:10 or the neighborhood thereof can be suitably used.

Here, in the case where a metal oxide having a polycrystalline structure is used for each of the semiconductor layer 108 and the semiconductor layer 208, the grain boundary becomes a recombination center and captures carriers and thus might reduce the on-state current of the transistor. When a metal oxide having a polycrystalline structure is used for the semiconductor layer 108, unevenness of the surface of the semiconductor layer 108 is increased in some cases. This increases a step in the formation surface of a layer formed over the semiconductor layer 108 (e.g., the insulating layer 106), so that generation of defects such as step disconnection or voids in the layer sometimes occurs. In the case where a metal oxide with a composition that tends to form a polycrystalline structure is used for the semiconductor layer 108, the metal oxide preferably contains an element that hinders crystallization. This inhibits the semiconductor layer 108 from having a polycrystalline structure, so that a transistor with a high on-state current can be obtained. In addition, the step coverage with a layer formed over the semiconductor layer 108 (e.g., the insulating layer 106) can be improved, which can inhibit defects such as step disconnection or a void from being generated in the layer.

For example, indium tin oxide containing silicon (ITSO) is less likely to have a polycrystalline structure than indium tin oxide (ITO), and thus can be suitably used for each of the semiconductor layer 108 and the semiconductor layer 208. In the case where ITSO is used, the content percentage of silicon (the proportion of the number of silicon atoms in the total number of atoms of all the metal elements contained) is preferably higher than or equal to 1% and lower than or equal to 20%, further preferably higher than or equal to 3% and lower than or equal to 20%, further preferably higher than or equal to 3% and lower than or equal to 15%, still further preferably higher than or equal to 5% and lower than or equal to 15%. Specifically, a metal oxide with In:Sn:Si of 45:5:4, In:Sn:Si of 95:5:8, or the neighborhood thereof can be suitably used. In the case where indium tin oxide containing silicon (ITSO) is used for the semiconductor layer 108, the semiconductor layer 108 preferably has crystallinity. Note that the semiconductor layer 108 may include an amorphous region or may be amorphous.

A metal oxide that does not contain the element M can be used for each of the semiconductor layer 108 and the semiconductor layer 208. In the case where the metal oxide is In—Zn oxide, examples of the atomic ratio of metal elements include In:Zn=1:1, In:Zn=2:1, In:Zn=1:2, In:Zn=3:1, In:Zn=3:2, In:Zn=2:3, In:Zn=4:1, In:Zn=4:3, In:Zn=5:1, In:Zn=5:2, In:Zn=5:3, In:Zn=5:4, In:Zn=5:6, In:Zn=5:7, In:Zn=5:8, In:Zn=5:9, In:Zn=7:1, In:Zn=10:1, In:Zn=10:3, In:Zn=10:7, or the vicinity thereof. Furthermore, the atomic proportion of In is preferably higher than or equal to the atomic proportion of Zn. By increasing the atomic proportion of indium in the metal oxide, the on-state current or field-effect mobility of the transistor can be increased.

For analysis of the compositions of the semiconductor layer 108 and the semiconductor layer 208, for example, energy dispersive X-ray spectrometry (EDX), X-ray photoelectron spectrometry (XPS or ESCA: Electron Spectrometry for Chemical Analysis), inductively coupled plasma-mass spectrometry (ICP-MS), or inductively coupled plasma-atomic emission spectrometry (ICP-AES) can be used. Alternatively, these methods may be combined for the analysis. It is preferable that peak separation of a spectrum obtained by the analysis be performed to identify and quantify an element. Note that as for an element whose content percentage is low, the actual content percentage may be different from the content percentage obtained by analysis because of the influence of the analysis accuracy. In the case where the content percentage of the element M is low, for example, the content percentage of the element M obtained by analysis may be lower than the actual content percentage or difficult to quantify, or the element M may be below the lower detection limit.

A sputtering method or an atomic layer deposition (ALD) method can be suitably used for formation of the metal oxide. Note that in the case where the metal oxide is formed by a sputtering method, the composition of the formed metal oxide may be different from the composition of a sputtering target. In particular, the content percentage of zinc in the formed metal oxide may be reduced to approximately 50% of that of the sputtering target.

It is preferable to use a metal oxide having crystallinity for each of the semiconductor layer 108 and the semiconductor layer 208. Examples of the structure of a metal oxide having crystallinity include a CAAC (c-axis aligned crystalline) structure, a polycrystalline structure, and a nano-crystal (nc) structure. With use of a metal oxide having crystallinity, the density of defect states in the semiconductor layer 108 and the semiconductor layer 208 can be reduced, which enables the semiconductor device to have high reliability.

For each of the semiconductor layer 108 and the semiconductor layer 208, a CAAC-OS or an nc-OS is preferably used.

The CAAC-OS includes a plurality of layered crystals. The c-axis of the crystal is aligned in the normal direction of the formation surface. The semiconductor layer 108 and the semiconductor layer 208 each preferably include a layered crystal parallel or substantially parallel to the formation surface. For example, the semiconductor layer 108 preferably includes a layered crystal parallel or substantially parallel to the top surface of the conductive layer 112b in a region in contact with the top surface, and a layered crystal parallel or substantially parallel to the side surface of the conductive layer 112b in a region in contact with the side surface. In particular, in the opening 141, the semiconductor layer 108 preferably includes a layered crystal parallel or substantially parallel to the side surface of the insulating layer 110 serving as the formation surface. With such a structure, the layered crystals of the semiconductor layer 108 are formed parallel or substantially parallel to the channel length direction of the transistor 100, so that the on-state current of the transistor can be increased. Similarly, the semiconductor layer 208 preferably includes a layered crystal parallel or substantially parallel to the formation surface (here, the top surface and the side surface of the insulating layer 120 and the top surface of the insulating layer 110). In particular, in a region overlapping with the conductive layer 204, the semiconductor layer 208 preferably includes a layered crystal parallel or substantially parallel to the top surface of the insulating layer 120 serving as the formation surface.

The use of a metal oxide having high crystallinity in a channel formation region can reduce the density of defect states in the channel formation region. By contrast, the use of a metal oxide having low crystallinity enables a transistor to flow a large amount of current.

The higher the substrate temperature at the time of forming of the metal oxide is, the higher the crystallinity of the formed metal oxide can be. For example, the substrate temperature at the time of formation can be adjusted by the temperature of the stage on which the substrate is placed at the time of formation. Furthermore, the higher the proportion of the flow rate of an oxygen gas to the total flow rate of the film formation gas used for the formation (also referred to as an oxygen flow rate ratio) or the oxygen partial pressure in a treatment chamber is, the higher the crystallinity of the formed metal oxide can be.

The crystallinity of the semiconductor layer 108 and the semiconductor layer 208 can be analyzed with X-ray diffraction (XRD), a transmission electron microscope (TEM), electron diffraction (ED), or the like, for example. Alternatively, these methods may be combined for the analysis.

In the case where a metal oxide is used for each of the semiconductor layer 108 and the semiconductor layer 208, V_{O}H in the channel formation region is preferably reduced as much as possible so that the semiconductor layer 108 and the semiconductor layer 208 become highly purified intrinsic or substantially highly purified intrinsic semiconductor layers. In order to obtain such a metal oxide with sufficiently reduced V_{O}H, it is important to remove impurities such as water and hydrogen in the metal oxide (this treatment is sometimes referred to as dehydration or dehydrogenation treatment) and supply oxygen to the metal oxide to repair oxygen vacancies (V_{O}). When a metal oxide in which impurities such as V_{O}H are sufficiently reduced is used for a channel formation region of a transistor, stable electrical characteristics can be given. Supplying oxygen to a metal oxide to repair oxygen vacancies (V_{O}) is sometimes referred to as oxygen adding treatment.

When a metal oxide is used for each of the semiconductor layer 108 and the semiconductor layer 208, the carrier concentration in the channel formation region is preferably lower than or equal to 1×10¹⁸ cm⁻³, further preferably lower than 1×10¹⁷ cm⁻³, still further preferably lower than 1×10¹⁶ cm⁻³, yet still further preferably lower than 1×10¹³ cm³, yet still further preferably lower than 1×10¹² cm⁻³. Note that the lower limit of the carrier concentration in the channel formation region is not particularly limited and can be, for example, 1×10⁻⁹ cm⁻³.

A change in electrical characteristics of an OS transistor due to irradiation with radiation is small, i.e., an OS transistor has high resistance to radiation; thus, an OS transistor can be suitably used even in an environment where radiation might enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

The semiconductor layer 108 and the semiconductor layer 208 may each include a layered substance functioning as a semiconductor. The layered substance generally refers to a group of materials having a layered crystal structure. In the layered crystal structure, layers formed by covalent bonding or ionic bonding are stacked with bonding such as the van der Waals bonding, which is weaker than covalent bonding or ionic bonding. The layered substance has high electrical conductivity in a unit layer, that is, high two-dimensional electrical conductivity. When a material functioning as a semiconductor and having high two-dimensional electrical conductivity is used for a channel formation region, a transistor having a high on-state current can be provided.

Examples of the layered substance include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide that can be used for a channel formation region of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The semiconductor layer 108 and the semiconductor layer 208 can each have a stacked-layer structure including two or more metal oxide layers. The compositions of the two or more metal oxide layers included in each of the semiconductor layer 108 and the semiconductor layer 208 may be the same or substantially the same. Employing a stacked-layer structure of metal oxide layers having the same composition can reduce the manufacturing cost because the metal oxide layers can be formed using the same sputtering target. When the compositions of the two or more metal oxide layers included in each of the semiconductor layer 108 and the semiconductor layer 208 are the same or substantially the same, a boundary (interface) between the metal oxide layers cannot be clearly observed in some cases.

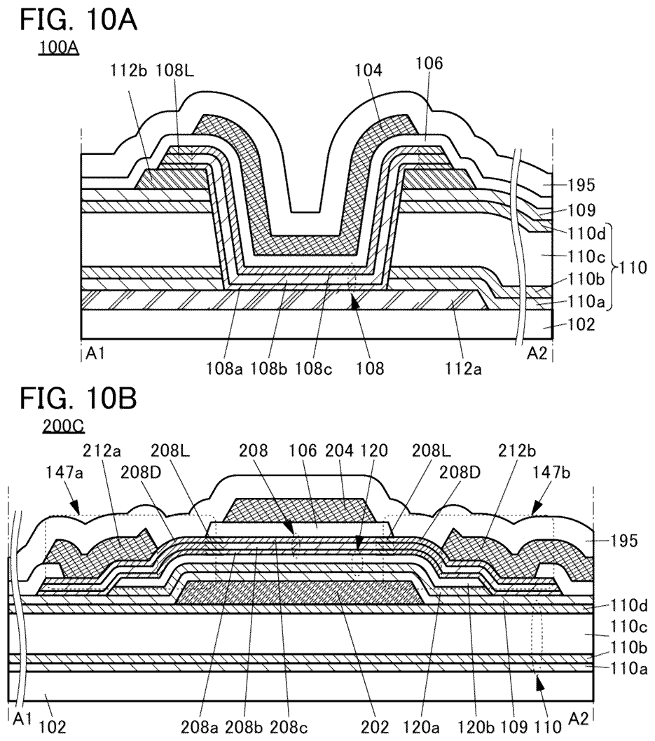

FIG. 10A and FIG. 10B illustrate structures where the semiconductor layer 108 and the semiconductor layer 208 have a stacked-layer structure. In a transistor 100A illustrated in FIG. 10A, the semiconductor layer 108 has a stacked-layer structure of the semiconductor layer 108a, a semiconductor layer 108b over the semiconductor layer 108a, and a semiconductor layer 108c over the semiconductor layer 108b. In a transistor 200C illustrated in FIG. 10B, the semiconductor layer 208 has a stacked-layer structure of a semiconductor layer 208a, a semiconductor layer 208b over the semiconductor layer 208a, and a semiconductor layer 208c over the semiconductor layer 208b.

The compositions of the semiconductor layer 108a and the semiconductor layer 208a can be the same or substantially the same. The compositions of the semiconductor layer 108b and the semiconductor layer 208b can be the same or substantially the same. The compositions of the semiconductor layer 108c and the semiconductor layer 208c can be the same or substantially the same. The semiconductor layer 108a and the semiconductor layer 208a can be formed in the same step, the semiconductor layer 108b and the semiconductor layer 208b can be formed in the same step, and the semiconductor layer 108c and the semiconductor layer 208c can be formed in the same step. For example, a first semiconductor film to be the semiconductor layer 108a and the semiconductor layer 208a, a second semiconductor film to be the semiconductor layer 108b and the semiconductor layer 208b, and a third semiconductor film to be the semiconductor layer 108c and the semiconductor layer 208c are formed and processed, so that the semiconductor layer 108 including the semiconductor layer 108a to the semiconductor layer 108c and the semiconductor layer 208 including the semiconductor layer 208a to the semiconductor layer 208c can be formed.

The semiconductor layer 108a, the semiconductor layer 108b, the semiconductor layer 108c, the semiconductor layer 208a, the semiconductor layer 208b, and the semiconductor layer 208c each preferably include a metal oxide exhibiting semiconductor characteristics. The band gaps of a first metal oxide included in the semiconductor layer 108a and the semiconductor layer 208a, a second metal oxide included in the semiconductor layer 108b and the semiconductor layer 208b, and a third metal oxide included in the semiconductor layer 108c and the semiconductor layer 208c are each preferably greater than or equal to 2.0 eV, further preferably greater than or equal to 2.5 eV.

The band gap of the first metal oxide is preferably different from the band gap of the second metal oxide. The band gap of the third metal oxide is preferably different from the band gap of the second metal oxide. Furthermore, the band gap of the third metal oxide is preferably different from the band gap of the first metal oxide.

The band gap of the first metal oxide is preferably wider than the band gap of the second metal oxide. The band gap of the third metal oxide is preferably wider than the band gap of the second metal oxide. The semiconductor layer 108b is interposed between the semiconductor layer 108a and the semiconductor layer 108c, each of which has a wider band gap than the semiconductor layer 108b, and thus can have a structure of a buried channel. Thus, the semiconductor layer 108b serves as a main current path in the semiconductor layer 108. Similarly, the semiconductor layer 208b serves as a main current path in the semiconductor layer 208

It is further preferable that the band gap of the third metal oxide be wider than the band gap of the first metal oxide. By using a material having a wide band gap for the semiconductor layer 108c positioned closer to the conductive layer 104 functioning as the gate electrode of the transistor 100, carriers can be inhibited from being generated and induced in the semiconductor layer 108c and at the interface between the semiconductor layer 108c and the gate insulating layer (here, the insulating layer 106); thus, the transistor can have high reliability. For example, carriers can be inhibited from being generated and induced in the semiconductor layer 108c and at the interface due to light entering the transistor, so that a change in electrical characteristics of the transistor due to the light can be inhibited. The same applies to the semiconductor layer 208c positioned closer to the conductive layer 204 functioning as the gate electrode of the transistor 200. Note that there is no particular limitation on the magnitude relationship in width of the band gap between the first metal oxide, the second metal oxide, and the third metal oxide.

The semiconductor layer 108a includes regions in contact with the conductive layer 112a and the conductive layer 112b functioning as the source electrode and the drain electrode. When the band gap of the first metal oxide included in the semiconductor layer 108a is narrower than the band gap of the third metal oxide, the contact resistance between the semiconductor layer 108a and the conductive layer 112a and the contact resistance between the semiconductor layer 108a and the conductive layer 112b can be reduced. This enables the transistor to have a high on-state current.

The conduction band minimum of the first metal oxide is preferably closer to the vacuum level than the conduction band minimum of the second metal oxide is. The conduction band minimum of the third metal oxide is preferably closer to the vacuum level than the conduction band minimum of the second metal oxide is. In other words, the electron affinity of the first metal oxide is preferably smaller than the electron affinity of the second metal oxide. The electron affinity of the third metal oxide is preferably smaller than the electron affinity of the second metal oxide. It is further preferable that the conduction band minimum of the third metal oxide be closer to the vacuum level than the conduction band minimum of the first metal oxide is. In other words, it is further preferable that the electron affinity of the third metal oxide be smaller than the electron affinity of the first metal oxide. Note that there is no particular limitation on the magnitude relationship in electron affinity between the first metal oxide, the second metal oxide, and the third metal oxide.

The band gaps of the first metal oxide, the second metal oxide, and the third metal oxide can be evaluated using optical evaluation with a spectrophotometer, spectroscopic ellipsometry, a photoluminescence method, X-ray photoelectron spectroscopy (XPS or ESCA), or an X-ray absorption fine structure (XAFS). Alternatively, any of these methods may be combined with each other for the analysis. The electron affinity or the conduction band minimum can be obtained from a band gap and an ionization potential, which is the difference between a vacuum level and the energy of valence band maximum. The ionization potential can be evaluated by, for example, ultraviolet photoelectron spectrometry (UPS).

Here, a trap state due to impurities or defects can be formed at the interface between the insulating layer 110 and the semiconductor layer 108 and in the vicinity thereof. Examples of the impurities include a remaining component of an etchant or an etching gas used in the formation of the opening 141 and components of the conductive layer 112a and the conductive layer 112b attached to the side surface of the insulating layer 110 in the formation of the opening 141. Providing the semiconductor layer 108a between the semiconductor layer 108b and the insulating layer 110 can make the semiconductor layer 108b and the trap state to be distant from each other.

The interface between the insulating layer 106 and the semiconductor layer 108, the interface between the insulating layer 106 and the semiconductor layer 208, and the vicinity of the interfaces might be damaged at the time of forming the insulating layer 106. Accordingly, trap states can be formed at the interface between the insulating layer 106 and the semiconductor layer 108, the interface between the insulating layer 106 and the semiconductor layer 208, and the vicinity of the interfaces. Providing the semiconductor layer 108c between the semiconductor layer 108b and the insulating layer 106 can make the semiconductor layer 108b and the trap state to be distant from each other. Similarly, providing the semiconductor layer 208c between the semiconductor layer 208b and the insulating layer 106 can make the semiconductor layer 208b and the trap state to be distant from each other.

When the semiconductor layer 108b, which is the main current path of the semiconductor layer 108, is interposed between the semiconductor layer 108a and the semiconductor layer 108c, the trap states at the interface of the semiconductor layer 108b and the vicinity thereof can be reduced. Similarly, when the semiconductor layer 208b, which is the main current path of the semiconductor layer 208, is interposed between the semiconductor layer 208a and the semiconductor layer 208c, the trap states at the interface of the semiconductor layer 208b and the vicinity thereof can be reduced. This structure enables the transistor to have a high-on state and high reliability. Consequently, the semiconductor device achieving both high speed operation and high reliability can be provided.

The compositions of the first metal oxide, the second metal oxide, and the third metal oxide are preferably different from each other. The electrical characteristics and reliability of the transistor depend on the composition of the metal oxide used for the semiconductor layer. Therefore, by making the compositions of the first metal oxide, the second metal oxide, and the third metal oxide different from each other in accordance with the electrical characteristics and reliability required for the transistor, the semiconductor device can have both favorable electrical characteristics and high reliability.

The second metal oxide used for each of the semiconductor layer 108b and the semiconductor layer 208b preferably has a high atomic proportion of indium. In the second metal oxide, the atomic proportion of indium is preferably higher than the atomic proportion of the element M. By using a metal oxide having a high atomic proportion of indium for each of the semiconductor layer 108b and the semiconductor layer 208b, which are main current paths, the on-state current or field-effect mobility of the transistor can be increased. It is further preferable that in the second metal oxide, the atomic proportion of In be higher than or equal to the atomic proportion of Zn. By increasing the atomic proportion of indium in the metal oxide, the on-state current or field-effect mobility of the transistor can be increased. Note that in the second metal oxide, the atomic proportion of In may be lower than the atomic proportion of Zn.

The use of a material with a high indium content percentage for each of the semiconductor layer 108b and the semiconductor layer 208b can increase the on-state current or field-effect mobility of the transistors. Furthermore, with the element M, generation of oxygen vacancies (V_{O}) can be inhibited. Alternatively, the second metal oxide may have a composition not including the element M.

The content percentage of indium in the second metal oxide is preferably higher than the content percentage of indium in the first metal oxide. The content percentage of indium in the second metal oxide is preferably higher than the content percentage of indium in the third metal oxide. Thus, the on-state current or field-effect mobility of the transistor can be increased.

By making the compositions of the metal oxides different from each other, the band gap can be adjusted. The first metal oxide and the third metal oxide each preferably have a high atomic proportion of the element M. In the first metal oxide, the atomic proportion of the element M is preferably higher than or equal to the atomic proportion of indium. In this case, the band gap of the first metal oxide can be widened. Similarly, in the third metal oxide, the atomic proportion of the element M is preferably higher than or equal to the atomic proportion of indium. In this case, the band gap of the third metal oxide can be widened.

The content percentage of the element M in the first metal oxide is preferably higher than the content percentage of the element M in the second metal oxide. In this case, the band gap of the first metal oxide can be wider than the band gap of the second metal oxide. Similarly, the content percentage of the element M in the third metal oxide is preferably higher than the content percentage of the element M in the second metal oxide. In this case, the band gap of the third metal oxide can be wider than the band gap of the second metal oxide.

It is further preferable that the content percentage of the element M in the third metal oxide be higher than the content percentage of the element M in the first metal oxide. In this case, the band gap of the third metal oxide can be wider than the band gap of the first metal oxide.

When the first metal oxide has a low content percentage of the element M having a high bonding energy with oxygen, the semiconductor layer 108a can easily transmit oxygen. That is, oxygen contained in the insulating layer 110 can be efficiently supplied to the semiconductor layer 108b through the semiconductor layer 108a. Accordingly, the oxygen vacancies (V_{O}) and V_{O}H in the semiconductor layer 108b, which is a main current path, can be reduced. This inhibits the threshold voltage shift and allows the transistor to have both a low cut-off current and a high on-state current. The semiconductor device can have both low power consumption and high performance.

In the case where the first metal oxide, the second metal oxide, and the third metal oxide are each In-M-Zn oxide, for example, the first metal oxide can have a composition of In:M:Zn=1:1:1 [atomic ratio] or in the neighborhood thereof, the second metal oxide can have a composition of In:M:Zn=40:1:10 [atomic ratio] or in the neighborhood thereof, and the third metal oxide can have a composition of In:M:Zn=1:3:4 [atomic ratio] or in the neighborhood thereof. Alternatively, the first metal oxide can have a composition of In:M:Zn=1:1:1 [atomic ratio] or in the neighborhood thereof, the second metal oxide can have a composition of In:M:Zn=10:1:10 [atomic ratio] or in the neighborhood thereof, and the third metal oxide can have a composition of In:M:Zn=1:3:4 [atomic ratio] or in the neighborhood thereof.

More specifically, the first metal oxide can suitably employ a composition of In:Ga:Zn=1:1:1 [atomic ratio] or in the neighborhood thereof, the second metal oxide can suitably employ a composition of In:Sn:Zn=40:1:10 [atomic ratio] or in the neighborhood thereof, and the third metal oxide can suitably employ a composition of In:Ga:Zn=1:3:4 [atomic ratio] or in the neighborhood thereof. Alternatively, the first metal oxide can suitably employ a composition of In:Ga:Zn=1:1:1 [atomic ratio] or in the neighborhood thereof, the second metal oxide can suitably employ a composition of In:Sn:Zn=10:1:10 [atomic ratio] or in the neighborhood thereof, and the third metal oxide can suitably employ a composition of In:Ga:Zn=1:3:4 [atomic ratio] or in the neighborhood thereof.

The second metal oxide can have a composition not including the element M. For example, the second metal oxide can be In—Zn oxide, and the first metal oxide and the third metal oxide can each be In-M-Zn oxide. Specifically, the first metal oxide can suitably employ a composition of In:Ga:Zn=1:1:1 [atomic ratio] or in the neighborhood thereof, the second metal oxide can suitably employ a composition of In:Zn=4:1 [atomic ratio] or in the neighborhood thereof, and the third metal oxide can suitably employ a composition of In:Ga:Zn=1:3:4 [atomic ratio] or in the neighborhood thereof. Alternatively, the first metal oxide can suitably employ a composition of In:Ga:Zn=1:1:1 [atomic ratio] or in the neighborhood thereof, the second metal oxide can suitably employ a composition of In:Zn=1:1 [atomic ratio] or in the neighborhood thereof, and the third metal oxide can suitably employ a composition of In:Ga:Zn=1:3:4 [atomic ratio] or in the neighborhood thereof.

Note that the composition of the third metal oxide can be the same or substantially the same as the composition of the first metal oxide. Employing the metal oxides having the same composition can reduce the manufacturing cost because the semiconductor layer 108a and the semiconductor layer 108c can be formed using the same sputtering target.

Note that there is no particular limitation on the compositions of the first metal oxide, the second metal oxide, and the third metal oxide.

In the case where the composition of the first metal oxide and the composition of the third metal oxide are the same or substantially the same, the crystallinity of the semiconductor layer 108c is preferably higher than the crystallinity of the semiconductor layer 108a. When the crystallinity of the semiconductor layer 108c is higher than the crystallinity of the semiconductor layer 108a, the semiconductor layer 108 can be inhibited from being damaged in forming the insulating layer 106. Meanwhile, when the crystallinity of the semiconductor layer 108a is lower than the crystallinity of the semiconductor layer 108c, the semiconductor layer 108a easily transmits oxygen, and thus oxygen contained in the insulating layer 110 can be efficiently supplied to the semiconductor layer 108b. Note that the crystallinity of the semiconductor layer 108c may be substantially equal to or lower than the crystallinity of the semiconductor layer 108a.

The substrate temperature at the time of forming the semiconductor layer 108c is preferably higher than the substrate temperature at the time of forming the semiconductor layer 108a. Alternatively, the oxygen flow rate ratio or oxygen partial pressure at the time of forming the semiconductor layer 108c is preferably higher than the oxygen flow rate ratio or oxygen partial pressure at the time of forming the semiconductor layer 108a. Accordingly, the crystallinity of the semiconductor layer 108c can be made higher than the crystallinity of the semiconductor layer 108a.

By increasing the thickness of the semiconductor layer 108b, which is a main current path, the transistor 100 having a high on-state current can be obtained. Similarly, by increasing the thickness of the semiconductor layer 208b, the transistor 200 having a high on-state current can be obtained. The thicknesses of the semiconductor layer 108b and the semiconductor layer 208b are each preferably larger than the thicknesses of the semiconductor layer 108a, the semiconductor layer 108c, the semiconductor layer 208a, and the semiconductor layer 208c.

The thicknesses of the semiconductor layer 108c and the semiconductor layer 208c that are positioned on the insulating layer 106 side are preferably larger than the thicknesses of the semiconductor layer 108a and the semiconductor layer 208a. By increasing the thicknesses of the semiconductor layer 108c and the semiconductor layer 208c, the semiconductor layer 108 and the semiconductor layer 208 can be inhibited from being damaged in forming the insulating layer 106.

The thicknesses of the semiconductor layer 108a and the semiconductor layer 208a are each preferably smaller than the thicknesses of the semiconductor layer 108b, the semiconductor layer 108c, the semiconductor layer 208b, and the semiconductor layer 208c. Here, oxygen contained in the insulating layer 110 is supplied to the semiconductor layer 108b through the semiconductor layer 108a. When the thickness of the semiconductor layer 108a is small, the semiconductor layer 108a easily transmits oxygen, and thus oxygen contained in the insulating layer 110 can be efficiently supplied to the semiconductor layer 108b. Similarly, oxygen contained in the insulating layer 120 (e.g., the insulating layer 120b) is supplied to the semiconductor layer 208b through the semiconductor layer 208a. When the thickness of the semiconductor layer 208a is small, the semiconductor layer 208a easily transmits oxygen, and thus oxygen contained in the insulating layer 120 can be efficiently supplied to the semiconductor layer 208b. This structure enables the transistor to have a high-on state and high reliability. Note that there is no particular limitation on the magnitude relationship in thickness between the semiconductor layer 108a, the semiconductor layer 108b, the semiconductor layer 108c, the semiconductor layer 208a, the semiconductor layer 208b, and the semiconductor layer 208c.

Although the structure where the semiconductor layer 108 and the semiconductor layer 208 have a three-layer structure is described here, one embodiment of the present invention is not limited thereto. In the case where the semiconductor layer 108 and the semiconductor layer 208 have a stacked-layer structure, at least the semiconductor layers 108b and 208b are preferably included. For example, the semiconductor layer 108 can have a two-layer structure of the semiconductor layer 108a and the semiconductor layer 108b, and the semiconductor layer 208 can have a two-layer structure of the semiconductor layer 208a and the semiconductor layer 208b. Alternatively, the semiconductor layer 108 can have a two-layer structure of the semiconductor layer 108b and the semiconductor layer 108c, and the semiconductor layer 208 can have a two-layer structure of the semiconductor layer 208b and the semiconductor layer 208c. Alternatively, the semiconductor layer 108 and the semiconductor layer 208 may each have a stacked-layer structure of four or more layers or a single-layer structure.

### [Conductive Layer 112a, Conductive Layer 112b, Conductive Layer 104, Conductive Layer 204, Conductive Layer 212a, Conductive Layer 212b, and Conductive Layer 202]

The conductive layer 112a, the conductive layer 112b, the conductive layer 104, the conductive layer 204, the conductive layer 212a, the conductive layer 212b, and the conductive layer 202 can each have a single-layer structure or a stacked-layer structure of two or more layers. The conductive layer 112a, the conductive layer 112b, the conductive layer 104, the conductive layer 204, the conductive layer 212a, the conductive layer 212b, and the conductive layer 202 can each be formed using, for example, one or more of chromium, copper, aluminum, gold, silver, zinc, tantalum, titanium, tungsten, manganese, nickel, iron, cobalt, molybdenum, and niobium, or an alloy containing one or more of these metals as its components. For each of the conductive layer 112a, the conductive layer 112b, the conductive layer 104, the conductive layer 204, the conductive layer 212a, the conductive layer 212b, and the conductive layer 202, a conductive material with low electrical resistivity that contains one or more of copper, silver, gold, and aluminum can be suitably used. Copper or aluminum is particularly preferable because of its high mass-productivity.

For each of the conductive layer 112a, the conductive layer 112b, the conductive layer 104, the conductive layer 204, the conductive layer 212a, the conductive layer 212b, and the conductive layer 202, a conductive metal oxide (also referred to as an oxide conductor) can be used. Examples of an oxide conductor (OC) include indium oxide, zinc oxide, In—Sn oxide (ITO), In—Zn oxide, In—W oxide, In—W—Zn oxide, In—Ti oxide, In—Ti—Sn oxide, In—Sn—Si oxide (also referred to as ITO containing silicon or ITSO), zinc oxide to which gallium is added, and In—Ga—Zn oxide. A metal oxide containing indium is particularly preferable because of its high conductivity.

When an oxygen vacancy (V_{O}) is formed in a metal oxide having semiconductor characteristics and hydrogen is added to the oxygen vacancy (V_{O}), a donor level is formed in the vicinity of the conduction band. As a result, the conductivity of the metal oxide is increased, and thus, the metal oxide becomes a conductor. The metal oxide having become a conductor can be referred to as an oxide conductor.

The conductive layer 112a, the conductive layer 112b, the conductive layer 104, the conductive layer 204, the conductive layer 212a, the conductive layer 212b, and the conductive layer 202 can each have a stacked-layer structure of a conductive film including the above-described oxide conductor (metal oxide) and a conductive film including a metal or an alloy. The use of the conductive film including a metal or an alloy can reduce the wiring resistance.

A Cu—X alloy film (X is Mn, Ni, Cr, Fe, Co, Mo, Ta, or Ti) may be used for each of the conductive layer 112a, the conductive layer 112b, the conductive layer 104, the conductive layer 204, the conductive layer 212a, the conductive layer 212b, and the conductive layer 202. The use of a Cu—X alloy film can reduce the manufacturing cost because a wet etching method can be used in the processing.

Note that for the conductive layer 112a, the conductive layer 112b, the conductive layer 104, the conductive layer 204, the conductive layer 212a, the conductive layer 212b, and the conductive layer 202, the same material or different materials may be used.

The conductive layer 112a and the conductive layer 112b each include a region that is in contact with the semiconductor layer 108. In the case where a metal oxide is used for the semiconductor layer 108, when a metal that is easily oxidized (e.g., aluminum) is used for each of the conductive layer 112a and the conductive layer 112b, an insulating oxide (e.g., aluminum oxide) might be formed between the conductive layer 112a and the semiconductor layer 108 and between the conductive layer 112b and the semiconductor layer 108 to prevent electrical continuity between these layers. Thus, a conductive material that is not easily oxidized, a conductive material that maintains low electric resistance even after being oxidized, or an oxide conductor is preferably used for each of the conductive layer 112a and the conductive layer 112b.

For each of the conductive layer 112a and the conductive layer 112b, for example, titanium, tantalum nitride, titanium nitride, a nitride containing titanium and aluminum, a nitride containing tantalum and aluminum, ruthenium, ruthenium oxide, ruthenium nitride, an oxide containing strontium and ruthenium, or an oxide containing lanthanum and nickel is preferably used. These materials are preferable because they are conductive materials that are not easily oxidized or materials that maintain low electric resistance even after being oxidized. In the case where the conductive layer 112a has a stacked-layer structure, a conductive material that is not easily oxidized is preferably used for at least the layer in the stacked-layer structure that is in contact with the semiconductor layer 108. The same applies to the conductive layer 112b.

The above-described oxide conductor can be used for each of the conductive layer 112a and the conductive layer 112b. Specifically, a metal oxide such as indium oxide, zinc oxide, ITO, In—Zn oxide, In—W oxide, In—W—Zn oxide, In—Ti oxide, In—Ti—Sn oxide, In—Sn oxide containing silicon, or zinc oxide to which gallium is added can be used.

For each of the conductive layer 112a and the conductive layer 112b, a nitride conductor can be used. Examples of the nitride conductor include tantalum nitride and titanium nitride.

The conductive layer 112a, the conductive layer 112b, and the conductive layer 104 may each have a stacked-layer structure.

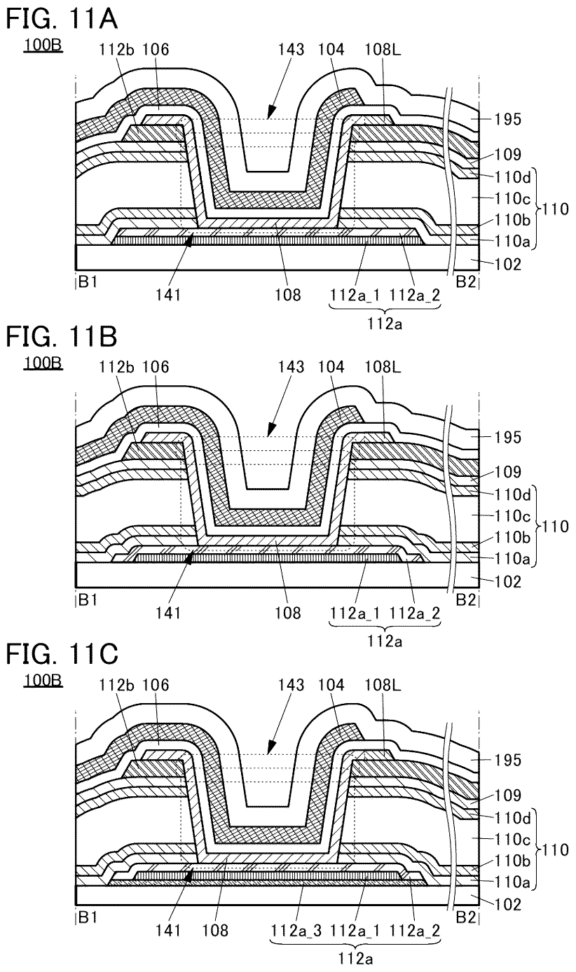

FIG. 11A to FIG. 11C each illustrate a structure where the conductive layer 112a has a stacked-layer structure.

In a transistor 100B illustrated in FIG. 11A and FIG. 11B, the conductive layer 112a has a stacked-layer structure of a conductive layer 112a_1 and a conductive layer 112a_2 over the conductive layer 112a_1.

A conductive material that is not easily oxidized, a conductive material that maintains low electric resistance even after being oxidized, or an oxide conductor is preferably used for the conductive layer 112a_2 including a region in contact with the semiconductor layer 108. The description of the conductive layer 112a can be referred to for the material that can be used for the conductive layer 112a_2.

The conductive layer 112a_1 is not in contact with the semiconductor layer 108 and there is no particular limitation on the material to be used. For example, a material having lower electric resistivity than the conductive layer 112a_2 is preferably used for the conductive layer 112a_1. Thus, the electric resistance of the conductive layer 112a can be reduced. For example, In—Sn—Si oxide (ITSO) can be suitably used for the conductive layer 112a_2, and copper or tungsten can be suitably used for the conductive layer 112a_1.

As illustrated in FIG. 11A, an end portion of the conductive layer 112a_2 may be aligned or substantially aligned with an end portion of the conductive layer 112a_1. For example, a first film to be the conductive layer 112a_1 and a second film to be the conductive layer 112a_2 are formed and then the first film and the second film are processed, so that the conductive layer 112a can be formed. Processing the first film and the second film in the same step can reduce the manufacturing cost.

The end portion of the conductive layer 112a_2 is not necessarily aligned with the end portion of the conductive layer 112a_1. As illustrated in FIG. 11B, the conductive layer 112a_2 can be provided to cover the conductive layer 112a_1. The conductive layer 112a_2 is in contact with the top surface and the side surface of the conductive layer 112a_1. In other words, the conductive layer 112a_2 includes a portion protruding beyond the end portion of the conductive layer 112a_1. For example, it is possible to form the conductive layer 112a_1, form a film to be the conductive layer 112a_2 over the conductive layer 112a_1, and process the film to form the conductive layer 112a_2. When the conductive layer 112a_2 protrudes beyond the end portion of the conductive layer 112a_1, a step on the formation surface of a layer (e.g., the insulating layer 110) formed over the conductive layer 112a is reduced, so that coverage with the layer can be improved. This can inhibit generation of a defect such as step disconnection or a void in the layer.

Although FIG. 11A and FIG. 11B each illustrate a structure where the thickness of the conductive layer 112a_1 and the thickness of the conductive layer 112a 2 are the same or substantially the same, one embodiment of the present invention is not limited thereto. The thickness of the conductive layer 112a_1 and the thickness of the conductive layer 112a_2 can be made different from each other. For example, it is further preferable that a layer including a material having low electrical resistivity have a larger thickness than the other layers, in which case the conductive layer 112a can have reduced electric resistance. Specifically, the conductive layer 112a_1 may include a material having lower electrical resistivity than the conductive layer 112a 2 and the thickness of the conductive layer 112a_1 may be larger than the thickness of the conductive layer 112a_2. Thus, the electric resistance of the conductive layer 112a can be reduced.

FIG. 11C illustrates a structure where the conductive layer 112a has a three-layer structure of a conductive layer 112a_3, the conductive layer 112a_1 over the conductive layer 112a_3, and the conductive layer 112a_2 over the conductive layer 112a_1.

The end portion of the conductive layer 112a_1 is in contact with the top surface of the conductive layer 112a_3. The conductive layer 112a_2 is in contact with the top surface and the side surface of the conductive layer 112a_1 and the top surface of the conductive layer 112a_3. In other words, the conductive layer 112a_2 and the conductive layer 112a_3 each include a portion protruding beyond the end portion of the conductive layer 112a_1. That is, the top surface, the side surface, and the bottom surface of the conductive layer 112a_1 are surrounded by the conductive layer 112a_2 and the conductive layer 112a_3. For the conductive layer 112a_3, a material with high adhesion to the formation surface of the conductive layer 112a_3 (here, the surface of the substrate 102) is preferably used.

As described above, a material with low electrical resistivity is preferably used for the conductive layer 112a_1. However, depending on the material, adhesion between the conductive layer 112a_1 and the formation surface of the conductive layer 112a_1 (here, the surface of the substrate 102) might be low and the manufacturing yield of the semiconductor device might be low. When a material having higher adhesion to the formation surface than the conductive layer 112a 1 is used for the conductive layer 112a_3, the manufacturing yield of the semiconductor device can be increased. Note that the thickness of the conductive layer 112a_3 is preferably a thickness effective for increasing adhesion to the formation surface of the conductive layer 112a_3 and may be smaller than the thicknesses of the conductive layer 112a_1 and the conductive layer 112a_2. By reducing the thickness of the conductive layer 112a_3, the manufacturing cost can be reduced.

The end portion of the conductive layer 112a_2 may be aligned or substantially aligned with an end portion of the conductive layer 112a_3. For example, a first film to be the conductive layer 112a_3 is formed, the conductive layer 112a_1 is formed over the first film, and a second film to be the conductive layer 112a_2 is formed over the first film and the conductive layer 112a_1. Then, the first film and the second film are processed, whereby the conductive layer 112a including the conductive layer 112a_3, the conductive layer 112a_1, and the conductive layer 112a_2 can be formed. Processing the first film and the second film in the same step can reduce the manufacturing cost.

For example, In—Sn—Si oxide (ITSO), copper, and In—Sn—Si oxide (ITSO) can be suitably used for the conductive layer 112a_3, the conductive layer 112a_1, and the conductive layer 112a_2, respectively. In the case of using a glass substrate as the substrate 102, the adhesion between the glass substrate and an ITSO film is higher than the adhesion between the glass substrate and a copper film. Moreover, by using the same material for the conductive layer 112a_2 and the conductive layer 112a_3, the conductive layer 112a_2 and the conductive layer 112a 3 can be easily processed when formed in the same step, so that the manufacturing yield of the semiconductor device can be increased.

Note that the layers (e.g., the conductive layer 112a_1, the conductive layer 112a_2, and the conductive layer 112a_3) included in the conductive layer 112a may each have a single-layer structure or a stacked-layer structure.

Although the example where the conductive layer 112a has a stacked-layer structure of two layers or three layers is described here, one embodiment of the present invention is not limited thereto. The conductive layer 112a may have a stacked-layer structure of four or more layers.

Note that the structure of the conductive layer 112a described here can also be applied to other structure examples.

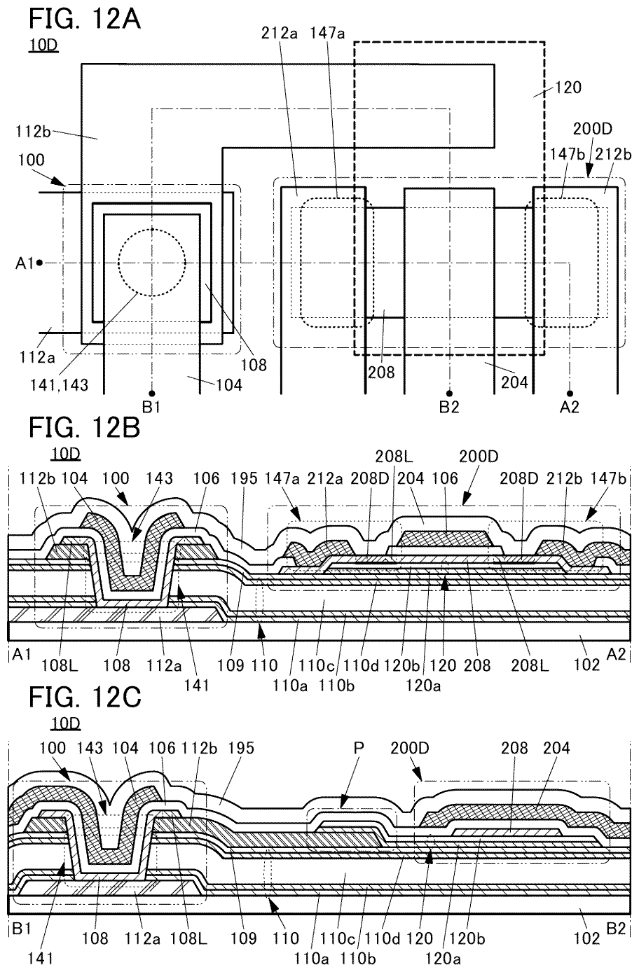

A structure not provided with the conductive layer 202 can be employed. FIG. 12A is a top view of a semiconductor device 10D of one embodiment of the present invention. FIG. 12B is a cross-sectional view of a cut plane along the dashed-dotted line A1-A2 illustrated in FIG. 12A, and FIG. 12C is a cross-sectional view of a cut plane along the dashed-dotted line B1-B2 illustrated in FIG. 12A. The semiconductor device 10D includes the transistor 100, a transistor 200D, and the insulating layer 110. The transistor 200D is different from the transistor 200 illustrated in FIG. 1A and the like mainly in not including the conductive layer 202.

The transistor 200D can be regarded as not including the conductive layer 202 functioning as the back gate electrode of the transistor 200. Thus, the transistor 200 and the transistor 200D can be formed over the same substrate by the same steps. That is, the transistor 100 having a short channel length and the transistor 200 and the transistor 200D each having a long channel length can be formed over the same substrate by the steps some of which are shared.

Note that the conductive layer 202 can be omitted also in other structure examples.

### [Insulating Layer 106]

The insulating layer 106 preferably includes one or more inorganic insulating layers. For the insulating layer 106, a material that can be used for the insulating layer 110 can be used.

The insulating layer 106 includes regions in contact with the semiconductor layer 108, the conductive layer 112b, the conductive layer 104, the semiconductor layer 208, the conductive layer 212a, the conductive layer 212b, the conductive layer 204, the insulating layer 120, and the insulating layer 109. In the case where a metal oxide is used for the semiconductor layer 108, any of the above-described oxides and oxynitrides is preferably used for at least a film of the insulating layer 106 that is in contact with the semiconductor layer 108. In the case where the insulating layer 106 has a single-layer structure, silicon oxide, silicon oxynitride, or aluminum oxide can be suitably used for the insulating layer 106.

A miniaturized transistor including a thin gate insulating layer might have a high leakage current. When a high dielectric constant material (also referred to as a high-k material) is used for the gate insulating layer, the voltage at the time of operation of the transistor can be reduced while the physical thickness is maintained. Examples of the high-k material that can be used for the insulating layer 106 include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium. Alternatively, a material that can have ferroelectricity may be used for the gate insulating layer. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

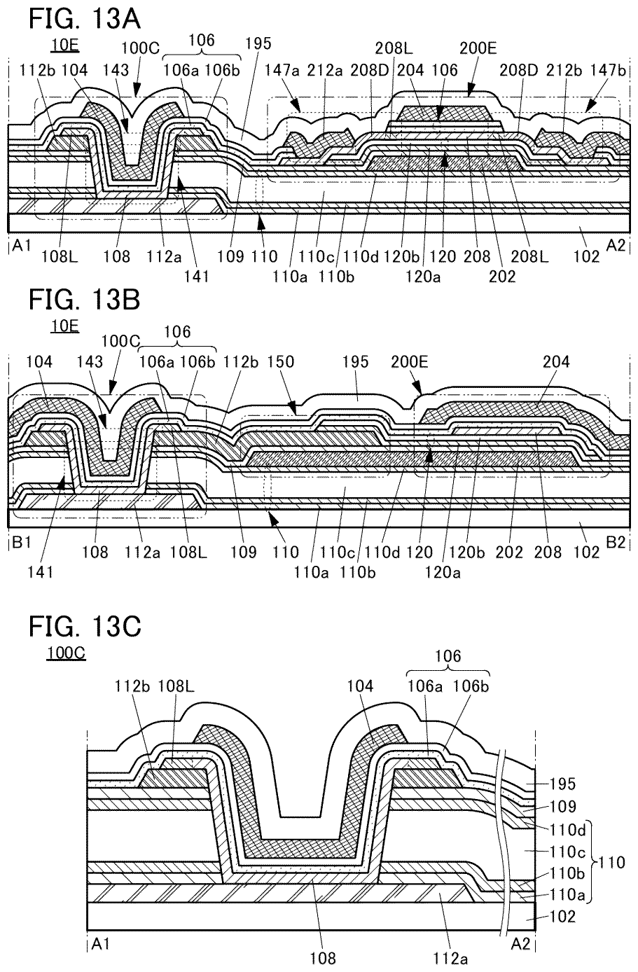

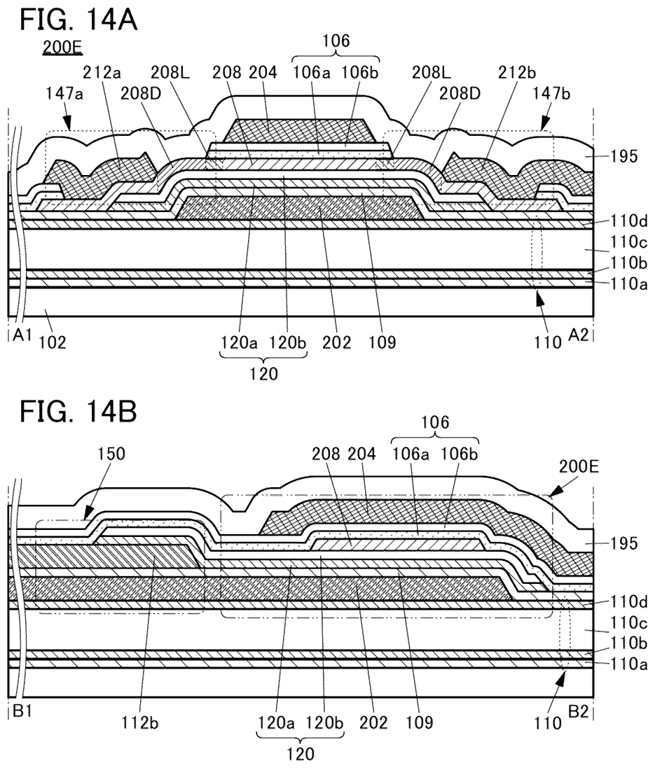

The insulating layer 106 can have a single-layer structure or a stacked-layer structure of two or more layers. FIG. 13A and FIG. 13B are cross-sectional views of a semiconductor device 10E of one embodiment of the present invention. FIG. 1A can be referred to for a top view of the semiconductor device 10E. FIG. 13A is a cross-sectional view of a cut plane along the dashed-dotted line A1-A2 illustrated in FIG. 1A, and FIG. 13B is a cross-sectional view of a cut plane along the dashed-dotted line B1-B2 illustrated in FIG. 1A. The semiconductor device 10E includes a transistor 100C, a transistor 200E, the capacitor 150, and the insulating layer 110. FIG. 13C is an enlarged view of the transistor 100C, and FIG. 14A and FIG. 14B are enlarged views of the transistor 200E.

FIG. 13A to FIG. 13C and FIG. 14A and FIG. 14B illustrate a structure in which the insulating layer 106 functioning as a gate insulating layer of each of the transistor 100C and the transistor 200E has a two-layer structure of an insulating layer 106a and an insulating layer 106b over the insulating layer 106a.

In the case where the insulating layer 106 has a stacked-layer structure, the insulating layer (here, the insulating layer 106a) on the side of the semiconductor layer 108 and the semiconductor layer 208 preferably includes an oxide or an oxynitride. For example, one or more of silicon oxide, silicon oxynitride, and aluminum oxide can be suitably used for the insulating layer 106a.

As one or more layers included in the insulating layer 106, a layer that is less likely to transmit a substance is preferably used. That is, the layer functions as a barrier film. Providing the layer functioning as a barrier film can inhibit diffusion of a metal component contained in the conductive layer 104 and impurities (e.g., water and hydrogen) contained in a layer formed over the transistor 100 into the semiconductor layer 108 through the insulating layer 106 in the transistor 100C. Moreover, oxygen contained in the semiconductor layer 108 can be inhibited from being diffused to the conductive layer 104 side through the insulating layer 106. In that case, formation of oxygen vacancies (V_{O}) in the semiconductor layer 108 can be inhibited. Furthermore, the conductive layer 104 can be inhibited from being oxidized by oxygen contained in the semiconductor layer 108 and from having increased electric resistance. The same applies to the transistor 200E. Consequently, the transistor 100C and the transistor 200E with favorable electrical characteristics and high reliability can be obtained. One or more of the above-described nitride and nitride oxide are preferably used for the layer functioning as a barrier film. Alternatively, one or more of an oxide and an oxynitride can be used for the layer, and aluminum oxide can be suitably used, for example.

Note that in this specification and the like, a barrier film refers to a film having a barrier property. A barrier property means one or both of a function of hindering diffusion of a target substance and thereby inhibiting the substance from being transmitted through a film (also referred to as low permeability) and a function of capturing or fixing (also referred to as gettering) a target substance. For example, an insulating layer having a barrier property can be referred to as a barrier insulating layer.

In the case where the insulating layer 106 has a stacked-layer structure, silicon oxynitride can be used for the insulating layer 106a and silicon nitride can be used for the insulating layer 106b, for example. Alternatively, silicon oxynitride can be used for the insulating layer 106a and aluminum oxide can be used for the insulating layer 106b. Alternatively, aluminum oxide can be used for the insulating layer 106a and silicon oxynitride can be used for the insulating layer 106b. Alternatively, aluminum oxide can be used for the insulating layer 106a and silicon nitride can be used for the insulating layer 106b.

Although the example where the insulating layer 106 has a stacked-layer structure of two layers is described here, one embodiment of the present invention is not limited thereto. The insulating layer 106 can also have a stacked-layer structure of three or more layers.

Note that the structure of the insulating layer 106 described here can also be applied to other structure examples.

### [Insulating Layer 195]

For the insulating layer 195 functioning as a protective layer, a material that does not easily allow diffusion of impurities is preferably used. Providing the insulating layer 195 can effectively inhibit diffusion of impurities into the transistors from the outside and increase the reliability of the semiconductor device. Examples of the impurities include water and hydrogen.

The insulating layer 195 can be an insulating layer including an inorganic material or an insulating layer including an organic material. For example, an inorganic material such as an oxide, an oxynitride, a nitride oxide, or a nitride can be suitably used for the insulating layer 195. Specifically, one or more of silicon nitride, silicon nitride oxide, silicon oxynitride, aluminum oxide, aluminum oxynitride, aluminum nitride, hafnium oxide, and hafnium aluminate can be used. As the organic material, for example, one or more of an acrylic resin and a polyimide resin can be used. As the organic material, a photosensitive material may be used. A stack including two or more of the above insulating films may also be used. The insulating layer 195 may have a stacked-layer structure of an insulating layer including an inorganic material and an insulating layer including an organic material.

### [Substrate 102]

Although there is no great limitation on a material of the substrate 102, it is necessary that the substrate have heat resistance high enough to withstand at least heat treatment performed later. For example, a single crystal semiconductor substrate or a polycrystalline semiconductor substrate of silicon or silicon carbide, a compound semiconductor substrate of silicon germanium or the like, an SOI substrate, a glass substrate, a quartz substrate, a sapphire substrate, a ceramic substrate, or an organic resin substrate may be used as the substrate 102. The substrate 102 may be provided with a semiconductor element. As the substrate 102, a substrate provided with an insulating film on its surface can be used. The shape of the semiconductor substrate and an insulating substrate may be a circular shape or a shape with corners.

A flexible substrate may be used as the substrate 102, and the transistor 100 and the like may be formed directly on the flexible substrate. Alternatively, a separation layer may be provided between the substrate 102 and the transistor 100 and the like. With the separation layer, part or the whole of a semiconductor device completed thereover can be separated from the substrate 102 and transferred onto another substrate. In that case, the transistor 100 and the like can be transferred onto a substrate having low heat resistance or a flexible substrate as well.

A structure example which is partly different from that of Structure example 1 shown above will be described below. Note that description of the same portions as those in Structure example 1 shown above is omitted below in some cases. Furthermore, in drawings that are referred to later, the same hatching pattern is applied to portions having functions similar to those in Structure example 1 shown above, and the portions are not denoted by reference numerals in some cases.

### Structure Example 2

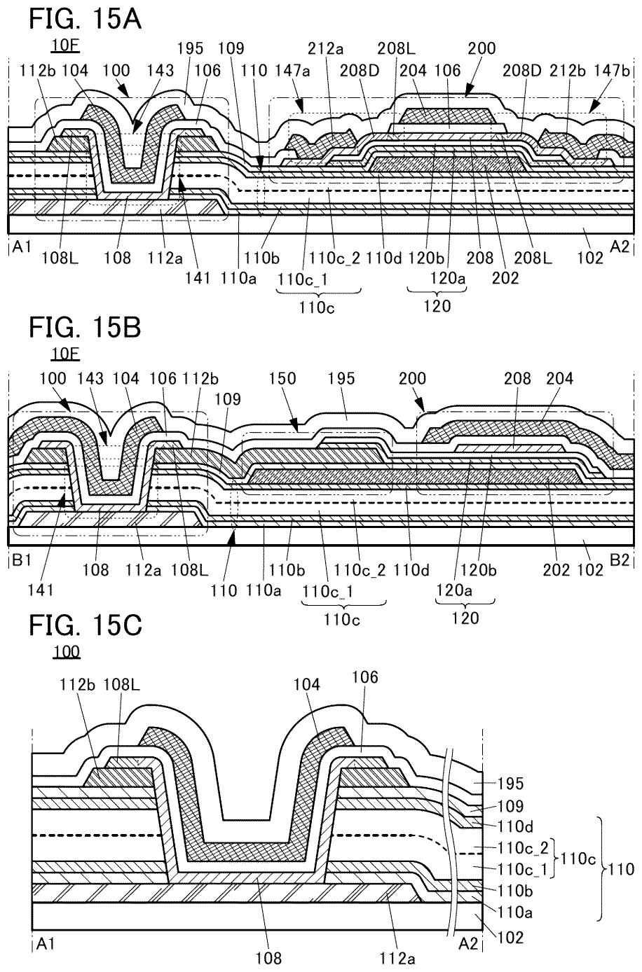

FIG. 15A and FIG. 15B are cross-sectional views of a semiconductor device 10F of one embodiment of the present invention. FIG. 1A can be referred to for a top view of the semiconductor device 10F. FIG. 15A is a cross-sectional view of a cut plane along the dashed-dotted line A1-A2 illustrated in FIG. 1A, and FIG. 15B is a cross-sectional view of a cut plane along the dashed-dotted line B1-B2 illustrated in FIG. 1A.

The semiconductor device 10F includes the transistor 100, the transistor 200, the capacitor 150, and the insulating layer 110. The semiconductor device 10F is different from the semiconductor device 10 illustrated in FIG. 1B and the like mainly in that the insulating layer 110c has a stacked-layer structure.

FIG. 15C is an enlarged view of the transistor 100 illustrated in FIG. 15A. The insulating layer 110c includes an insulating layer 110c_1 and an insulating layer 110c_2 over the insulating layer 110c_1. For each of the insulating layer 110c_1 and the insulating layer 110c_2, the material given for the insulating layer 110c can be used. For example, silicon oxide or silicon oxynitride can be suitably used for each of the insulating layer 110c_1 and the insulating layer 110c 2. For the insulating layer 110c_1 and the insulating layer 110c_2, the same material or different materials may be used.

Note that when the same material is used for the insulating layer 110c_1 and the insulating layer 110c_2, the boundary between the insulating layer 110c_1 and the insulating layer 110c_2 cannot be clearly observed in some cases. Thus, the boundary is denoted by a dashed line in FIG. 15A and the like.

After a first insulating film to be the insulating layer 110c_1 is formed, oxygen can be supplied to the first insulating film and a second insulating film to be the insulating layer 110c_2 can be formed over the first insulating film. Accordingly, a portion to be supplied with a larger amount of oxygen is generated at the interface between the first insulating film (to be the insulating layer 110c_1 later) and the second insulating film (to be the insulating layer 110c_2 later) and in the vicinity of the interface. Thus, a larger amount of oxygen can be supplied to a region of the semiconductor layer 108 that is in contact with the portion. For example, when the thickness of the first insulating film and the thickness of the second insulating film are the same or substantially the same, a larger amount of oxygen is supplied to the center portion of the insulating layer 110c. Therefore, oxygen can be supplied more efficiently to the center portion of the channel formation region in the semiconductor layer 108. Consequently, the transistor 100 with favorable electrical characteristics and high reliability can be provided.

Although the insulating layer 110c_1 and the insulating layer 110c_2 have the same thickness here, one embodiment of the present invention is not limited thereto. The insulating layer 110c_1 and the insulating layer 110c_2 can have different thicknesses. In addition, the insulating layer 110c may have a stacked-layer structure of three or more layers or a single-layer structure. In the case where the insulating layer 110c has a stacked-layer structure of three or more layers, oxygen may be supplied after each of the insulating films to be the insulating layer 110c is formed.

Note that the structure of the insulating layer 110c described in Structure example 2 can also be applied to other structure examples.

### Structure Example 3

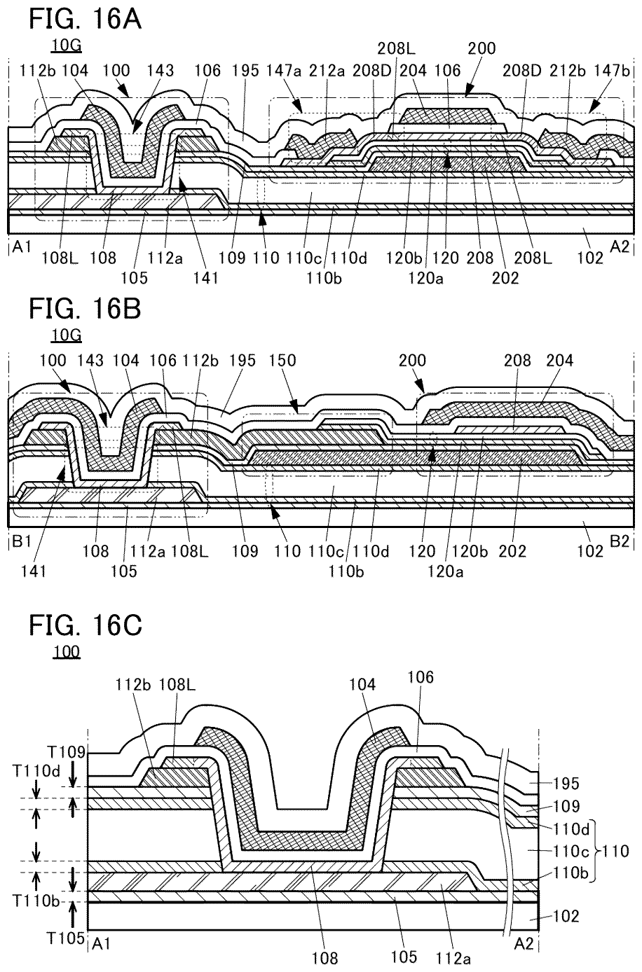

FIG. 16A and FIG. 16B are cross-sectional views of a semiconductor device 10G of one embodiment of the present invention. FIG. 1A can be referred to for a top view of the semiconductor device 10G. FIG. 16A is a cross-sectional view of a cut plane along the dashed-dotted line A1-A2 illustrated in FIG. 1A, and FIG. 16B is a cross-sectional view of a cut plane along the dashed-dotted line B1-B2 illustrated in FIG. 1A.

The semiconductor device 10G includes the transistor 100, the transistor 200, the capacitor 150, the insulating layer 109, and the insulating layer 110. The semiconductor device 10G is different from the semiconductor device 10 illustrated in FIG. 1B and the like mainly in including an insulating layer 105. FIG. 16C is an enlarged view of the transistor 100.

The insulating layer 105 is provided over the substrate 102, the conductive layer 112a is provided over the insulating layer 105, and the insulating layer 110 is provided over the conductive layer 112a. The insulating layer 105 is in contact with the top surface of the substrate 102, the bottom surface of the conductive layer 112a, and the bottom surface of the insulating layer 110. The conductive layer 112a includes a region interposed between the insulating layer 105 and the insulating layer 110. The insulating layer 110 is in contact with the top surface and the side surface of the conductive layer 112a, the top surface of the insulating layer 105, the side surface of the semiconductor layer 108, the bottom surface of the conductive layer 112b, and the bottom surface of the insulating layer 106.

For the insulating layer 105, a material that releases impurities (e.g., water and hydrogen) that reduce the electric resistance of the semiconductor layer 108 is preferably used. For the insulating layer 105, a material that can be used for each of the insulating layer 110a and the insulating layer 109 can be used. For example, silicon nitride or silicon nitride oxide can be suitably used for the insulating layer 105.

Impurities released from the insulating layer 105 are diffused into a region of the conductive layer 112a that is in contact with the insulating layer 105. The impurities diffused into the conductive layer 112a are diffused into the region of the semiconductor layer 108 that is in contact with the conductive layer 112a. This can reduce the electric resistance in the region of the semiconductor layer 108 that is in contact with the conductive layer 112a, i.e., one of the source region and the drain region. Accordingly, the transistor can have a high on-state current and the semiconductor device can operate at high speed.

It is further preferable that in the case of using a metal oxide for the semiconductor layer 108, impurities released from the insulating layer 105 contain hydrogen. Hydrogen diffused from the insulating layer 105 into the semiconductor layer 108 through the conductive layer 112a increases the carrier concentration in the region of the semiconductor layer 108 that is in contact with the conductive layer 112a, which can reduce the electric resistance in the one of the source region and the drain region.

It is further preferable that for the insulating layer 105, a material that releases impurities that reduce the electric resistance of the conductive layer 112a be used. In this case, the electric resistance of the conductive layer 112a can be reduced. For example, in the case of using a metal oxide for the conductive layer 112a, it is further preferable that the impurities contain hydrogen. In this case, the conductive layer 112a can have a high carrier concentration and low electric resistance. Moreover, the conductive layer 112a can function as a wiring, and the semiconductor device can have low wiring resistance. Note that an impurity that reduces the electric resistance of the conductive layer 112a may be the same as or different from an impurity that reduces the electric resistance of the semiconductor layer 108.

Materials that can be used for the conductive layer 112a are as described above. Note that it is further preferable that the conductive layer 112a be likely to transmit impurities. It is further preferable that the conductive layer 112a be less likely to adsorb impurities.

The insulating layer 110 includes the insulating layer 110b, the insulating layer 110c, and the insulating layer 110d.

The insulating layer 110b is in contact with the top surface of the insulating layer 105 and the top surface and the side surface of the conductive layer 112a. Thus, impurities contained in the insulating layer 105 and the conductive layer 112a can be inhibited from being diffused into the channel formation region in the semiconductor layer 108 through the insulating layer 110c.

The insulating layer 105 preferably includes a region having a higher hydrogen content than the insulating layer 110b. The film density of the insulating layer 110b is preferably higher than the film density of the insulating layer 105. For the insulating layer 105, the description of the insulating layer 110a and the insulating layer 109 can be referred to.

Note that impurities released from the insulating layer 105 are diffused into the channel formation region through the conductive layer 112a and one of the source region and the drain region of the semiconductor layer 108 in some cases. However, oxygen is supplied from the insulating layer 110c to at least the region of the semiconductor layer 108 that is in contact with the insulating layer 110c, reducing the oxygen vacancies (V_{O}) and V_{O}H in the channel formation region. This inhibits the threshold voltage shift and allows the transistor to have both a low cut-off current and a high on-state current. Consequently, the semiconductor device can have both low power consumption and high performance.

It is further preferable that for the insulating layer 105, a material that releases impurities that reduce the electric resistance of the conductive layer 112b be used. In this case, the electric resistance of the conductive layer 112b can be reduced. For example, in the case of using a metal oxide for the conductive layer 112b, it is further preferable that the impurities contain hydrogen. In this case, the conductive layer 112b can have a high carrier concentration and low electric resistance. The conductive layer 112b can function as a wiring, and the semiconductor device can have low wiring resistance.

Although FIG. 16A and the like illustrate the structure where the insulating layer 110 has a three-layer structure of the insulating layer 110b to the insulating layer 110d, one embodiment of the present invention is not limited thereto. For example, the insulating layer 110 can have a four-layer structure of the insulating layer 110a to the insulating layer 110d.

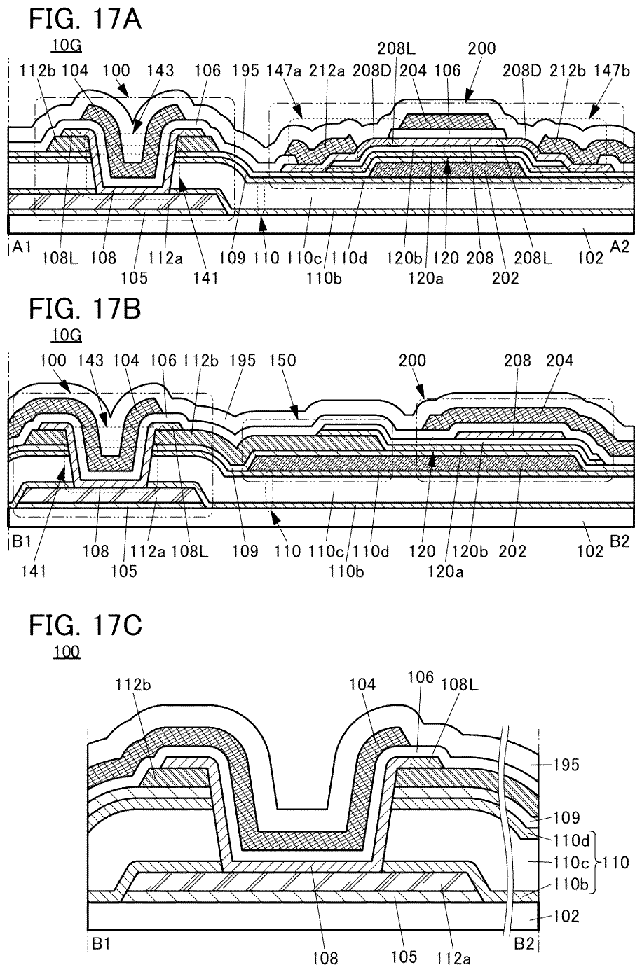

As illustrated in FIG. 17A to FIG. 17C, the insulating layer 110 can be in contact with the side surface of the insulating layer 105. An end portion of the insulating layer 105 may be aligned or substantially aligned with the end portion of the conductive layer 112a. For example, an insulating film to be the insulating layer 105 and a conductive film to be the conductive layer 112a are formed and processed, so that the insulating layer 105 and the conductive layer 112a can be formed. Processing the insulating film and the conductive film in the same step can reduce the manufacturing cost.

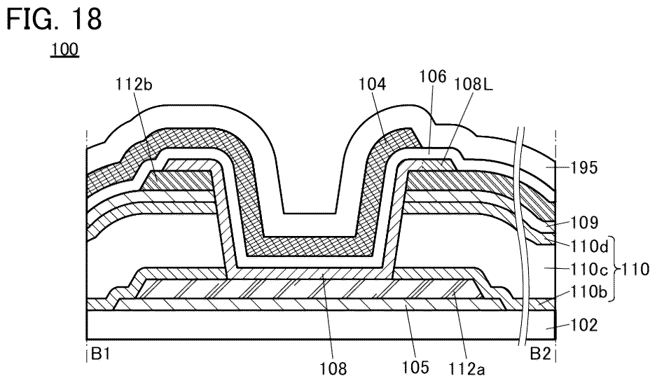

The end portion of the insulating layer 105 is not necessarily aligned with the end portion of the conductive layer 112a. As illustrated in FIG. 18, the insulating layer 105 may include a portion protruding beyond the end portion of the conductive layer 112a. The end portion of the conductive layer 112a is in contact with the top surface of the insulating layer 105. With such a structure, a step on the formation surface of a layer (e.g., the insulating layer 110) formed over the conductive layer 112a and the insulating layer 105 is reduced, so that coverage with the layer can be improved. This can inhibit generation of a defect such as step disconnection or a void in the layer.

Note that the structure of the insulating layer 105 described in Structure example 3 can also be applied to other structure examples.

### Structure Example 4

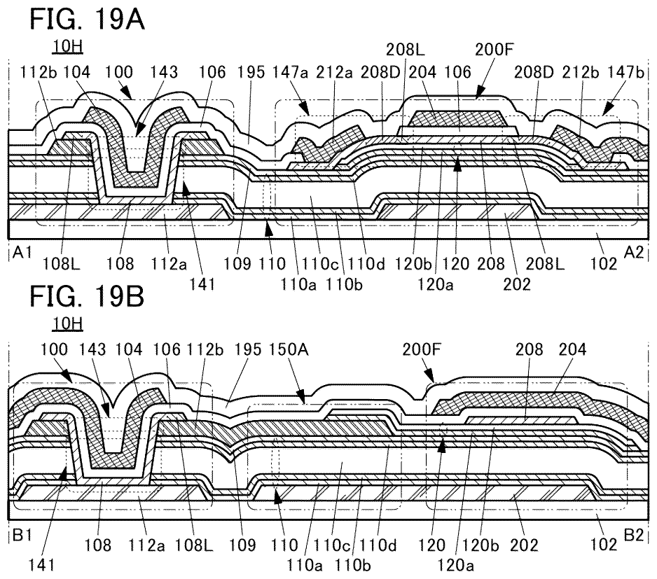

FIG. 19A and FIG. 19B are cross-sectional views of a semiconductor device 10H of one embodiment of the present invention. FIG. 1A can be referred to for a top view of the semiconductor device 10H. FIG. 19A is a cross-sectional view of a cut plane along the dashed-dotted line A1-A2 illustrated in FIG. 1A, and FIG. 19B is a cross-sectional view of a cut plane along the dashed-dotted line B1-B2 illustrated in FIG. 1A.

The semiconductor device 10H includes the transistor 100, a transistor 200F, a capacitor 150A, and the insulating layer 110. The transistor 200F is different from the transistor 200 illustrated in FIG. 1B and the like mainly in that the conductive layer 202 is provided between the insulating layer 110 and the substrate 102. The capacitor 150A is different from the capacitor 150 mainly in including the insulating layer 110 and the insulating layer 109 instead of the insulating layer 120.

The conductive layer 202 is provided over the substrate 102. The conductive layer 202 can be formed in the same step as the conductive layer 112a. For example, a film to be the conductive layer 202 and the conductive layer 112a is formed and then the film is processed, so that the conductive layer 202 and the conductive layer 112a can be formed. When the conductive layer 202 and the conductive layer 112a are formed in the same step, the productivity of the semiconductor device 10H can be increased and the manufacturing cost can be reduced.

In the transistor 200F, part of the insulating layer 110 and part of the insulating layer 120 function as a back gate insulating layer (a second gate insulating layer).

The capacitor 150A includes the conductive layer 112b and the conductive layer 202 functioning as a pair of electrodes and the insulating layer 110 and the insulating layer 109 interposed therebetween. In each of the insulating layer 110 and the insulating layer 109, a region interposed between the conductive layer 112b and the conductive layer 202 serves as a dielectric of the capacitor 150A.

Note that the structures of the conductive layer 202 and the capacitor 150A described in Structure example 4 can also be applied to other structure examples.

### Structure Example 5

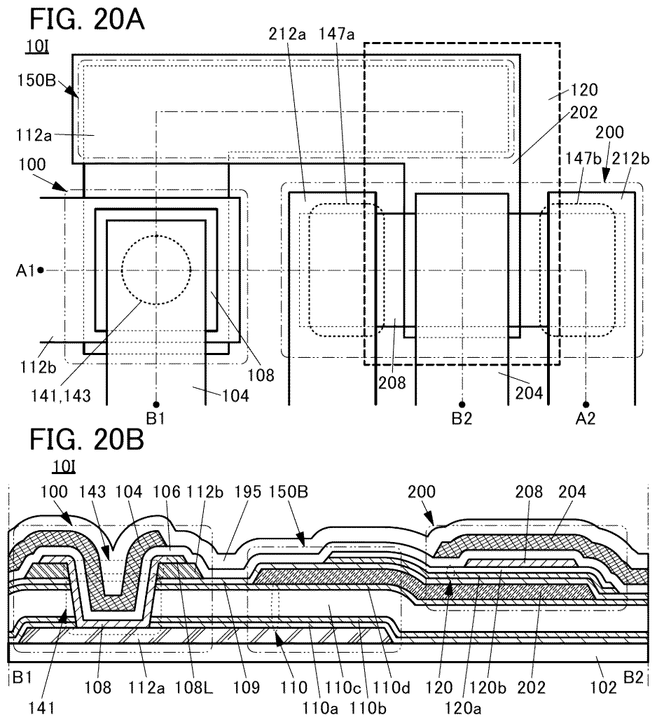

FIG. 20A is a top view of a semiconductor device 101 of one embodiment of the present invention. FIG. 1B can be referred to for a cross-sectional view of a cut plane along the dashed-dotted line A1-A2 illustrated in FIG. 20A. FIG. 20B is a cross-sectional view of a cut plane along the dashed-dotted line B1-B2 illustrated in FIG. 20A.

The semiconductor device 10I includes the transistor 100, the transistor 200, a capacitor 150B, and the insulating layer 110. The capacitor 150B is different from the capacitor 150 illustrated in FIG. 1C and the like mainly in including the conductive layer 112a instead of the conductive layer 112b and including the insulating layer 110 instead of the insulating layer 120.

The capacitor 150B includes the conductive layer 112a and the conductive layer 202 functioning as a pair of electrodes and the insulating layer 110 interposed therebetween. The conductive layer 112a functions as one of the source electrode and the drain electrode of the transistor 100 and also functions as one of the pair of electrodes of the capacitor 150B.

Note that the structure of the capacitor 150B described in Structure example 5 can also be applied to other structure examples.

### Structure Example 6

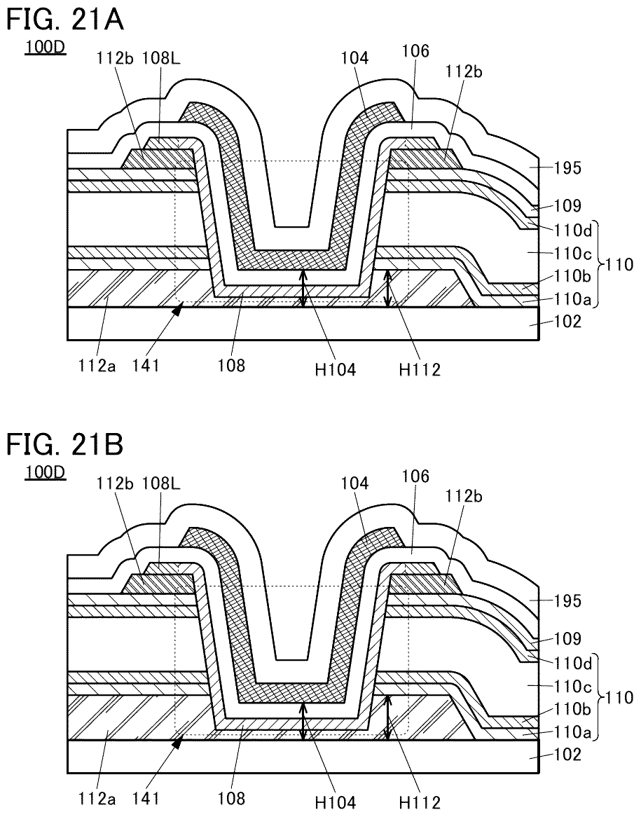

FIG. 21A is a cross-sectional view of a transistor 100D that can be used in the semiconductor device of one embodiment of the present invention. The top view of the transistor 100 illustrated in FIG. 1A can be referred to for that of the transistor 100D. FIG. 21A is a cross-sectional view of a cut plane along the dashed-dotted line A1-A2 of the transistor 100 illustrated in FIG. 1A.

The transistor 100D is different from the transistor 100 illustrated in FIG. 1B and the like mainly in that the thickness of a region of the conductive layer 112a that is in contact with the bottom surface of the semiconductor layer 108 is different from the thickness of a region of the conductive layer 112a that is not in contact with the semiconductor layer 108.

As illustrated in FIG. 21A, the thickness of the region of the conductive layer 112a that is in contact with the bottom surface of the semiconductor layer 108 is preferably smaller than the thickness of the region of the conductive layer 112a that is not in contact with the semiconductor layer 108. FIG. 21A illustrates a height H104 from the formation surface of the conductive layer 112a (here, the top surface of the substrate 102) to the lowest position of the bottom surface of the conductive layer 104. FIG. 21A also illustrates a height H112 from the formation surface of the conductive layer 112a (here, the top surface of the substrate 102) to the highest position of the region where the conductive layer 112a and the semiconductor layer 108 are in contact with each other. As illustrated in FIG. 21A, the height H104 is preferably equal or substantially equal to the height H112. Alternatively, as illustrated in FIG. 21B, the height H104 is preferably smaller than the height H112.

When the height H104 to the lowest position of the bottom surface of the conductive layer 104 is equal to the height H112 to the highest position of the region where the conductive layer 112a and the semiconductor layer 108 are in contact with each other or smaller than the height H112, the electric field of the gate electrode applied to the channel formation region in the vicinity of the conductive layer 112a can be increased and the on-state current of the transistor 100D can be increased. In addition, the electric field of the gate electrode applied to the channel formation region can be more uniform.

Here, in the case where the electric field of the gate electrode applied to the channel formation region is not uniform, the electrical characteristics in the case where the conductive layer 112a is a source electrode and the conductive layer 112b is a drain electrode might be different from the electrical characteristics in the case where the conductive layer 112a is the drain electrode and the conductive layer 112b is the source electrode. By making the electric field of the gate electrode applied to the channel formation region of the transistor 100D more uniform, the electrical characteristics in the both cases can be made equivalent to each other. Thus, the transistor 100D can be suitably used in a circuit structure where a source and a drain are interchanged with each other.

Note that the thickness of the conductive layer 112a is preferably adjusted as appropriate so that the height H104 is equal to the height H112 or smaller than the height H112.

Note that the structure of the conductive layer 112a described in Structure example 6 can also be applied to other structure examples.

### Structure Example 7

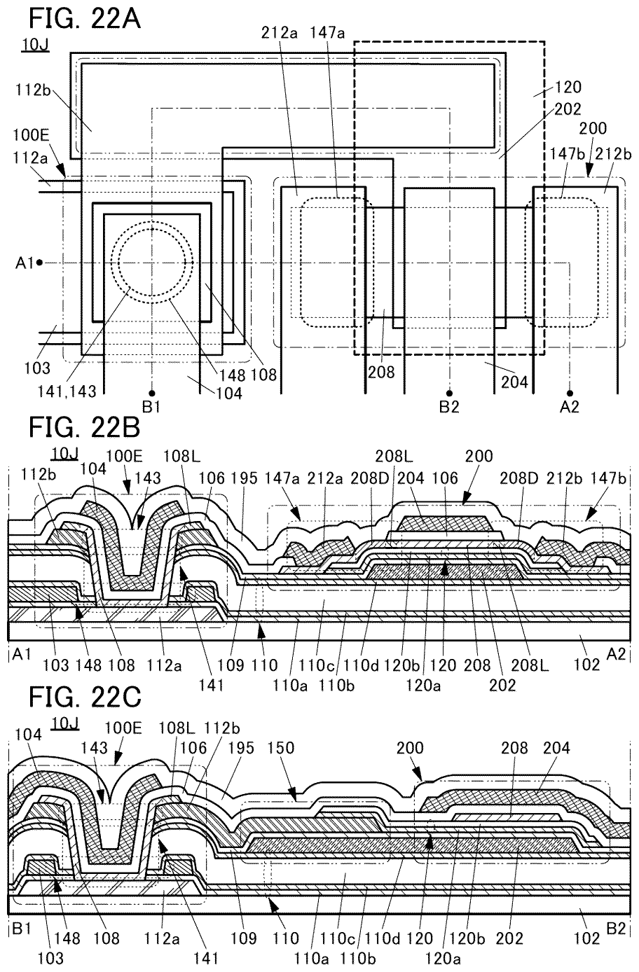

FIG. 22A is a top view of a semiconductor device 10J of one embodiment of the present invention. FIG. 22B is a cross-sectional view of a cut plane along the dashed-dotted line A1-A2 illustrated in FIG. 22A, and FIG. 22C is a cross-sectional view of a cut plane along the dashed-dotted line B1-B2 illustrated in FIG. 22A.

The semiconductor device 10J includes a transistor 100E, the transistor 200, the capacitor 150, and the insulating layer 110. The transistor 100E is different from the transistor 100 illustrated in FIG. 1B and the like mainly in including a conductive layer 103.

The conductive layer 103 is provided between the insulating layer 110a and the insulating layer 110b. The conductive layer 103 is provided over the insulating layer 110a, and the insulating layer 110b is provided to cover the conductive layer 103.

The conductive layer 112a and the conductive layer 103 are electrically insulated from each other by the insulating layer 110a. In the conductive layer 103, an opening 148 reaching the insulating layer 110a is provided in a region overlapping with the conductive layer 112a.

There is no particular limitation on the top surface shape of the opening 148. The top surface shape of the opening 148 can be a shape that can be employed for the opening 141. The top surface shapes of the opening 141 and the opening 148 are preferably circles as illustrated in FIG. 22A. When the top surface shapes of the openings are circles, processing accuracy in forming the openings can be high, whereby the openings can be formed to have minute sizes.

In this specification and the like, the top surface shape of the opening 148 refers to the shape of the end portion of the top surface or the end portion of the bottom surface of the conductive layer 103 on the opening 148 side.

When the top surface shapes of the opening 141 and the opening 148 are circles, the opening 141 and the opening 148 are preferably concentrically arranged. In that case, the shortest distances between the semiconductor layer 108 and the conductive layer 103 on the left and right sides of the opening 141 can be the same in the cross-sectional view. The opening 141 and the opening 148 are not concentrically arranged in some cases.

In the transistor 100E, the semiconductor layer 108 includes a region overlapping with the conductive layer 104 with the insulating layer 106 therebetween and overlapping with the conductive layer 103 with part of the insulating layer 110 (specifically, the insulating layer 110b and the insulating layer 110c) therebetween. In other words, the semiconductor layer 108 includes a region interposed between the conductive layer 104 and the conductive layer 103, with the insulating layer 106 positioned between the region and the conductive layer 104 and with part of the insulating layer 110 (specifically, the insulating layer 110b and the insulating layer 110c) positioned between the region and the conductive layer 103.

The conductive layer 103 functions as a back gate electrode (also referred to as a second gate electrode) of the transistor 100E. Part of the insulating layer 110 functions as a back gate insulating layer (also referred to as a second gate insulating layer) of the transistor 100E. For the conductive layer 103, a material that can be used for each of the conductive layer 112a and the conductive layer 104 can be used. Note that the conductive layer 103 is not necessarily provided.

When the transistor 100E includes a back gate electrode, the potential of the semiconductor layer 108 on the back gate electrode side (also referred to as back channel side) is fixed, so that the saturation characteristics in the Id-Vd characteristics can be improved.

Since the transistor 100E includes the back gate electrode, the potential on the back gate electrode side of the semiconductor layer 108 can be fixed and a shift of the threshold voltage can be inhibited. A shift in the threshold voltage of the transistor might increase the cut-off current. When the shift in the threshold voltage is inhibited, the cut-off current of the transistor can be reduced. Thus, a semiconductor device with low power consumption can be obtained.

The conductive layer 103 and the conductive layer 112a can be electrically connected to each other. For example, when an opening is provided in a region of the insulating layer 110a that overlaps with the conductive layer 112a and the conductive layer 103 is provided to cover the opening, the conductive layer 103 and the conductive layer 112a can be in contact with each other. When the conductive layer 112a functioning as a source electrode or a drain electrode and the conductive layer 103 functioning as the back gate electrode are electrically connected to each other, the back gate electrode can have the same potential as the source electrode or the drain electrode. For example, in the case where the conductive layer 112a functions as the source electrode, a shift in the threshold voltage of the transistor 100E can be inhibited. In addition, the reliability of the transistor 100E can be improved.

The conductive layer 103 can be electrically connected to the conductive layer 104. For example, when an opening is provided in regions of the insulating layer 106 and the insulating layer 110 that overlap with the conductive layer 103 and the conductive layer 104 is provided to cover the opening, the conductive layer 103 and the conductive layer 104 can be in contact with each other. When the conductive layer 104 functioning as the gate electrode and the conductive layer 103 functioning as the back gate electrode are electrically connected to each other, the back gate electrode and the gate electrode can have the same potential, so that the on-state current of the transistor 100E can be increased.

The thickness of the conductive layer 103 may be larger than the thickness T110c of the insulating layer 110. Accordingly, the potential of the back gate electrode side of the semiconductor layer 108 can be fixed in a wide range between the source region and the drain region in the semiconductor layer 108.

In a region of the transistor 100E, the conductive layer 103, the insulating layer 110b, the insulating layer 110c, the semiconductor layer 108, the insulating layer 106, and the conductive layer 104 are stacked in this order in one direction with no any other layer provided between these layers. The direction can be a direction perpendicular to the channel length direction. When the above region is wide, the potential of the back gate electrode side of the semiconductor layer 108 can be controlled more reliably.

The thickness of the conductive layer 103 can be larger than the sum of the thickness of a portion of the semiconductor layer 108 that is in contact with the conductive layer 112a inside the opening 141 and the thickness of the insulating layer 106 in contact with the portion.

Note that the structure of the conductive layer 103 described in Structure example 7 can also be applied to other structure examples.

### Structure Example 8

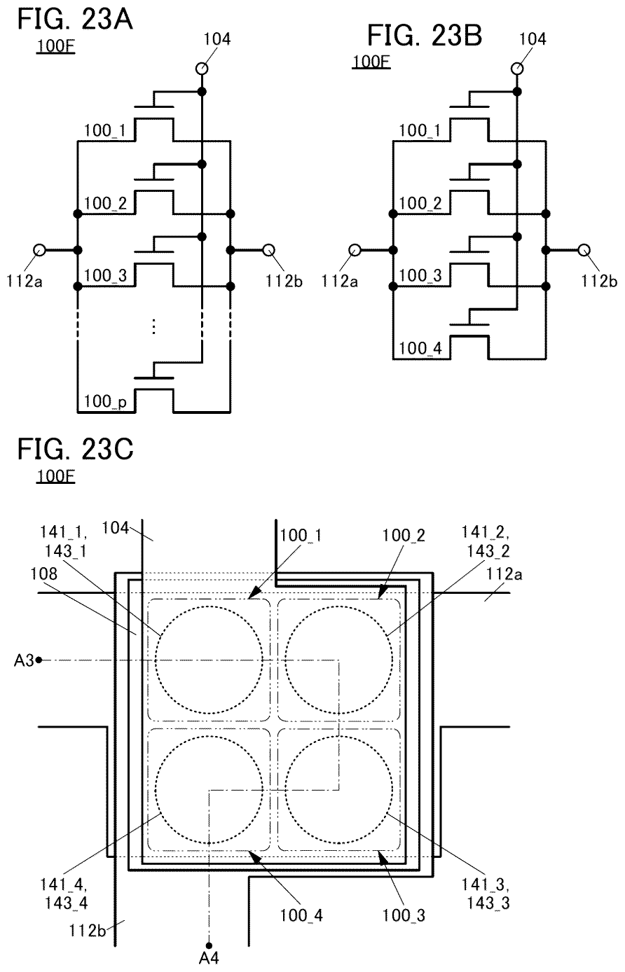

FIG. 23A is an equivalent circuit diagram of a transistor 100F that can be used in the semiconductor device of one embodiment of the present invention. The transistor 100F is a transistor group including a transistor 100_1 to a transistor 100_p (p is an integer greater than or equal to 2). The transistor 100F can be regarded as one transistor, in which the transistor 100_1 to the transistor 100_p are connected in parallel.

Gate electrodes of the transistor 100_1 to the transistor 100_p are electrically connected to each other. Source electrodes of the transistor 100_1 to the transistor 100_p are electrically connected to each other. Drain electrodes of the transistor 100_1 to the transistor 100_p are electrically connected to each other.

Although the transistor 100_1 to the transistor 100_p are illustrated as n-channel transistors in FIG. 23A, one embodiment of the present invention is not limited thereto. The transistor 100_1 to the transistor 100_p can be p-channel transistors.

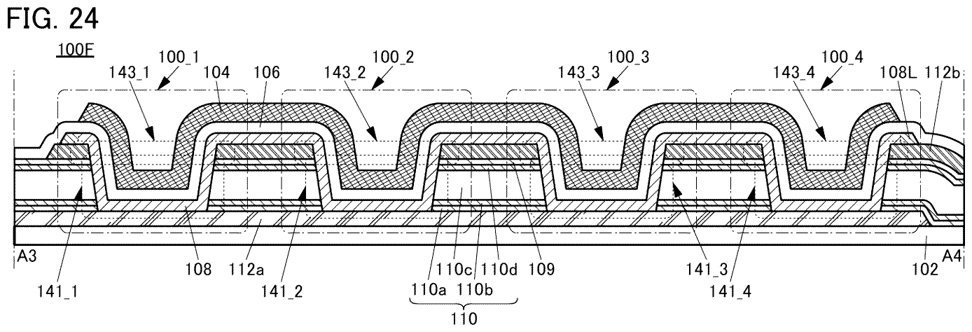

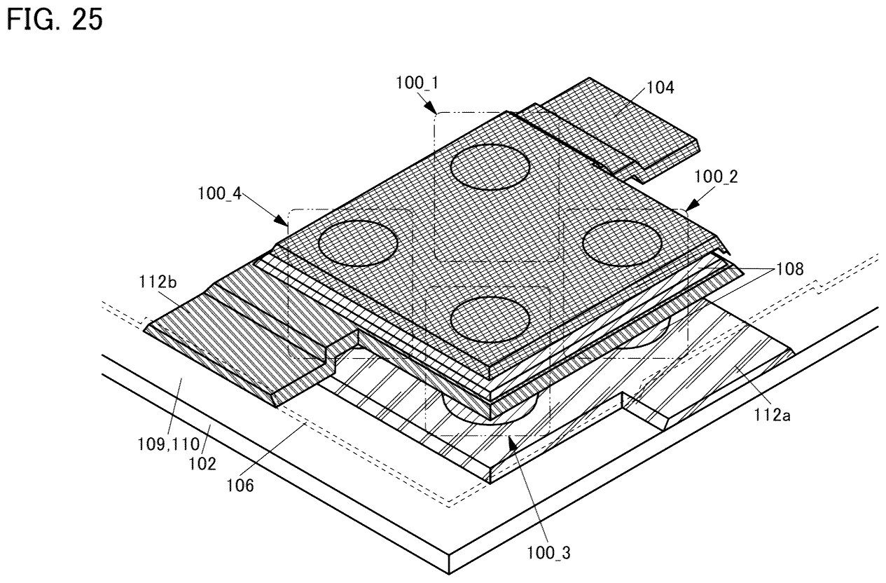

The case where p is 4 is specifically described as an example. FIG. 23B is an equivalent circuit diagram of the transistor 100F that is one embodiment of the present invention. FIG. 23C is a top view of the transistor 100F. FIG. 24 is a cross-sectional view of a cut plane along the dashed-dotted line A3-A4 illustrated in FIG. 23C. FIG. 25 is a perspective view of the transistor 100F.

The transistor 100F includes the transistor 100_1 to a transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to a transistor 100G can be used as the transistor 100_1 to the transistor 100_4.

Although the transistor 100_1 to the transistor 100_4 are arranged in two rows and two columns in FIG. 23C and the like, there is no limitation on the transistor arrangement. For example, the transistor 100_1 to the transistor 100_4 can be arranged in one row and four columns. The transistor arrangement may be in a matrix and is not necessarily in a matrix.

The transistor 100_1 to the transistor 100_4 each include the conductive layer 104, the insulating layer 106, the semiconductor layer 108, the conductive layer 112a, and the conductive layer 112b. The conductive layer 104 functions as the gate electrode of each of the transistor 100_1 to the transistor 100_4. Part of the insulating layer 106 functions as a gate insulating layer of each of the transistor 100_1 to the transistor 100_4. The conductive layer 112b functions as one of the source electrode and the drain electrode, and the conductive layer 112a functions as the other in each of the transistor 100_1 to the transistor 100_4.

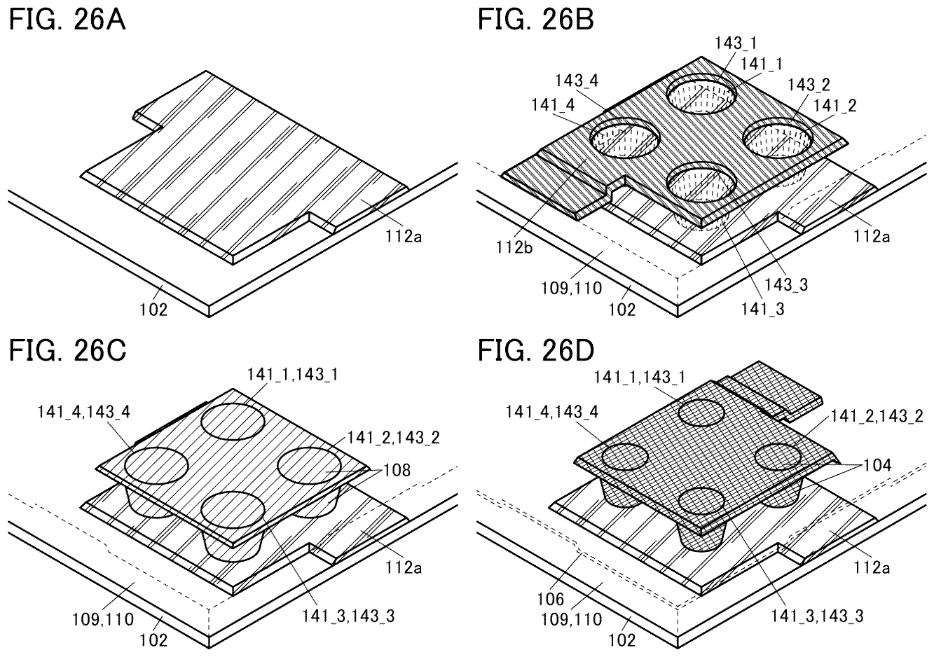

FIG. 26A is a perspective view selectively illustrating the conductive layer 112a.

FIG. 26B is a perspective view selectively illustrating the conductive layer 112a, the conductive layer 112b, an opening 141_1 to an opening 141_4, and an opening 143_1 to an opening 143_4. The opening 141_1 to the opening 141_4 provided in the insulating layer 110 are indicated by dashed lines. The description of the opening 141 and the opening 143 can be referred to for the opening 141_1 to the opening 141_4 and the opening 143_1 to the opening 143_4; thus, the detailed description thereof is omitted.

In the case where the transistor 100F is regarded as one transistor, the channel width of the transistor is the sum of the channel widths of the transistor 100_1 to the transistor 100_4. For example, in the case where the top surface shapes of the opening 141_1 to the opening 141_4 are circles and the width D141 corresponds to the width of each of the opening 141_1 to the opening 141_4, the transistor 100F can be regarded as a transistor having a channel width of “D141×π×4” (see FIG. 4A and FIG. 4B). The transistor 100F composed of p transistors can be regarded as a transistor having a channel width of “D141×π×p”. Note that the transistor 100F can be regarded as a transistor having the channel length L100 (see FIG. 4B). A plurality of transistors connected in parallel can have a larger channel width and a higher on-state current. By adjusting the number (p) of transistors connected in parallel, the channel width can be changed. The number (p) of transistors connected in parallel is determined so that a desired on-state current is obtained.

FIG. 26C is a perspective view selectively illustrating the conductive layer 112a and the semiconductor layer 108. The semiconductor layer 108 is provided to cover the opening 141_1 to the opening 141_4 and the opening 143_1 to the opening 143_4. Although FIG. 26C and the like illustrate the structure where the transistor 100_1 to the transistor 100_4 share the semiconductor layer 108, one embodiment of the present invention is not limited thereto. The semiconductor layer 108 can be separated for each of the transistor 100_1 to the transistor 100_4.

FIG. 26D is a perspective view selectively illustrating the conductive layer 112a and the conductive layer 104. The conductive layer 104 is provided to cover the opening 141_1 to the opening 141_4 and the opening 143_1 to the opening 143_4.

Note that the structure of the transistor 100F described in Structure example 8 can also be applied to other structure examples. For example, the transistor 100F can be used as one or more of the transistors included in the semiconductor devices illustrated in FIG. 1 to FIG. 22.

### Structure Example 9

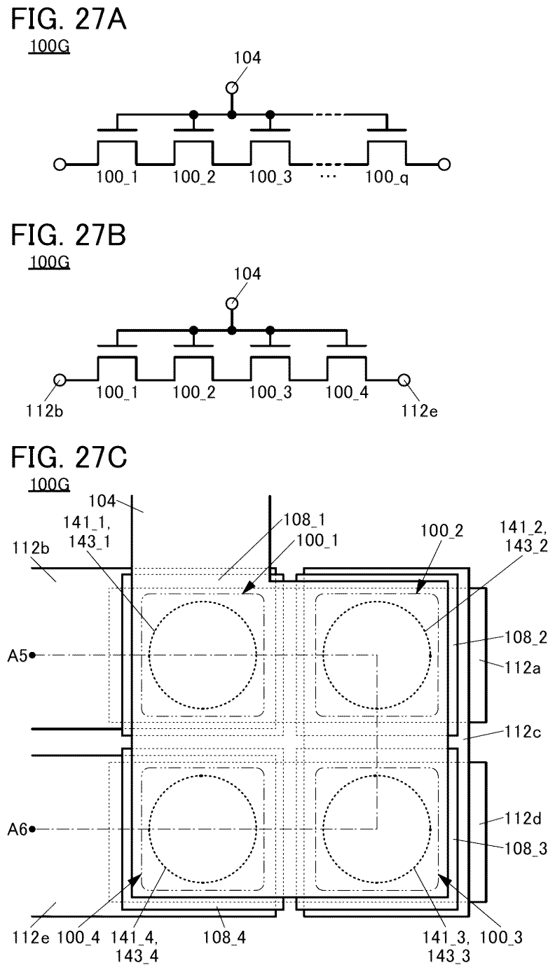

FIG. 27A is an equivalent circuit diagram of the transistor 100G that can be used in the semiconductor device of one embodiment of the present invention. The transistor 100G is a transistor group including the transistor 100_1 to a transistor 100_q (q is an integer greater than or equal to 2). The transistor 100G can be regarded as one transistor, in which the transistor 100_1 to the transistor 100_q are connected in series.

Although the transistor 100_1 to the transistor 100_q are illustrated as n-channel transistors in FIG. 27A, one embodiment of the present invention is not limited thereto. The transistor 100_1 to the transistor 100_q can be p-channel transistors.

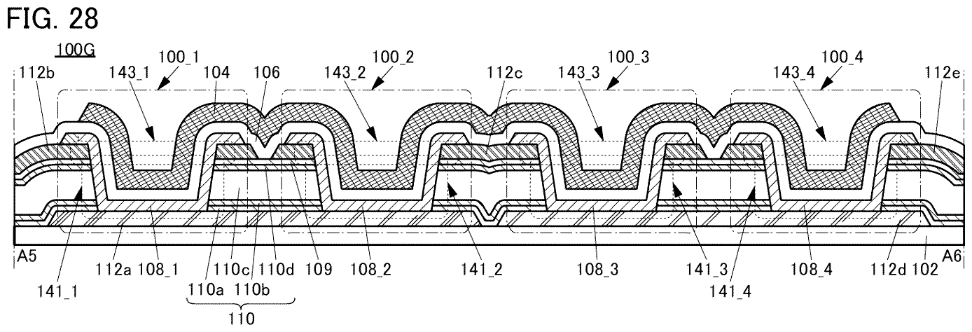

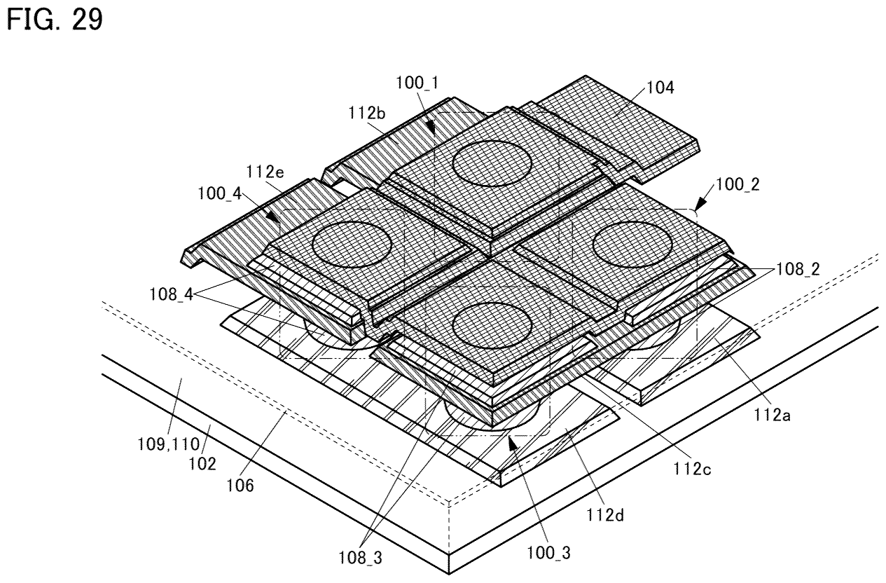

The case where q is 4 is specifically described as an example. FIG. 27B is an equivalent circuit diagram of the transistor 100G that is one embodiment of the present invention. FIG. 27C is a top view of the transistor 100G. FIG. 28 is a cross-sectional view of a cut plane along the dashed-dotted line A5-A6 illustrated in FIG. 27C. FIG. 29 is a perspective view of the transistor 100G.

The transistor 100G includes the transistor 100_1 to the transistor 100_4. The transistor 100_1 to the transistor 100_4 can each employ the above-described structure of the transistor 100. Although the transistor 100 is described as an example here, one embodiment of the present invention is not limited thereto. Any of the transistor 100A to the transistor 100G can be used as the transistor 100_1 to the transistor 100_4.

Although the transistor 100_1 to the transistor 100_4 are arranged in two rows and two columns in FIG. 27C and the like, there is no limitation on the transistor arrangement. For example, the transistor 100_1 to the transistor 100_4 can be arranged in one row and four columns. The transistor arrangement may be in a matrix and is not necessarily in a matrix.

The transistor 100_1 includes the conductive layer 104, the insulating layer 106, a semiconductor layer 108_1, the conductive layer 112a, and the conductive layer 112b. The conductive layer 112a functions as one of the source electrode and the drain electrode of the transistor 100_1, and the conductive layer 112b functions as the other.

The transistor 100_2 includes the conductive layer 104, the insulating layer 106, a semiconductor layer 108_2, the conductive layer 112a, and a conductive layer 112c. The conductive layer 112a functions as one of the source electrode and the drain electrode of the transistor 100_2, and the conductive layer 112c functions as the other. The conductive layer 112a is shared by the transistor 100_1 and the transistor 100_2.

The transistor 100_3 includes the conductive layer 104, the insulating layer 106, a semiconductor layer 108_3, the conductive layer 112c, and a conductive layer 112d. The conductive layer 112c functions as one of the source electrode and the drain electrode of the transistor 100_3, and the conductive layer 112d functions as the other. The conductive layer 112c is shared by the transistor 100_2 and the transistor 100_3.

The transistor 100_4 includes the conductive layer 104, the insulating layer 106, a semiconductor layer 108_4, the conductive layer 112d, and a conductive layer 112e. The conductive layer 112d functions as one of the source electrode and the drain electrode of the transistor 100_4, and the conductive layer 112e functions as the other. The conductive layer 112d is shared by the transistor 100_3 and the transistor 100_4.

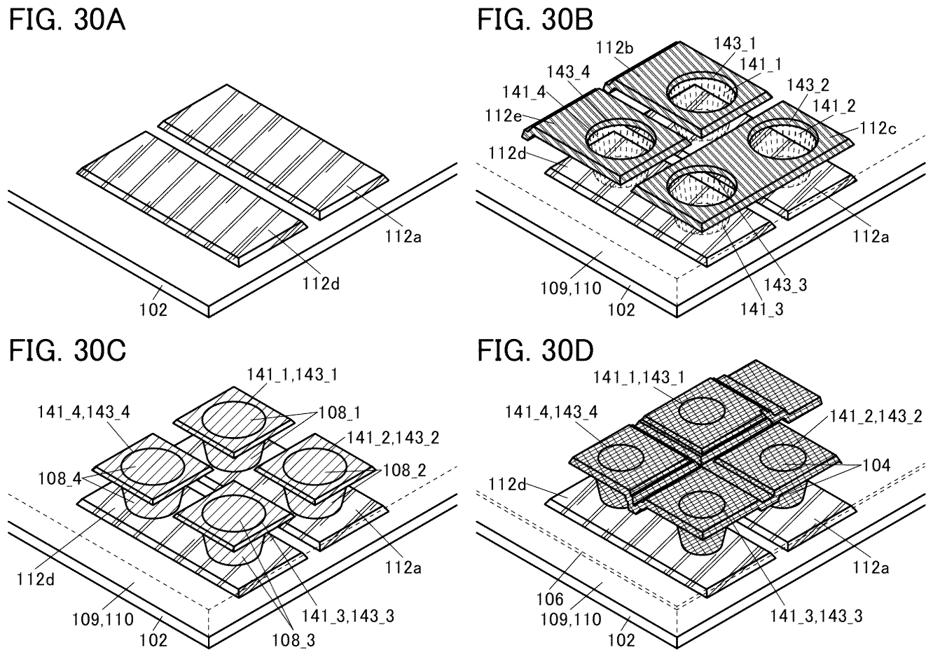

FIG. 30A is a perspective view selectively illustrating the conductive layer 112a and the conductive layer 112d. The conductive layer 112a and the conductive layer 112d can be formed in the same step.

FIG. 30B is a perspective view selectively illustrating the conductive layer 112a, the conductive layer 112b, the conductive layer 112c, the conductive layer 112d, the conductive layer 112e, the opening 141_1 to the opening 141_4, and the opening 143_1 to the opening 143_4. The conductive layer 112a to the conductive layer 112e can be formed in the same step. The opening 143_1 is provided in the conductive layer 112b, the opening 143_2 and the opening 143_3 are provided in the conductive layer 112c, and the opening 143_4 is provided in the conductive layer 112e.

FIG. 30C is a perspective view selectively illustrating the conductive layer 112a, the conductive layer 112d, and the semiconductor layer 108_1 to the semiconductor layer 108_4. The semiconductor layer 108_1 to the semiconductor layer 108_4 can be formed in the same step.

FIG. 30D is a perspective view selectively illustrating the conductive layer 112a, the conductive layer 112d, and the conductive layer 104. The conductive layer 104 functions as the gate electrode of each of the transistor 100_1 to the transistor 100_4.

One of the source electrode and the drain electrode of the transistor 100_1 is electrically connected to one of the source electrode and the drain electrode of the transistor 100_2. The other of the source electrode and the drain electrode of the transistor 100_2 is electrically connected to one of the source electrode and the drain electrode of the transistor 100_3. The other of the source electrode and the drain electrode of the transistor 100_3 is electrically connected to one of the source electrode and the drain electrode of the transistor 100_4.

In the case where the transistor 100G is regarded as one transistor, the channel length of the transistor is the sum of the channel lengths of the transistor 100_1 to the transistor 100_4. For example, in the case where the channel length L100 corresponds to the channel length of each of the transistor 100_1 to the transistor 100_4, the transistor 100G can be regarded as a transistor having a channel length of “L100×4” (see FIG. 4B). The transistor 100G composed of q transistors can be regarded as a transistor having a channel length of “L100×q”. Note that the transistor 100G can be regarded as a transistor having the channel width W100 (see FIG. 4A and FIG. 4B). A plurality of transistors connected in series can have a larger channel length and favorable saturation characteristics. By adjusting the number (q) of transistors connected in series, the channel length can be changed. The number (q) of transistors connected in series is determined so that desired saturation characteristics are obtained.

Note that the structure of the transistor 100G described in Structure example 9 can also be applied to other structure examples. For example, the transistor 100G can be used as one or more of the transistors included in the semiconductor devices illustrated in FIG. 1 to FIG. 22.

The transistor 100G can be used as each transistor included in the transistor 100F. That is, the groups of transistors connected in parallel can further be connected in series (hereinafter also referred to as series-parallel connection).

This embodiment can be combined with the other embodiments as appropriate. In this specification, in the case where a plurality of structure examples are shown in one embodiment, the structure examples can be combined as appropriate.

### Embodiment 2

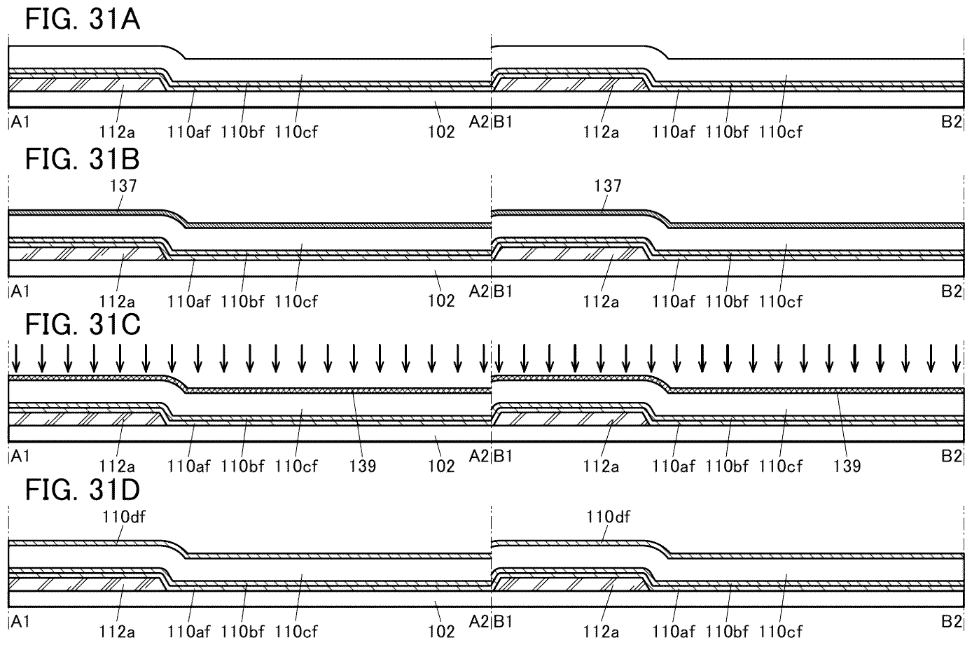

In this embodiment, a method for manufacturing a semiconductor device of one embodiment of the present invention will be described with reference to FIG. 31A to FIG. 37C. Note that as for a material and a formation method of each component, the description of portions similar to the portions described in Embodiment 1 is omitted in some cases.

Thin films included in the semiconductor device (e.g., insulating films, semiconductor films, and conductive films) can be formed by a sputtering method, a chemical vapor deposition (CVD) method, a vacuum evaporation method, a pulsed laser deposition (PLD) method, an ALD method, or the like. Examples of a CVD method include a PECVD method and a thermal CVD method. As an example of the thermal CVD method, a metal organic chemical vapor deposition (MOCVD: Metal Organic CVD) method can be given.

Thin films included in the semiconductor device (e.g., insulating films, semiconductor films, and conductive films) can be formed by a wet film formation method such as spin coating, dipping, spray coating, ink-jetting, dispensing, screen printing, offset printing, a doctor knife method, slit coating, roll coating, curtain coating, or knife coating.

When the thin films included in the semiconductor device are processed, a photolithography method or the like can be used. Alternatively, the thin films may be processed by a nanoimprinting method, a sandblasting method, a lift-off method, or the like. Alternatively, island-shaped thin films may be directly formed by a film formation method using a shielding mask such as a metal mask.

There are two typical examples of a photolithography method. In one of the methods, a resist mask is formed over a thin film to be processed, the thin film is processed by etching or the like, and then the resist mask is removed. In the other method, after a photosensitive thin film is formed, light exposure and development are performed, so that the thin film is processed into a desired shape.

As light used for light exposure in a photolithography method, it is possible to use the i-line (wavelength: 365 nm), the g-line (wavelength: 436 nm), the h-line (wavelength: 405 nm), or combined light of them. Alternatively, ultraviolet light, KrF laser light, ArF laser light, or the like can be used. In addition, light exposure may be performed by liquid immersion exposure technique. As the light used for light exposure, extreme ultraviolet (EUV) light or X-rays may be used. Instead of the light used for light exposure, an electron beam can be used. It is preferable to use extreme ultraviolet light, X-rays, or an electron beam because extremely minute processing can be performed. Note that a photomask is not needed when light exposure is performed by scanning with a beam such as an electron beam.

For etching of thin films, one or more of a dry etching method, a wet etching method, and a sandblast method can be used.

### Manufacturing Method Example 1

Here, an example of a method for manufacturing the semiconductor device 10 illustrated in FIG. 1A and FIG. 1C is described with reference to FIG. 31A to FIG. 36B. FIG. 31A to FIG. 36B each illustrate, side by side, a cross section along the dashed-dotted line A1-A2 illustrated in FIG. 1A and a cross section along the dashed-dotted line B1-B2 illustrated in FIG. 1A.

First, a film to be the conductive layer 112a is formed over the substrate 102, and the film is processed to form the conductive layer 112a. For the formation of the film, a sputtering method can be suitably used.

Next, an insulating film 110af to be the insulating layer 110a, an insulating film 110bf to be the insulating layer 110b, and an insulating film 110cf to be the insulating layer 110c are formed over the conductive layer 112a (FIG. 31A).

A sputtering method or a PECVD method can be suitably used for the formation of the insulating film 110af, the insulating film 110bf, and the insulating film 110cf. It is preferable that the insulating film 110bf be formed after the formation of the insulating film 110af, without exposure of a surface of the insulating film 110af to the air. Similarly, it is preferable that the insulating film 110cf be formed after the formation of the insulating film 110bf, without exposure of a surface of the insulating film 110bf to the air. This can inhibit attachment of atmospherically-derived impurities to the interface between the insulating film 110af and the insulating film 110bf and the interface between the insulating film 110bf and the insulating film 110cf. Examples of the impurities include water and organic substances. It is preferable that the insulating film 110af is formed, and in succession, the insulating film 110bf and the insulating film 110cf be formed with the same apparatus, for example.

As described above, the amount of oxygen released from the insulating layer 110c is preferably large. Furthermore, the diffusion coefficient of a substance (in particular, oxygen) in the insulating layer 110c is preferably high. In the case where a PECVD method is used for forming the insulating film 110cf to be the insulating layer 110c, the F ratio is preferably within the above range. This facilitates diffusion of oxygen in the insulating layer 110c to efficiently supply oxygen contained in the insulating layer 110c to the semiconductor layer 108 (in particular, the channel formation region), and makes the amount of impurities released from the insulating layer 110c small.

The substrate temperatures at the time of forming the insulating film 110af, the insulating film 110bf, and the insulating film 110cf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 110af, the insulating film 110bf, and the insulating film 110cf are within the above range, impurities (e.g., water and hydrogen) released from the insulating films themselves can be reduced, which inhibits diffusion of the impurities into the semiconductor layer 108. Consequently, a transistor with favorable electrical characteristics and high reliability can be obtained.

Note that since the insulating film 110af, the insulating film 110bf, and the insulating film 110cf are formed earlier than the semiconductor layer 108 and the semiconductor layer 208, there is no need to consider the probability of oxygen release from the semiconductor layer 108 and the semiconductor layer 208 due to heat applied thereto at the time of forming the insulating film 110af, the insulating film 110bf, and the insulating film 110cf.

After the insulating film 110cf is formed, oxygen may be supplied to the insulating film 110cf. As a method for supplying oxygen, an ion implantation method, an ion doping method, a plasma immersion ion implantation method, or plasma treatment can be used, for example. For the plasma treatment, an apparatus in which an oxygen gas is made to be plasma by high-frequency power can be suitably used. Examples of the apparatus in which a gas is made to be plasma by high-frequency power include a PECVD apparatus, a plasma etching apparatus, and a plasma ashing apparatus. The plasma treatment is preferably performed in an atmosphere containing oxygen. For example, plasma treatment is preferably performed in an atmosphere containing one or more of oxygen, dinitrogen monoxide (N₂O), nitrogen dioxide (NO₂), carbon monoxide, and carbon dioxide.

Note that the plasma treatment may be performed without exposure of the surface of the insulating film 110cf to the air. For example, in the case where a PECVD apparatus is used for forming the insulating film 110cf, the plasma treatment is preferably performed with the PECVD apparatus. Accordingly, the productivity can be increased. Specifically, after the insulating film 110cf is formed with the PECVD apparatus, N₂O plasma treatment can be successively performed with the same apparatus.

A film 137 is preferably formed over the insulating film 110cf (FIG. 31B). The film 137 preferably contains oxygen. The formation of the film 137 enables oxygen supply to the insulating film 110cf.

There is no limitation on the conductivity of the film 137. As the film 137, at least one of an insulating film, a semiconductor film, and a conductive film can be used. For the film 137, aluminum oxide, hafnium oxide, hafnium aluminate, indium oxide, indium tin oxide (ITO), or indium tin oxide containing silicon (ITSO) can be used, for example.

An oxide material containing one or more elements that are the same as those in the semiconductor layer 108 and the semiconductor layer 208 is preferably used for the film 137. It is particularly preferable to use an metal oxide material that can be used for each of the semiconductor layer 108 and the semiconductor layer 208.

At the time of forming the film 137, the amount of oxygen supplied into the insulating film 110cf can be increased with a higher oxygen flow rate ratio in the film formation gas introduced into a processing chamber of a film formation apparatus or with a higher oxygen partial pressure in the processing chamber. The oxygen flow rate ratio or the oxygen partial pressure is, for example, set to higher than or equal to 50% and lower than or equal to 100%, preferably higher than or equal to 65% and lower than or equal to 100%, further preferably higher than or equal to 80% and lower than or equal to 100%, still further preferably higher than or equal to 90% and lower than or equal to 100%. It is particularly preferable that the oxygen flow rate ratio be 100% and the oxygen partial pressure be as close to 100% as possible.

When the film 137 is formed by a sputtering method in an atmosphere containing oxygen in the above manner, oxygen can be supplied to the insulating film 110cf and release of oxygen from the insulating film 110cf can be prevented during the formation of the film 137. As a result, a large amount of oxygen can be enclosed in the insulating film 110cf. Moreover, a large amount of oxygen can be supplied to the semiconductor layer 108 by heat treatment performed later. As a result, oxygen vacancies (V_{O}) and V_{O}H in the semiconductor layer 108 can be reduced, so that a highly reliable transistor exhibiting favorable electrical characteristics can be obtained.

After the film 137 is formed, heat treatment may be performed. By the heat treatment performed after the formation of the film 137, oxygen can be effectively supplied from the film 137 to the insulating film 110cf.

The temperature of the heat treatment is preferably higher than or equal to 150° C., higher than or equal to 200° C., higher than or equal to 230° C., or higher than or equal to 250° C. and lower than the strain point of the substrate, lower than or equal to 450° C., lower than or equal to 400° C., lower than or equal to 350° C., or lower than or equal to 300° C. The heat treatment can be performed in an atmosphere containing one or more of a noble gas, nitrogen, and oxygen. As an atmosphere containing nitrogen or an atmosphere containing oxygen, clean dry air (CDA) can be used. Note that the content of hydrogen, water, or the like in the atmosphere is preferably as low as possible. As the atmosphere, a high-purity gas with a dew point of −60° C. or lower, preferably −100° C. or lower is preferably used. With use of an atmosphere where the content of hydrogen, water, or the like is as low as possible, entry of hydrogen, water, or the like into the insulating film 110af, the insulating film 110bf, and the insulating film 110cf can be prevented as much as possible. An oven, a rapid thermal annealing (RTA) apparatus, or the like can be used for the heat treatment. The use of the RTA apparatus can shorten the heat treatment time.

After the formation of the film 137 or after the above-described heat treatment, oxygen may be further supplied to the insulating film 110cf through the film 137. As a method for supplying oxygen, an ion implantation method, an ion doping method, a plasma immersion ion implantation method, or plasma treatment can be used, for example. The above description can be referred to for the plasma treatment; thus, the detailed description thereof is omitted.

Then, the film 137 is removed. There is no particular limitation on a method for removing the film 137, and a wet etching method can be suitably used. With use of a wet etching method, the insulating film 110cf can be inhibited from being etched at the time of removing the film 137. This can inhibit a reduction in the thickness of the insulating film 110cf and the thickness of the insulating layer 110c can be uniform.

After the film 137 is removed, oxygen may be further supplied to the insulating film 110cf. The above description can be referred to for a method for supplying oxygen. For example, as illustrated in FIG. 31C, a film 139 may be formed over the insulating film 110cf and oxygen may be supplied to the insulating film 110cf through the film 139. As the treatment, plasma treatment in an atmosphere containing oxygen can be used. FIG. 31C schematically illustrates a state where oxygen is supplied to the insulating film 110cf by arrows.

As the film 139, a conductive film or a semiconductor film is preferably used. As the film 139, a metal oxide film, a metal film, or an alloy film can be used. The film 139 is preferably formed using a metal oxide in an atmosphere containing oxygen by a sputtering method or the like, in which case oxygen can be supplied to the insulating film 110cf also at the time of forming the film 139.

The thickness of the film 139 is preferably small. Specifically, the thickness of the film 139 is preferably greater than or equal to 1 nm, greater than or equal to 2 nm, or greater than or equal to 3 nm and less than or equal to 20 nm, less than or equal to 15 nm, or less than or equal to 10 nm. Typically, the thickness can be approximately 5 nm.

The substrate temperature at the time of forming the film 139 is preferably lower than or equal to 350° C., further preferably lower than or equal to 340° C., still further preferably lower than or equal to 330° C., yet still further preferably lower than or equal to 300° C. Accordingly, the amount of oxygen supplied to the insulating film 110cf can be increased.

By provision of the film 139, when a bias voltage is applied between a pair of electrodes at the time of supplying oxygen, ionized oxygen is easily drawn. Accordingly, the amount of oxygen supplied to the insulating film 110cf can be increased.

As a treatment apparatus for supplying oxygen, a dry etching apparatus, an ashing apparatus, or a PECVD apparatus can be suitably used. In particular, an ashing apparatus is preferably used. When a bias voltage is applied between a pair of electrodes in the treatment apparatus, the bias voltage can be higher than or equal to 10 V and lower than or equal to 1 kV, for example. The power density of the bias can be higher than or equal to 1 W/cm² and lower than or equal to 5 W/cm², for example.

Next, the film 139 is removed. For the removal of the film 139, a wet etching method can be suitably used.

The treatment for supplying oxygen to the insulating film 110cf is not necessarily performed in the above-described manner. For example, an oxygen radical, an oxygen atom, an oxygen atomic ion, or an oxygen molecular ion is supplied to the insulating film 110cf by an ion doping method, an ion implantation method, or plasma treatment. Alternatively, a film that inhibits oxygen release may be formed over the insulating film 110cf, and then oxygen may be supplied to the insulating film 110cf through the film. It is preferable to remove the film after supply of oxygen. As the above film that inhibits oxygen release, a conductive film or a semiconductor film containing one or more of indium, zinc, gallium, tin, aluminum, chromium, tantalum, titanium, molybdenum, nickel, iron, cobalt, and tungsten can be used.

The amount of oxygen released from the insulating layer 110c in contact with the channel formation region of the transistor 100 having a short channel length is preferably larger than that of oxygen released from the insulating layer 120b in contact with the channel formation region of the transistor 200 having a long channel length. By supplying oxygen to the insulating film 110cf to be the insulating layer 110c, the amount of oxygen contained in the insulating layer 110c can be increased, so that the amount of oxygen supplied from the insulating layer 110c to the semiconductor layer 108 can be increased and the transistor 100 having a short channel length can have favorable electrical characteristics.

Next, an insulating film 110df to be the insulating layer 110d is formed over the insulating film 110cf (FIG. 31D). The description of the formation of the insulating film 110af and the insulating film 110bf can be referred to for the formation of the insulating film 110df; thus, the detailed description thereof is omitted.

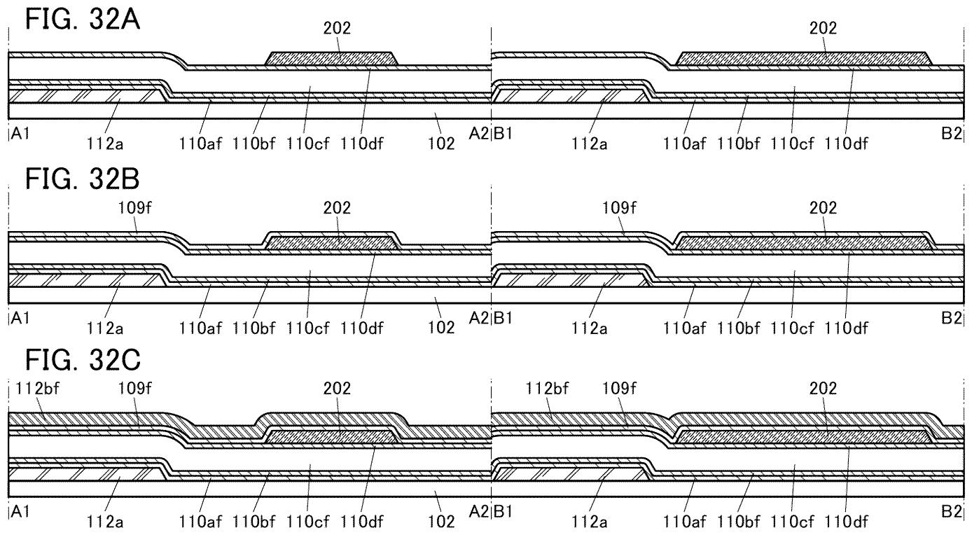

Next, a film to be the conductive layer 202 is formed over the insulating film 110df and then the film is processed, so that the conductive layer 202 is formed (FIG. 32A). For the formation of the film, a sputtering method can be suitably used.

Then, an insulating film 109f to be the insulating layer 109 is formed over the conductive layer 202 and the insulating layer 110df (FIG. 32B).

Then, a conductive film 112bf to be the conductive layer 112b is formed over the insulating film 109f (FIG. 32C). For the formation of the conductive film 112bf, a sputtering method can be suitably used, for example.

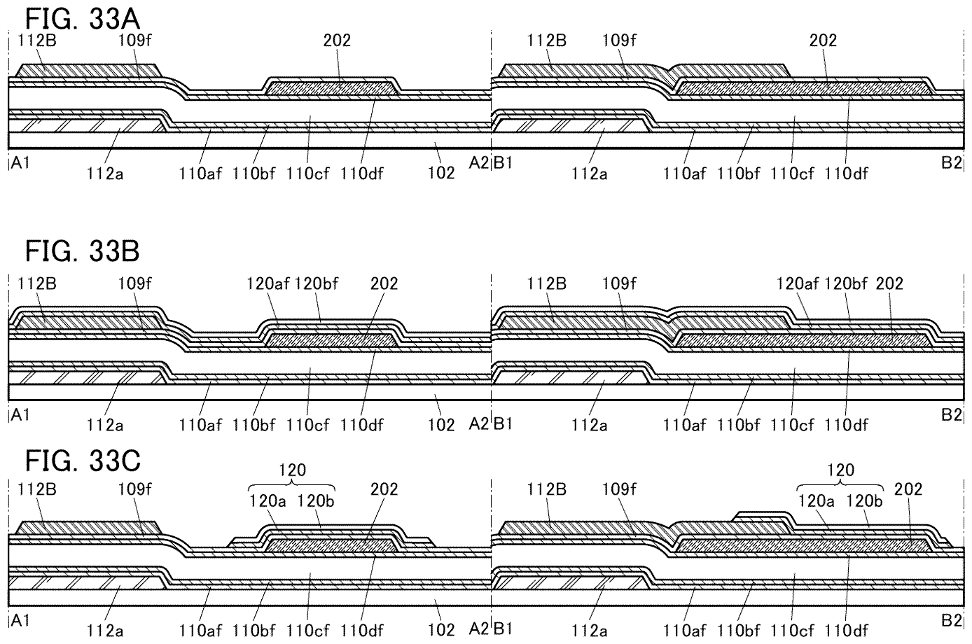

Next, the conductive film 112bf is processed to form a conductive layer 112B (FIG. 33A). The conductive layer 112B becomes the conductive layer 112b later. For the formation of the conductive layer 112B, a wet etching method can be suitably used, for example.

Then, an insulating film 120af to be the insulating layer 120a and an insulating film 120bf to be the insulating layer 120b are formed over the conductive layer 112B and the insulating film 109f (FIG. 33B).

For the formation of the insulating film 120af and the insulating film 120bf, a sputtering method or a PECVD method can be suitably used. It is preferable that the insulating film 120bf be formed after the formation of the insulating film 120af, without exposure of a surface of the insulating film 120af to the air. This can inhibit attachment of atmospherically-derived impurities to the interface between the insulating film 120af and the insulating film 120bf. Examples of the impurities include water and organic substances. It is preferable that the insulating film 120bf be formed successively after the formation of the insulating film 120af with the same apparatus, for example.

As described above, the amount of oxygen released from the insulating layer 120b may be smaller than the amount of oxygen released from the insulating layer 110c. The diffusion coefficient of oxygen in the insulating layer 120b may be lower than the diffusion coefficient of oxygen in the insulating layer 110c. In the case where a PECVD method is used for forming the insulating film 120bf to be the insulating layer 120b, the F ratio is preferably within the above range.

The substrate temperatures at the time of forming the insulating film 120af and the insulating film 120bf are each preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C., yet still further preferably higher than or equal to 350° C. and lower than or equal to 400° C. When the substrate temperatures at the time of forming the insulating film 120af and the insulating film 120bf are within the above range, impurities (e.g., water and hydrogen) released from the insulating films themselves can be reduced, which inhibits diffusion of the impurities into the semiconductor layer 108. Consequently, a transistor with favorable electrical characteristics and high reliability can be obtained.

Note that since the insulating film 120af and the insulating film 120bf are formed earlier than the semiconductor layer 108 and the semiconductor layer 208, there is no need to consider the probability of oxygen release from the semiconductor layer 108 and the semiconductor layer 208 due to heat applied thereto at the time of forming the insulating film 120af and the insulating film 120bf.

After the insulating film 120bf is formed, oxygen may be supplied to the insulating film 120bf. The above description can be referred to for the method for supplying oxygen.

Next, the insulating film 120af and the insulating film 120bf are processed to form the insulating layer 120 including the insulating layer 120a and the insulating layer 120b (FIG. 33C). The insulating layer 120 is formed at least in a region where the semiconductor layer 208 is to be provided. In addition, at least part of the conductive layer 112B is exposed by the formation of the insulating layer 120. For the processing of the insulating film 120af and the insulating film 120bf, a dry etching method can be suitably used, for example.

Next, the conductive layer 112B is partly removed, so that the conductive layer 112b including the opening 143 is formed. For the formation of the conductive layer 112b, a wet etching method can be suitably used, for example.

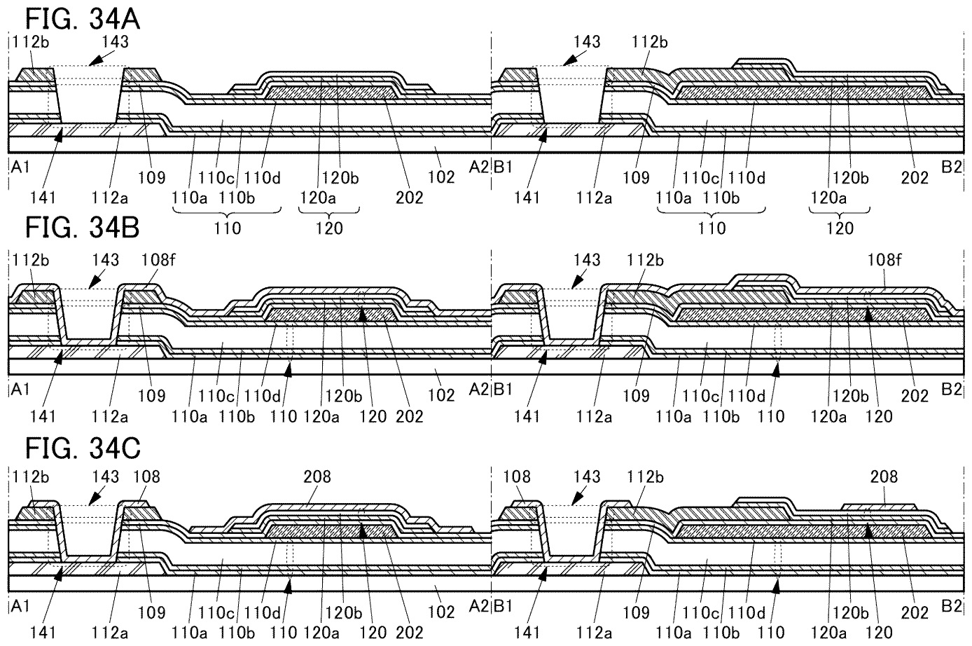

Next, part of the insulating film 110af, part of the insulating film 110bf, part of the insulating film 110cf, part of the insulating film 110df, and part of the insulating film 109f are removed, so that the insulating layer 110 including the opening 141 is formed (FIG. 34A). The opening 141 is provided in a region overlapping with the opening 143. The top surface of part of the conductive layer 112a is exposed by the formation of the opening 141. For the formation of the insulating layer 110, a dry etching method can be suitably used, for example.

The opening 141 can be formed using a resist mask used for the formation of the opening 143, for example. Specifically, the resist mask is formed over the conductive layer 112B, part of the conductive layer 112B is removed using the resist mask to form the opening 143, and part of the insulating film 110af, part of the insulating film 110bf, part of the insulating film 110cf, part of the insulating film 110df, and part of the insulating film 109f are removed using the resist mask, so that the opening 141 can be formed. The opening 141 can also be formed using a resist mask that is different from the resist mask used for the formation of the opening 143.

Note that in the formation of the opening 141 or after the formation of the opening 141, part of the conductive layer 112a in a region overlapping with the opening 141 may be removed. When the thickness of the region of the conductive layer 112a that is in contact with the bottom surface of the semiconductor layer 108 is smaller than the thickness of the region of the conductive layer 112a that is not in contact with the semiconductor layer 108, the electric field of the gate electrode applied to the channel formation region in the vicinity of the conductive layer 112a can be intensified, leading to a high on-state current of the transistor.

Next, a metal oxide film 108f to be the semiconductor layer 108 and the semiconductor layer 208 is formed to cover the opening 141 and the opening 143 (FIG. 34B). The metal oxide film 108f is provided in contact with the top surface and the side surface of the conductive layer 112b, the top surface and the side surface of the insulating layer 109, the side surface of the insulating layer 110, the top surface of the conductive layer 112a, and the top surface and the side surface of the insulating layer 120.

The metal oxide film 108f is preferably formed by a sputtering method using a metal oxide target. Alternatively, the metal oxide film 108f is preferably formed by an ALD method. An ALD method offers high coverage, and thus can be suitably used for forming the metal oxide film 108f provided to cover the opening 141 and the opening 143. By an ALD method, a metal oxide film can be formed also on the side surface of the insulating layer 110 with high coverage. In an ALD method, the film formation rate can be easily controlled, so that a thin film can be formed with high yield.

The metal oxide film 108f is preferably a dense film with as few defects as possible. The metal oxide film 108f is preferably a highly purified film in which impurities containing a hydrogen element are reduced as much as possible. It is particularly preferable to use a metal oxide film having crystallinity as the metal oxide film 108f.

In forming the metal oxide film 108f, an oxygen gas is preferably used. With use of an oxygen gas, oxygen can be suitably supplied into the insulating layer 110 and the insulating layer 120. For example, in the case of using an oxide or an oxynitride for the insulating layer 110c, oxygen can be suitably supplied into the insulating layer 110c. Similarly, in the case of using an oxide or an oxynitride for the insulating layer 120b, oxygen can be suitably supplied into the insulating layer 120b.

By the supply of oxygen to the insulating layer 110c, oxygen is supplied to the channel formation region in the semiconductor layer 108 in a later step, so that oxygen vacancies (V_{O}) and V_{O}H in the channel formation region can be reduced. In addition, by the supply of oxygen to the insulating layer 120b, oxygen is supplied to the channel formation region in the semiconductor layer 208 in a later step, so that oxygen vacancies (V_{O}) and V_{O}H in the channel formation region can be reduced.

In forming the metal oxide film 108f, an oxygen gas and an inert gas (e.g., a helium gas, an argon gas, or a xenon gas) may be mixed. Note that when the oxygen flow rate ratio of the film formation gas or the oxygen partial pressure in the treatment chamber is higher in forming the metal oxide film, the metal oxide film can have higher crystallinity and the transistor can have higher reliability. On the other hand, when the oxygen flow rate ratio or the oxygen partial pressure is lower, the metal oxide film can have lower crystallinity and higher electrical conductivity and the transistor can have a higher on-state current.

Here, when the oxygen flow rate ratio or the oxygen partial pressure is high, the metal oxide film has a polycrystalline structure in some cases. In the case of a metal oxide film having a polycrystalline structure, the grain boundary becomes a recombination center and captures carriers and thus might reduce the on-state current of the transistor. Therefore, the oxygen flow rate ratio or the oxygen partial pressure is preferably adjusted so that the metal oxide film 108f does not have a polycrystalline structure. Since the ease of forming the polycrystalline structure depends on the composition of the metal oxide film, the oxygen flow rate ratio or the oxygen partial pressure can be adjusted in accordance with the composition of the metal oxide film 108f.

As the substrate temperature in forming the metal oxide film is higher, a denser metal oxide film having higher crystallinity can be formed. On the other hand, as the substrate temperature is lower, a metal oxide film having lower crystallinity and higher electric conductivity can be formed.

The substrate temperature at the time of forming the metal oxide film 108f is preferably higher than or equal to room temperature and lower than or equal to 250° C., further preferably higher than or equal to room temperature and lower than or equal to 200° C., still further preferably higher than or equal to room temperature and lower than or equal to 140° C. For example, the substrate temperature is preferably higher than or equal to room temperature and lower than or equal to 140° C., in which case high productivity is achieved. When the metal oxide film 108f is formed with the substrate temperature set at room temperature or without heating the substrate, the metal oxide film 108f can have low crystallinity.

When the substrate temperature is high, the metal oxide film has a polycrystalline structure in some cases. The substrate temperature is preferably adjusted so that the metal oxide film 108f does not have a polycrystalline structure. The substrate temperature can be adjusted in accordance with the composition employed for the metal oxide film 108f.

In the case of using an ALD method, a film formation method such as a thermal ALD method or PEALD (Plasma Enhanced ALD) is preferably used. The thermal ALD method is preferable because of its capability of offering extremely high coverage. The PEALD method is preferable because of its capability of forming a film at low temperatures, in addition to its capability of offering high coverage.

For example, the metal oxide film can be formed by an ALD method using a precursor containing a constituent metal element and an oxidizer.

For example, in the case where In—Ga—Zn oxide is formed, three precursors of a precursor containing indium, a precursor containing gallium, and a precursor containing zinc can be used. Alternatively, two precursors of a precursor containing indium and a precursor containing gallium and zinc can be used.

Examples of the precursor containing indium include triethylindium, trimethylindium, tris(2,2,6,6-tetramethyl-3,5-heptanedionato)indium, cyclopentadienylindium, indium(III) chloride, (3-(dimethylamino)propyl)dimethylindium, and [1,1,1-trimethyl-N-(trimethylsilyl)amide]-indium.

Examples of the precursor containing gallium include trimethylgallium, triethylgallium, gallium trichloride, tris(dimethylamido)gallium(III), gallium(III) acetylacetonate, tris(2,2,6,6-tetramethyl-3,5-heptanedionato)gallium, dimethylchlorogallium, and diethylchlorogallium.

Examples of a precursor containing aluminum include aluminum chloride and trimethylaluminum.

Examples of a precursor containing tin include tin(IV) chloride and tetrakis(dimethylamido)tin.

Examples of the precursor containing zinc include dimethylzinc, diethylzinc, bis(2,2,6,6-tetramethyl-3,5-heptanedionato)zinc, and zinc chloride.

Examples of the oxidizer include ozone, oxygen, and water.

As a method for controlling the composition of a film to be obtained, adjusting one or more of the kinds of source gases, the flow rate ratio of source gases, the flowing time of the source gases, and the order in which the source gases flow is given. By adjusting these, the composition of the metal oxide film 108f can be controlled. Moreover, by adjusting these, a film whose composition is continuously changed can also be formed. The composition of the metal oxide film 108f may be continuously changed.

Before the formation of the metal oxide film 108f, at least one of treatment for desorbing water, hydrogen, an organic substance, and the like adsorbed on the surfaces of the insulating layer 109, the insulating layer 110, and the insulating layer 120, and treatment for supplying oxygen to the insulating layer 110 and the insulating layer 120 is preferably performed. For example, heat treatment can be performed at a temperature higher than or equal to 70° C. and lower than or equal to 200° C. in a reduced-pressure atmosphere. Alternatively, plasma treatment may be performed in an atmosphere containing oxygen. Alternatively, oxygen may be supplied to the insulating layer 110 and the insulating layer 120 by plasma treatment in an atmosphere containing an oxidizing gas such as dinitrogen monoxide (N₂O). Performing plasma treatment containing a dinitrogen monoxide gas can supply oxygen to the insulating layer 110 and the insulating layer 120 while suitably removing an organic substance on the surfaces of the insulating layer 109, the insulating layer 110, and the insulating layer 120. It is preferable that the metal oxide film 108f be formed successively after such treatment, without exposure of the surfaces of the insulating layer 109, the insulating layer 110, and the insulating layer 120 to the air.

Note that in the case where each of the semiconductor layer 108 and the semiconductor layer 208 has a stacked-layer structure, an upper metal oxide film is preferably formed successively after the formation of a lower metal oxide film without exposure of the surface of the lower metal oxide layer to the air.

In the case where the semiconductor layer 108 and the semiconductor layer 208 have a stacked-layer structure, all the layers included in the semiconductor layer 108 and the semiconductor layer 208 may be formed by the same film formation method (e.g., a sputtering method or an ALD method) or the layers may be formed by different film formation methods. For example, the first metal oxide layer may be formed by a sputtering method and the second metal oxide layer may be formed by an ALD method.

Next, the metal oxide film 108f is processed into an island shape, so that the semiconductor layer 108 and the semiconductor layer 208 are formed (FIG. 34C).

For the formation of each of the semiconductor layer 108 and the semiconductor layer 208, a wet etching method can be suitably used. At this time, part of the insulating layer 109 and part of the insulating layer 120 in a region overlapping with neither the semiconductor layer 108 nor the semiconductor layer 208 are etched and thinned in some cases. Note that a material having high selectivity is preferably used for each of the insulating layer 109 and the insulating layer 120 in etching of the metal oxide film 108f, in which case a reduction in the thicknesses of the insulating layer 109 and the insulating layer 120 can be inhibited.

Heat treatment is preferably performed after the metal oxide film 108f is formed or after the metal oxide film 108f is processed into the semiconductor layer 108 and the semiconductor layer 208. By the heat treatment, hydrogen and water contained in the metal oxide film 108f or the semiconductor layer 108 and the semiconductor layer 208 or adsorbed onto the surface thereof can be removed. Furthermore, the film quality of the metal oxide film 108f or the semiconductor layer 108 and the semiconductor layer 208 is improved (e.g., the number of defects is reduced or the crystallinity is increased) by the heat treatment in some cases.

Oxygen can also be supplied from the insulating layer 110c and the insulating layer 120b to the metal oxide film 108f, from the insulating layer 110c to the semiconductor layer 108, or from the insulating layer 120b to the semiconductor layer 208 by heat treatment. Accordingly, the oxygen vacancies (V_{O}) and V_{O}H in the channel formation regions of the transistor 100 and the transistor 200 can be reduced. In this case, it is further preferable that heat treatment be performed before processing the metal oxide film 108f into the semiconductor layer 108 and the semiconductor layer 208. The above description can be referred to for the heat treatment; thus, the detailed description thereof is omitted. Note that supply of oxygen to the channel formation region may be performed not only through the heat treatment but also in a heat application step in and after the formation of the metal oxide film 108f (e.g., the step of forming the insulating layer 106).

Note that the heat treatment may be omitted when not needed. The heat treatment in this step may be omitted, and heat treatment performed in a later step may also serve as the heat treatment in this step. In some cases, heat application treatment in a later step (e.g., a film formation step) can serve as the heat treatment in this step.

As described above, it is preferable that the insulating layer 120 be formed after a conductive film to be the conductive layer 112b is formed, and the semiconductor layer 208 be formed over the insulating layer 120. In that case, a component included in the conductive layer (e.g., a metal included in the conductive layer 112b) can be inhibited from being attached to the interface between the insulating layer 120 and the semiconductor layer 208, whereby the transistor 200 can have favorable electrical characteristics and high reliability.

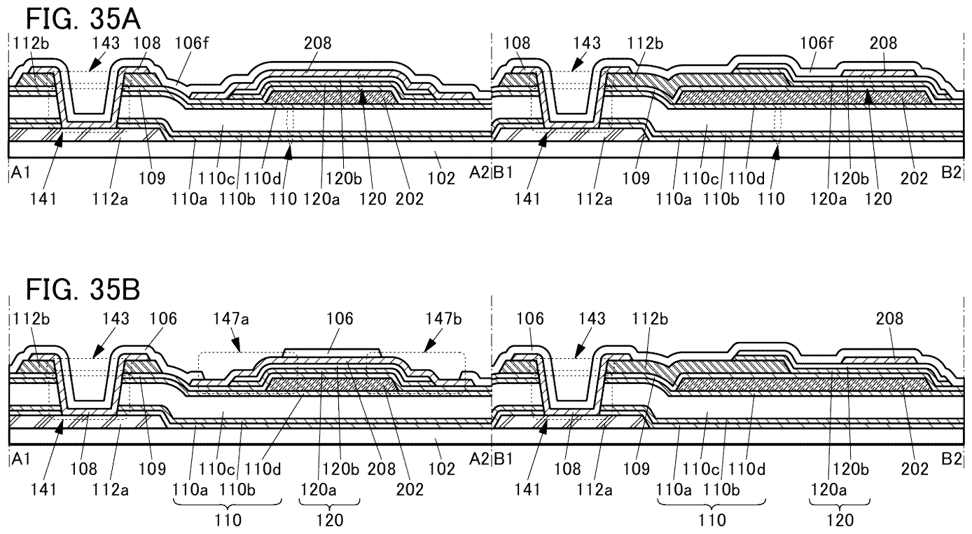

Next, an insulating film 106f to be the insulating layer 106 functioning as a gate insulating layer is formed to cover the semiconductor layer 108, the semiconductor layer 208, and the insulating layer 110 (FIG. 35A). For the formation of the insulating film 106f, a PECVD method or an ALD method can be suitably used, for example.

In the case of using a metal oxide for each of the insulating layer 108 and the semiconductor layer 208, the insulating layer 106 preferably functions as a barrier film inhibiting diffusion of oxygen. When the insulating layer 106 has a function of inhibiting diffusion of oxygen, oxygen contained in the semiconductor layer 108 and the semiconductor layer 208 is inhibited from being diffused to above the insulating layer 106, and an increase in oxygen vacancies (V_{O}) in the semiconductor layer 108 and the semiconductor layer 208 can be inhibited. Consequently, the transistor can have favorable electrical characteristics and high reliability.

By increasing the temperature at the time of forming the insulating film 106f, the insulating layer 106 including a small number of defects can be obtained. However, the high temperature at the time of forming the insulating film 106f sometimes allows release of oxygen from the semiconductor layer 108 and the semiconductor layer 208, which increases oxygen vacancies (V_{O}) and V_{O}H in the semiconductor layer 108 and the semiconductor layer 208 in some cases. The substrate temperature at the time of forming the insulating film 106f is preferably higher than or equal to 180° C. and lower than or equal to 450° C., further preferably higher than or equal to 200° C. and lower than or equal to 450° C., still further preferably higher than or equal to 250° C. and lower than or equal to 450° C., yet still further preferably higher than or equal to 300° C. and lower than or equal to 450° C., yet still further preferably higher than or equal to 300° C. and lower than or equal to 400° C. When the substrate temperature at the time of forming the insulating film 106f is within the above range, release of oxygen from the semiconductor layer 108 and the semiconductor layer 208 can be inhibited while the defects in the insulating layer 106 can be reduced. Consequently, a transistor with favorable electrical characteristics and high reliability can be obtained.

Before the formation of the insulating film 106f, plasma treatment may be performed on the surfaces of the semiconductor layer 108 and the semiconductor layer 208. By the plasma treatment, impurities such as water adsorbed on the surfaces of the semiconductor layer 108 and the semiconductor layer 208 can be reduced. Therefore, impurities at the interface between the semiconductor layer 108 and the insulating layer 106 and the interface between the semiconductor layer 208 and the insulating layer 106 can be reduced, and highly reliable transistors can be provided. The plasma treatment is particularly suitable in the case where the surfaces of the semiconductor layer 108 and the semiconductor layer 208 are exposed to the air after the formation of the semiconductor layer 108 and the semiconductor layer 208 and before the formation of the insulating film 106f. For example, the plasma treatment can be performed in an atmosphere of oxygen, ozone, nitrogen, dinitrogen monoxide, argon, or the like. The plasma treatment and the formation of the insulating film 106f are preferably performed successively without exposure to the air.

Next, the insulating film 106f is processed to form the insulating layer 106 (FIG. 35B). The opening 147a and the opening 147b reaching the semiconductor layer 208 are provided in the insulating layer 106. For the formation of the insulating layer 106, a dry etching method can be suitably used.

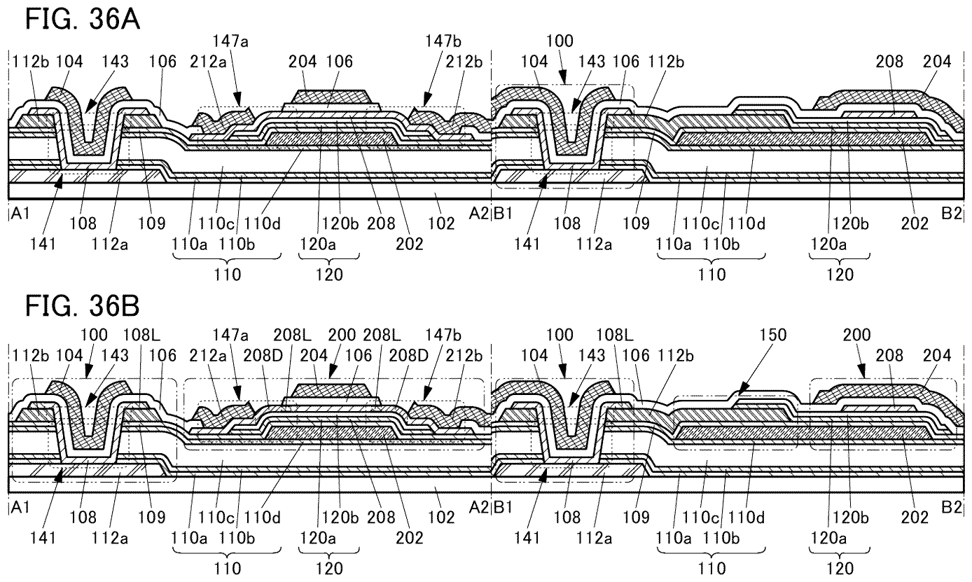

Next, a film to be the conductive layer 104, the conductive layer 204, the conductive layer 212a, and the conductive layer 212b is formed over the insulating layer 106 and the film is processed, so that the conductive layer 104, the conductive layer 204, the conductive layer 212a, and the conductive layer 212b are formed (FIG. 36A). For the formation of the film, a sputtering method, a thermal CVD method (including an MOCVD method), or an ALD method can be suitably used, for example.

Next, an impurity is supplied (or added or implanted) to the semiconductor layer 208 using the conductive layer 204, the conductive layer 212a, and the conductive layer 212b as masks. Thus, the region 208D is formed in the region of the semiconductor layer 208 that overlaps with none of the conductive layer 204, the conductive layer 212a, the conductive layer 212b, and the insulating layer 106, and the region 208L is formed in the region of the semiconductor layer 208 that overlaps with none of the conductive layer 204, the conductive layer 212a, and the conductive layer 212b and overlaps with the insulating layer 106 (FIG. 36B). At this time, the conditions for supplying the impurity are preferably determined in consideration of the material and thickness of the conductive layer 204 serving as the mask so that the impurity is supplied as little as possible to the region of the semiconductor layer 208 that overlaps with the conductive layer 204. In that case, a channel formation region with a sufficiently reduced impurity concentration can be formed in the region of the semiconductor layer 208 that overlaps with the conductive layer 204. Similarly, the semiconductor layer 108 may also be supplied with an impurity using the conductive layer 104 as a mask. The region 108L is formed in the region of the semiconductor layer 108 that does not overlap with the conductive layer 104 and overlaps with the insulating layer 106.

A plasma ion doping method or an ion implantation method can be suitably used for the supply of the impurity. In these methods, the concentration profile in the depth direction can be controlled with high accuracy by the acceleration voltage and the dosage of ions, for example. Using a plasma ion doping method can increase productivity. In addition, using an ion implantation method with mass separation can increase the purity of the impurity to be supplied.

The conditions for supplying the impurity are preferably adjusted such that the impurity concentration is highest at a surface of the semiconductor layer 208 or a portion near the surface.

As a source material used for supplying the impurity, a gas containing the above impurity element can be used, for example. In the case where boron is supplied, typically, one or more of a B₂H₆ gas and a BF₃ gas can be used. In the case where phosphorus is supplied, typically, a PH₃ gas can be used. A mixed gas in which any of these source gases is diluted with a noble gas can also be used.

For example, any of CH₄, N₂, NH₃, AlH₃, AlCl₃, SiH₄, Si₂H₆, F₂, HF, H₂, (C₅H₅)₂Mg, and a noble gas can be used as the source material used for supplying the impurity. Note that the source material is not limited to a gas, and a solid or a liquid that is vaporized by heating can also be used.

Supply of the impurity can be controlled by setting the conditions such as the acceleration voltage and the dosage in consideration of the compositions, densities, thicknesses, and the like of the insulating layer 106 and the semiconductor layer 208.

For example, in the case where boron is supplied by an ion implantation method or a plasma ion doping method, the acceleration voltage can be, for example, higher than or equal to 5 kV and lower than or equal to 100 kV, preferably higher than or equal to 7 kV and lower than or equal to 70 kV, further preferably higher than or equal to 10 kV and lower than or equal to 50 kV. The dosage can be, for example, greater than or equal to 1×10¹³ ions/cm² and less than or equal to 1×10¹⁷ ions/cm², preferably greater than or equal to 1×10¹⁴ ions/cm² and less than or equal to 5×10¹⁶ ions/cm², further preferably greater than or equal to 1×10¹⁵ ions/cm² and less than or equal to 3×10¹⁶ ions/cm².

In the case where phosphorus is supplied by an ion implantation method or a plasma ion doping method, the acceleration voltage can be, for example, higher than or equal to 10 kV and lower than or equal to 100 kV, preferably higher than or equal to 30 kV and lower than or equal to 90 kV, further preferably higher than or equal to 40 kV and lower than or equal to 80 kV. The dosage can be, for example, greater than or equal to 1×10¹³ ions/cm² and less than or equal to 1×10¹⁷ ions/cm² , preferably greater than or equal to 1×10¹⁴ ions/cm² and less than or equal to 5×10¹⁶ ions/cm² , further preferably greater than or equal to 1×10¹⁵ ions/cm² and less than or equal to 3×10¹⁶ ions/cm².

Note that a method for supplying the impurity is not limited thereto; plasma treatment, treatment using thermal diffusion by heating, or the like can also be used, for example. In a plasma treatment method, plasma is generated in a gas atmosphere containing an impurity to be supplied and plasma treatment is performed, so that the impurity can be supplied. A dry etching apparatus, an ashing apparatus, a plasma CVD apparatus, a high-density plasma CVD apparatus, or the like can be used as an apparatus for generating the plasma.

For example, when plasma treatment is performed with a plasma CVD apparatus in an atmosphere containing a gas containing hydrogen, hydrogen can be supplied as the impurity to the region of the semiconductor layer 208 that does not overlap with the conductive layer 204. With the use of a plasma CVD apparatus for the supply of the impurity and the formation of the insulating layer 195, the supply of the impurity and the formation of the insulating layer 195 can be successively performed in the apparatus, so that the productivity can be increased.

The capacitor 150 is formed in a region where the conductive layer 202, the insulating layer 109, and the conductive layer 112b overlap with each other.

Next, the insulating layer 195 is formed to cover the conductive layer 104, the conductive layer 204, the conductive layer 212a, the conductive layer 212b, the insulating layer 106, and the semiconductor layer 208 (FIG. 1B and FIG. 1C). For the formation of the insulating layer 195, a PECVD method can be suitably used.

If the film formation temperature of the insulating layer 195 is too high, impurities contained in the region 108L, the region 208L, and the region 208D might be diffused into peripheral portions, which include the channel formation regions in the semiconductor layer 108 and the semiconductor layer 208. Furthermore, the electric resistance of the region 108L, the region 208L, and the region 208D might be increased. Thus, the film formation temperature of the insulating layer 195 is preferably determined in consideration of the impurity diffusion.

The film formation temperature of the insulating layer 195 is preferably higher than or equal to 150° C. and lower than or equal to 400° C., further preferably higher than or equal to 180° C. and lower than or equal to 360° C., still further preferably higher than or equal to 200° C. and lower than or equal to 250° C., for example. Formation of the insulating layer 195 at low temperatures enables the transistor to have favorable electrical characteristics even when it has a short channel length.

Heat treatment may be performed after the formation of the insulating layer 195. The heat treatment can further reduce the electric resistance of the region 108L, the region 208L, and the region 208D in some cases. For example, by the heat treatment, an impurity is diffused moderately, so that the region 208L and the region 208D each having an ideal concentration gradient of the impurity can be formed. The above description can be referred to for the heat treatment; thus, the detailed description thereof is omitted. Note that when the temperature of the heat treatment is too high (e.g., higher than or equal to 500° C.), the impurity might also be diffused into the channel formation region to degrade the electrical characteristics and reliability of the transistors.

Note that the heat treatment may be omitted. The heat treatment in this step may be omitted, and heat treatment performed in a later step may also serve as the heat treatment in this step. In the case where heat application treatment (e.g., a film formation step) is performed in a later step, such treatment can serve as the heat treatment in this step in some cases.

Through the above steps, the semiconductor device of one embodiment of the present invention can be manufactured.

### Manufacturing Method Example 2

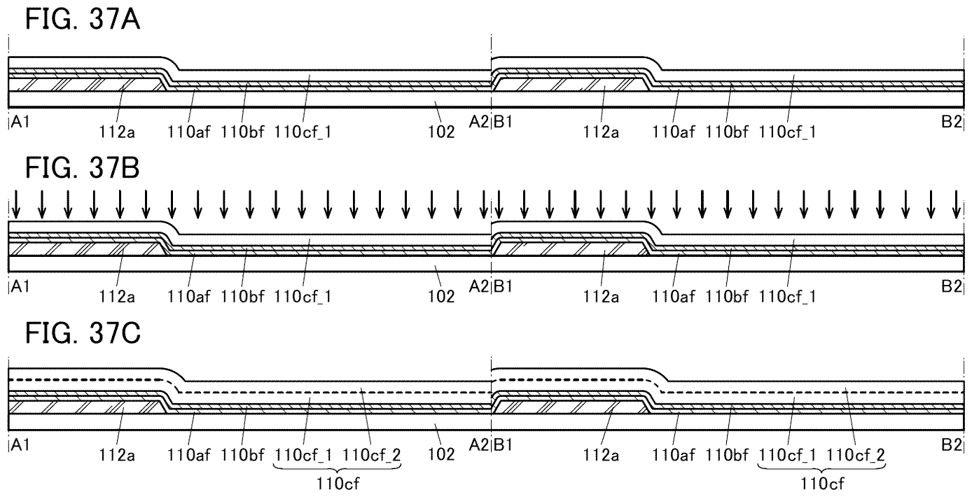

An example of a method for manufacturing the semiconductor device 10F illustrated in FIG. 15A to FIG. 15C is described. FIG. 37A to FIG. 37C each illustrate, side by side, a cross section along the dashed-dotted line A1-A2 illustrated in FIG. 15A and a cross section along the dashed-dotted line B1-B2 illustrated in FIG. 15B.

First, as in Manufacturing method example 1, the conductive layer 112a is formed.

Next, the insulating film 110af to be the insulating layer 110a, the insulating film 110bf to be the insulating layer 110b, and an insulating film 110cf_1 to be the insulating layer 110c_1 are formed over the conductive layer 112a (FIG. 37A).

Then, oxygen is supplied to the insulating film 110cf_1. The above description can be referred to for a method for supplying oxygen. For example, plasma treatment is preferably performed in an atmosphere containing one or more of oxygen, dinitrogen monoxide (N₂O), nitrogen dioxide (NO₂), carbon monoxide, and carbon dioxide. FIG. 37B schematically illustrates a state where oxygen is supplied to the insulating film 110cf_1 by arrows.

After the insulating film 110cf_1 is formed, the plasma treatment can be performed without exposure of the surface of the insulating film 110cf_1 to the air. For example, in the case where a PECVD apparatus is used for forming the insulating film 110cf_1, the plasma treatment is preferably performed with the PECVD apparatus. Accordingly, the productivity can be increased. Specifically, after the insulating film 110cf_1 is formed with the PECVD apparatus, plasma treatment can be successively performed.

Next, an insulating film 110cf_2 to be the insulating layer 110c_2 is formed over the insulating film 110cf_1 (FIG. 37C). Thus, the insulating film 110cf including the insulating film 110cf_1 and the insulating film 110cf_2 is formed.

Note that it is further preferable that formation of the insulating film 110cf_1, supply of oxygen to the insulating film 110cf_1, and formation of the insulating film 110cf_2 be successively performed. It is still further preferable that formation of the insulating film 110af, formation of the insulating film 110bf, formation of the insulating film 110cf_1, supply of oxygen to the insulating film 110cf_1, and formation of the insulating film 110cf_2 be successively performed. By successively performing these treatments with the same apparatus, the productivity can be increased. Attachment of atmospherically-derived impurities to the interface between the insulating films can be inhibited. For example, a PECVD apparatus can be suitably used for these treatments.

After the insulating film 110cf is formed, oxygen may be supplied to the insulating film 110cf. The above description can be referred to for the method for supplying oxygen.

Next, the insulating film 110df to be the insulating layer 110d is formed over the insulating film 110cf. Manufacturing method example 1 described above can be referred to for the steps after the formation of the insulating film 110df; thus, the detailed description thereof is omitted.

Through the above steps, the semiconductor device 10F of one embodiment of the present invention can be manufactured.

This embodiment can be combined with the other embodiments as appropriate.

### Embodiment 3

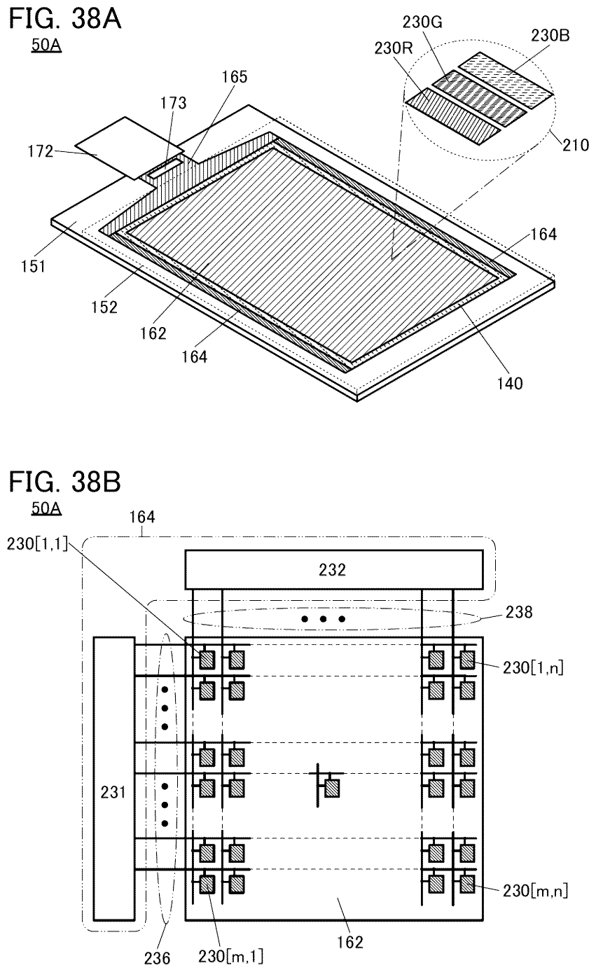

In this embodiment, display apparatuses of one embodiment of the present invention will be described with reference to FIG. 38 to FIG. 46.

The display apparatus of this embodiment can be a high-definition display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or laptop computer, a monitor of a computer or the like, digital signage, and a large game machine such as a pachinko machine.

The display apparatus of this embodiment can be a high-resolution display apparatus. Accordingly, the display apparatus of this embodiment can be used for display portions of information terminals (wearable devices) such as watch-type and bracelet-type information terminals and display portions of wearable devices capable of being worn on a head, such as a VR device like a head-mounted display (HMD) and a glasses-type AR device.

The semiconductor device of one embodiment of the present invention can be used for a display apparatus or a module including the display apparatus. Examples of the module including the display apparatus are a module in which a connector such as a flexible printed circuit board (hereinafter referred to as an FPC) or a tape carrier package (TCP) is attached to the display apparatus and a module in which the display apparatus is mounted with an integrated circuit (IC) by a chip on glass (COG) method, a chip on film (COF) method, or the like.

The display apparatus of this embodiment may have a function of a touch panel. The display apparatus can employ any of a variety of sensing elements (also referred to as sensor elements) that can sense proximity or touch of a sensing target such as a finger, for example.

Examples of a sensor type include a capacitive type, a resistive type, a surface acoustic wave type, an infrared type, an optical type, and a pressure-sensitive type.

Examples of the capacitive type include a surface capacitive type and a projected capacitive type. Examples of the projected capacitive type include a self-capacitive type and a mutual capacitive type. The use of a mutual capacitive type is preferable because multiple points can be sensed simultaneously.

Examples of a touch panel include an out-cell touch panel, an on-cell touch panel, and an in-cell touch panel. An in-cell touch panel has a structure where an electrode included in a sensor element is provided on one or both of a substrate supporting a display element (also referred to as a display device) and a counter substrate.

### Structure Example 1 of Display Apparatus

FIG. 38A is a perspective view of a display apparatus 50A.

In the display apparatus 50A, a substrate 152 and a substrate 151 are attached to each other. In FIG. 38A, the substrate 152 is denoted by a dashed line.

The display apparatus 50A includes a display portion 162, a connection portion 140, a circuit portion 164, a conductive layer 165, and the like. FIG. 38A illustrates an example where an IC 173 and an FPC 172 are mounted onto the display apparatus 50A. Thus, the structure illustrated in FIG. 38A can be regarded as a display module including the display apparatus 50A, the IC, and the FPC.

The connection portion 140 is provided outside the display portion 162. The connection portion 140 can be provided along one or more sides of the display portion 162. The number of the connection portions 140 can be one or more. FIG. 38A illustrates an example where the connection portion 140 is provided to surround the four sides of the display portion. In the connection portion 140, a common electrode of a display element is electrically connected to a conductive layer so that a potential can be supplied to the common electrode.

The circuit portion 164 includes a scan line driver circuit (also referred to as a gate driver), for example. The circuit portion 164 may include both a scan line driver circuit and a signal line driver circuit (also referred to as a source driver).

The conductive layer 165 has a function of supplying a signal and power to the display portion 162 and the circuit portion 164. The signal and power are input to the conductive layer 165 from the outside through the FPC 172 or input to the conductive layer 165 from the IC 173.

FIG. 38A illustrates an example where the IC 173 is provided on the substrate 151 by a COG method, a COF method, or the like. An IC including one or both of a scan line driver circuit and a signal line driver circuit can be used as the IC 173, for example. Note that the display apparatus 50A and the display module are not necessarily provided with an IC. The IC may be mounted on the FPC by a COF method or the like.

The semiconductor device of one embodiment of the present invention can be used for one or both of the display portion 162 and the circuit portion 164 of the display apparatus 50A, for example. An oxide semiconductor (OS) can be suitably used for a channel formation region of a transistor included in the display apparatus. By using an OS transistor, a display apparatus can have low power consumption. Alternatively, the semiconductor device of one embodiment of the present invention can be used for both the display portion 162 and the circuit portion 164, that is, all the transistors included in the display apparatus can be OS transistors. Using OS transistors as all the transistors included in the display apparatus as described above has an effect of reducing the manufacturing cost.

When the semiconductor device of one embodiment of the present invention is used for a pixel circuit of a display apparatus, for example, the area occupied by the pixel circuit can be reduced and a high-resolution display apparatus can be obtained. When the semiconductor device of one embodiment of the present invention is used for a driver circuit (e.g., one or both of a gate line driver circuit and a source line driver circuit) of a display apparatus, the area occupied by the driver circuit can be reduced and the display apparatus can have a narrow bezel, for example. Since the semiconductor device of one embodiment of the present invention has favorable electrical characteristics, a display apparatus can have increased reliability by using the semiconductor device.

The display portion 162 of the display apparatus 50A is a region where an image is to be displayed, and includes a plurality of pixels 210 that are periodically arranged. FIG. 38A is an enlarged view of one pixel 210.

There is no particular limitation on the arrangement of the pixels in the display apparatus of this embodiment, and a variety of methods can be employed. Examples of the arrangement of the pixels include stripe arrangement, S-stripe arrangement, matrix arrangement, delta arrangement, Bayer arrangement, and PenTile arrangement.

The pixel 210 illustrated in FIG. 38A includes a pixel 230R emitting red light, a pixel 230G emitting green light, and a pixel 230B emitting blue light. The pixel 230R, the pixel 230G, and the pixel 230B form one pixel 210, which achieves full-color display. The pixel 230R, the pixel 230G, and the pixel 230B each function as a subpixel. The display apparatus 50A illustrated in FIG. 38A shows an example where stripe arrangement is employed for pixels 230 each functioning as a subpixel. There is no particular limitation on the number of subpixels forming one pixel 210. For example, four subpixels emitting light of R, G, B, and white (W) may be included. Alternatively, four subpixels emitting light of four colors, R, G, B, and Y may be included.

The pixel 230R, the pixel 230G, and the pixel 230B each include a display element and a circuit for controlling the driving of the display element.

A variety of elements can be used as the display element, and a liquid crystal element or a light-emitting element can be used, for example. Alternatively, it is also possible to use, for example, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like. Alternatively, a QLED (Quantum-dot LED) employing a light source and color conversion technology using quantum dot materials may be used.

As examples of a display apparatus using a liquid crystal element, a transmissive liquid crystal display apparatus, a reflective liquid crystal display apparatus, and a transflective liquid crystal display apparatus can be given.

Examples of a mode that can be used for a display apparatus using a liquid crystal element include a vertical alignment (VA) mode, an FFS (Fringe Field Switching) mode, an IPS (In-Plane-Switching) mode, a TN (Twisted Nematic) mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, and a guest-host mode. Examples of the VA mode include an MVA (Multi-Domain Vertical Alignment) mode, a PVA (Patterned Vertical Alignment) mode, and an ASV (Advanced Super View) mode.

Examples of a liquid crystal material that can be used for the liquid crystal element include a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, and an anti-ferroelectric liquid crystal. These liquid crystal materials exhibit a cholesteric phase, a smectic phase, a cubic phase, a chiral nematic phase, an isotropic phase, a blue phase, or the like depending on conditions. As the liquid crystal material, either a positive liquid crystal or a negative liquid crystal may be used, and the selection can be made in accordance with the mode or design that is used.

Examples of the light-emitting element include a self-luminous light-emitting element such as an LED (Light Emitting Diode), an OLED (Organic LED), and a semiconductor laser. Examples of the LED include a mini LED and a micro LED.

Examples of a light-emitting substance contained in the light-emitting element include a substance emitting fluorescent light (a fluorescent material), a substance emitting phosphorescent light (a phosphorescent material), a substance exhibiting thermally activated delayed fluorescence (a thermally activated delayed fluorescence (TADF) material), and an inorganic compound (e.g., a quantum dot material).

The emission color of the light-emitting element can be infrared, red, green, blue, cyan, magenta, yellow, white, or the like. When the light-emitting element has a microcavity structure, the color purity can be increased.

One electrode of the pair of electrodes included in the light-emitting element functions as an anode, and the other electrode functions as a cathode.

The display apparatus of one embodiment of the present invention can have any of the following structures: a top-emission structure where light is emitted in a direction opposite to the substrate where the light-emitting element is formed, a bottom-emission structure where light is emitted toward the substrate where the light-emitting element is formed, and a dual-emission structure where light is emitted toward both surfaces.

In this embodiment, the case where a light-emitting element is used as the display element is mainly described as an example.

FIG. 38B is a block diagram illustrating the display apparatus 50A. The display apparatus 50A includes the display portion 162 and the circuit portion 164. The display portion 162 includes a plurality of the pixels 230 arranged periodically (a pixel 230[1,1] to a pixel 230[m, n], where each of m and n is independently an integer greater than or equal to 2). The circuit portion 164 includes a first driver circuit portion 231 and a second driver circuit portion 232.

A circuit included in the first driver circuit portion 231 functions as, for example, a scan line driver circuit. A circuit included in the second driver circuit portion 232 functions as, for example, a signal line driver circuit. Note that some sort of circuit may be provided at a position facing the first driver circuit portion 231 with the display portion 162 therebetween. Some sort of circuit may be provided at a position facing the second driver circuit portion 232 with the display portion 162 therebetween.

Any of various circuits such as a shift register circuit, a level shifter circuit, an inverter circuit, a latch circuit, an analog switch circuit, a demultiplexer circuit, and a logic circuit can be used for the circuit portion 164. In the circuit portion 164, a transistor, a capacitor, and the like can be used. Transistors included in the circuit portion 164 may be formed in the same step as transistors included in the pixels 230.

The display apparatus 50A includes wirings 236 which are arranged substantially parallel to each other and whose potentials are controlled by the circuits included in the first driver circuit portion 231, and wirings 238 which are arranged substantially parallel to each other and whose potentials are controlled by the circuits included in the second driver circuit portion 232. FIG. 38B illustrates an example where the wirings 236 and the wirings 238 are connected to the pixels 230. Note that the wirings 236 and the wirings 238 are examples, and the wirings connected to the pixels 230 are not limited to the wirings 236 and the wirings 238.

In the semiconductor device of one embodiment of the present invention, some formation steps can be common between a vertical transistor (VFET) having a short channel length and a high on-state current and a TGSA transistor having a long channel length and favorable saturation characteristics. An oxide semiconductor (OS) can be suitably used for the channel formation regions of these transistors, so that the transistors can have a low off-state current. The semiconductor device of one embodiment of the present invention can be used for one or both of the display portion 162 and the circuit portion 164. Alternatively, the semiconductor device of one embodiment of the present invention can be used for both the display portion 162 and the circuit portion 164, that is, all the transistors included in the display apparatus can be OS transistors. Using OS transistors as all the transistors included in the display apparatus as described above has an effect of reducing the manufacturing cost.

### Structure Example of Driver Circuit

Using a latch circuit as an example, a structure example of a circuit that can be used as a driver circuit will be described.

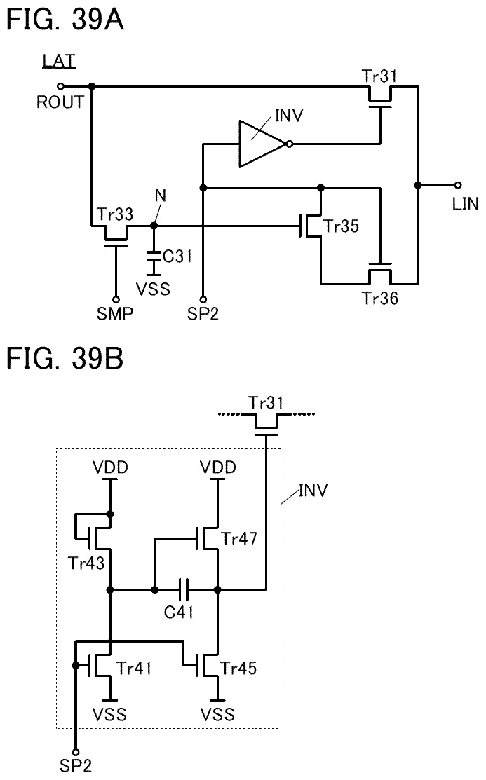

FIG. 39A is a circuit diagram illustrating a structure example of a latch circuit LAT. The latch circuit LAT illustrated in FIG. 39A includes a transistor Tr31, a transistor Tr33, a transistor Tr35, a transistor Tr36, a capacitor C31, and an inverter circuit INV. In FIG. 39A, a node where one of a source and a drain of the transistor Tr33, a gate of the transistor Tr35, and one electrode of the capacitor C31 are electrically connected to each other is referred to as a node N.

In the latch circuit LAT illustrated in FIG. 39A, when a high-potential signal is input to a terminal SMP, the transistor Tr33 is turned on. Thus, the potential of the node N becomes a potential corresponding to the potential of a terminal ROUT, and data corresponding to a signal input from the terminal ROUT to the latch circuit LAT is written to the latch circuit LAT. After data is written to the latch circuit LAT, the potential of the terminal SMP is set to a low potential, so that the transistor Tr33 is turned off. Thus, the potential of the node N is retained and the data written to the latch circuit LAT is retained. Specifically, when the potential of the node N is a low potential, data having a value “0” is retained in the latch circuit LAT and when the potential of the node N is a high potential, data having a value “1” is retained in the latch circuit LAT, for example.

A transistor with a low off-state current is preferably used as the transistor Tr33. An OS transistor can be suitably used as the transistor Tr33. In that case, the latch circuit LAT can retain data for a long period. Thus, the frequency of rewriting data to the latch circuit LAT can be lowered.

In this specification and the like, writing data to the latch circuit LAT such that a signal input from a terminal SP2 is output to the terminal LIN is simply referred to as “writing data to the latch circuit LAT”, in some cases. That is, writing data having a value “1”, for example, to the latch circuit LAT is simply referred to as “writing data to the latch circuit LAT”, in some cases.

The semiconductor device of one embodiment of the present invention can be suitably used for the latch circuit LAT. For example, the transistor 100 or the transistor 200 illustrated in FIG. 1B and the like can be used as one or more of the transistor Tr31, the transistor Tr33, the transistor Tr35, and the transistor Tr36.

FIG. 39B illustrates a structure example of the inverter circuit INV. The inverter circuit INV includes a transistor Tr41, a transistor Tr43, a transistor Tr45, a transistor Tr47, and a capacitor C41.

When the latch circuit LAT has the structure illustrated in FIG. 39A and the inverter circuit INV has the structure illustrated in FIG. 39B, all the transistors included in the latch circuit LAT can be transistors having the same polarity, for example, n-channel transistors. In that case, the transistor Tr31, the transistor Tr35, the transistor Tr36, the transistor Tr41, the transistor Tr43, the transistor Tr45, and the transistor Tr47 as well as the transistor Tr33 can be OS transistors, for example. Accordingly, all the transistors included in the latch circuit LAT can be formed in the same step.

The semiconductor device of one embodiment of the present invention can be suitably used for the inverter circuit INV. For example, the transistor 100 or the transistor 200 illustrated in FIG. 1B and the like can be used as one or more of the transistor Tr41, the transistor Tr43, the transistor Tr45, and the transistor Tr47.

Using one or more types of transistors among the transistor 100 to the transistor 100G can reduce the occupied area, so that a display apparatus with a narrow bezel can be obtained. One or more types of transistors among the transistor 100 to the transistor 100G can be suitably used as the transistors that are required to have a high on-state current. Furthermore, one or more types of transistors among the transistor 200 to the transistor 200F can be suitably used as the transistors that are required to have favorable saturation characteristics. In that case, a high-performance display apparatus can be provided.

### Structure Example 1 of Pixel Circuit

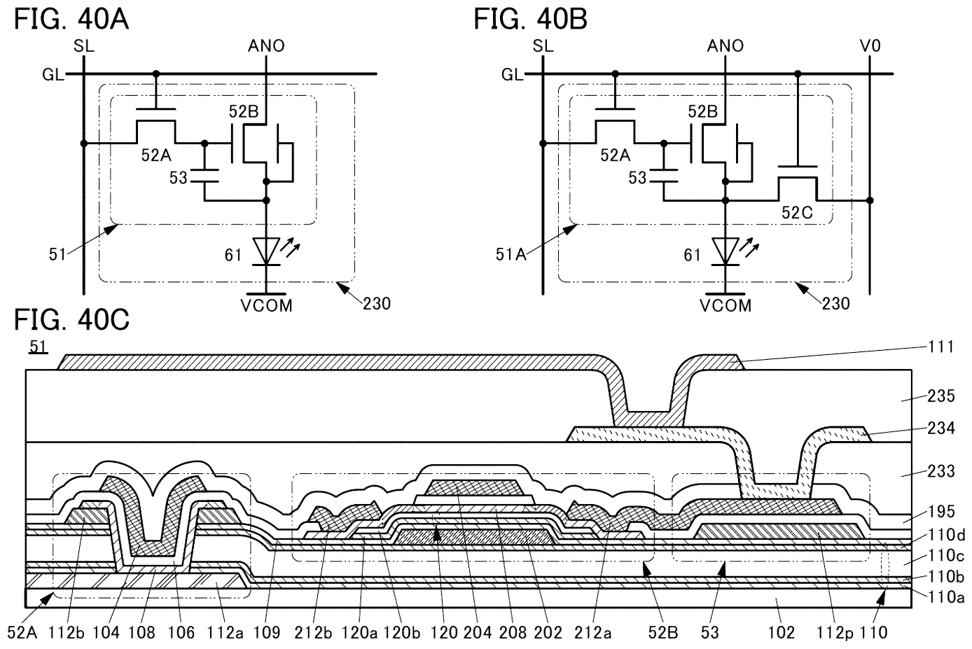

FIG. 40A illustrates a structure example of the pixel 230. The pixel 230 includes a pixel circuit 51 and a light-emitting device 61.

The pixel circuit 51 illustrated in FIG. 40A includes a transistor 52A, a transistor 52B, and a capacitor 53. The pixel circuit 51 is a 2Tr1C-type pixel circuit including two transistors and one capacitor. Note that there is no particular limitation on the pixel circuit that can be used for the display apparatus of one embodiment of the present invention.

An anode of the light-emitting device 61 is electrically connected to one of a source and a drain of the transistor 52B and one electrode of the capacitor 53. The other of the source and the drain of the transistor 52B is electrically connected to a wiring ANO. A gate of the transistor 52B is electrically connected to one of a source and a drain of the transistor 52A and the other electrode of the capacitor 53. The other of the source and the drain of the transistor 52A is electrically connected to a wiring GL. A gate of the transistor 52A is electrically connected to the wiring GL. A cathode of the light-emitting device 61 is electrically connected to a wiring VCOM.

The wiring GL corresponds to the wiring 236, and the wiring SL corresponds to the wiring 238. The wiring VCOM is a wiring supplying a potential for supplying a current to the light-emitting device 61. The transistor 52A has a function of controlling electrical continuity and discontinuity between the wiring SL and the gate of the transistor 52B in accordance with the potential of the wiring GL. For example, VDD is supplied to the wiring ANO, and VSS is supplied to the wiring VCOM.

The transistor 52B has a function of controlling the amount of current flowing through the light-emitting device 61. The capacitor 53 has a function of retaining a gate potential of the transistor 52B. The intensity of light emitted by the light-emitting device 61 is controlled in accordance with an image signal supplied to the gate of the transistor 52B.

Some or all of the transistors included in the pixel circuit 51 can be provided with back gates. In the pixel circuit 51 illustrated in FIG. 40A, the transistor 52B includes a back gate, and the back gate is electrically connected to one of the source and the drain of the transistor 52B. Note that a structure where the back gate of the transistor 52B is electrically connected to the gate of the transistor 52B can be employed.

The above-described semiconductor device can be suitably used for the pixel circuit 51. The transistor 52B functioning as a driving transistor that controls a current flowing through the light-emitting device 61 preferably has more favorable saturation characteristics than the transistor 52A functioning as a selection transistor for controlling a selection state of the pixel 230. The use of one type of transistor among the transistor 200 to the transistor 200F having a long channel length as the transistor 52B enables the display apparatus to have high reliability. Furthermore, the use of one type of transistor among the transistor 100 to the transistor 100G as the transistor 52A can reduce the area occupied by the pixel circuit 51A, so that the display apparatus can have high resolution.

Note that one type of transistor among the transistor 100 to the transistor 100G can also be used as the transistor 52B. The use of the transistor having a short channel length as the transistor 52B enables the display apparatus to have high luminance. Furthermore, the area occupied by the pixel circuit 51 can be reduced, so that a high-resolution display apparatus can be obtained.

FIG. 40B illustrates a structure example of the pixel 230 different from that illustrated in FIG. 40A. The pixel 230 includes the pixel circuit 51A and the light-emitting device 61.

The pixel circuit 51A illustrated in FIG. 40B is different from the pixel circuit 51 illustrated in FIG. 40A mainly in including a transistor 52C. The pixel circuit 51A includes the transistor 52A, the transistor 52B, the transistor 52C, and the capacitor 53. The pixel circuit 51A is a 3Tr1C-type pixel circuit including three transistors and one capacitor.

One of a source and a drain of the transistor 52C is electrically connected to the one of the source and the drain of the transistor 52B. The other of the source and the drain of the transistor 52C is electrically connected to a wiring V0. For example, a reference potential is supplied to the wiring V0. A gate of the transistor 52C is electrically connected to the wiring GL.

The transistor 52C has a function of controlling electrical continuity and discontinuity between the wiring V0 and the one of the source electrode and the drain electrode of the transistor 52B in accordance with the potential of the wiring GL. Variation in the gate-source potential of the transistor 52B can be inhibited by the reference potential of the wiring V0 supplied through the transistor 52C.

A current value that can be used for setting pixel parameters can be obtained with the use of the wiring V0. Specifically, the wiring V0 can function as a monitor line for outputting, to the outside, a current flowing through the transistor 52B or a current flowing through the light-emitting device 61. A current output to the wiring V0 is converted into a voltage by a source follower circuit and can be output to the outside. Alternatively, the current is converted into a digital signal by an A/D converter, and can be output to the outside.

The above-described semiconductor device can be suitably used for the pixel circuit 51A. The use of one type of transistor among the transistor 200 to the transistor 200F having a long channel length as the transistor 52B enables the display apparatus to have high reliability. Furthermore, the use of one or more types of transistors among the transistor 100 to the transistor 100G as the transistor 52A and the transistor 52C can reduce the area occupied by the pixel circuit 51A, so that the display apparatus can have high resolution. Note that one type of transistor among the transistor 100 to the transistor 100G can also be used as the transistor 52B.

FIG. 40C illustrates a structure example of the pixel circuit 51. FIG. 40C is a cross-sectional view of the pixel circuit 51. FIG. 40C selectively illustrates the transistor 52A, the transistor 52B, the capacitor 53, and the pixel electrode included in the light-emitting device 61. Note that the electrical connection between the transistor 52A and the transistor 52B is not illustrated.

The transistor 52A includes the conductive layer 104, the insulating layer 106, the semiconductor layer 108, the conductive layer 112a, and the conductive layer 112b. The transistor 52B includes the conductive layer 202, the insulating layer 106, the semiconductor layer 208, the insulating layer 120, the conductive layer 204, the conductive layer 212a, and the conductive layer 212b. The above description can be referred to for the transistor 52A and the transistor 52B; thus, the detailed description thereof is omitted.

The capacitor 53 includes the conductive layer 212a, a conductive layer 112p, and the insulating layer 106 interposed therebetween. The conductive layer 112p is provided over the insulating layer 120. The conductive layer 112p can be formed in the same step as the conductive layer 112b, for example. The insulating layer 106 is provided over the conductive layer 112p, and the conductive layer 212a is provided over the insulating layer 106. The conductive layer 212a functions as one of the source electrode and the drain electrode of the transistor 52B and functions as one electrode of the capacitor 53. Note that there is no particular limitation on the structure of the capacitor 53.

The insulating layer 195 is provided to cover the transistor 52A, the transistor 52B, and the capacitor 53, an insulating layer 233 is provided to cover the insulating layer 195, and an insulating layer 235 is provided to cover the insulating layer 233. The light-emitting device 61 can be provided over the insulating layer 235. FIG. 40C illustrates a pixel electrode 111 functioning as one electrode of the light-emitting device 61. The insulating layer 195 and the insulating layer 233 include a first opening reaching the conductive layer 212a, and a conductive layer 234 is provided to cover the first opening. The conductive layer 234 is electrically connected to the conductive layer 212a through the first opening. The insulating layer 235 includes a second opening reaching the conductive layer 234, and the pixel electrode 111 is provided to cover the second opening. The pixel electrode 111 is electrically connected to the conductive layer 234 through the second opening. The above description can be referred to for the insulating layer 195; thus, the detailed description thereof is omitted. The insulating layer 233 and the insulating layer 235 have a function of reducing unevenness due to the transistor 52A, the transistor 52B, and the transistor 52C and making the formation surface of the light-emitting device 61 flatter. Note that in this specification and the like, each of the insulating layer 233 and the insulating layer 235 is referred to as a planarization layer in some cases.

An organic insulating film is suitable for each of the insulating layer 233 and the insulating layer 235. Examples of a material that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 235 can have a stacked-layer structure of an organic insulating film and an inorganic insulating film. The insulating layer 235 preferably has a stacked-layer structure of an organic insulating film and an inorganic insulating film over the organic insulating film. Thus, the inorganic insulating film can function as an etching protective layer at the time of forming the light-emitting device 61. Specifically, partial etching of the insulating layer 235, which forms a depressed portion in the insulating layer 235, can be inhibited at the time of forming the pixel electrode 111. Alternatively, a depressed portion may be formed in the insulating layer 235 at the time of forming the pixel electrode 111. Similarly, the insulating layer 233 may have a stacked-layer structure of an organic insulating film and an inorganic insulating film.

### Structure Example 2 of Pixel Circuit

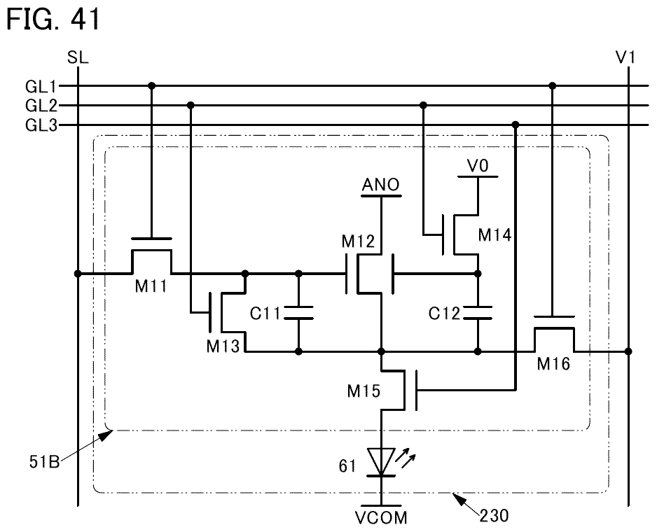

FIG. 41 illustrates a structure example different from that of the above-described pixel 230. The pixel 230 includes a pixel circuit 51B and the light-emitting device 61.

The pixel circuit 51B includes a transistor M11, a transistor M12, a transistor M13, a transistor M14, a transistor M15, a transistor M16, a capacitor C11, and a capacitor C12. The pixel circuit 51B is a 6Tr2C-type pixel circuit including six transistors and two capacitors.

The anode of the light-emitting device 61 is electrically connected to one of a source and a drain of the transistor M15. The cathode of the light-emitting device 61 is electrically connected to the wiring VCOM. The other of the source and the drain of the transistor M15 is electrically connected to one of a source and a drain of the transistor M12, one of a source and a drain of the transistor M13, one of a source and a drain of the transistor M16, one electrode of the capacitor C11, and one electrode of the capacitor C12. A gate of the transistor M12 is electrically connected to one of a source and a drain of the transistor M11, the other of the source and the drain of the transistor M13, and the other electrode of the capacitor C11. A back gate of the transistor M12 is electrically connected to one of a source and a drain of the transistor M14 and the other electrode of the capacitor C12.

The other of the source and the drain of the transistor M11 is electrically connected to the wiring SL. The other of the source and the drain of the transistor M12 is electrically connected to the wiring ANO. The other of the source and the drain of the transistor M14 is electrically connected to the wiring V0. The other of the source and the drain of the transistor M16 is electrically connected to a wiring V1. For example, a constant potential is supplied to the wiring V1. A gate of the transistor M11 and a gate of the transistor M16 are electrically connected to a wiring GL1. A gate of the transistor M13 and a gate of the transistor M14 are electrically connected to a wiring GL2. A gate of the transistor M15 is electrically connected to a wiring GL3.

The transistor M11 functions as a selection transistor that controls electrical continuity and discontinuity between the gate of the transistor M12 and the wiring SL. The transistor M12 functions as a driving transistor that controls current flowing through the light-emitting device 61. The transistor M14 has a function of supplying a potential of the wiring V0 to the back gate of the transistor M12. When a constant potential is supplied to the back gate of the transistor M12, the threshold voltage can be controlled. The capacitor C11 has a function of retaining a gate potential of the transistor M12. The capacitor C12 has a function of retaining a back gate potential of the transistor M12. The pixel circuit 51B has a function of correcting the threshold voltage of the transistor M12 with use of the back gate thereof, what is called an internal correcting function of the threshold voltage. Specifically, a back gate potential that makes the threshold voltage of the transistor M12 be 0 V is retained in the capacitor C12. Accordingly, regardless of variation in the threshold voltage and over-time deterioration of the transistor, the threshold voltage of the transistor M12 can be corrected to be constant at 0 V or the vicinity thereof.

The above-described semiconductor device can be suitably used for the pixel circuit 51B. For example, one or more types of transistors among the transistor 100 to the transistor 100G illustrated in FIG. 1B and the like can be used as the transistor M11, the transistor M13, the transistor M14, the transistor M15, and the transistor M16, and one or more types of transistors among the transistor 200 to the transistor 200F can be used as the transistor M12.

The transistor M12 functioning as a driving transistor preferably has favorable saturation characteristics. When one type of transistor among the transistor 200 to the transistor 200F having a long channel length is used as the transistor M12, a highly reliable display apparatus can be obtained. Furthermore, when one or more types of transistors among the transistor 100 to the transistor 100G are used as the transistor M11, the transistor M13, the transistor M14, the transistor M15, and the transistor M16, the area occupied by the pixel circuit 51B can be reduced, so that a high-resolution display apparatus can be obtained.

Note that one type of transistor among the transistor 100 to the transistor 100G can also be used as the transistor M12. The use of the transistor having a short channel length as the transistor M12 enables the display apparatus to have high luminance. Furthermore, the area occupied by the pixel circuit 51B can be reduced, so that a high-resolution display apparatus can be obtained.

The use of a plurality of transistors and a plurality of capacitors in the pixel circuit achieves a high-performance display apparatus. With the use of the semiconductor device of one embodiment of the present invention, the occupation area can be reduced even when the numbers of the transistors and the capacitors are increased, so that a high-performance and high-resolution display apparatus can be obtained. For example, the resolution of the display apparatus can be higher than or equal to 300 ppi, higher than or equal to 500 ppi, higher than or equal to 1000 ppi, higher than or equal to 2000 ppi, or higher than or equal to 3000 ppi.

Since the occupation area can be reduced with the use of the semiconductor device of one embodiment of the present invention, the aperture ratio of a pixel can be increased in a display apparatus having a bottom-emission structure. For example, the aperture ratio can be higher than or equal to 50%, higher than or equal to 55%, or higher than or equal to 60% in the display apparatus.

In this specification and the like, the aperture ratio refers to a ratio of the area of a region, where light is emitted, to the area of a pixel.

### Structure Example 1 of Display Apparatus

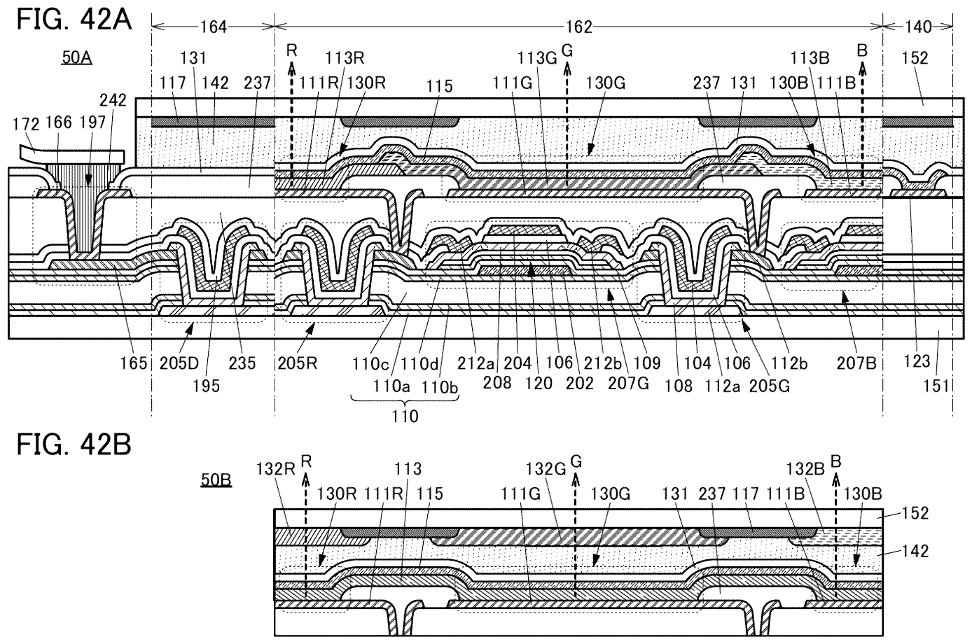

FIG. 42A illustrates an example of cross sections of part of a region including the FPC 172, part of the circuit portion 164, part of the display portion 162, part of the connection portion 140, and part of a region including an end portion of the display apparatus 50A.

The display apparatus 50A illustrated in FIG. 42A includes a transistor 205D, a transistor 205R, a transistor 205G, a transistor 207G, a transistor 207B, a light-emitting element 130R, a light-emitting element 130G, a light-emitting element 130B, and the like between the substrate 151 and the substrate 152. The light-emitting element 130R is a display element included in the pixel 230R emitting red light, the light-emitting element 130G is a display element included in the pixel 230G emitting green light, and the light-emitting element 130B is a display element included in the pixel 230B emitting blue light.

The display apparatus 50A employs an SBS structure. The SBS structure can optimize materials and structures of light-emitting elements and thus can increase the degree of freedom in selecting materials and structures, so that the luminance and the reliability can be easily improved.

The display apparatus 50A has a top-emission structure. The aperture ratio of pixels in a top-emission structure can be higher than that of pixels in a bottom-emission structure because a transistor and the like can be placed to overlap with a light-emitting region of a light-emitting element in the top-emission structure.

All of the transistor 205D, the transistor 205R, the transistor 205G, the transistor 207G, and the transistor 207B are formed over the substrate 151. Some of the formation steps can be common between these transistors.

One or more types of transistors among the transistor 100 to the transistor 100G and the transistor 200 to the transistor 200F described above can be used as one or more of the transistor 205D, the transistor 205R, the transistor 205G, the transistor 207G, and the transistor 207B. FIG. 42A illustrates a structure example where the above-described transistor 100 is used as each of the transistor 205D, the transistor 205R, and the transistor 205G and the above-described transistor 200 is used as each of the transistor 207G and the transistor 207B.

When one or more types of transistors among the transistor 100 to the transistor 100G described above are used as the transistor provided in the display portion 162, a high-resolution display apparatus can be obtained. One or more types of transistors among the transistor 200 to the transistor 200F with favorable saturation characteristics can be suitably used as the driving transistor of the light-emitting element 130. In that case, a highly reliable display apparatus can be obtained.

When one or more types of transistors among the transistor 100 to the transistor 100G described above are used in the circuit portion 164, the display apparatus can operate at high speed. The transistor provided in the circuit portion 164 is sometimes required to have a higher on-state current than the transistor provided in the display portion 162. A transistor having a short channel length is preferably used in the circuit portion 164. For example, one or more types of transistors among the transistor 100 to the transistor 100G described above can be suitably used in the circuit portion 164. When one or more types of transistors among the transistor 100 to the transistor 100G are used in the circuit portion 164, the occupied area can be reduced, so that the display apparatus can have a narrow bezel. Note that one or more types of transistors among the transistor 200 to the transistor 200F can be used in the circuit portion 164.

Note that the transistor included in the display apparatus of this embodiment is not limited to the transistor included in the semiconductor device of one embodiment of the present invention. For example, the display apparatus of this embodiment may include the transistor included in the semiconductor device of one embodiment of the present invention and a transistor having another structure in combination. The display apparatus of this embodiment may include any one or more of a planar transistor, a staggered transistor, and an inverted staggered transistor. A transistor included in the display apparatus of this embodiment may have either a top-gate structure or a bottom-gate structure. Alternatively, gates may be provided above and below the semiconductor layer where a channel is formed.

An OS transistor can be suitably used as each of the transistor 205D, the transistor 205R, the transistor 205G, the transistor 207G, and the transistor 207B.

A Si transistor may be included in the display apparatus of this embodiment.

To increase the emission luminance of the light-emitting element included in the pixel circuit, the amount of current flowing through the light-emitting element needs to be increased. To increase the amount of current, the source-drain voltage of a driving transistor included in the pixel circuit needs to be increased. Since an OS transistor has a higher withstand voltage between the source and the drain than a Si transistor, a high voltage can be applied between the source and the drain of the OS transistor. Accordingly, when an OS transistor is used as the driving transistor included in the pixel circuit, the amount of current flowing through the light-emitting element can be increased, so that the emission luminance of the light-emitting element can be increased.

When a transistor operates in a saturation region, a change in source-drain current relative to a change in gate-source voltage can be smaller in an OS transistor than in a Si transistor. Accordingly, when an OS transistor is used as the driving transistor included in the pixel circuit, the amount of current flowing between the source and the drain can be set minutely by a change in gate-source voltage; hence, the amount of current flowing through the light-emitting element can be controlled. Accordingly, the number of gray levels in the pixel circuit can be increased.

Regarding saturation characteristics of current flowing when a transistor operates in a saturation region, even in the case where the source-drain voltage of an OS transistor increases gradually, more stable current (saturation current) can be made to flow through an OS transistor than through a Si transistor. Thus, by using an OS transistor as the driving transistor, a stable current can be made to flow through a light-emitting element even when the current-voltage characteristics of a light-emitting element vary, for example. In other words, when the OS transistor operates in the saturation region, the source-drain current hardly changes with a change in the source-drain voltage; hence, the emission luminance of the light-emitting element can be stable.

The transistors included in the circuit portion 164 and the transistors included in the display portion 162 may have the same structure or different structures. A plurality of transistors included in the circuit portion 164 may have the same structure or two or more kinds of structures. Similarly, a plurality of transistors included in the display portion 162 may have the same structure or two or more kinds of structures.

All of the transistors included in the display portion 162 may be OS transistors or all of the transistors included in the display portion 162 may be Si transistors; alternatively, some of the transistors included in the display portion 162 may be OS transistors and the others may be Si transistors.

For example, when both an LTPS transistor and an OS transistor are used in the display portion 162, the display apparatus can have low power consumption and high drive capability. A structure where an LTPS transistor and an OS transistor are used in combination is referred to as LTPO in some cases. As a more suitable example, a structure where the OS transistor is used as a transistor or the like functioning as a switch for controlling electrical continuity and discontinuity between wirings, and the LTPS transistor is used as a transistor or the like for controlling current, can be given.

For example, one of the transistors included in the display portion 162 functions as a transistor for controlling current flowing through the light-emitting element and can also be referred to as a driving transistor. One of a source and a drain of the driving transistor is electrically connected to a pixel electrode of the light-emitting element. An LTPS transistor is preferably used as the driving transistor. In that case, the amount of current flowing through the light-emitting element can be increased in the pixel circuit.

By contrast, another transistor included in the display portion 162 functions as a switch for controlling selection or non-selection of a pixel and can also be referred to as a selection transistor. A gate of the selection transistor is electrically connected to a gate line, and one of a source and a drain thereof is electrically connected to a source line (signal line). An OS transistor is preferably used as the selection transistor. Accordingly, the gray level of the pixel can be maintained even with an extremely low frame frequency (e.g., lower than or equal to 1 fps); thus, power consumption can be reduced by stopping the driver in displaying a still image.

The insulating layer 195 is provided to cover the transistor 205D, the transistor 205R, the transistor 205G, the transistor 207G, and the transistor 207B, and the insulating layer 235 is provided over the insulating layer 195.

The light-emitting elements 130R, 130G, and 130B are provided over the insulating layer 235.

The light-emitting element 130R includes the pixel electrode 111R over the insulating layer 235, an EL layer 113R over the pixel electrode 111R, and a common electrode 115 over the EL layer 113R. The light-emitting element 130R illustrated in FIG. 42A emits red light (R). The EL layer 113R includes a light-emitting layer emitting red light.

The light-emitting element 130G includes the pixel electrode 111G over the insulating layer 235, an EL layer 113G over the pixel electrode 111G, and the common electrode 115 over the EL layer 113G. The light-emitting element 130G illustrated in FIG. 42A emits green light (G). The EL layer 113G includes a light-emitting layer emitting green light.

The light-emitting element 130B includes the pixel electrode 111B over the insulating layer 235, an EL layer 113B over the pixel electrode 111B, and the common electrode 115 over the EL layer 113B. The light-emitting element 130B illustrated in FIG. 42A emits blue light (B). The EL layer 113B includes a light-emitting layer emitting blue light.

Although the EL layers 113R, 113G, and 113B have the same thickness in FIG. 42A, the present invention is not limited thereto. The EL layers 113R, 113G, and 113B may have different thicknesses. For example, the thicknesses of the EL layers 113R, 113G, and 113B are preferably set to match an optical path length that intensifies light emitted from each EL layer. Accordingly, a microcavity structure is achieved, and the color purity of light emitted from each light-emitting element can be improved.

The pixel electrode 111R is electrically connected to the conductive layer 112b included in the transistor 205R through an opening provided in the insulating layer 106, the insulating layer 195, and the insulating layer 235. Similarly, the pixel electrode 111G is electrically connected to the conductive layer 112b included in the transistor 205G, and the pixel electrode 111B is electrically connected to the conductive layer 112b included in the transistor 205B (not illustrated).

End portions of the pixel electrodes 111R, 111G, and 111B are covered with an insulating layer 237. The insulating layer 237 functions as a partition wall. The insulating layer 237 can be provided to have a single-layer structure or a stacked-layer structure using one or both of an inorganic insulating material and an organic insulating material. A material that can be used for the insulating layer 195 and a material that can be used for the insulating layer 235 can be used for the insulating layer 237, for example. With the insulating layer 237, the pixel electrode and the common electrode can be electrically insulated from each other. Furthermore, with the insulating layer 237, adjacent light-emitting elements can be electrically insulated from each other.

The insulating layer 237 is provided in at least the display portion 162. The insulating layer 237 may be provided in not only the display portion 162 but also the connection portion 140 and the circuit portion 164. The insulating layer 237 may be provided to extend to the end portion of the display apparatus 50A.

The common electrode 115 is a continuous film provided to be shared by the light-emitting elements 130R, 130G, and 130B. The common electrode 115 shared by the plurality of light-emitting elements is electrically connected to a conductive layer 123 provided in the connection portion 140. The conductive layer 123 is preferably formed using a conductive layer formed using the same material in the same step as the pixel electrodes 111R, 111G, and 111B.

In the display apparatus of one embodiment of the present invention, a conductive film transmitting visible light is used for the electrode through which light is extracted, which is either the pixel electrode or the common electrode. A conductive film reflecting visible light is preferably used for the electrode through which light is not extracted.

A conductive film transmitting visible light may be used also for the electrode through which light is not extracted. In that case, this electrode is preferably provided between a reflective layer and the EL layer. In other words, light emitted from the EL layer may be reflected by the reflective layer to be extracted from the display apparatus.

As a material forming the pair of electrodes of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing appropriate combination of any of these metals. Other examples of the material include indium tin oxide (also referred to as In—Sn oxide or ITO), In—Si—Sn oxide (also referred to as ITSO), indium zinc oxide (In—Zn oxide), and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The light-emitting element preferably employs a microcavity structure. Thus, one of the pair of electrodes of the light-emitting element is preferably an electrode having properties of transmitting and reflecting visible light (a transflective electrode), and the other is preferably an electrode having a property of reflecting visible light (a reflective electrode). When the light-emitting element has a microcavity structure, light obtained from the light-emitting layer can be resonated between the electrodes, whereby light emitted from the light-emitting element can be intensified.

A transparent electrode has a light transmittance higher than or equal to 40%. For example, an electrode having a visible light (light with wavelengths greater than or equal to 400 nm and less than 750 nm) transmittance higher than or equal to 40% is preferably used as the transparent electrode of the light-emitting element. The transflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have an electrical resistivity lower than or equal to 1×10⁻² Ωcm.

The EL layers 113R, 113G, and 113B are each provided to have an island shape. In FIG. 42A, an end portion of the EL layer 113R and an end portion of the EL layer 113G that are adjacent to each other overlap with each other, an end portion of the EL layer 113G and an end portion of the EL layer 113B that are adjacent to each other overlap with each other, and an end portion of the EL layer 113R and an end portion of the EL layer 113B that are adjacent to each other overlap with each other. When island-shaped EL layers are formed using a fine metal mask, end portions of the EL layers adjacent to each other may overlap with each other as illustrated in FIG. 42A; however, the present invention is not limited thereto. That is, it is also possible that the EL layers adjacent to each other do not overlap with each other and are apart from each other. Furthermore, both a portion where the EL layers adjacent to each other overlap with each other and a portion where the EL layers adjacent to each other do not overlap with each other and are apart from each other may exist in the display apparatus.

Each of the EL layers 113R, 113G, and 113B includes at least a light-emitting layer. The light-emitting layer contains one or more kinds of light-emitting substances. As the light-emitting substance, a substance whose emission color is blue, violet, bluish violet, green, yellow green, yellow, orange, red, or the like is appropriately used. Alternatively, as the light-emitting substance, a substance emitting near-infrared light can be used.

Examples of the light-emitting substance include a fluorescent material, a phosphorescent material, a TADF material, and a quantum dot material.

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

The light-emitting layer preferably includes a phosphorescent material and a combination of a hole-transport material and an electron-transport material that easily forms an exciplex, for example. With such a structure, light emission can be efficiently obtained by ExTET (Exciplex-Triplet Energy Transfer), which is energy transfer from the exciplex to the light-emitting substance (phosphorescent material). When a combination of materials is selected to form an exciplex emitting light whose wavelength overlaps with the wavelength of a lowest-energy-side absorption band of the light-emitting substance, energy can be transferred smoothly and light emission can be obtained efficiently. With this structure, high efficiency, low-voltage driving, and a long lifetime of the light-emitting element can be achieved at the same time.

In addition to the light-emitting layer, the EL layer can include one or more of a layer containing a substance with a high hole-injection property (a hole-injection layer), a layer containing a hole-transport material (a hole-transport layer), a layer containing a substance with a high electron-blocking property (an electron-blocking layer), a layer containing a substance with a high electron-injection property (an electron-injection layer), a layer containing an electron-transport material (an electron-transport layer), and a layer containing a substance with a high hole-blocking property (a hole-blocking layer). The EL layer may further contain one or both of a bipolar substance and a TADF material.

Either a low molecular compound or a high molecular compound can be used for the light-emitting element, and an inorganic compound may also be included. Each of the layers included in the light-emitting element can be formed by an evaporation method (including a vacuum evaporation method), a transfer method, a printing method, an inkjet method, a coating method, or the like.

For the light-emitting element, a single structure (a structure including only one light-emitting unit) or a tandem structure (a structure including a plurality of light-emitting units) may be employed. The light-emitting unit includes at least one light-emitting layer. In a tandem structure, a plurality of light-emitting units are connected in series with a charge-generation layer therebetween. The charge-generation layer has a function of injecting electrons into one of the two light-emitting units and injecting holes into the other when voltage is applied between the pair of electrodes. The tandem structure enables a light-emitting element capable of high-luminance light emission. Furthermore, the amount of current needed for obtaining a predetermined luminance can be smaller in a tandem structure than in a single structure; thus, a tandem structure enables higher reliability. The tandem structure can be referred to as a stack structure.

In the case of using a light-emitting element having a tandem structure in FIG. 42A, it is preferable that the EL layer 113R include a plurality of light-emitting units emitting red light, the EL layer 113G include a plurality of light-emitting units emitting green light, and the EL layer 113B include a plurality of light-emitting units emitting blue light.

A protective layer 131 is provided over the light-emitting elements 130R, 130G, and 130B. The protective layer 131 and the substrate 152 are bonded to each other with an adhesive layer 142 therebetween. The substrate 152 is provided with a light-blocking layer 117. For example, a solid sealing structure or a hollow sealing structure can be employed to seal the light-emitting elements. In FIG. 42A, a solid sealing structure is employed, in which a space between the substrate 152 and the substrate 151 is filled with the adhesive layer 142. Alternatively, a hollow sealing structure may be employed, in which the space is filled with an inert gas (nitrogen, argon, or the like). Here, the adhesive layer 142 may be provided not to overlap with the light-emitting element. The space may be filled with a resin different from that of the frame-like adhesive layer 142.

The protective layer 131 is provided at least in the display portion 162, and preferably provided to cover the entire display portion 162. The protective layer 131 is preferably provided to cover not only the display portion 162 but also the connection portion 140 and the circuit portion 164. In addition, the protective layer 131 is preferably provided to extend to the end portion of the display apparatus 50A. Meanwhile, a connection portion 197 has a portion not provided with the protective layer 131 so that the FPC 172 and a conductive layer 166 are electrically connected to each other.

By providing the protective layer 131 over the light-emitting elements 130R, 130G, and 130B, the reliability of the light-emitting elements can be increased.

The protective layer 131 can have either a single-layer structure or a stacked-layer structure of two or more layers. There is no limitation on the conductivity of the protective layer 131. As the protective layer 131, at least one kind of an insulating film, a semiconductor film, and a conductive film can be used.

The protective layer 131 including an inorganic film can inhibit deterioration of the light-emitting elements by preventing oxidation of the common electrode 115 and inhibiting entry of impurities (moisture, oxygen, and the like) into the light-emitting elements, for example; thus, the reliability of the display apparatus can be improved.

An inorganic insulating film can be used as the protective layer 131. Examples of a material that can be used for the inorganic insulating film include an oxide, a nitride, an oxynitride, and a nitride oxide. Specific examples of these inorganic insulating films are as described above. In particular, the protective layer 131 preferably includes a nitride or a nitride oxide, and further preferably includes a nitride.

An inorganic film containing ITO, In—Zn oxide, Ga—Zn oxide, Al—Zn oxide, IGZO, or the like can also be used as the protective layer 131. The inorganic film preferably has high resistance, specifically, higher resistance than the common electrode 115. The inorganic film may further contain nitrogen.

When light emitted from the light-emitting element is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (water, oxygen, and the like) to the EL layer side.

Furthermore, the protective layer 131 may include an organic film. For example, the protective layer 131 may include both an organic film and an inorganic film. Examples of an organic film that can be used for the protective layer 131 include organic insulating films that can be used for the insulating layer 235.

The connection portion 197 is provided in a region of the substrate 151 not overlapping with the substrate 152. In the connection portion 197, the conductive layer 165 is electrically connected to the FPC 172 through the conductive layer 166 and a connection layer 242. The conductive layer 165 can be formed by processing the conductive film which is the same as that for the conductive layer 112b, for example. The conductive layer 166 can be formed by processing the conductive film which is the same as that for the pixel electrodes 111R, 111G, and 111B, for example. A structure similar to that of the connection portion between the pixel electrode and the conductive layer 112b can be applied to the connection portion between the conductive layer 165 and the conductive layer 166. Specifically, FIG. 42A illustrates an example where an opening is provided in the upper layer of the conductive layer 165 and the conductive layer 166 is in contact with the top surface of the conductive layer 165 through the opening. On the top surface of the connection portion 197, the conductive layer 166 is exposed. Thus, the connection portion 197 and the FPC 172 can be electrically connected to each other through the connection layer 242.

The display apparatus 50A has a top-emission structure. Light emitted from the light-emitting element is emitted to the substrate 152 side. For the substrate 152, a material having a high visible-light-transmitting property is preferably used. The pixel electrodes 111R, 111G, and 111B include a material reflecting visible light, and the counter electrode (the common electrode 115) includes a material transmitting visible light.

The light-blocking layer 117 is preferably provided on the surface of the substrate 152 on the substrate 151 side. The light-blocking layer 117 can be provided between adjacent light-emitting elements, in the connection portion 140, and in the circuit portion 164, for example.

A coloring layer such as a color filter may be provided on the surface of the substrate 152 on the substrate 151 side or over the protective layer 131. When the color filter is provided to overlap with the light-emitting element, the color purity of light emitted from the pixel can be increased.

The coloring layer is a colored layer that selectively transmits light in a specific wavelength range and absorbs light in the other wavelength ranges. For example, a red (R) color filter for transmitting light in the red wavelength range, a green (G) color filter for transmitting light in the green wavelength range, a blue (B) color filter for transmitting light in the blue wavelength range, or the like can be used. For each coloring layer, one or more of a metal material, a resin material, a pigment, and a dye can be used. Each coloring layer is formed in a desired position by a printing method, an ink-jet method, an etching method using a photolithography method, or the like.

A variety of optical members can be provided on the outer side of the substrate 152 (the surface opposite to the substrate 151). Examples of the optical members include a polarizing plate, a retardation plate, a light diffusion layer (a diffusion film or the like), an anti-reflective layer, and a light-condensing film. Furthermore, a surface protective layer such as an antistatic film inhibiting the attachment of dust, a water repellent film inhibiting the attachment of stain, a hard coat film inhibiting generation of a scratch caused by the use, or an impact-absorbing layer may be provided on the outer side of the substrate 152. For example, it is preferable to provide, as the surface protective layer, a glass layer or a silica layer (SiOₓ layer) because the surface contamination and generation of a scratch can be inhibited. For the surface protective layer, DLC (diamond-like carbon), aluminum oxide (AlOₓ), a polyester-based material, a polycarbonate-based material, or the like may be used. For the surface protective layer, a material having a high visible-light transmittance is preferably used. For the surface protective layer, a material with high hardness is preferably used.

For each of the substrate 151 and the substrate 152, glass, quartz, ceramics, sapphire, a resin, a metal, an alloy, a semiconductor, or the like can be used. For the substrate on the side from which light from the light-emitting element is extracted, a material transmitting the light is used. When a flexible material is used for each of the substrate 151 and the substrate 152, the flexibility of the display apparatus can be increased and a flexible display can be achieved. Furthermore, a polarizing plate may be used as at least one of the substrate 151 and the substrate 152.

For each of the substrate 151 and the substrate 152, a polyester resin such as polyethylene terephthalate (PET) or polyethylene naphthalate (PEN), a polyacrylonitrile resin, an acrylic resin, a polyimide resin, a polymethyl methacrylate resin, a polycarbonate (PC) resin, a polyether sulfone (PES) resin, a polyamide resin (nylon, aramid, or the like), a poly siloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, or cellulose nanofiber can be used, for example. Glass that is thin enough to have flexibility may be used as at least one of the substrate 151 and the substrate 152.

In the case where a circularly polarizing plate overlaps with the display apparatus, a highly optically isotropic substrate is preferably used as the substrate included in the display apparatus. A highly optically isotropic substrate has a low birefringence (i.e., a small amount of birefringence). Examples of the film having high optical isotropy include a triacetyl cellulose (TAC, also referred to as cellulose triacetate) film, a cycloolefin polymer (COP) film, a cycloolefin copolymer (COC) film, and an acrylic film.

As the adhesive layer 142, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene vinyl acetate) resin. In particular, a material with low moisture permeability, such as an epoxy resin, is preferable. A two-liquid-mixture-type resin may be used. An adhesive sheet or the like may be used.

As the connection layer 242, an anisotropic conductive film (ACF), an anisotropic conductive paste (ACP), or the like can be used.

### Structure Example 2 of Display Apparatus

FIG. 42B illustrates an example of a cross section of the display portion 162 of a display apparatus 50B. The display apparatus 50B is different from the display apparatus 50A mainly in that the subpixels of different colors include respective coloring layers (color filters or the like) and the light-emitting elements sharing the EL layer 113. The structure illustrated in FIG. 42B can be combined with the structure illustrated in FIG. 42A of the region including the FPC 172, the circuit portion 164, the stacked-layer structure from the substrate 151 to the insulating layer 235 in the display portion 162, the connection portion 140, and the end portion. As for the following description of the display apparatus, description of portions similar to those of the above-described display apparatus is omitted in some cases.

The display apparatus 50B illustrated in FIG. 42B includes the light-emitting elements 130R, 130G, and 130B, a coloring layer 132R transmitting red light, a coloring layer 132G transmitting green light, a coloring layer 132B transmitting blue light, and the like.

The light-emitting element 130R includes the pixel electrode 111R, the EL layer 113 over the pixel electrode 111R, and the common electrode 115 over the EL layer 113. Light emitted from the light-emitting element 130R is extracted as red light to the outside of the display apparatus 50B through the coloring layer 132R.

The light-emitting element 130G includes the pixel electrode 111G, the EL layer 113 over the pixel electrode 111G, and the common electrode 115 over the EL layer 113. Light emitted from the light-emitting element 130G is extracted as green light to the outside of the display apparatus 50B through the coloring layer 132G.

The light-emitting element 130B includes the pixel electrode 111B, the EL layer 113 over the pixel electrode 111B, and the common electrode 115 over the EL layer 113. Light emitted from the light-emitting element 130B is extracted as blue light to the outside of the display apparatus 50B through the coloring layer 132B.

The EL layer 113 and the common electrode 115 are shared by the light-emitting elements 130R, 130G, and 130B. The number of manufacturing steps can be smaller in the structure where the EL layer 113 is provided to be shared by the subpixels of different colors than in the structure where the subpixels of different colors are provided with different EL layers.

The light-emitting elements 130R, 130G, and 130B illustrated in FIG. 42B emit white light, for example. When white light emitted from the light-emitting elements 130R, 130G, and 130B passes through the coloring layers 132R, 132G, and 132B, light of desired colors can be obtained.

The light-emitting element emitting white light preferably includes two or more light-emitting layers. When white light emission is obtained using two light-emitting layers, the two light-emitting layers are selected such that emission colors of the light-emitting layers are complementary colors. For example, when an emission color of a first light-emitting layer and an emission color of a second light-emitting layer are complementary colors, the light-emitting element can be configured to emit white light as a whole. In the case where three or more light-emitting layers are used to obtain white light, the light-emitting element can be configured to emit white light as a whole by combining emission colors of the three or more light-emitting layers.

The EL layer 113 preferably includes a light-emitting layer containing a light-emitting substance that emits blue light and a light-emitting layer containing a light-emitting substance that emits visible light with a longer wavelength than blue light, for example. The EL layer 113 preferably includes a light-emitting layer emitting yellow light and a light-emitting layer emitting blue light, for example. Alternatively, the EL layer 113 preferably includes a light-emitting layer emitting red light, a light-emitting layer emitting green light, and a light-emitting layer emitting blue light, for example.

A light-emitting element emitting white light preferably has a tandem structure. Specifically, examples of applicable structures are as follows: a two-unit tandem structure including a light-emitting unit emitting yellow light and a light-emitting unit emitting blue light; a two-unit tandem structure including a light-emitting unit emitting red light and green light and a light-emitting unit emitting blue light; a three-unit tandem structure where a light-emitting unit emitting blue light, a light-emitting unit emitting yellow light, yellow-green light, or green light, and a light-emitting unit emitting blue light are stacked in this order; and a three-unit tandem structure where a light-emitting unit emitting blue light, a light-emitting unit emitting yellow light, yellow-green light, or green light and red light, and a light-emitting unit emitting blue light are stacked in this order. Examples of the number of stacked light-emitting units and the order of colors from the anode side include a two-unit structure of B and Y; a two-unit structure of B and a light-emitting unit X; a three-unit structure of B, Y, and B; and a three-unit structure of B, X, and B. Examples of the number of light-emitting layers stacked in the light-emitting unit X and the order of colors from an anode side include a two-layer structure of R and Y; a two-layer structure of R and G; a two-layer structure of G and R; a three-layer structure of G, R, and G; and a three-layer structure of R, G, and R. Another layer may be provided between two light-emitting layers.

In the case where the light-emitting element configured to emit white light has a microcavity structure, light with a specific wavelength such as red, green, or blue is sometimes intensified and emitted.

Alternatively, the light-emitting elements 130R, 130G, and 130B illustrated in FIG. 42B emit blue light, for example. In this case, the EL layer 113 includes one or more light-emitting layers emitting blue light. In the pixel 230B emitting blue light, blue light emitted from the light-emitting element 130B can be extracted. In each of the pixel 230R emitting red light and the pixel 230G emitting green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. In some cases, part of light emitted from the light-emitting element passes through the color conversion layer without being converted. When light passing through the color conversion layer is extracted through the coloring layer, light other than light of the desired color can be absorbed by the coloring layer, and color purity of light exhibited by the subpixel can be improved.

### Structure Example 3 of Display Apparatus

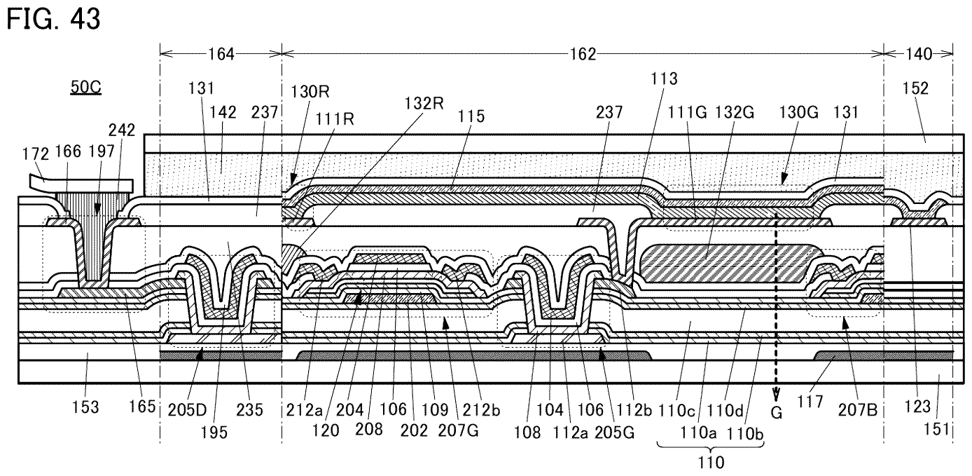

A display apparatus 50C illustrated in FIG. 43 is different from the display apparatus 50B mainly in having a bottom-emission structure.

Light emitted from the light-emitting element is emitted to the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 43 illustrates an example where the light-blocking layers 117 are provided over the substrate 151, an insulating layer 153 is provided over the light-blocking layers 117, and the transistor 205D, the transistor 205R (not illustrated), the transistor 205G, the transistor 207G, and the transistor 207B and the like are provided over the insulating layer 153. In addition, the coloring layer 132R and the coloring layer 132G are provided over the insulating layer 195, and the insulating layer 195 is provided over the coloring layer 132R and the coloring layer 132G.

The light-emitting element 130R overlapping with the coloring layer 132R includes the pixel electrode 111R, the EL layer 113, and the common electrode 115.

The light-emitting element 130G overlapping with the coloring layer 132G includes the pixel electrode 111G, the EL layer 113, and the common electrode 115.

The light-emitting element 130B overlapping with the coloring layer 132B includes the pixel electrode 111B, the EL layer 113, and the common electrode 115.

A material having a high visible-light-transmitting property is used for each of the pixel electrodes 111R, 111G, and 111B. A material reflecting visible light is preferably used for the common electrode 115. In the display apparatus having a bottom-emission structure, a metal or the like having low electric resistivity can be used for the common electrode 115; thus, a voltage drop due to the electric resistance of the common electrode 115 can be inhibited and the display quality can be high.

The transistor of one embodiment of the present invention can be miniaturized and the area occupied by the transistor can be reduced, so that the aperture ratio of the pixel can be increased or the pixel size can be reduced in the display apparatus having a bottom-emission structure.

### Structure Example 4 of Display Apparatus

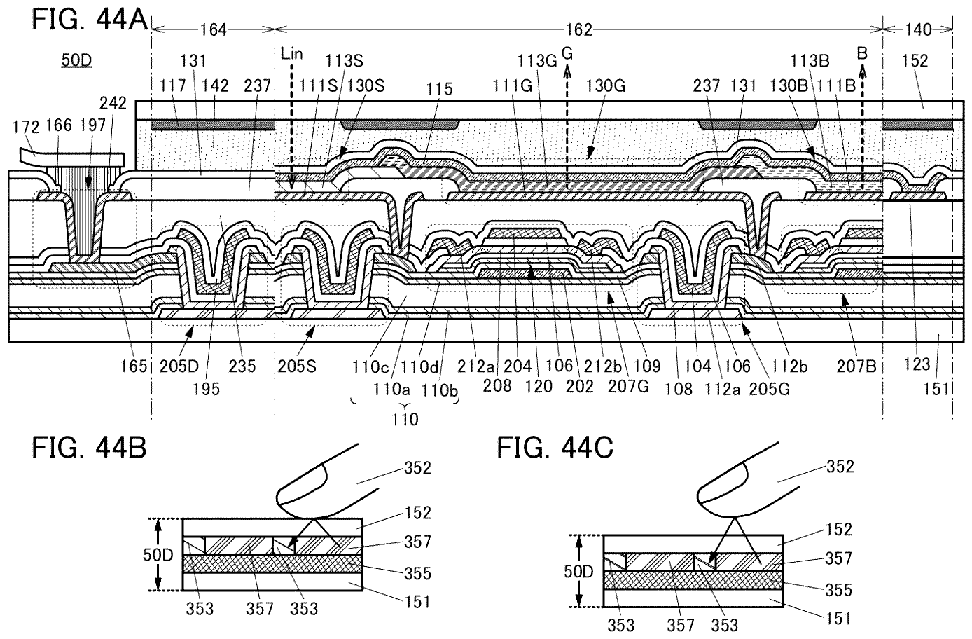

A display apparatus 50D illustrated in FIG. 44A is different from the display apparatus 50A mainly in including a light-receiving element 130S.

The display apparatus 50D includes light-emitting elements and a light-receiving element in a pixel. In the display apparatus 50D, organic EL elements are preferably used as the light-emitting elements and an organic photodiode is preferably used as the light-receiving element. The organic EL elements and the organic photodiode can be formed over the same substrate. Thus, the organic photodiode can be incorporated in a display apparatus including the organic EL elements.

In the display apparatus 50D including light-emitting elements and a light-receiving element in each pixel, the pixel has a light-receiving function; thus, a contact or approach of an object can be detected while an image is displayed. Accordingly, the display portion 162 has one or both of an image capturing function and a sensing function in addition to an image displaying function. For example, all the subpixels included in the display apparatus 50D can display an image; alternatively, some of the subpixels can emit light as a light source, some of the rest of the subpixels can detect light, and the other subpixels can display an image.

Accordingly, a light-receiving portion and a light source do not need to be provided separately from the display apparatus 50D; hence, the number of components of an electronic device can be reduced. For example, a biometric authentication device provided in the electronic device, a capacitive touch panel for scroll operation, or the like is not necessarily provided separately. Thus, with the use of the display apparatus 50D, the electronic device can be provided at lower manufacturing cost.

When the light-receiving elements are used as an image sensor, the display apparatus 50D can capture an image using the light-receiving elements. For example, image capturing for personal authentication with the use of a fingerprint, a palm print, the iris, the shape of a blood vessel (including the shape of a vein and the shape of an artery), a face, or the like is possible by using the image sensor.

The light-receiving element can be used for a touch sensor (also referred to as a direct touch sensor), a contactless sensor (also referred to as a hover sensor, a hover touch sensor, or a touchless sensor), or the like. The touch sensor can detect an object (a finger, a hand, a pen, or the like) when the display apparatus and the object come in direct contact with each other. Furthermore, the contactless sensor can detect an object even when the object is not in contact with the display apparatus.

The light-receiving element 130S includes a pixel electrode 111S over the insulating layer 235, a functional layer 113S over the pixel electrode 111S, and the common electrode 115 over the functional layer 113S. Light Lin enters the functional layer 113S from the outside of the display apparatus 50D.

The pixel electrode 111S is electrically connected to the conductive layer 112b included in a transistor 205S through an opening provided in the insulating layer 106, the insulating layer 195, and the insulating layer 235.

An end portion of the pixel electrode 111S is covered with the insulating layer 237.

The common electrode 115 is a continuous film provided to be shared by the light-receiving element 130S, the light-emitting element 130R (not illustrated), the light-emitting element 130G, and the light-emitting element 130B. The common electrode 115 shared by the light-emitting elements and the light-receiving element is electrically connected to the conductive layer 123 provided in the connection portion 140.

The functional layer 113S includes at least an active layer (also referred to as a photoelectric conversion layer). The active layer includes a semiconductor. Examples of the semiconductor include an inorganic semiconductor such as silicon and an organic semiconductor including an organic compound. This embodiment describes an example where an organic semiconductor is used as the semiconductor included in the active layer. An organic semiconductor is preferably used, in which case the light-emitting layer and the active layer can be formed by the same method (e.g., a vacuum evaporation method) and thus the same manufacturing apparatus can be used.

In addition to the active layer, the functional layer 113S may further include a layer containing a substance with a high hole-transport property, a substance with a high electron-transport property, a substance with a bipolar property, or the like. Without limitation to the above, the functional layer 113S may further include a layer containing a substance with a high hole-injection property, a hole-blocking material, a substance with a high electron-injection property, an electron-blocking material, or the like. The functional layer 113S can be formed using a material that can be used for the light-emitting element.

Either a low molecular compound or a high molecular compound can be used for the light-receiving element, and an inorganic compound may be included. Each of the layers included in the light-receiving element can be formed by an evaporation method (including a vacuum evaporation method), a transfer method, a printing method, an inkjet method, a coating method, or the like.

In the display apparatus 50D illustrated in FIG. 44B and FIG. 44C, a layer 353 including a light-receiving element, a circuit layer 355, and a layer 357 including a light-emitting element are provided between the substrate 151 and the substrate 152.

The layer 353 includes the light-receiving element 130S, for example. The layer 357 includes the light-emitting elements 130R, 130G, and 130B, for example.

The functional layer 355 includes a circuit for driving the light-receiving element and a circuit for driving the light-emitting element. The circuit layer 355 includes the transistors 205R, 205G, and 205B, for example. One or more of a switch, a capacitor, a resistor, a wiring, a terminal, and the like can be provided in the circuit layer 355.

FIG. 44B illustrates an example where the light-receiving element 130S is used as a touch sensor. Light emitted from the light-emitting element in the layer 357 is reflected by a finger 352 that touches the display apparatus 50D as illustrated in FIG. 44B, and the light-receiving element in the layer 353 detects the reflected light. Thus, the touch of the finger 352 on the display apparatus 50D can be detected.

FIG. 44C illustrates an example where the light-receiving element 130S is used as a contactless sensor. Light emitted from the light-emitting element in the layer 357 is reflected by the finger 352 that is close to (i.e., that does not touch) the display apparatus 50D as illustrated in FIG. 44C, and the light-receiving element in the layer 353 detects the reflected light.

### Structure Example 5 of Light-Emitting Apparatus

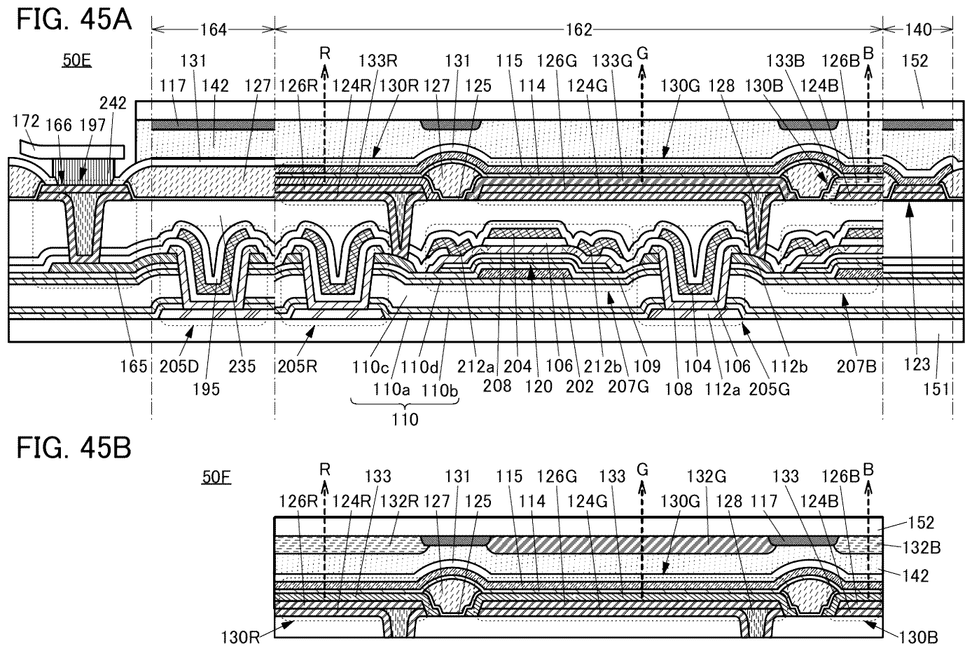

A display apparatus 50E illustrated in FIG. 45A is an example of a display apparatus having an MML (metal maskless) structure. In other words, the display apparatus 50E includes a light-emitting element that is formed without using a fine metal mask.

An island-shaped light-emitting layer of the light-emitting element included in the display apparatus having the MML structure is formed in the following manner: a light-emitting layer is formed on the entire surface, and then, the light-emitting layer is processed by a photolithography method. Accordingly, a high-resolution display apparatus or a display apparatus with a high aperture ratio, which has been difficult to be formed so far, can be obtained. Moreover, light-emitting layers can be formed separately for the respective colors, enabling the display apparatus to perform extremely clear display with high contrast and high display quality. For example, in the case where the display apparatus includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Moreover, manufacturing a device without using a metal mask can eliminate the need for the manufacturing equipment of a metal mask and the cleaning step of the metal mask. Furthermore, for processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of the device.

It is not necessary to conduct a pseudo improvement in resolution by employing a unique pixel arrangement such as PenTile arrangement in a display apparatus employing the MML structure; thus, the display apparatus can achieve high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

Providing a sacrificial layer over the light-emitting layer can reduce damage to the light-emitting layer in the manufacturing process of the display apparatus, resulting in an increase in reliability of the light-emitting element.

Employing a film formation step using an area mask and a processing step using a resist mask enables a light-emitting element to be manufactured by a relatively easy process.

The stacked-layer structure from the substrate 151 to the insulating layer 235 and the stacked-layer structure from the protective layer 131 to the substrate 152 are similar to those in the display apparatus 50A; thus, the description thereof is omitted.

In FIG. 45A, the light-emitting elements 130R, 130G, and 130B are provided over the insulating layer 235.

The light-emitting element 130R includes a conductive layer 124R over the insulating layer 235, a conductive layer 126R over the conductive layer 124R, a layer 133R over the conductive layer 126R, a common layer 114 over the layer 133R, and the common electrode 115 over the common layer 114. The light-emitting element 130R illustrated in FIG. 45A emits red light (R). The layer 133R includes a light-emitting layer emitting red light. In the light-emitting element 130R, the layer 133R and the common layer 114 can be collectively referred to as an EL layer. One or both of the conductive layer 124R and the conductive layer 126R can be referred to as a pixel electrode.

The light-emitting element 130G includes a conductive layer 124G over the insulating layer 235, a conductive layer 126G over the conductive layer 124G, a layer 133G over the conductive layer 126G, the common layer 114 over the layer 133G, and the common electrode 115 over the common layer 114. The light-emitting element 130G illustrated in FIG. 45A emits green light (G). The layer 133G includes a light-emitting layer emitting green light. In the light-emitting element 130G, the layer 133G and the common layer 114 can be collectively referred to as an EL layer. One or both of the conductive layer 124G and the conductive layer 126G can be referred to as a pixel electrode.

The light-emitting element 130B includes a conductive layer 124B over the insulating layer 235, a conductive layer 126B over the conductive layer 124B, a layer 133B over the conductive layer 126B, the common layer 114 over the layer 133B, and the common electrode 115 over the common layer 114. The light-emitting element 130B illustrated in FIG. 45A emits blue light (B). The layer 133B includes a light-emitting layer emitting blue light. In the light-emitting element 130B, the layer 133B and the common layer 114 can be collectively referred to as an EL layer. One or both of the conductive layer 124B and the conductive layer 126B can be referred to as a pixel electrode.

In this specification and the like, in the EL layers included in the light-emitting elements, the island-shaped layer provided in each light-emitting element is referred to as the layer 133B, the layer 133G, or the layer 133R, and the layer shared by the plurality of light-emitting elements is referred to as the common layer 114. In this specification and the like, the layer 133R, the layer 133G, and the layer 133B are sometimes referred to as island-shaped EL layers, EL layers formed in island shapes, or the like, in which case the common layer 114 is not included. The light-emitting elements formed without using a metal mask do not necessarily include a common layer, and all the layers included in the EL layer may be formed in island shapes.

The layer 133R, the layer 133G, and the layer 133B are separated from one another. When the EL layer is provided to have an island shape for each light-emitting element, a leakage current between adjacent light-emitting elements can be inhibited. This can prevent unintended light emission due to crosstalk, so that a display apparatus with extremely high contrast can be obtained.

Although the layers 133R, 133G, and 133B have the same thickness in FIG. 45A, the present invention is not limited thereto. The layers 133R, 133G, and 133B may have different thicknesses.

The conductive layer 124R is electrically connected to the conductive layer 112b included in the transistor 205R through an opening provided in the insulating layer 106, the insulating layer 195, and the insulating layer 235. Similarly, the conductive layer 124G is electrically connected to the conductive layer 112b included in the transistor 205G and the conductive layer 124B is electrically connected to the conductive layer 112b included in the transistor 205B.

The conductive layers 124R, 124G, and 124B are formed to cover the openings provided in the insulating layer 235. A layer 128 is embedded in each of the depressed portions of the conductive layers 124R, 124G, and 124B.

The layer 128 has a planarization function for the depressed portions of the conductive layers 124R, 124G, and 124B. The conductive layers 126R, 126G, and 126B electrically connected to the conductive layers 124R, 124G, and 124B, respectively, are provided over the conductive layers 124R, 124G, and 124B and the layer 128. Thus, regions overlapping with the depressed portions of the conductive layers 124R, 124G, and 124B can also be used as the light-emitting regions, increasing the aperture ratio of the pixels. For each of the conductive layer 124R and the conductive layer 126R, a conductive layer functioning as a reflective electrode is preferably used.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. For the layer 128, an organic insulating material that can be used for the insulating layer 237 can be used, for example.

Although FIG. 45A illustrates an example where the top surface of the layer 128 includes a flat portion, the shape of the layer 128 is not particularly limited. The top surface of the layer 128 may include at least one of a convex surface, a concave surface, and a flat surface.

The level of the top surface of the layer 128 and the level of the top surface of the conductive layer 124R may be the same or substantially the same, or may be different from each other. For example, the level of the top surface of the layer 128 may be either lower or higher than the level of the top surface of the conductive layer 124R.

An end portion of the conductive layer 126R may be aligned with an end portion of the conductive layer 124R or may cover the side surface of the end portion of the conductive layer 124R. The end portions of the conductive layer 124R and the conductive layer 126R each preferably have a tapered shape. Specifically, the end portions of the conductive layer 124R and the conductive layer 126R each preferably have a tapered shape with a taper angle greater than 0° and less than 90°. In the case where the end portion of the pixel electrode has a tapered shape, the layer 133R provided along the side surface of the pixel electrode has an inclined portion. When the side surface of the pixel electrode has a tapered shape, coverage with an EL layer provided along the side surface of the pixel electrode can be favorable.

Since the conductive layers 124G and 126G and the conductive layers 124B and 126B are similar to the conductive layers 124R and 126R, the detailed description thereof is omitted.

The top surface and the side surface of the conductive layer 126R are covered with the layer 133R. Similarly, the top surface and the side surface of the conductive layer 126G are covered with the layer 133G, and the top surface and the side surface of the conductive layer 126B are covered with the layer 133B. Accordingly, regions provided with the conductive layers 126R, 126G, and 126B can be entirely used as the light-emitting regions of the light-emitting elements 130R, 130G, and 130B, increasing the aperture ratio of the pixels.

The side surface and part of the top surface of each of the layer 133R, the layer 133G, and the layer 133B are covered with insulating layers 125 and 127. The common layer 114 is provided over the layer 133R, the layer 133G, and the layer 133B and the insulating layers 125 and 127, and the common electrode 115 is provided over the common layer 114. The common layer 114 and the common electrode 115 are each a continuous film provided to be shared by the plurality of light-emitting elements.

In FIG. 45A, the insulating layer 237 illustrated in FIG. 42A or the like is not provided between the conductive layer 126R and the layer 133R. That is, an insulating layer (also referred to as a partition wall, a bank, a spacer, or the like) in contact with the pixel electrode and covering an end portion of the top surface of the pixel electrode is not provided in the display apparatus 50E. Thus, the distance between adjacent light-emitting elements can be extremely short. Accordingly, the display apparatus can have high resolution or high definition. In addition, a mask (e.g., a photomask) for forming the insulating layer is not needed, which leads to a reduction in manufacturing cost of the display apparatus.

As described above, the layer 133R, the layer 133G, and the layer 133B each include the light-emitting layer. The layer 133R, the layer 133G, and the layer 133B each preferably include the light-emitting layer and a carrier-transport layer (an electron-transport layer or a hole-transport layer) over the light-emitting layer. Alternatively, the layer 133R, the layer 133G, and the layer 133B each preferably include the light-emitting layer and a carrier-blocking layer (a hole-blocking layer or an electron-blocking layer) over the light-emitting layer. Alternatively, the layer 133R, the layer 133G, and the layer 133B each preferably include the light-emitting layer, the carrier-blocking layer over the light-emitting layer, and the carrier-transport layer over the carrier-blocking layer. Since surfaces of the layer 133R, the layer 133G, and the layer 133B are exposed in the manufacturing process of the display apparatus, providing one or both of the carrier-transport layer and the carrier-blocking layer over the light-emitting layer inhibits the light-emitting layer from being exposed on the outermost surface, so that damage to the light-emitting layer can be reduced. Thus, the reliability of the light-emitting element can be increased.

The common layer 114 includes, for example, an electron-injection layer or a hole-injection layer. Alternatively, the common layer 114 may include a stack of an electron-transport layer and an electron-injection layer, or may include a stack of a hole-transport layer and a hole-injection layer. The common layer 114 is shared by the light-emitting elements 130R, 130G, and 130B.

The side surfaces of the layer 133R, the layer 133G, and the layer 133B are each covered with the insulating layer 125. The insulating layer 127 covers the side surfaces of the layer 133R, the layer 133G, and the layer 133B with the insulating layer 125 therebetween.

The side surfaces (and part of the top surfaces) of the layer 133R, the layer 133G, and the layer 133B are covered with at least one of the insulating layer 125 and the insulating layer 127, so that the common layer 114 (or the common electrode 115) can be inhibited from being in contact with the side surfaces of the pixel electrodes and the layers 133R, 133G, and 133B, leading to inhibition of a short circuit of the light-emitting elements. Thus, the reliability of the light-emitting element can be increased.

The insulating layer 125 preferably includes regions in contact with the side surfaces of the layer 133R, the layer 133G, and the layer 133B. The insulating layer 125 in contact with the layer 133R, the layer 133G, and the layer 133B can prevent film separation of the layer 133R, the layer 133G, and the layer 133B, whereby the reliability of the light-emitting element can be increased.

The insulating layer 127 is provided over the insulating layer 125 to fill a depressed portion of the insulating layer 125. The insulating layer 127 preferably covers at least part of the side surface of the insulating layer 125.

The insulating layer 125 and the insulating layer 127 can fill a gap between adjacent island-shaped layers, whereby unevenness with a large level difference on the formation surface of the layers (e.g., the carrier-injection layer and the common electrode) provided over the island-shaped layers can be reduced and higher flatness can be obtained. Consequently, coverage with the carrier-injection layer, the common electrode, and the like can be improved.

The common layer 114 and the common electrode 115 are provided over the layer 133R, the layer 133G, the layer 133B, the insulating layer 125, and the insulating layer 127. Before the insulating layer 125 and the insulating layer 127 are provided, there is a step due to a region where the pixel electrode and the island-shaped EL layer are provided and a region where neither the pixel electrode nor the island-shaped EL layer is provided (a region between the light-emitting elements). In the display apparatus of one embodiment of the present invention, the step can be reduced with the insulating layer 125 and the insulating layer 127, and the coverage with the common layer 114 and the common electrode 115 can be improved. Thus, connection defects caused by step disconnection can be inhibited. Alternatively, an increase in electric resistance caused by local thinning of the common electrode 115 due to the step can be inhibited.

The top surface of the insulating layer 127 preferably has a shape with higher flatness. The top surface of the insulating layer 127 may include at least one of a flat surface, a convex surface, and a concave surface. For example, the top surface of the insulating layer 127 preferably has a convex shape with a large radius of curvature.

An inorganic insulating film can be used for the insulating layer 125. Examples of a material that can be used for the inorganic insulating film include an oxide, a nitride, an oxynitride, and a nitride oxide. Specific examples of these inorganic insulating films are as described above. The insulating layer 125 may have a single-layer structure or a stacked-layer structure. In particular, aluminum oxide is preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film formed by an ALD method is used for the insulating layer 125, the insulating layer 125 having few pinholes and an excellent function of protecting the EL layer can be formed. The insulating layer 125 may have a stacked-layer structure of a film formed by an ALD method and a film formed by a sputtering method. The insulating layer 125 may have a stacked-layer structure of an aluminum oxide film formed by an ALD method and a silicon nitride film formed by a sputtering method, for example.

The insulating layer 125 preferably has a function of a barrier insulating layer against at least one of water and oxygen. The insulating layer 125 preferably has a function of inhibiting diffusion of at least one of water and oxygen. Alternatively, the insulating layer 125 preferably has a function of capturing or fixing (also referred to as gettering) at least one of water and oxygen.

When the insulating layer 125 has a function of the barrier insulating layer, entry of impurities (typically, at least one of water and oxygen) that may be diffused into the light-emitting elements from the outside can be inhibited. With this structure, a highly reliable light-emitting element and a highly reliable display apparatus can be provided.

The insulating layer 125 preferably has a low impurity concentration. Accordingly, deterioration of the EL layer, which is caused by entry of impurities into the EL layer from the insulating layer 125, can be inhibited. In addition, when the impurity concentration is reduced in the insulating layer 125, a barrier property against at least one of water and oxygen can be increased. For example, the insulating layer 125 preferably has one of a sufficiently low hydrogen concentration and a sufficiently low carbon concentration, desirably has both of them.

The insulating layer 127 provided over the insulating layer 125 has a function of reducing unevenness with a large level difference on the insulating layer 125 formed between adjacent light-emitting elements. In other words, the insulating layer 127 has an effect of improving the flatness of the formation surface of the common electrode 115.

As the insulating layer 127, an insulating layer containing an organic material can be suitably used. As the organic material, a photosensitive organic resin is preferably used, and for example, a photosensitive resin composite including an acrylic resin is preferably used. In this specification and the like, an acrylic resin refers to not only a polymethacrylic acid ester or a methacrylic resin, but also all the acrylic-based polymers in a broad sense in some cases.

For the insulating layer 127, an acrylic resin, a polyimide resin, an epoxy resin, an imide resin, a polyamide resin, a polyimide-amide resin, a silicone resin, a siloxane resin, a benzocyclobutene-based resin, a phenol resin, precursors of these resins, or the like may be used. For the insulating layer 127, an organic material such as polyvinyl alcohol (PVA), polyvinyl butyral, polyvinyl pyrrolidone, polyethylene glycol, polyglycerin, pullulan, water-soluble cellulose, or an alcohol-soluble polyamide resin may be used. A photoresist may be used for the photosensitive resin. As the photosensitive organic resin, either a positive material or a negative material may be used.

For the insulating layer 127, a material absorbing visible light may be used. When the insulating layer 127 absorbs light emitted from the light-emitting element, leakage of light (stray light) from the light-emitting element to an adjacent light-emitting element through the insulating layer 127 can be inhibited. Thus, the display quality of the display apparatus can be improved. Since no polarizing plate is required to improve the display quality of the display apparatus, the weight and thickness of the display apparatus can be reduced.

Examples of the material absorbing visible light include materials including pigment of black or the like, materials including dye, light-absorbing resin materials (e.g., polyimide), and resin materials that can be used for color filters (color filter materials). Using a resin material obtained by stacking or mixing color filter materials of two colors or three or more colors is particularly preferable, in which case the effect of blocking visible light can be enhanced. In particular, mixing color filter materials of three or more colors enables the formation of a black or nearly black resin layer.

### Structure Example 6 of Display Apparatus

FIG. 45B illustrates an example of a cross section of the display portion 162 of a display apparatus 50F. The display apparatus 50F is different from the display apparatus 50E mainly in including coloring layers (color filters or the like). The structure illustrated in FIG. 45B can be combined with the structure of the region including the FPC 172, the circuit portion 164, the stacked-layer structure from the substrate 151 to the insulating layer 235 in the display portion 162, the connection portion 140, and the end portion, which is illustrated in FIG. 45A.

In the display apparatus 50F illustrated in FIG. 45B, the light-emitting elements 130R, 130G, and 130B, the coloring layer 132R transmitting red light, the coloring layer 132G transmitting green light, the coloring layer 132B transmitting blue light, and the like are provided.

Light emitted from the light-emitting element 130R is extracted as red light to the outside of the display apparatus 50F through the coloring layer 132R. Similarly, light emitted from the light-emitting element 130G is extracted as green light to the outside of the display apparatus 50F through the coloring layer 132G. Light emitted from the light-emitting element 130B is extracted as blue light to the outside of the display apparatus 50F through the coloring layer 132B.

The light-emitting elements 130R, 130G, and 130B each include the layer 133. These three layers 133 are formed using the same material in the same step. The three layers 133 are separated from each other. When the EL layer is provided to have an island shape for each light-emitting element, a leakage current between adjacent light-emitting elements can be inhibited. This can prevent unintended light emission due to crosstalk, so that a display apparatus with extremely high contrast can be obtained.

The light-emitting elements 130R, 130G, and 130B illustrated in FIG. 45B emit white light, for example. When white light emitted from the light-emitting elements 130R, 130G, and 130B passes through the coloring layers 132R, 132G, and 132B, light of desired colors can be obtained.

Alternatively, the light-emitting elements 130R, 130G, and 130B illustrated in FIG. 45B emit blue light, for example. In this case, the layer 133 includes one or more light-emitting layers emitting blue light. In the pixel 230B emitting blue light, blue light emitted from the light-emitting element 130B can be extracted. In each of the pixel 230R emitting red light and the pixel 230G emitting green light, a color conversion layer is provided between the light-emitting element 130R or the light-emitting element 130G and the substrate 152 so that blue light emitted from the light-emitting element 130R or the light-emitting element 130G is converted into light with a longer wavelength, whereby red light or green light can be extracted. Furthermore, it is preferable that over the light-emitting element 130R, the coloring layer 132R be provided between the color conversion layer and the substrate 152 and over the light-emitting element 130G, the coloring layer 132G be provided between the color conversion layer and the substrate 152. When light passing through the color conversion layer is extracted through the coloring layer, light other than light of the desired color can be absorbed by the coloring layer, and color purity of light exhibited by the subpixel can be improved.

### Structure Example 7 of Display Apparatus

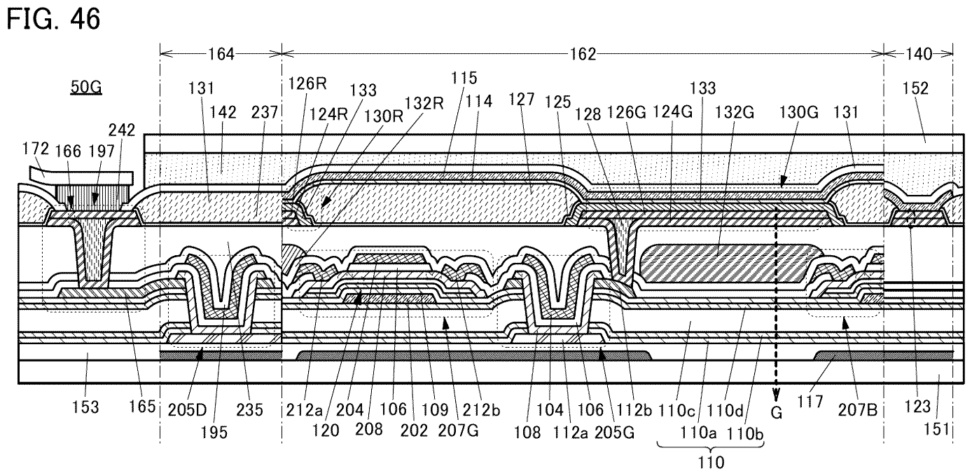

A display apparatus 50G illustrated in FIG. 46 is different from the display apparatus 50F mainly in having a bottom-emission structure.

Light emitted from the light-emitting element is emitted to the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor. FIG. 46 illustrates an example where the light-blocking layers 117 are provided over the substrate 151, the insulating layer 153 is provided over the light-blocking layers 117, and the transistor 205D, the transistor 205R (not illustrated), the transistor 205G, the transistor 205B, and the like are provided over the insulating layer 153. In addition, the coloring layer 132R, the coloring layer 132G, and the coloring layer 132B are provided over the insulating layer 195 and the insulating layer 235 is provided over the coloring layer 132R, the coloring layer 132G, and the coloring layer 132B.

The light-emitting element 130R overlapping with the coloring layer 132R includes the conductive layer 124R, the conductive layer 126R, the layer 133, the common layer 114, and the common electrode 115.

The light-emitting element 130G overlapping with the coloring layer 132G includes the conductive layer 124G, the conductive layer 126G, the layer 133, the common layer 114, and the common electrode 115.

The light-emitting element 130B overlapping with the coloring layer 132B includes the conductive layer 124B, the conductive layer 126B, the layer 133, the common layer 114, and the common electrode 115.

A material having a high visible-light-transmitting property is used for each of the conductive layers 124R, 124G, 124B, 126R, 126G, and 126B. A material reflecting visible light is preferably used for the common electrode 115. In the display apparatus having a bottom-emission structure, a metal or the like having low electric resistivity can be used for the common electrode 115; thus, a voltage drop due to the electric resistance of the common electrode 115 can be inhibited and the display quality can be high.

The transistor of one embodiment of the present invention can be miniaturized and the area occupied by the transistor can be reduced, so that the aperture ratio of the pixel can be increased or the pixel size can be reduced in the display apparatus having a bottom-emission structure.

This embodiment can be combined with the other embodiments as appropriate.

### Embodiment 4

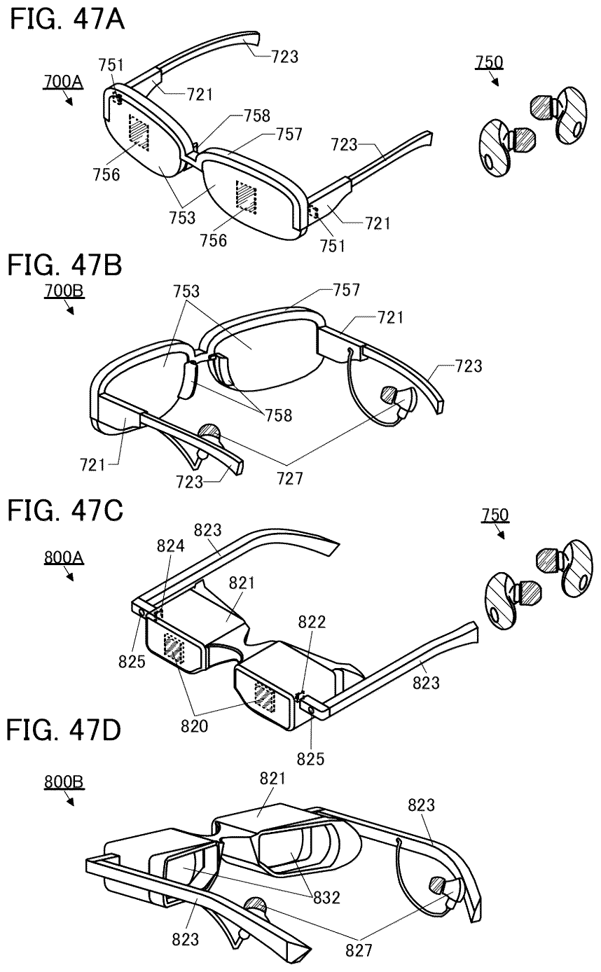

In this embodiment, electronic devices of one embodiment of the present invention will be described with reference to FIG. 47 to FIG. 49.

Electronic devices of this embodiment each include the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic device include a digital camera, a digital video camera, a digital photo frame, a mobile phone, a portable game console, a portable information terminal, and an audio reproducing device, in addition to electronic devices with a relatively large screen, such as a television device, a desktop or laptop computer, a monitor of a computer or the like, digital signage, and a large game machine such as a pachinko machine.

In particular, the display apparatus of one embodiment of the present invention can have high resolution, and thus can be suitably used for an electronic device having a relatively small display portion. Examples of such an electronic device include watch-type and bracelet-type information terminals (wearable devices) and wearable devices that can be worn on a head, such as a VR device like a head-mounted display, a glasses-type AR device, and an MR device.

The definition of the display apparatus of one embodiment of the present invention is preferably as high as HD (number of pixels: 1280×720), FHD (number of pixels: 192×1080), WQHD (number of pixels: 256×1440), WQXGA (number of pixels: 256×1600), 4K (number of pixels: 3840×2160), or 8K (number of pixels: 7680×4320). In particular, the definition is preferably 4K, 8K, or higher. The pixel density (resolution) of the display apparatus of one embodiment of the present invention is preferably higher than or equal to 100 ppi, further preferably higher than or equal to 300 ppi, further preferably higher than or equal to 500 ppi, further preferably higher than or equal to 1000 ppi, still further preferably higher than or equal to 2000 ppi, still further preferably higher than or equal to 3000 ppi, still further preferably higher than or equal to 5000 ppi, yet further preferably higher than or equal to 7000 ppi. The use of the display apparatus having one or both of such high definition and high resolution can further increase realistic sensation, sense of depth, and the like. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device of this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays).

The electronic device of this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of a wearable device that can be worn on a head are described with reference to FIG. 47A to FIG. 47D. These wearable devices have at least one of a function of displaying AR contents, a function of displaying VR contents, a function of displaying SR contents, and a function of displaying MR contents. The electronic device having a function of displaying contents of at least one of AR, VR, SR, MR, and the like enables a user to feel a higher sense of immersion.

An electronic device 700A illustrated in FIG. 47A and an electronic device 700B illustrated in FIG. 47B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758. Note that the display panels 751 are omitted in FIG. 47B.

The display apparatus of one embodiment of the present invention can be used for the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Instead of the wireless communication device or in addition to the wireless communication device, a connector to which a cable for supplying a video signal and a power supply potential can be connected may be provided.

The electronic device 700A and the electronic device 700B are each provided with a battery (not illustrated) so that they can be charged wirelessly and/or by wire.

A touch sensor module may be provided in the housing 721. The touch sensor module has a function of detecting touch on the outer surface of the housing 721. A tap operation or a slide operation, for example, by the user can be detected with the touch sensor module, whereby a variety of processing can be executed. For example, processing such as a pause or a restart of a moving image can be executed by a tap operation, and processing such as fast-forward and fast-rewind can be executed by a slide operation. The touch sensor module is provided in each of two housings 721, whereby the range of the operation can be increased.

A variety of touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion element can be used as a light-receiving element. One or both of an inorganic semiconductor and an organic semiconductor can be used for an active layer of the photoelectric conversion element.

An electronic device 800A illustrated in FIG. 47C and an electronic device 800B illustrated in FIG. 47D each include a pair of display portions 820, a housing 821, a communication portion 822, a pair of wearing portions 823, a control portion 824, a pair of image capturing portions 825, and a pair of lenses 832. Note that the display portions 820, the communication portion 822, and the image capturing portions 825 are omitted in FIG. 47D.

The display apparatus of one embodiment of the present invention can be used for the display portions 820. Thus, the electronic device can perform display with extremely high resolution. This enables a user to feel high sense of immersion.

The display portions 820 are positioned inside the housing 821 to be seen through the lenses 832. When the pair of display portions 820 display different images, three-dimensional display using parallax can be performed.

The electronic device 800A and the electronic device 800B can be regarded as electronic devices for VR. The user wearing the electronic device 800A or the electronic device 800B can see images displayed on the display portions 820 through the lenses 832.

The electronic device 800A and the electronic device 800B preferably include a mechanism for adjusting the lateral positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 47C and the like illustrate examples where the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example of including the image capturing portion 825 is described here, a range sensor (hereinafter, also referred to as a sensing portion) that is capable of measuring a distance from an object may be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic device 800A.

The electronic device 800A and the electronic device 800B may each include an input terminal. To the input terminal, a cable for supplying a video signal from a video output device or the like, power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 47A has a function of transmitting information to the earphones 750 with the wireless communication function. As another example, the electronic device 800A illustrated in FIG. 47C has a function of transmitting information to the earphones 750 with the wireless communication function.

The electronic device may include an earphone portion. The electronic device 700B illustrated in FIG. 47B includes earphone portions 727. For example, the earphone portion 727 and the control portion can be connected to each other by wire. Part of a wiring connecting the earphone portion 727 and the control portion may be positioned inside the housing 721 or the wearing portion 723.

Similarly, the electronic device 800B illustrated in FIG. 47D includes earphone portions 827. For example, the earphone portion 827 and the control portion 824 can be connected to each other by wire. Part of a wiring connecting the earphone portion 827 and the control portion 824 may be positioned inside the housing 821 or the wearing portion 823. The earphone portions 827 and the wearing portions 823 may include magnets. This is preferable because the earphone portions 827 can be fixed to the wearing portions 823 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (the electronic device 700A, the electronic device 700B, and the like) and the goggles-type device (the electronic device 800A, the electronic device 800B, and the like) are preferable as the electronic device of one embodiment of the present invention.

The electronic device of one embodiment of the present invention can transmit information to earphones by wire or wirelessly.

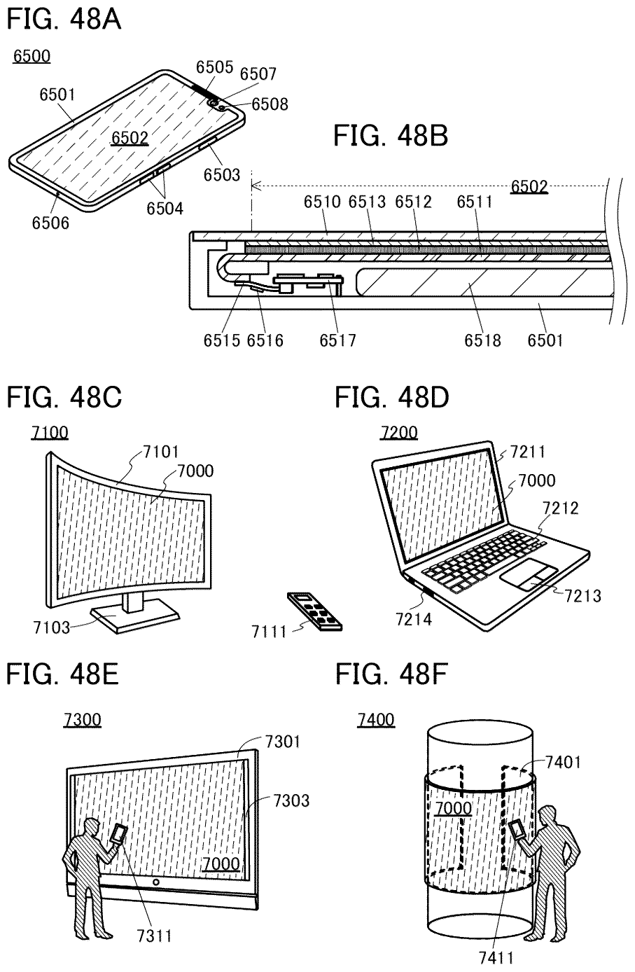

An electronic device 6500 illustrated in FIG. 48A is a portable information terminal that can be used as a smartphone.

The electronic device 6500 includes a housing 6501, a display portion 6502, a power button 6503, buttons 6504, a speaker 6505, a microphone 6506, a camera 6507, and a light source 6508. The display portion 6502 has a touch panel function.

The display apparatus of one embodiment of the present invention can be used for the display portion 6502.

FIG. 48B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be achieved. Since the display panel 6511 is extremely thin, the battery 6518 with high capacity can be mounted without an increase in the thickness of the electronic device. Moreover, part of the display panel 6511 is folded back so that a connection portion with the FPC 6515 is provided on the back side of a pixel portion, whereby an electronic device with a narrow bezel can be achieved.

FIG. 48C illustrates an example of a television device. In a television device 7100, a display portion 7000 is incorporated in a housing 7101. Here, a structure where the housing 7101 is supported by a stand 7103 is illustrated.

The display apparatus of one embodiment of the present invention can be used for the display portion 7000.

Operation of the television device 7100 illustrated in FIG. 48C can be performed with an operation switch provided in the housing 7101 and a separate remote control 7111. Alternatively, the display portion 7000 may include a touch sensor, and the television device 7100 may be operated by touch on the display portion 7000 with a finger or the like. The remote control 7111 may include a display portion for displaying information output from the remote control 7111. With operation keys or a touch panel provided in the remote control 7111, channels and volume can be controlled and videos displayed on the display portion 7000 can be controlled.

Note that the television device 7100 has a structure where a receiver, a modem, and the like are provided. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 48D illustrates an example of a laptop computer. A laptop computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 48E and FIG. 48F illustrate examples of digital signage.

Digital signage 7300 illustrated in FIG. 48E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 48F is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in each of FIG. 48E and FIG. 48F.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 48E and FIG. 48F, it is preferable that the digital signage 7300 or the digital signage 7400 work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

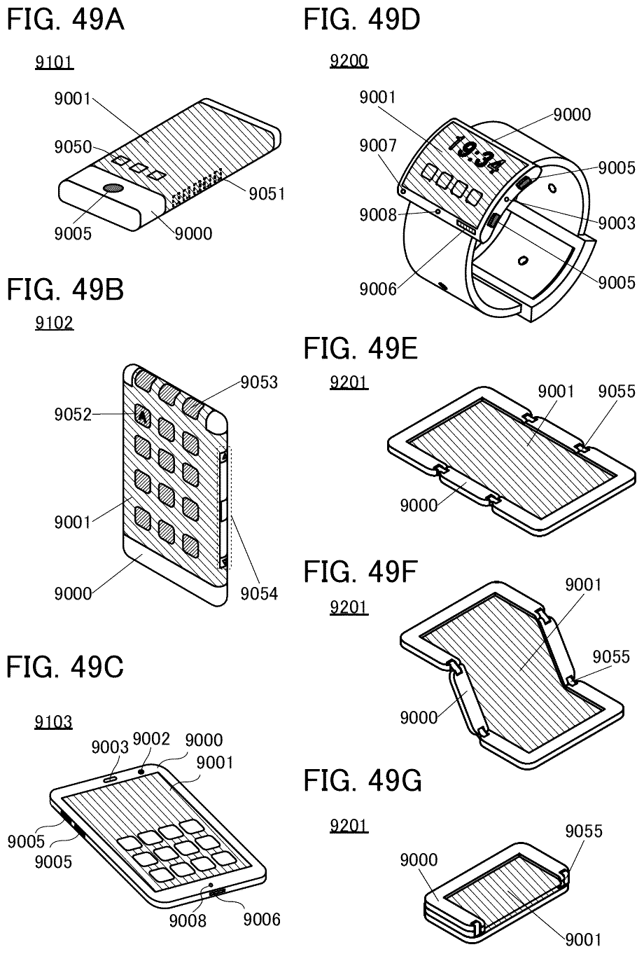

Electronic devices illustrated in FIG. 49A to FIG. 49G include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, power, radiation, flow rate, humidity, gradient, oscillation, a smell, or infrared rays), a microphone 9008, and the like.

The display apparatus of one embodiment of the present invention can be used for the display portion 9001 in FIG. 49A to FIG. 49G.

The electronic devices illustrated in FIG. 49A to FIG. 49G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. The functions of the electronic devices are not limited thereto, and the electronic devices can have a variety of functions. The electronic devices may each include a plurality of display portions. The electronic devices may each be provided with a camera or the like and have a function of taking a still image or a moving image and storing the taken image in a recording medium (an external recording medium or a recording medium incorporated in the camera), a function of displaying the taken image on the display portion, or the like.

The electronic devices illustrated in FIG. 49A to FIG. 49G are described in detail below.

FIG. 49A is a perspective view illustrating a portable information terminal 9101. The portable information terminal 9101 can be used as a smartphone, for example. The portable information terminal 9101 may be provided with the speaker 9003, the connection terminal 9006, the sensor 9007, or the like. The portable information terminal 9101 can display characters and image information on its plurality of surfaces. FIG. 49A illustrates an example where three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 49B is a perspective view illustrating a portable information terminal 9102. The portable information terminal 9102 has a function of displaying information on three or more surfaces of the display portion 9001. Here, an example where information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 49C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the side surface of the housing 9000; and the connection terminal 9006 on the bottom surface of the housing 9000.

FIG. 49D is a perspective view illustrating a watch-type portable information terminal 9200. The portable information terminal 9200 can be used as a Smartwatch (registered trademark), for example. The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 49E to FIG. 49G are perspective views illustrating a foldable portable information terminal 9201. FIG. 49E is a perspective view of an opened state of the portable information terminal 9201, FIG. 49G is a perspective view of a folded state thereof, and FIG. 49F is a perspective view of a state in the middle of change from one of FIG. 49E and FIG. 49G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### EXAMPLE

In this example, a sample including transistors of one embodiment of the present invention was formed, the electrical characteristics of the transistors were evaluated, and the cross-sectional shapes of the transistors were observed.

Here, the transistor 100, which is a VFET, and the transistor 200 and the transistor 200D, which are TGSA transistors, were fabricated. For the structure of the fabricated sample, the description of the transistor 100 and the transistor 200 illustrated in FIG. 1B and the like and the transistor 200D illustrated in FIG. 12B and the like can be referred to. For the fabrication method, the description of Manufacturing method example 1 described in Embodiment 2 can be referred to. Note that the conductive layer 112a of the transistor 100 had the structure illustrated in FIG. 11B.

### <Fabrication of Sample>

First, an approximately 300-nm-thick copper film to be the conductive layer 112a_1 was formed over the substrate 102 by a sputtering method, and then processed to form the conductive layer 112a_1. Next, an approximately 100-nm-thick In—Sn—Si oxide (ITSO) film to be the conductive layer 112a_2 was formed by a sputtering method, and then processed to form the conductive layer 112a_2, whereby the conductive layer 112a was obtained. A glass substrate with a size of 600 mm×720 mm was used as the substrate 102.

Next, an approximately 70-nm-thick silicon nitride film was formed as the insulating film 110af, an approximately 100-nm-thick silicon nitride film was formed as the insulating film 110bf, and an approximately 500-nm-thick silicon oxynitride film was formed as the insulating film 110cf. The insulating film 110af, the insulating film 110bf, and the insulating film 110cf were successively formed by a PECVD method with the same apparatus. Note that silane (SiH₄), nitrogen (N₂), and ammonia (NH₃) were used as film formation gases for forming the insulating film 110af and the insulating film 110bf. The ammonia flow rate ratio at the time of forming the insulating film 110af was made higher than the ammonia flow rate ratio at the time of forming the insulating film 110bf.

Next, an approximately 20-nm-thick IGZO layer was formed as the film 137 over the insulating film 110cf. The film 137 was formed by a sputtering method using an IGZO sputtering target with an atomic ratio of metal elements of In:Ga:Zn=1:1:1.

Then, heat treatment was performed at 250° C. in a dry air atmosphere for one hour. An oven apparatus was used for the heat treatment.

Next, the film 137 was removed. The film 137 was removed by a wet etching method.

Next, an approximately 50-nm-thick silicon nitride film was formed as the insulating film 110df over the insulating film 110cf.

Next, an approximately 100-nm-thick In—Sn—Si oxide (ITSO) film was formed over the insulating film 110df by a sputtering method, and then processed to obtain the conductive layer 202. Here, the conductive layer 202 was formed for the transistor 200, and the conductive layer 202 was not formed for the transistor 200D.

Next, an approximately 120-nm-thick silicon nitride film was formed as the insulating film 109f to be the insulating layer 109 over the insulating film 110df and the conductive layer 202 by a plasma CVD method.

Then, an approximately 100-nm-thick In—Sn—Si oxide (ITSO) film was formed as the conductive film 112bf over the insulating film 109f by a sputtering method.

Subsequently, the conductive film 112bf was processed to obtain the conductive layer 112B.

Next, the insulating film 120af and the insulating film 120bf were formed over the insulating film 109f and the conductive layer 112B by a plasma CVD method. An approximately 60-nm-thick silicon nitride film was formed as the insulating film 120af, and an approximately 50-nm-thick silicon oxynitride film was formed as the insulating film 120bf.

Note that silane (SiH₄), nitrogen (N₂), and ammonia (NH₃) were used as film formation gases for forming the insulating film 110df, the insulating film 109f, and the insulating film 120af. The ammonia flow rate ratio at the time of forming the insulating film 109f was made higher than the ammonia flow rate ratio at the time of forming the insulating film 110df. The ammonia flow rate ratio at the time of forming the insulating film 109f was made higher than the ammonia flow rate ratio at the time of forming the insulating film 120af.

Next, the insulating film 120af and the insulating film 120bf were processed, whereby the insulating layer 120 including the insulating layer 120a and the insulating layer 120b was obtained.

Next, the conductive layer 112B in a region overlapping with the conductive layer 112a was removed to form the conductive layer 112b including the opening 143, and the insulating film 110af, the insulating film 110bf, the insulating film 110cf, the insulating film 110df, and the insulating film 109f in a region overlapping with the conductive layer 112a were removed to form the insulating layer 110 and the insulating layer 109 including the opening 141. The conductive layer 112B was removed by a wet etching method. The insulating film 110af, the insulating film 110bf, the insulating film 110cf, the insulating film 110df, and the insulating film 109f were removed by a dry etching method. The top surface shapes of the opening 141 and the opening 143 were circles.

Next, as the metal oxide film 108f, an approximately 20-nm-thick metal oxide film was formed to cover the opening 141 and the opening 143. The metal oxide film was formed by a sputtering method using an IGZO sputtering target with an atomic ratio of metal elements of In:Ga:Zn=1:1:1.

Then, heat treatment was performed at 340° C. in a dry air atmosphere for two hours. An oven apparatus was used for the heat treatment.

Then, the metal oxide film 108f was processed to obtain the semiconductor layer 108 and the semiconductor layer 208.

Subsequently, as the insulating film 106f, an approximately 70-nm-thick silicon oxynitride film was formed by a plasma CVD method.

Then, heat treatment was performed at 340° C. in a dry air atmosphere for one hour. An oven apparatus was used for the heat treatment.

Next, the insulating film 106f in regions overlapping with the semiconductor layer 208 was removed to form the opening 147a and the opening 147b.

Next, a conductive film to be the conductive layer 104, the conductive layer 204, the conductive layer 212a, and the conductive layer 212b was formed. As the conductive film, an approximately 50-nm-thick titanium film, an approximately 400-nm-thick aluminum film, and an approximately 50-nm-thick titanium film were formed in this order by a sputtering method. After that, the conductive film was processed to obtain the conductive layer 104, the conductive layer 204, the conductive layer 212a, and the conductive layer 212b.

Then, boron was supplied as an impurity element. A plasma ion doping method was used for the supply treatment. A B₂H₆ gas was used as a gas for supplying boron. Through this supply treatment, the regions 208D were formed in the regions of the semiconductor layer 208 overlapping with none of the conductive layer 204, the conductive layer 212a, the conductive layer 212b, and the insulating layer 106, and the regions 208L were formed in the regions of the semiconductor layer 208 overlapping with none of the conductive layer 204, the conductive layer 212a, and the conductive layer 212b and overlapping with the insulating layer 106.

Thus, a transistor corresponding to the transistor 100 and the transistor 200 was formed.

Next, as the insulating layer 195, an approximately 300-nm-thick silicon nitride oxide film was formed by a plasma CVD method.

Then, an approximately 1.5-μm-thick polyimide film was formed as a protective layer.

Then, heat treatment was performed at 250° C. in a nitrogen atmosphere for one hour. An oven apparatus was used for the heat treatment.

Through the above process, the sample was obtained.

### <STEM Observation>

Next, the sample was thinned by focused ion beam (FIB) and a cross section was observed with a scanning transmission electron microscope (by STEM: Scanning Transmission Electron Microscopy).

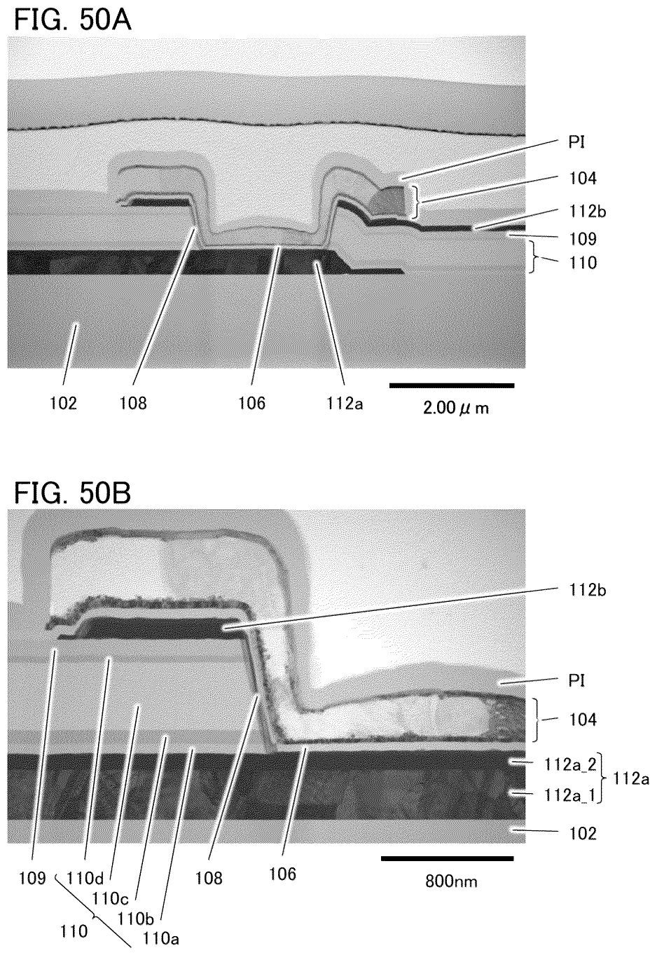

FIG. 50A and FIG. 50B are cross-sectional STEM images of the transistor 100. FIG. 50A is a transmitted electron (TE) image at a magnification of 15000 times. FIG. 50B is a transmitted electron (TE) image at a magnification of 40000 times, which is an enlarged view of the opening 141, the opening 143, and the vicinity of the openings.

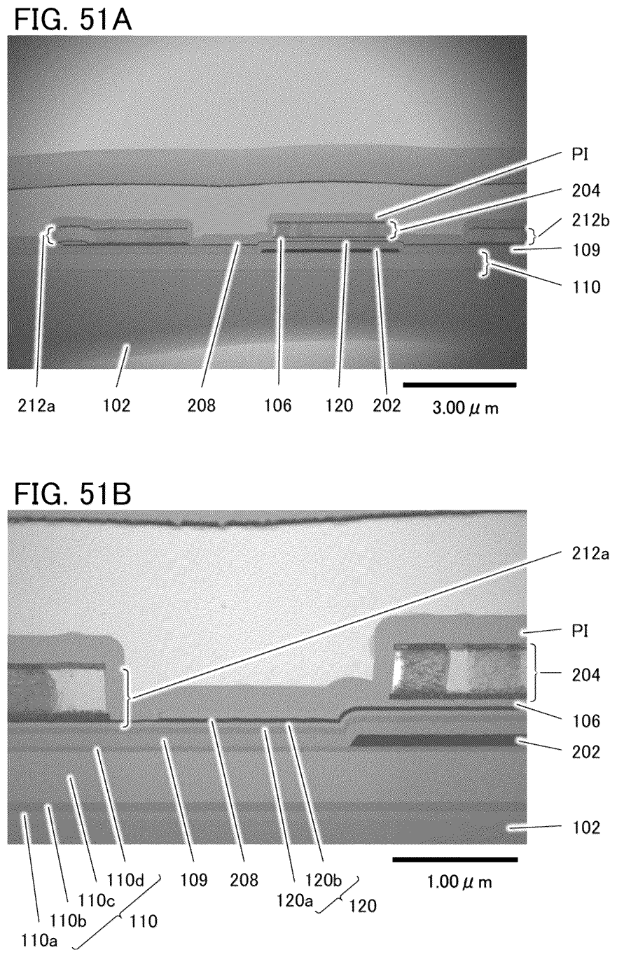

FIG. 51A and FIG. 51B are cross-sectional STEM images of the transistor 200. FIG. 51A is a transmitted electron (TE) image at a magnification of 9000 times. FIG. 51B is a transmitted electron (TE) image at a magnification of 30000 times, which is an enlarged view of the conductive layer 204, the conductive layer 202, the conductive layer 212a, and the vicinity of the conductive layers.

As shown in FIG. 50A to FIG. 51B, both the transistor 100 and the transistor 200 were found to have favorable cross-sectional shapes.

### <Id-Vg Characteristics>

Then, the Id-Vg characteristics of the transistors of the sample fabricated in the above manner were measured.

For the measurement of the Id-Vg characteristics of the transistors, a voltage applied to the gate electrode (hereinafter also referred to as gate voltage (Vg)) was applied from −10 V to +10 V in increments of 0.1 V. Moreover, a voltage applied to the source electrode (hereinafter also referred to as source voltage (Vs)) was 0 V (comm), and a voltage applied to the drain electrode (hereinafter also referred to as drain voltage (Vd)) was 0.1 V and 5.1 V. In the transistor 200, the back gate electrode (the conductive layer 202) was electrically connected to the source electrode (GND), and the Id-Vg measurement was performed with a gate voltage (Vg) applied to the gate electrode (the conductive layer 204).

As the transistor 100, a transistor with the channel length L100 of approximately 0.5 μm and the channel width W100 of approximately 6.3 μm (the width D141 of the opening 141 of 2.0 μm) was subjected to the measurement. As each of the transistor 200 and the transistor 200D, a transistor with the channel length L200 of approximately 3 μm and the channel width W200 of approximately 3 μm was subjected to the measurement. In the measurement, the number of each kind of transistors was set to 20 in a substrate plane of 600 mm×720 mm.

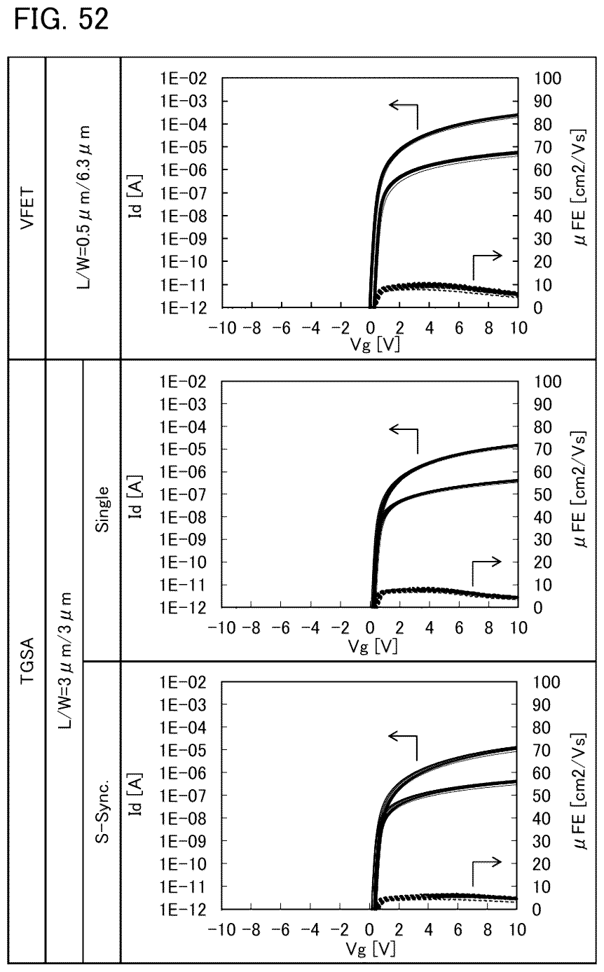

FIG. 52 shows the Id-Vg characteristics. In FIG. 52, transistor conditions are shown on the left side, and the transistor 100, the transistor 200D, and the transistor 200 are denoted by “VFET”, “TGSA, Single”, and “TGSA, S-Sync.”, respectively. In FIG. 52, the horizontal axis represents the gate voltage (Vg), the left vertical axis represents the drain current (Id), and the right vertical axis represents the field-effect mobility (μFE) at a drain voltage (Vd) of 5.1 V. FIG. 52 shows superimposed Id-Vg characteristics of the 20 transistors 100, the 20 transistors 200D, and the 20 transistors 200.

As shown in FIG. 52, it was confirmed that all the transistors achieved all of normally-off characteristics, a high on-state current, and a low off-state current. It was also confirmed that an in-plane variation in electrical characteristics was small. It was confirmed that the transistor 100, which is a VFET, had a higher on-state current than the transistor 200 and the transistor 200D, which are TGSA transistors.

### REFERENCE NUMERALS

ANO: wiring, C11: capacitor, C12: capacitor, C31: capacitor, C41: capacitor, GL: wiring, INV: inverter circuit, L100: channel length, L200: channel length, LAT: latch circuit, LIN: terminal, M11: transistor, M12: transistor, M13: transistor, M14: transistor, M15: transistor, M16: transistor, ROUT: terminal, SL: wiring, SMP: terminal, Tr31: transistor, Tr33: transistor, Tr35: transistor, Tr36: transistor, Tr41: transistor, Tr43: transistor, Tr45: transistor, Tr47: transistor, VCOM: wiring, 10A: semiconductor device, 10B: semiconductor device, 10C: semiconductor device, 10D: semiconductor device, 10E: semiconductor device, 10F: semiconductor device, 10G: semiconductor device, 10H: semiconductor device, 10I: semiconductor device, 10J: semiconductor device, 10: semiconductor device, 50A: display apparatus, 50B: display apparatus, 50C: display apparatus, 50D: display apparatus, 50E: display apparatus, 50F: display apparatus, 50G: display apparatus, 51A: pixel circuit, 51B: pixel circuit, 51: pixel circuit, 52A: transistor, 52B: transistor, 52C: transistor, 53: capacitor, 61: light-emitting device, 100_1: transistor, 100_2: transistor, 100_3: transistor, 100_4: transistor, 100_p: transistor, 100_q: transistor, 100A: transistor, 100B: transistor, 100C: transistor, 100D: transistor, 100E: transistor, 100F: transistor, 100G: transistor, 100: transistor, 102: substrate, 103: conductive layer, 104: conductive layer, 105: insulating layer, 106a: insulating layer, 106b: insulating layer, 106f: insulating film, 106: insulating layer, 108_1: semiconductor layer, 108_2: semiconductor layer, 108_3: semiconductor layer, 108_4: semiconductor layer, 108a: semiconductor layer, 108b: semiconductor layer, 108c: semiconductor layer, 108f: metal oxide film, 108L: region, 108: semiconductor layer, 109f: insulating film, 109: insulating layer, 110a: insulating layer, 110af: insulating film, 110b: insulating layer, 110bf: insulating film, 110c: insulating layer, 110c_1: insulating layer, 110c_2: insulating layer, 110cf: insulating film, 110cf_1: insulating film, 110cf_2: insulating film, 110d: insulating layer, 110df: insulating film, 110: insulating layer, 111B: pixel electrode, 111G: pixel electrode, 111R: pixel electrode, 111S: pixel electrode, 111: pixel electrode, 112a: conductive layer, 112a_1: conductive layer, 112a_2: conductive layer, 112a_3: conductive layer, 112B: conductive layer, 112b: conductive layer, 112bf: conductive film, 112c: conductive layer, 112d: conductive layer, 112e: conductive layer, 112p: conductive layer, 113B: EL layer, 113G: EL layer, 113R: EL layer, 113S: functional layer, 113: EL layer, 114: common layer, 115: common electrode, 117: light-blocking layer, 120a: insulating layer, 120af: insulating film, 120b: insulating layer, 120bf: insulating film, 120: insulating layer, 123: conductive layer, 124B: conductive layer, 124G: conductive layer, 124R: conductive layer, 125: insulating layer, 126B: conductive layer, 126G: conductive layer, 126R: conductive layer, 127: insulating layer, 128: layer, 130B: light-emitting element, 130G: light-emitting element, 130R: light-emitting element, 130S: light-receiving element, 130: light-emitting element, 131: protective layer, 132B: coloring layer, 132G: coloring layer, 132R: coloring layer, 133B: layer, 133G: layer, 133R: layer, 133: layer, 137: film, 139: film, 140: connection portion, 141_1: opening, 141_4: opening, 141: opening, 142: adhesive layer, 143_1: opening, 143_2: opening, 143_3: opening, 143_4: opening, 143: opening, 147a: opening, 147b: opening, 148: opening, 150A: capacitor, 150B: capacitor, 150: capacitor, 151: substrate, 152: substrate, 153: insulating layer, 162: display portion, 164: circuit portion, 165: conductive layer, 166: conductive layer, 172: FPC, 173: IC, 195: insulating layer, 197: connection portion, 200A: transistor, 200B: transistor, 200C: transistor, 200D: transistor, 200E: transistor, 200F: transistor, 200: transistor, 202: conductive layer, 204: conductive layer, 205B: transistor, 205D: transistor, 205G: transistor, 205R: transistor, 205S: transistor, 207B: transistor, 207G: transistor, 208a: semiconductor layer, 208b: semiconductor layer, 208c: semiconductor layer, 208D: region, 208L: region, 208: semiconductor layer, 210: pixel, 212a: conductive layer, 212b: conductive layer, 230B: pixel, 230G: pixel, 230R: pixel, 230: pixel, 231: first driver circuit portion, 232: second driver circuit portion, 233: insulating layer, 234: conductive layer, 235: insulating layer, 236: wiring, 237: insulating layer, 238: wiring, 242: connection layer, 352: finger, 353: layer, 355: circuit layer, 357: layer, 700A: electronic device, 700B: electronic device, 721: housing, 723: wearing portion, 727: earphone portion, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 6500: electronic device, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote control, 7200: laptop computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A semiconductor device comprising:
a first transistor, a second transistor and a first insulating layer,
wherein the first transistor comprises a first conductive layer, a second conductive layer and a first semiconductor layer,
wherein the second transistor comprises a third conductive layer over the first insulating layer, a second insulating layer in contact with a top surface and a side surface of the third conductive layer and a top surface of the first insulating layer, a third insulating layer over the second insulating layer, and a second semiconductor layer over the third insulating layer,
wherein the first insulating layer is over the first conductive layer,
wherein the first insulating layer and the second insulating layer comprise a first opening reaching the first conductive layer,
wherein the second conductive layer is over the second insulating layer,
wherein the second conductive layer comprises a second opening in a region overlapping with the first opening, and
wherein in the first opening and the second opening, the first semiconductor layer is in contact with a top surface of the first conductive layer, a side surface of the first insulating layer, a side surface of the second insulating layer, and a side surface of the second conductive layer.

2. The semiconductor device according to claim 1, wherein the first semiconductor layer comprises a region in contact with a top surface of the second conductive layer.

3. The semiconductor device according to claim 1, wherein the first semiconductor layer is not in contact with the third insulating layer.

4. The semiconductor device according to claim 1, wherein each of the first semiconductor layer and the second semiconductor layer comprises a metal oxide.

5. The semiconductor device according to claim 1,
wherein the first insulating layer comprises a fourth insulating layer and a fifth insulating layer over the fourth insulating layer,
wherein the fourth insulating layer comprises one of an oxide and an oxynitride, and
wherein each of the second insulating layer and the fifth insulating layer comprises one of a nitride and a nitride oxide.

6. The semiconductor device according to claim 5, wherein the second insulating layer comprises a region having a larger amount of hydrogen than the fifth insulating layer.

7. The semiconductor device according to claim 1, further comprising:
a fourth insulating layer,
wherein a top surface of the fourth insulating layer is in contact with a bottom surface of the first conductive layer,
wherein the first insulating layer comprises a fifth insulating layer and a sixth insulating layer over the fifth insulating layer,
wherein the sixth insulating layer comprises an oxide or an oxynitride, and
wherein the fourth insulating layer and the fifth insulating layer each comprise a nitride or a nitride oxide.

8. The semiconductor device according to claim 7, wherein the fourth insulating layer comprises a region having a larger amount of hydrogen than the fifth insulating layer.

9. The semiconductor device according to claim 1, further comprising:
a capacitor,
wherein the capacitor comprises the second conductive layer, the third conductive layer, and the second insulating layer interposed between the second conductive layer and the third conductive layer.

10. A method for manufacturing a semiconductor device, comprising:
forming a first conductive layer;
forming a first insulating film over the first conductive layer;
forming a second conductive layer over the first insulating film;
forming a second insulating film over the first insulating film and the second conductive layer;
forming, over the second insulating film, a third conductive layer comprising a region overlapping with the first conductive layer;
forming, over the second insulating film, a first insulating layer comprising a region overlapping with the second conductive layer;
processing the third conductive layer to form a fourth conductive layer comprising a first opening;
processing the first insulating film and the second insulating film to form a second insulating layer and a third insulating layer that comprise a second opening reaching the first conductive layer;
forming a first semiconductor layer in contact with a top surface of the first conductive layer, a side surface of the second insulating layer, a side surface of the third insulating layer, and a side surface of the fourth conductive layer in the first opening and the second opening and forming, over the first insulating layer, a second semiconductor layer comprising a region overlapping with the second conductive layer;
forming a fourth insulating layer over the first semiconductor layer and the second semiconductor layer; and
forming a fifth conductive layer comprising a region overlapping with the first semiconductor layer and forming a sixth conductive layer comprising a region overlapping with the second semiconductor layer over the fourth insulating layer.
